(19) United States
(12) Patent Application Publication
(10) Pub. No.: US 2024/0306417 A1
(43) Pub. Date: Sep. 12, 2024

(54) ORGANIC ELECTROLUMINESCENT ELEMENT, ORGANIC ELECTROLUMINESCENT DISPLAY DEVICE, AND ELECTRONIC EQUIPMENT

(71) Applicant: IDEMITSU KOSAN CO.,LTD., Chiyoda-ku, Tokyo (JP)

(72) Inventors: Yukitoshi JINDE, Chiyoda-ku (JP); Yuta HIGASHINO, Chiyoda-ku (JP); Hisato MATSUMOTO, Chiyoda-ku (JP); Takushi SHIOMI, Chiyoda-ku (JP)

(73) Assignee: IDEMITSU KOSAN CO.,LTD., Chiyoda-ku, Tokyo (JP)

(21) Appl. No.: 18/568,578

(22) PCT Filed: Jun. 9, 2022
(86) PCT No.: PCT/JP2022/023246

§ 371 Date: Dec. 8, 2023

(30) Foreign Application Priority Data
Jun. 10, 2021 (JP) 2021-097416
Jun. 25, 2021 (JP) 2021-106073

(51) Int. Cl. H10K 50/18; H10K 50/15; H10K 59/35; H10K 85/40; H10K 85/60; H10K 101/20; H10K 102/00

(52) U.S. Cl. CPC H10K 50/181; H10K 50/15; H10K 59/35; H10K 85/40; H10K 85/623; H10K 85/633; H10K 85/636; H10K 85/654; H10K 85/6572; H10K 85/6574; H10K 85/6576; H10K 85/658; H10K 2101/20; H10K 2102/351

(57) ABSTRACT

An organic electroluminescence device includes: an anode; a cathode; an emitting layer disposed between the anode and the cathode; and a first layer disposed between the anode and the emitting layer, in which the emitting layer contains a delayed fluorescent compound, the first layer contains a first compound, an ionization potential of the first compound Ip(HT1) satisfies a numerical formula (Numerical Formula 1), a hole mobility of the first compound μh(HT1) satisfies a numerical formula (Numerical Formula 2), and the first layer has a film thickness D1 of 15 nm or more,

$$Ip ( HT 1 ) \geq 5.7 eV \qquad ( Numerical Formula 1 )$$

$$μ h ( H T 1 ) \geq 1 \times 1 {0}^{- 5} {cm}^{2} / Vs . \qquad ( Numerical Formula 2 )$$

### TECHNICAL FIELD

The present invention relates to an organic electroluminescence device, an organic electroluminescence display device, and an electronic device.

### BACKGROUND ART

When voltage is applied to an organic electroluminescence device (hereinafter, occasionally referred to as “organic EL device”), holes are injected from an anode and electrons are injected from a cathode into an emitting layer. The injected holes and electrons are recombined in the emitting layer to form excitons. Specifically, according to the electron spin statistics theory, singlet excitons and triplet excitons are generated at a ratio of 25%:75%.

A fluorescent organic EL device using light emission from singlet excitons has been applied to a full-color display such as a mobile phone and a television, but an internal quantum efficiency is said to be at a limit of 25%. Studies have thus been made to improve performance of the organic EL device.

For instance, the organic EL device is expected to emit light more efficiently using triplet excitons in addition to singlet excitons. In view of the above, a highly-efficient fluorescent organic EL device using thermally activated delayed fluorescence (hereinafter simply referred to as “delayed fluorescence” in some cases) has been proposed and studied.

A thermally activated delayed fluorescence (TADF) mechanism uses a phenomenon in which inverse intersystem crossing from triplet excitons to singlet excitons thermally occurs when a material having a small energy difference (ΔST) between singlet energy level and triplet energy level is used. Thermally activated delayed fluorescence is explained in “Yuki Hando-tai no Debaisu Bussei (Device Physics of Organic Semiconductors)” (edited by ADACHI Chihaya, published by Kodansha, issued on Apr. 1, 2012, on pages 261-268).

For instance, Patent Literatures 1, 2, and 3 each describe an organic electroluminescence device using a delayed fluorescent compound.

### CITATION LIST

### Patent Literature(s)

Patent Literature 1 International Publication No. WO 2020/241580
Patent Literature 2 International Publication No. WO 2019/013063
Patent Literature 3 US Patent Application Publication No. 2020/0203621

### SUMMARY OF THE INVENTION

### Problem(s) to be Solved by the Invention

There is a demand for further improvement in performance of the organic electroluminescence device to improve performance of an electronic device such as a display.

An object of the invention is to provide an organic eiectroluminescenoe device and an organic electroluminescence display device excellent in performance, specifically, capable of achieving at least one of low voltage, high efficiency, or long lifetime, an electronic device including the organic electroluminescence device, and an electronic device including the organic electroluminescence display device.

### Means for Solving the Problem(s)

According to an aspect of the invention, there is provided an organic electroluminescence device including:
an anode;
a cathode;
an emitting layer disposed between the anode and the cathode, and
a first layer disposed between the anode and the emitting layer, in which
the emitting layer contains a delayed fluorescent compound,
the first layer contains a first compound,
an ionization potential of the first compound Ip(HT1) satisfies a numerical formula (Numerical Formula 1) below,
a hole mobility of the first compound μh(HT1) satisfies a numerical formula (Numerical Formula 2) below, and
the first layer has a film thickness of 15 nm or more.

$$Ip ( HT 1 ) \geq 5.7 eV \qquad ( Numerical Formula 1 )$$

$$μ h ( H T 1 ) \geq 1 \times 1 {0}^{- 5} {cm}^{2} / Vs \qquad ( Numerical Formula 2 )$$

According to another aspect of the invention, there is provided an electronic device including the organic electroluminescence device according to the aspect of the invention described above.

According to still another aspect of the invention, there is provided an organic electroluminescence display device, including:
an anode and a cathode arranged opposite each other;
a blue-emitting organic EL device as a blue pixel;
a green-emitting organic EL device as a green pixel; and
a red-emitting organic EL device as a red pixel, in which
the green pixel includes, as the green-emitting organic EL device, the organic electroluminescence device according to the aspect of the invention described above,
the green-emitting organic EL device includes a green emitting layer as the emitting layer and the first layer disposed between the green emitting layer and the anode,
the blue-emitting organic EL device includes a blue emitting layer disposed between the anode and the cathode and a blue organic layer disposed between the blue emitting layer and the anode, and
the red-emitting organic EL device includes a red emitting layer disposed between the anode and the cathode and a red organic layer disposed between the red emitting layer and the anode.

According to a further aspect of the invention, there is provided an electronic device including the organic electroluminescence display device according to the still another aspect of the invention described above.

According to the aspects of the invention, there can be provided an organic electroluminescence device and an organic electroluminescence display device excellent in performance, specifically, capable of achieving at least one of low voltage, high efficiency, or long lifetime, an electronic device including the organic electroluminescence device, and an electronic device including the organic electroluminescence display device.

### BRIEF EXPLANATION OF DRAWINGS

FIG. 1 schematically depicts an exemplary arrangement of an organic electroluminescence device according to a first exemplary embodiment of the invention.

FIG. 2 schematically depicts an apparatus for measuring transient PL.

FIG. 3 illustrates an example of decay curves of the transient PL.

FIG. 4 illustrates a relationship in energy level and energy transfer between a compound M1 and a compound M2 in an emitting layer of an exemplary organic electroluminescence device according to the first exemplary embodiment of the invention.

FIG. 5 illustrates a relationship in energy level and energy transfer between the compound M1, the compound M2, and a compound M3 in an emitting layer of an exemplary organic electroluminescence device according to a second exemplary embodiment of the invention.

FIG. 6 illustrates a relationship in energy level and energy transfer between the compound M2 and a compound M4 in an emitting layer of an exemplary organic electroluminescence device according to a third exemplary embodiment of the invention.

FIG. 7 schematically depicts an exemplary arrangement of an organic electroluminescence device according to a fourth exemplary embodiment of the invention.

FIG. 8 schematically depicts an exemplary arrangement of an organic eiectroluminescence display device according to a fifth exemplary embodiment of the invention.

FIG. 9 schematically depicts another exemplary arrangement of the organic electroluminescence display device according to the fifth exemplary embodiment of the invention.

### DESCRIPTION OF EMBODIMENT(S)

### Definitions

Herein, a hydrogen atom includes isotope having different numbers of neutrons, specifically, protium, deuterium and tritium.

In chemical formulae herein, it is assumed that a hydrogen atom (i.e. protium, deuterium and tritium) is bonded to each of bondable positions that are not annexed with signs “R” or the like or “D” representing a deuterium.

Herein, the ring carbon atoms refer to the number of carbon atoms among atoms forming a ring of a compound (e.g., a monocyclic compound, fused-ring compound, crosslinking compound, carbon ring compound, and heterocyclic compound) in which the atoms are bonded to each other to form the ring. When the ring is substituted by a substituent(s), carbon atom(s) contained in the substituent(s) is not counted in the ring carbon atoms. Unless otherwise specified, the same applies to the “ring carbon atoms” described later. For instance, a benzene ring has 6 ring carbon atoms, a naphthalene ring has 10 ring carbon atoms, a pyridine ring has 5 ring carbon atoms, and a furan ring has 4 ring carbon atoms. Further, for instance, 9,9-diphenylfiuorenyl group has 13 ring carbon atoms and 9,9′-spirobifluorenyl group has 25 ring carbon atoms.

When a benzene ring is substituted by a substituent in a form of, for instance, an alkyl group, the number of carbon atoms of the alkyl group is not counted in the number of the ring carbon atoms of the benzene ring. Accordingly, the benzene ring substituted by an alkyl group has 6 ring carbon atoms. When a naphthalene ring is substituted by a substituent in a form of, for instance, an alkyl group, the number of carbon atoms of the alkyl group is not counted in the number of the ring carbon atoms of the naphthalene ring. Accordingly, the naphthalene ring substituted by an alkyl group has 10 ring carbon atoms.

Herein, the ring atoms refer to the number of atoms forming a ring of a compound (e.g., a monocyclic compound, fused-ring compound, cross-linking compound, carbon ring compound, and heterocyclic compound) in which the atoms are bonded to each other to form the ring (e.g., monocyclic ring, fused ring, and ring assembly). Atom(s) not forming the ring (e.g., hydrogen atom(s) for saturating the valence of the atom which forms the ring) and atom(s) in a substituent by which the ring is substituted are not counted as the ring atoms. Unless otherwise specified, the same applies to the “ring atoms” described later. For instance, a pyridine ring has 6 ring atoms, a quinazoline ring has 10 ring atoms, and a furan ring has 5 ring atoms. For instance, the number of hydrogen atom(s) bonded to a pyridine ring or the number of atoms forming a substituent is not counted as the pyridine ring atoms. Accordingly, a pyridine ring bonded to a hydrogen atom(s) or a substituent(s) has 6 ring atoms. For instance, the hydrogen atom(s) bonded to carbon atom(s) of a quinazoline ring or the atoms forming a substituent are not counted as the quinazoline ring atoms. Accordingly, a quinazoline ring bonded to hydrogen atom(s) or a substituent(s) has 10 ring atoms.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of the substituted ZZ group. Herein, “YY” is larger than “XX,” “XX” representing an integer of 1 or more and “YY” representing an integer of 2 or more.

Herein, “XX to YY atoms” in the description of “substituted or unsubstituted ZZ group having XX to YY atoms” represent atoms of an unsubstituted ZZ group and does not include atoms of a substituent(s) of the substituted ZZ group. Herein, “YY” is larger than “XX,” “XX” representing an integer of 1 or more and “YY” representing an integer of 2 or more.

Herein, an unsubstituted ZZ group refers to an “unsubstituted ZZ group” in a “substituted or unsubstituted ZZ group,” and a substituted ZZ group refers to a “substituted ZZ group” in a “substituted or unsubstituted ZZ group.”

Herein, the term “unsubstituted” used in a “substituted or unsubstituted ZZ group” means that a hydrogen atom(s) in the ZZ group is not substituted with a substituent(s). The hydrogen atom(s) in the “unsubstituted ZZ group” is protium, deuterium, or tritium.

Herein, the term “substituted” used in a “substituted or unsubstituted ZZ group” means that at least one hydrogen atom in the ZZ group is substituted with a substituent. Similarly, the term “substituted” used in a “BB group substituted by AA group” means that at least one hydrogen atom in the BB group is substituted with the AA group.

### Substituent Mentioned Herein

Substituent mentioned herein will be described below.

An “unsubstituted aryl group” mentioned herein has, unless otherwise specified herein, 6 to 50, preferably 6 to 30, more preferably 6 to 18 ring carbon atoms.

An “unsubstituted heterocyclic group” mentioned herein has, unless otherwise specified herein, 5 to 50, preferably 5 to 30, more preferably 5 to 18 ring atoms.

An “unsubstituted alkyl group” mentioned herein has, unless otherwise specified herein, 1 to 50, preferably 1 to 20, more preferably 1 to 6 carbon atoms.

An “unsubstituted alkenyl group” mentioned herein has, unless otherwise specified herein, 2 to 50, preferably 2 to 20, more preferably 2 to 6 carbon atoms.

An “unsubstituted alkynyl group” mentioned herein has, unless otherwise specified herein, 2 to 50, preferably 2 to 20, more preferably 2 to 6 carbon atoms.

An “unsubstituted cycloalkyl group” mentioned herein has, unless otherwise specified herein, 3 to 50, preferably 3 to 20, more preferably 3 to 6 ring carbon atoms.

An “unsubstituted arylene group” mentioned herein has, unless otherwise specified herein, 6 to 50, preferably 6 to 30, more preferably 6 to 18 ring carbon atoms.

An “unsubstituted divalent heterocyclic group” mentioned herein has, unless otherwise specified herein, 5 to 50, preferably 5 to 30, more preferably 5 to 18 ring atoms.

An “unsubstituted alkylene group” mentioned herein has, unless otherwise specified herein, 1 to 50, preferably 1 to 20, more preferably 1 to 6 carbon atoms.

### Substituted or Unsubstituted Aryl Group

Specific examples (specific example group G1) of the “substituted or unsubstituted aryl group” mentioned herein include unsubstituted aryl groups (specific example group G1A) below and substituted aryl groups (specific example group G1B). (Herein, an unsubstituted aryl group refers to an “unsubstituted aryl group” in a “substituted or unsubstituted aryl group”, and a substituted aryl group refers to a “substituted aryl group” in a “substituted or unsubstituted aryl group.”) A simply termed “aryl group” herein includes both of an “unsubstituted aryl group” and a “substituted aryl group”.

The “substituted aryl group” refers to a group derived by substituting at least one hydrogen atom in an “unsubstituted aryl group” with a substituent. Examples of the “substituted aryl group” include a group derived by substituting at least one hydrogen atom in the “unsubstituted aryl group” in the specific example group G1A below with a substituent, and examples of the substituted aryl group in the specific example group G1B below. It should be noted that the examples of the “unsubstituted aryl group” and the “substituted aryl group” mentioned herein are merely exemplary, and the “substituted aryl group” mentioned herein includes a group derived by further substituting a hydrogen atom bonded to a carbon atom of a skeleton of a “substituted aryl group” in the specific example group G1B below, and a group derived by further substituting a hydrogen atom of a substituent of the “substituted aryl group” in the specific example group G18 below.

Unsubstituted Aryl Group (Specific Example Group G1A):
a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, benzanthryl group, phenanthryl group, benzophenanthryl group, phenalenyl group, pyrenyl group, chrysenyl group, benzochrysenyl group, triphenylenyl group, benzotriphenylenyl group, tetracenyl group, pentacenyl group, fluorenyl group, 9,9-spirobifluorenyl group, benzofluorenyl group, dibenzofluorenyl group, fluoranthenyl group, benzofluoranthenyl group, perylenyl group, and monovalent aryl group derived by removing one hydrogen atom from cyclic structures represented by formulae (TEMP-1) to (TEMP-15) below.

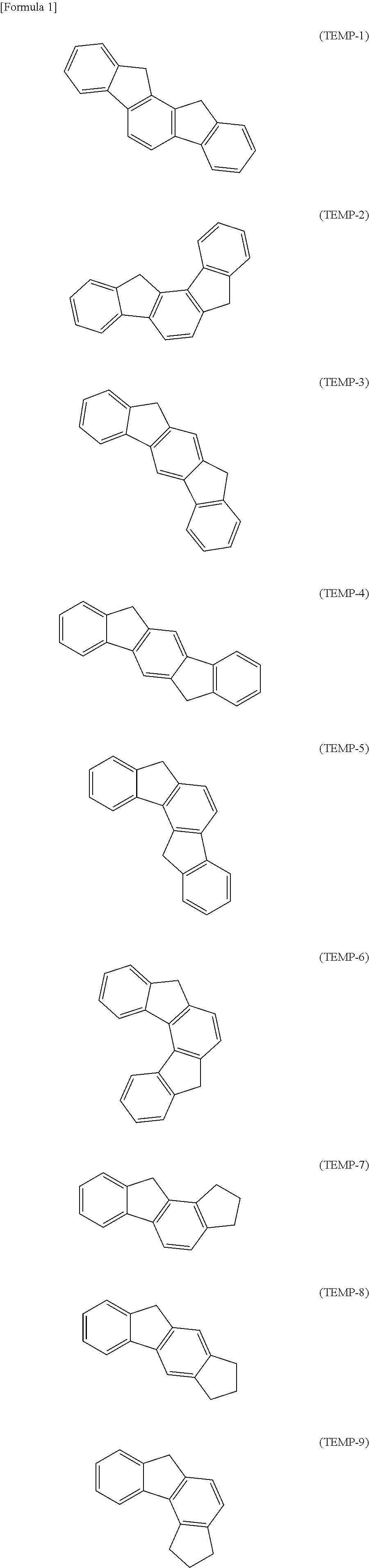

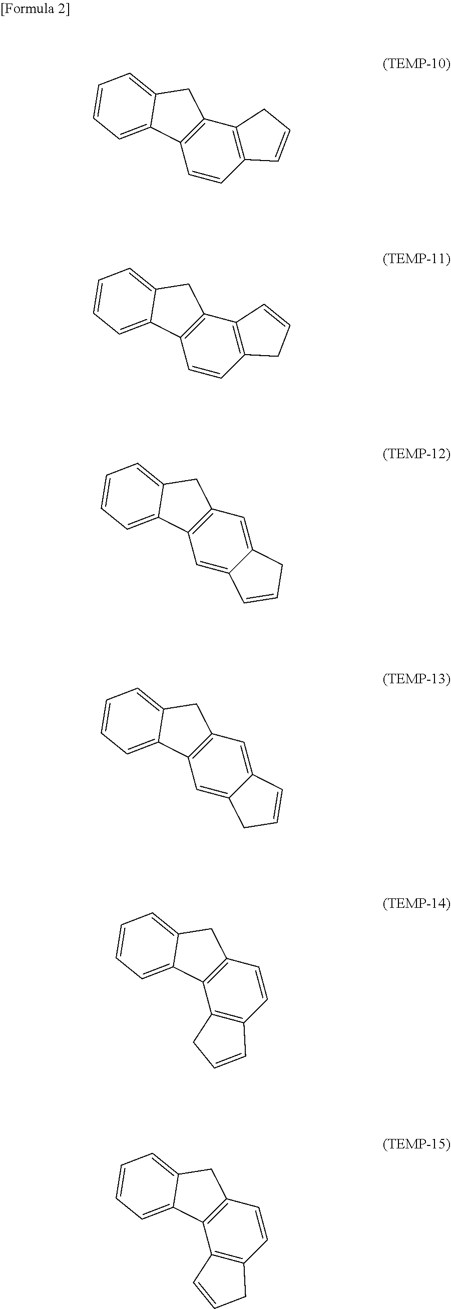

### Substituted Aryl Group (Specific Example Group G1B):

an o-tolyl group, m-tolyl group, p-tolyl group, para-xylyl group, meta-xylyl group, ortho-xylyl group, para-isopropylphenyl group, meta-isopropylphenyl group, ortho-isopropylphenyl group, para-t-butylphenyl group, meta-t-butylphenyl group, ortho-t-butylphenyl group, 3,4,5-trimethylphenyl group, 9,9-dimethylfluorenyl group, 9,9-diphenylfluorenyl group, 9,9-bis(4-methylphenyl)fluorenyl group, 9,9-bis(4-isopropylphenyl)fluorenyl group, 9,9-bis(4-t-butylphenyl)fluorenyl group, cyanophenyl group, triphenylsilyiphenyl group, trimethylsilylphenyl group, phenylnaphthyl group, naphthylphenyl group, and group derived by substituting at least one hydrogen atom of a monovalent group derived from one of the cyclic strictures represented by the formulae (TEMP-1) to (TEMP-15) with a substituent.

### Substituted or Unsubstituted Heterocyclic Group

The “heterocyclic group” mentioned herein refers to a cyclic group having at least one hetero atom in the ring atoms. Specific examples of the hetero atom include a nitrogen atom, oxygen atom, sulfur atom, silicon atom, phosphorus atom, and boron atom.

The “heterocyclic group” mentioned herein is a monocyclic group or a fused-ring group.

The “heterocyclic group” mentioned herein is an aromatic heterocyclic group or a non-aromatic heterocyclic group.

Specific examples (specific example group G2) of the “substituted or unsubstituted heterocyclic group” mentioned herein include unsubstituted heterocyclic groups (specific example group G2A) and substituted heterocyclic groups (specific example group G2B). (Herein, an unsubstituted heterocyclic group refers to an “unsubstituted heterocyclic group” in a “substituted or unsubstituted heterocyclic group,” and a substituted heterocyclic group refers to a “substituted heterocyclic group” in a “substituted or unsubstituted heterocyclic group.”) A simply termed “heterocyclic group” herein includes both of an “unsubstituted heterocyclic group” and a “substituted heterocyclic group.”

The “substituted heterocyclic group” refers to a group derived by substituting at least one hydrogen atom in an “unsubstituted heterocyclic group” with a substituent. Specific examples of the “substituted heterocyclic group” include a group derived by substituting at least one hydrogen atom in the “unsubstituted heterocyclic group” in the specific example group G2A below with a substituent, and examples of the substituted heterocyclic group in the specific example group G2B below. It should be noted that the examples of the “unsubstituted heterocyclic group” and the “substituted heterocyclic group” mentioned herein are merely exemplary, and the “substituted heterocyclic group” mentioned herein includes a group derived by further substituting a hydrogen atom bonded to a ring atom of a skeleton of a “substituted heterocyclic group” in the specific example group G28 below, and a group derived by further substituting a hydrogen atom of a substituent of the “substituted heterocyclic group” in the specific example group G2B below.

The specific example group G2A includes, for instance, unsubstituted heterocyclic groups including a nitrogen atom (specific example group G2A1) below, unsubstituted heterocyclic groups including an oxygen atom (specific example group G2A2) below, unsubstituted heterocyclic groups including a sulfur atom (specific example group G2A3) below, and monovalent heterocyclic groups (specific example group G2A4) derived by removing a hydrogen atom from cyclic structures represented by formulae (TEMP-16) to (TEMP-33) below.

The specific example group G28 includes, for instance, substituted heterocyclic groups including a nitrogen atom (specific example group G261) below, substituted heterocyclic groups including an oxygen atom (specific example group G282) below, substituted heterocyclic groups including a sulfur atom (specific example group G283) below, and groups derived by substituting at least one hydrogen atom of the monovalent heterocyclic groups (specific example group G2B4) derived from the cyclic structures represented by formulae (TEMP-16) to (TEMP-33) below.

Unsubstituted Heterocyclic Groups Including Nitrogen Atom (Specific Example Group G2A1):
a pyrrolyl group, imidazolyl group, pyrazolyl group, triazolyl group, tetrazolyl group, oxazolyl group, isoxazolyl group, oxadiazolyl group, thiazolyl group, isothiazoyl group, thiadiazolyl group, pyridyl group, pyridazinyl group, pyrimidinyl group, pyrazinyl group, triazinyl group, indolyl group, isoindolyl group, indolizinyl group, quinolizinyl group, quinolyl group, isoquinolyl group, cinnolyl group, phthalazinyl group, quinazolinyl group, quinoxalinyl group, benzimidazolyl group, indazolyl group, phenanthrolinyl group, phenanthridinyl group, acridinyl group, phenazinyl group, carbazolyl group, benzocarbazolyl group, morpholino group, phenoxazinyl group, phenothiazinyl group, azacarbazolyl group, and diazacarbazolyl group.

Unsubstituted Heterocyclic Groups Including Oxygen Atom (Specific Example Group G2A2):
a furyl group, oxazolyl group, isoxazolyl group, oxadiazolyl group, xanthenyl group, benzofuranyl group, isobenzofuranyl group, dibenzofuranyl group, naphthobenzofuranyl group, benzoxazolyl group, benzisoxazolyl group, phenoxazinyl group, morpholino group, dinaphthofuranyl group, azadibenzofuranyl group, diazadibenzofuranyl group, azanaphthobenzofuranyl group, and diazanaphthobenzofuranyl group.

Unsubstituted Heterocyclic Groups Including Sulfur Atom (Specific Example Group G2A3):
a thienyl group, thiazolyl group, isothiazoyl group, thiadiazolyl group, benzothiophenyl group (benzothienyl group), isobenzothiophenyl group (isobenzothienyl group), dibenzothiophenyl group (dibenzothienyl group), naphthobenzothiophenyl group (nahthobenzothienyl group), benzothiazolyl group, benzisothiazolyl group, phenothiazinyl group, dinaphthothiophenyl group (dinaphthothienyl group), azadibenzothiophenyl group (azadibenzothienyl group), diazadibenzothiophenyl group (diazadibenzothienyl group), azanaphthobenzothiophenyl group (azanaphthobenzothienyl group), and diazanaphthobenzothiophenyl group (diazanaphthobenzothienyl group).

Monovalent Heterocyclic Groups Derived by Removing One Hydrogen Atom from Cyclic Structures Represented by Formulae (TEMP-16) to (TEMP-33) (Specific Example Group G2A4):

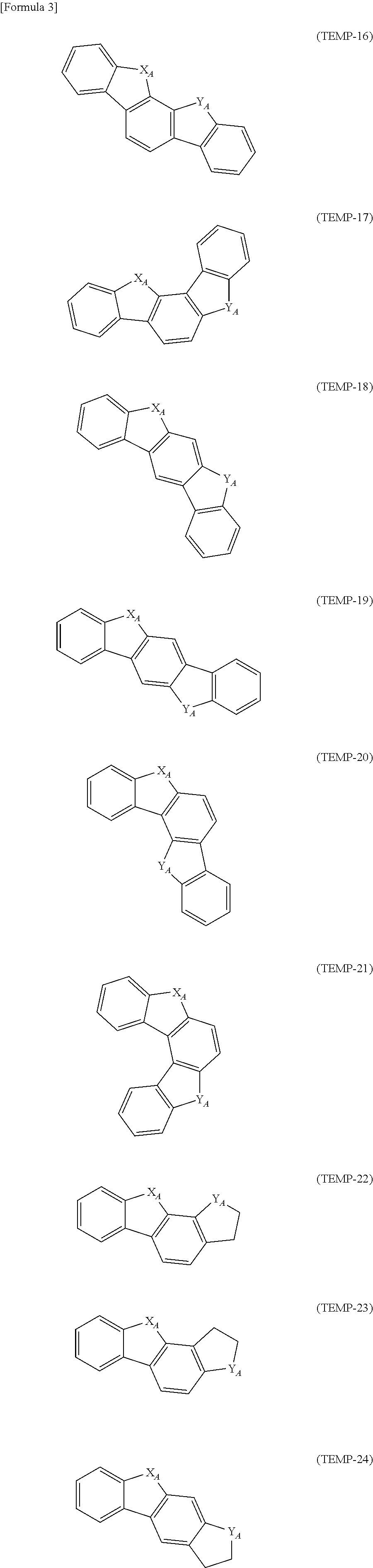

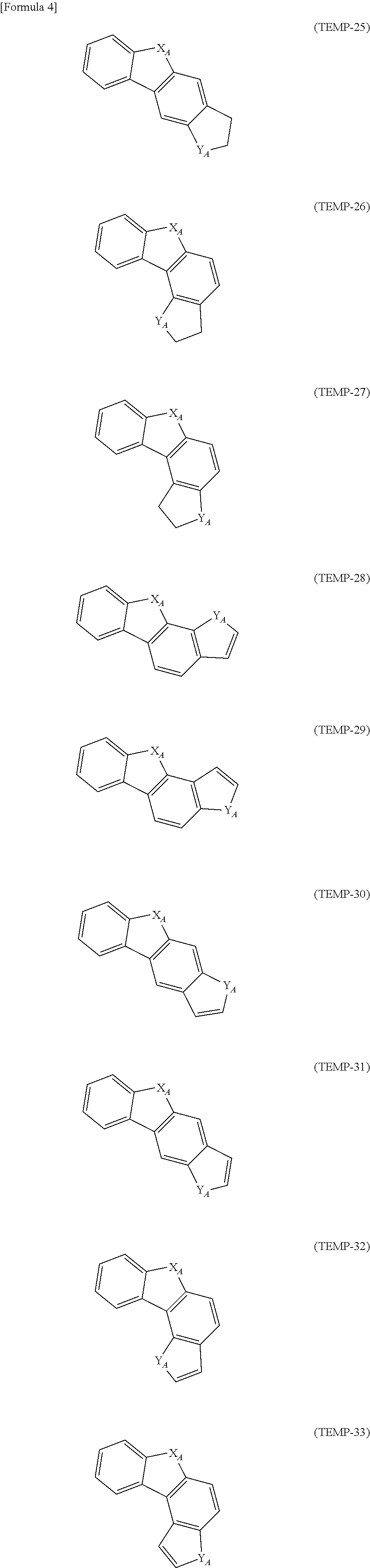

In the formulae (TEMP-16) to (TEMP-33), X_{A} and Y_{A} are each independently an oxygen atom, a sulfur atom, NH or CH₂, with a proviso that at least one of X_{A} or Y_{A} is an oxygen atom, a sulfur atom, or NH.

When at least one of X_{A} or Y_{A} in the formulae (TEMP-16) to (TEMP-33) is NH or CH₂, the monovalent heterocyclic groups derived from the cyclic structures represented by the formulae (TEMP-16) to (TEMP-33) include a monovalent group derived by removing one hydrogen atom from NH or CH₂.

Substituted Heterocyclic Groups Including Nitrogen Atom (Specific Example Group G2B1).
a (9-phenyl)carbazolyl group, (9-biphenylyl)carbazolyl group, (9-phenyl)phenylcarbazolyl group, (9-naphthyl)carbazolyl group, diphenylcarbazole-9-yl group, phenylcarbazole-9-yl group, methylbenzimidazolyl group, ethylbenzimidazolyl group, phenyltriazinyl group, biphenylyltriazinyl group, diphenyltriazinyl group, phenylquinazolinyl group, and biphenylquinazolinyl group.

Substituted Heterocyclic Groups Including Oxygen Atom (Specific Example Group G282).
a phenyldibenzofuranyl group, methyldibenzofuranyl group, t-butyldibenzofuranyl group, and monovalent residue of spiro[9H-xanthene-9,9′-[9H]fluorene].

Substituted Heterocyclic Groups Including Sulfur Atom (Specific Example Group G2B3):
a phenyldibenzothiophenyl group, methyldibenzothiophenyl group, t-butyldibenzothiophenyl group, and monovalent residue of spiro(9H-thioxanthene-9,9′-[9H]fluorene).

Groups Obtained by Substituting at Least One Hydrogen Atom of Monovalent Heterocyclic Group Derived from Cyclic Structures Represented by Formulae (TEMP-16) to (TEMP-33) with Substituent (Specific Example Group G2B4):

The “at least one hydrogen atom of a monovalent heterocyclic group” means at least one hydrogen atom selected from a hydrogen atom bonded to a ring carbon atom of the monovalent heterocyclic group, a hydrogen atom bonded to a nitrogen atom of at least one of X_{A} or Y_{A} in a form of NH, and a hydrogen atom of one of X_{A} and Y_{A} in a form of a methylene group (CH₂).

### Substituted or Unsubstituted Alkyl Group

Specific examples (specific example group G3) of the “substituted or unsubstituted alkyl group” mentioned herein include unsubstituted alkyl groups (specific example group G3A) and substituted alkyl groups (specific example group G3B) below. (Herein, an unsubstituted alkyl group refers to an “unsubstituted alkyl group” in a “substituted or unsubstituted alkyl group.” and a substituted alkyl group refers to a “substituted alkyl group” in a “substituted or unsubstituted alkyl group.”) A simply termed “alkyl group” herein includes both of an “unsubstituted alkyl group” and a “substituted alkyl groups”.

The “substituted alkyl group” refers to a group derived by substituting at least one hydrogen atom in an “unsubstituted alkyl group” with a substituent. Specific examples of the “substituted alkyl group” include a group derived by substituting at least one hydrogen atom of an “unsubstituted alkyl group” (specific example group G3A) below with a substituent, and examples of the substituted alkyl group (specific example group G3B) below. Herein, the alkyl group for the “unsubstituted alkyl group” refers to a chain alkyl group. Accordingly, the “unsubstituted alkyl group” include linear “unsubstituted alkyl group” and branched “unsubstituted alkyl group.” It should be noted that the examples of the “unsubstituted alkyl group” and the “substituted alkyl group” mentioned herein are merely exemplary, and the “substituted alkyl group” mentioned herein includes a group derived by further substituting a hydrogen atom of a skeleton of the “substituted alkyl group” in the specific example group G3B, and a group derived by further substituting a hydrogen atom of a substituent of the “substituted alkyl group” in the specific example group G3B

Unsubstituted Alkyl Group (Specific Example Group G3A):
a methyl group, ethyl group, n-propyl group, isopropyl group, n-butyl group, isobutyl group, s-butyl group, and t-butyl group.

Substituted Alkyl Group (Specific Example Group G3B):
a heptafluoropropyl group (including isomer thereof), pentafluoroethyl group, 2,2,2-trifluoroethyl group, and trifluoromethyl group.

### Substituted or Unsubstituted Alkenyl Group

Specific examples (specific example group G4) of the “substituted or unsubstituted alkenyl group” mentioned herein include unsubstituted alkenyl groups (specific example group G4A) and substituted alkenyl groups (specific example group G4B). (Herein, an unsubstituted alkenyl group refers to an “unsubstituted alkenyl group” in a “substituted or unsubstituted alkenyl group,” and a substituted alkenyl group refers to a “substituted alkenyl group” in a “substituted or unsubstituted alkenyl group.”) A simply termed “alkenyl group” herein includes both of an “unsubstituted alkenyl group” and a “substituted alkenyl group”.

The “substituted alkenyl group” refers to a group derived by substituting at least one hydrogen atom in an “unsubstituted alkenyl group” with a substituent. Specific examples of the “substituted alkenyl group” include an “unsubstituted alkenyl group” (specific example group G4A) substituted by a substituent, and examples of the substituted alkenyl group (specific example group G4B) below. It should be noted that the examples of the “unsubstituted alkenyl group” and the “substituted alkenyl group” mentioned herein are merely exemplary, and the “substituted alkenyl group” mentioned herein includes a group derived by further substituting a hydrogen atom of a skeleton of the “substituted alkenyl group” in the specific example group G4B with a substituent, and a group derived by further substituting a hydrogen atom of a substituent of the “substituted alkenyl group” in the specific example group G4B with a substituent.

Unsubstituted Alkenyl Group (Specific Example Group G4A):
a vinyl group, allyl group, 1-butenyl group, 2-butenyl group, and 3-butenyl group.

Substituted Alkenyl Group (Specific Example Group G4B):
a 1,3-butanedienyl group, 1-methylvinyl group, 1-methylallyl group, 1,1-dimethylallyl group, 2-methylallyl group, and 1,2-dimethylallyl group.

### Substituted or Unsubstituted Alkynyl Group

Specific examples (specific example group G5) of the “substituted or unsubstituted alkynyl group” mentioned herein include unsubstituted alkynyl groups (specific example group G5A) below. (Herein, an unsubstituted alkynyl group refers to an “unsubstituted alkynyl group” in a “substituted or unsubstituted alkynyl group.”) A simply termed “alkynyl group” herein includes both of “unsubstituted alkynyl group” and “substituted alkynyl group”.

The “substituted alkynyl group” refers to a group derived by substituting at least one hydrogen atom in an “unsubstituted alkynyl group” with a substituent. Specific examples of the “substituted alkynyl group” include a group derived by substituting at least one hydrogen atom of the “unsubstituted alkynyl group” (specific example group G5A) below with a substituent.

Unsubstituted Alkynyl Group (Specific Example Group G5A):
an ethynyl group.

### Substituted or Unsubstituted Cycloakyl Group

Specific examples (specific example group G6) of the “substituted or unsubstituted cycloalkyl group” mentioned herein include unsubstituted cycloalkyl groups (specific example group G6A) and substituted cycloalkyl groups (specific example group G6B). (Herein, an unsubstituted cycloalkyl group refers to an “unsubstituted cycloalkyl group” in a “substituted or unsubstituted cycloalkyl group,” and a substituted cycloalkyl group refers to a “substituted cycloalkyl group” in a “substituted or unsubstituted cycloalkyl group”) A simply termed “cycloalkyl group” herein includes both of “unsubstituted cycloalkyl group” and “substituted cycloalkyl group”.

The “substituted cycloalkyl group” refers to a group derived by substituting at least one hydrogen atom of an “unsubstituted cycloalkyl group” with a substituent. Specific examples of the “substituted cycloalkyl group” include a group derived by substituting at least one hydrogen atom of the “unsubstituted cycloalkyl group” (specific example group G6A) below with a substituent, and examples of the substituted cycloalkyl group (specific example group G6B) below. It should be noted that the examples of the “unsubstituted cycloalkyl group” and the “substituted cycloalkyl group” mentioned herein are merely exemplary, and the “substituted cycloalkyl group” mentioned herein includes a group derived by substituting at least one hydrogen atom bonded to a carbon atom of a skeleton of the “substituted cycloalkyl group” in the specific example group G6B with a substituent, and a group derived by further substituting a hydrogen atom of a substituent of the “substituted cycloalkyl group” in the specific example group G6B with a substituent.

Unsubstituted Cycloalkyl Group (Specific Example Group G6A):
a cyclopropyl group, cyclobutyl group, cyclopentyl group, cyclohexyl group, 1-adamantyl group, 2-adamantyl group, 1-norbornyl group, and 2-norbornyl group.

Substituted Cycloalkyl Group (Specific Example Group G68):
a 4-methylcyclohexyl group.
   Group Represented by —Si(R₉₀₁)(R₉₀₂)(R₉₀₃)

Specific examples (specific example group G7) of the group represented herein by —S₁(R₉₀₁)(R₉₀₂)(R₉₀₃) include: —Si(G1)(G1)(G1); —Si(G1)(G2)G2); —Si(G1)(G1)(G2); —Si(G2)(G2)(G2), —Si(G3)(G3)(G3); and —Si(G6)(G6)(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloakyl group” in the specific example group G6;
a plurality of G1 in —Si(G1)(G1)(G1) are mutually the same or different;
a plurality of G2 in —Si(G1)(G2)(G2) are mutually the same or different;
a plurality of G1 in —Si(G1)(G1)(G2) are mutually the same or different,
a plurality of G2 in —Si(G2)(G2)(G2) are mutually the same or different;
a plurality of G3 in —Si(G3)(G3)(G3) are mutually the same or different; and
a plurality of G6 in —Si(G6)(G6)(G6) are mutually the same or different.

### Group Represented by —O—(R₉₀₄)

Specific examples (specific example group G8) of a group represented by O—(R₉₀₄) herein include: —O(G1); —O(G2); —O(G3); and —O(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.

### Group Represented by —S—(R₉₀₅)

Specific examples (specific example group G9) of a group represented herein by —S—(R₉₀₅) include: —S(G1); —S(G2); —S(G3), and —S(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.
   Group Represented by —N(R₉₀₆)(R₉₀₇)

Specific examples (specific example group G10) of a group represented herein by —N(R₉₀₆)(R₉₀₇) include: —N(G1)(G1); —N(G2)(G2); —N(G1)(G2); —N(G3)(G3); and —N(G6)(G6).

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —N(G1)(G1) are mutually the same or different;
a plurality of G2 in —N(G2)(G2) are mutually the same or different;
a plurality of G3 in —N(G3)(G3) are mutually the same or different; and
a plurality of G6 in —N(G6)(G6) are mutually the same or different.

### Halogen Atom

Specific examples (specific example group G11) of “halogen atom” mentioned herein include a fluorine atom, chlorine atom, bromine atom, and iodine atom.

### Substituted or Unsubstituted Fluoroalkyl Group

The “substituted or unsubstituted fluoroalkyl group” mentioned herein refers a group derived by substituting at least one hydrogen atom bonded to at least one of carbon atoms forming an alkyl group in the “substituted or unsubstituted alkyl group” with a fluorine atom, and also includes a group (perfluoro group) derived by substituting all of hydrogen atoms bonded to carbon atoms forming the alkyl group in the “substituted or unsubstituted alkyl group” with fluorine atoms. An “unsubstituted fluoroalkyl group” has, unless otherwise specified herein, 1 to 50, preferably 1 to 30, more preferably 1 to 18 carbon atoms. The “substituted fluoroalkyl group” refers to a group derived by substituting at least one hydrogen atom in a “fluoroalkyl group” with a substituent. It should be noted that the examples of the “substituted fluoroalkyl group” mentioned herein include a group derived by further substituting at least one hydrogen atom bonded to a carbon atom of an alkyl chain of a “substituted fluoroalkyl group” with a substituent, and a group derived by further substituting at least one hydrogen atom of a substituent of the “substituted fluoroalkyl group” with a substituent. Specific examples of the “unsubstituted fluoroalkyl group” include a group derived by substituting at least one hydrogen atom of the “alkyl group” (specific example group G3) with a fluorine atom.

### Substituted or Unsubstituted Haloalkyl Group

The “substituted or unsubstituted haloalkyl group” mentioned herein refers to a group derived by substituting at least one hydrogen atom bonded to carbon atoms forming the alkyl group in the “substituted or unsubstituted alkyl group” with a halogen atom, and also includes a group derived by substituting all hydrogen atoms bonded to carbon atoms forming the alkyl group in the “substituted or unsubstituted alkyl group” with halogen atoms. An “unsubstituted haloalkyl group” has, unless otherwise specified herein, 1 to 50, preferably 1 to 30, and more preferably 1 to 18 carbon atoms. The “substituted haloalkyl group” refers to a group derived by substituting at least one hydrogen atom in a “haloalkyl group” with a substituent. It should be noted that the examples of the “substituted haloalkyl group” mentioned herein include a group derived by further substituting at least one hydrogen atom bonded to a carbon atom of an alkyl chain of a “substituted haloalkyl group” with a substituent, and a group derived by further substituting at least one hydrogen atom of a substituent of the “substituted haloalkyl group” with a substituent. Specific examples of the “unsubstituted haloalkyl group” include a group derived by substituting at least one hydrogen atom of the “alkyl group” (specific example group G3) with a halogen atom. The haloalkyl group is occasionally referred to as a halogenated alkyl group

### Substituted or Unsubstituted Alkoxy Group

Specific examples of a “substituted or unsubstituted alkoxy group” mentioned herein include a group represented by —O(G3), G3 being the “substituted or unsubstituted alkyl group” in the specific example group G3. An “unsubstituted alkoxy group” has, unless otherwise specified herein, 1 to 50, preferably 1 to 30, more preferably 1 to 18 carbon atoms.

### Substituted or Unsubstituted Alkylthio Group

Specific examples of a “substituted or unsubstituted alkylthio group” mentioned herein include a group represented by —S(G3). G3 being the “substituted or unsubstituted alkyl group” in the specific example group G3. An “unsubstituted alkylthio group” has, unless otherwise specified herein, 1 to 50, preferably 1 to 30, more preferably 1 to 18 carbon atoms.

### Substituted or Unsubstituted Aryloxy Group

Specific examples of a “substituted or unsubstituted aryloxy group” mentioned herein include a group represented by —O(G1). G1 being the “substituted or unsubstituted aryl group” in the specific example group G1. An “unsubstituted aryloxy group” has, unless otherwise specified herein, 6 to 50, preferably 6 to 30, more preferably 6 to 18 ring carbon atoms.

### Substituted or Unsubstituted Arylthio Group

Specific examples of a “substituted or unsubstituted arylthio group” mentioned herein include a group represented by —S(G1), G1 being the “substituted or unsubstituted aryl group” in the specific example group G1. An “unsubstituted arylthio group” has, unless otherwise specified herein, 6 to 50, preferably 6 to 30, more preferably 6 to 18 ring carbon atoms.

### Substituted or Unsubstituted Trialkylsilyl Group

Specific examples of a “trialkylsilyl group” mentioned herein include a group represented by —Si(G3)(G3)(G3). G3 being the “substituted or unsubstituted alkyl group” in the specific example group G3. A plurality of G3 in —Si(G3)(G3)(G3) are mutually the same or different. Each of the alkyl groups in the “trialkylsilyl group” has, unless otherwise specified herein, 1 to 50, preferably 1 to 20, more preferably 1 to 6 carbon atoms.

### Substituted or Unsubstituted Aralkyl Group

Specific examples of a “substituted or unsubstituted aralkyl group” mentioned herein include a group represented by -(G3)-(G1), G3 being the “substituted or unsubstituted alkyl group” in the specific example group G3. G1 being the “substituted or unsubstituted aryl group” in the specific example group G1. Accordingly, the “aralkyl group” is a group derived by substituting a hydrogen atom of the “alkyl group” with a substituent in a form of the “aryl group,” which is an example of the “substituted alkyl group.” An “unsubstituted aralkyl group,” which is an “unsubstituted alkyl group” substituted by an “unsubstituted aryl group,” has, unless otherwise specified herein, 7 to 50 carbon atoms, preferably 7 to 30 carbon atoms, more preferably 7 to 18 carbon atoms.

Specific examples of the “substituted or unsubstituted aralkyl group” include a benzyl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-p-naphthylethyl group, 2-n-naphthylethyl group, 1-β-naphthylisopropyl group, and 2-β-naphthylisopropyl group.

Preferable examples of the substituted or unsubstituted aryl group mentioned herein include, unless otherwise specified herein, a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, phenanthryl group, pyrenyl group, chrysenyl group, triphenylenyl group, fluorenyl group, 9,9′-spirobifluorenyl group, 9,9-dimethylfluorenyl group, and 9,9-diphenylfluorenyl group.

Preferable examples of the substituted or unsubstituted heterocyclic group mentioned herein include, unless otherwise specified herein, a pyrldyl group, pyrimidinyl group, triazinyl group, quinolyl group, isoquinolyl group, quinazolinyl group, benzimidazolyl group, phenanthrolinyl group, carbazolyl group (1-carbazolyl group, 2-carbazolyl group, 3-carbazolyl group, 4-carbazolyl group, or 9-carbazolyl group), benzocarbazolyl group, azacarbazolyl group, diazacarbazolyl group, dibenzofuranyl group, naphthobenzofuranyl group, azadibenzofuranyl group, diazadibenzofuranyl group, dibenzothiophenyl group, naphthobenzothiophenyl group, azadibenzothiophenyl group, diazadibenzothiophenyl group, (9-phenyl)carbazolyl group ((9-phenyl)carbazole-1-yl group, (9-phenyl)carbazole-2-yl group, (9-phenyl)carbazole-3-yl group, or (9-phenyl)carbazole-4-yl group), (9-biphenylyl)carbazolyl group, (9-phenyl)phenylcarbazolyl group, diphenylcarbazole-9-yl group, phenylcarbazole-9-yl group, phenyltriazinyl group, biphenylyltriazinyl group, diphenyltriazinyl group, phenyldibenzofuranyl group, and phenyldibenzothiophenyl group.

The carbazolyl group mentioned herein is, unless otherwise specified herein, specifically a group represented by one of formulae below.

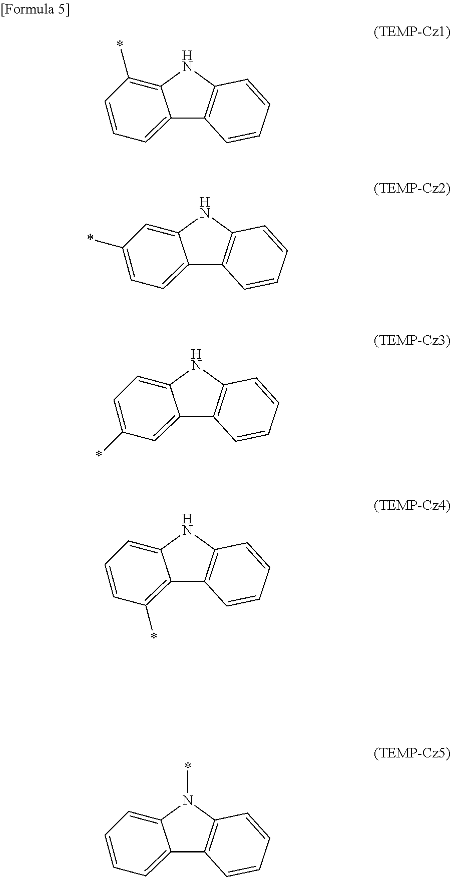 [SMILES: *c1cccc2c1[nH]c1ccccc12 ; *c1ccc2c(c1)[nH]c1ccccc12 ; *c1ccc2[nH]c3ccccc3c2c1 ; *c1cccc2[nH]c3ccccc3c12 ; *n1c2ccccc2c2ccccc21]

The (9-phenyl)carbazolyl group mentioned herein is, unless otherwise specified herein, specifically a group represented by one of formulae below.

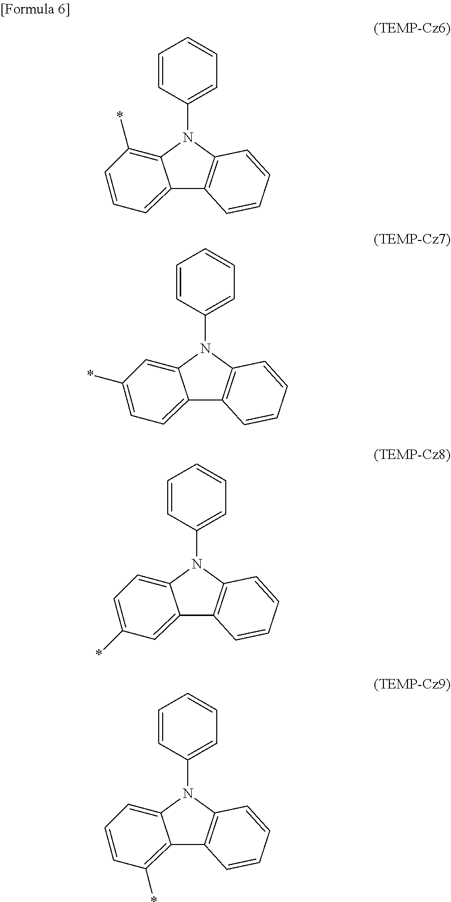

In the formulae (TEMP-Cz1) to (TEMP-Cz9), represents a bonding position.

The dibenzofuranyl group and dibenzothiophenyl group mentioned herein are, unless otherwise specified herein, each specifically represented by one of formulae below.

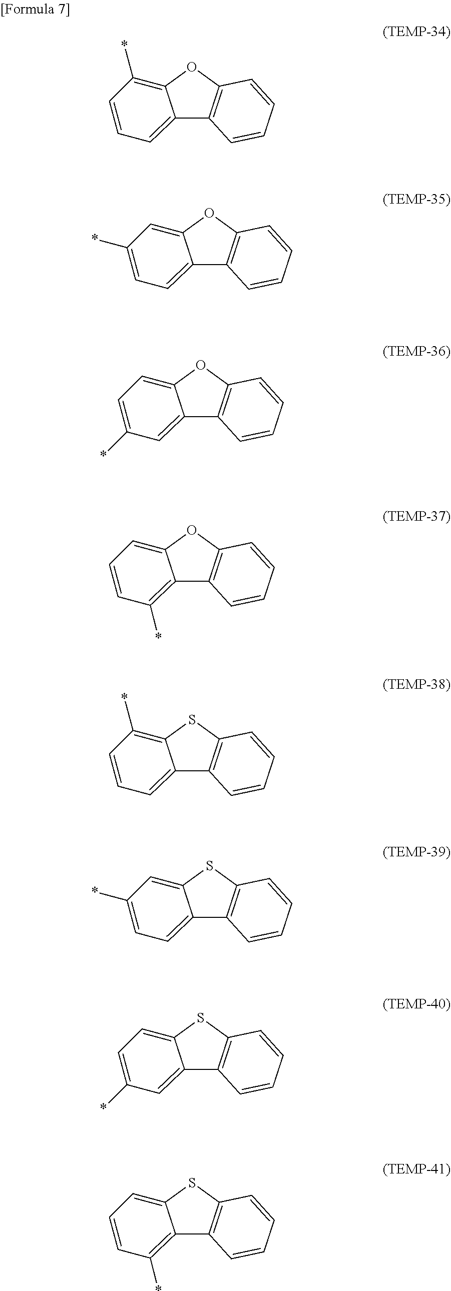

In the formulae (TEMP-34) to (TEMP-41). * represents a bonding position.

Preferable examples of the substituted or unsubstituted alkyl group mentioned herein include, unless otherwise specified herein, a methyl group, ethyl group, propyl group, isopropyl group, n-butyl group, isobutyl group, and t-butyl group.

### Substituted or Unsubstituted Arylene Group

The “substituted or unsubstituted arylene group” mentioned herein is, unless otherwise specified herein, a divalent group derived by removing one hydrogen atom on an aryl ring of the “substituted or unsubstituted aryl group.” Specific examples of the “substituted or unsubstituted arylene group” (specific example group G12) include a divalent group derived by removing one hydrogen atom on an aryl ring of the “substituted or unsubstituted aryl group” in the specific example group G1.

### Substituted or Unsubstituted Divalent Heterocyclic Group

The “substituted or unsubstituted divalent heterocyclic group” mentioned herein is, unless otherwise specified herein, a divalent group derived by removing one hydrogen atom on a heterocycle of the “substituted or unsubstituted heterocyclic group.” Specific examples of the “substituted or unsubstituted divalent heterocyclic group” (specific example group G13) include a divalent group derived by removing one hydrogen atom on a heterocyclic ring of the “substituted or unsubstituted heterocyclic group” in the specific example group G2.

### Substituted or Unsubstituted Alkylene Group

The “substituted or unsubstituted alkylene group” mentioned herein is, unless otherwise specified herein, a divalent group derived by removing one hydrogen atom on an alkyl chain of the “substituted or unsubstituted alkyl group.” Specific examples of the “substituted or unsubstituted alkylene group” (specific example group G14) include a divalent group derived by removing one hydrogen atom on an alkyl chain of the “substituted or unsubstituted alkyl group” in the specific example group G3.

The substituted or unsubstituted arylene group mentioned herein is, unless otherwise specified herein, preferably any one of groups represented by formulae (TEMP-42) to (TEMP-68) below.

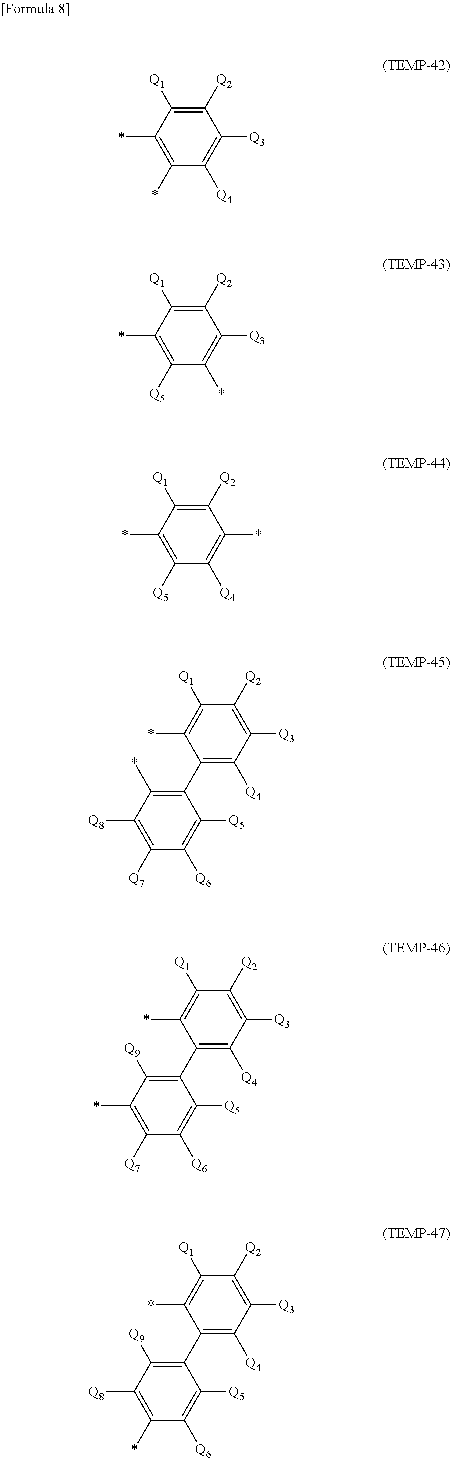

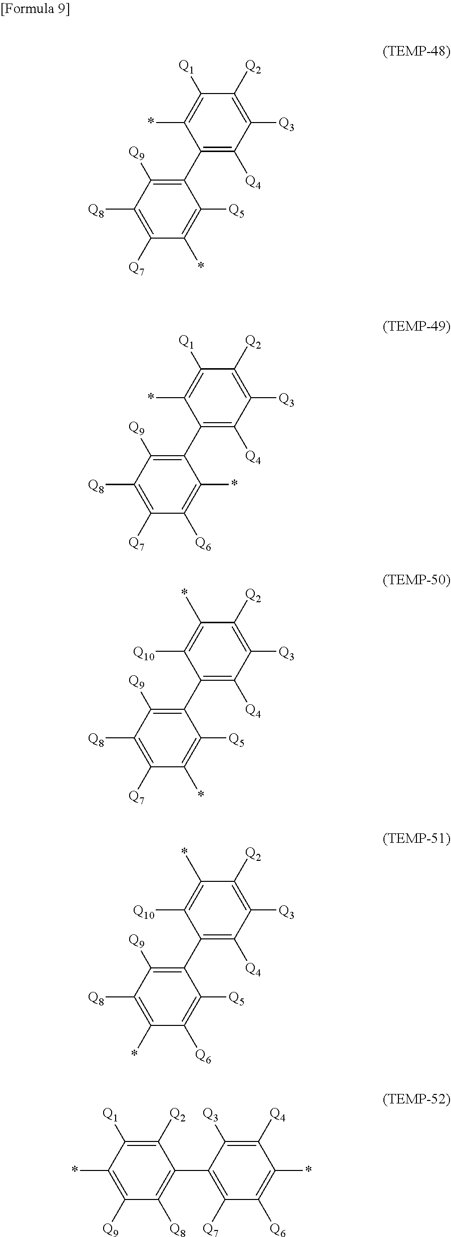

In the formulae (TEMP-42) to (TEMP-52), Q- to Clio are each independently a hydrogen atom or a substituent.

In the formulae (TEMP-42) to (TEMP-52), * represents a bonding position.

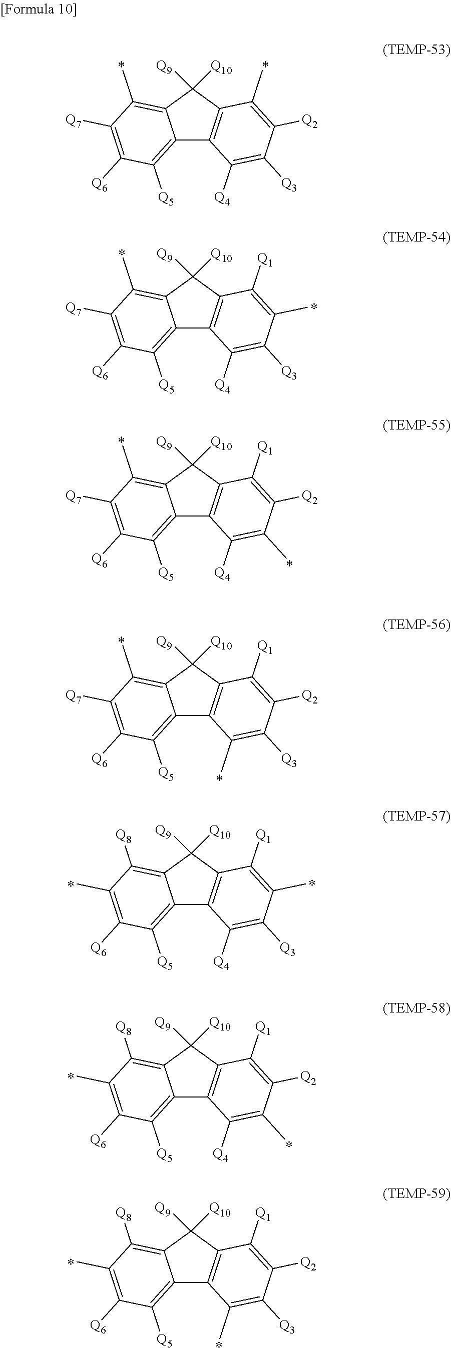

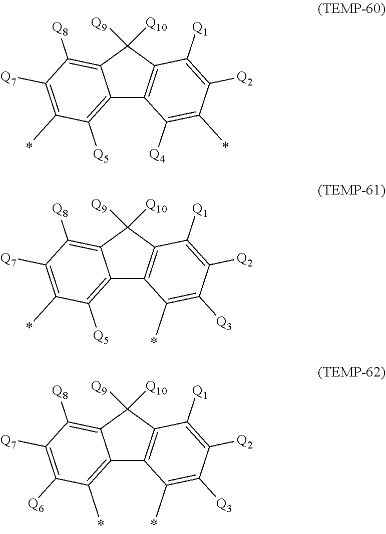

In the formulae (TEMP-53) to (TEMP-62). Q₁ to Q₁₀ are each independently a hydrogen atom or a substituent.

In the formulae, Q₉ and Q₁₀ may be mutually bonded through a single bond to form a ring.

In the formulae (TEMP-53) to (TEMP-62). * represents a bonding position.

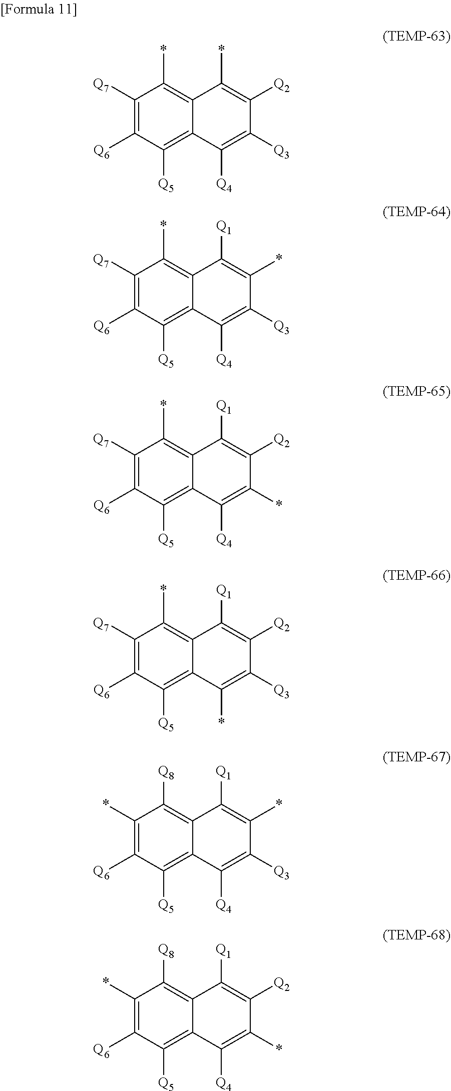

In the formulae (TEMP-63) to (TEMP-68), Q₁ to Q₈ are each independently a hydrogen atom or a substituent.

In the formulae (TEMP-63) to (TEMP-68), * represents a bonding position.

The substituted or unsubstituted divalent heterocyclic group mentioned herein is, unless otherwise specified herein, preferably a group represented by any one of formulae (TEMP-69) to (TEMP-102) below.

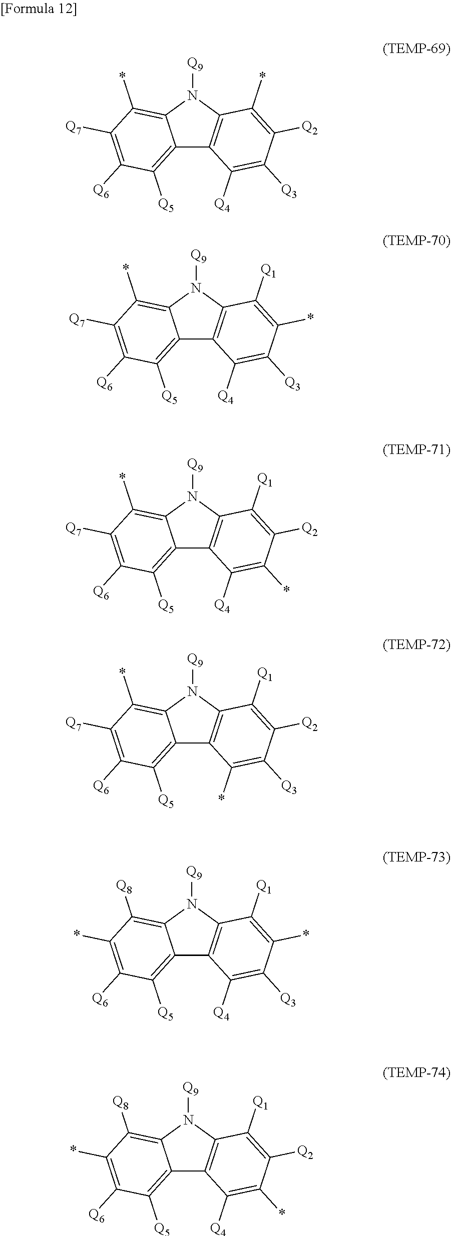

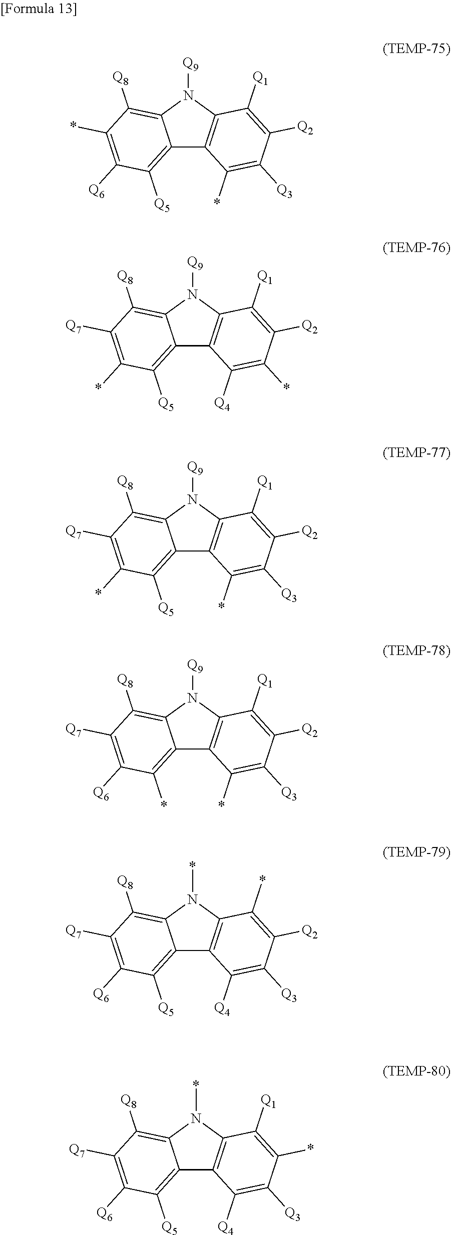

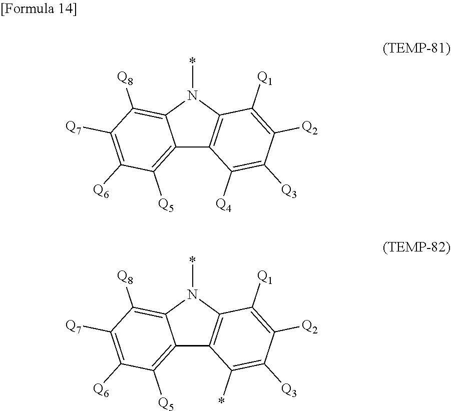

In the formulae (TEMP-69) to (TEMP-82). Q₁ to Q₉ are each independently a hydrogen atom or a substituent.

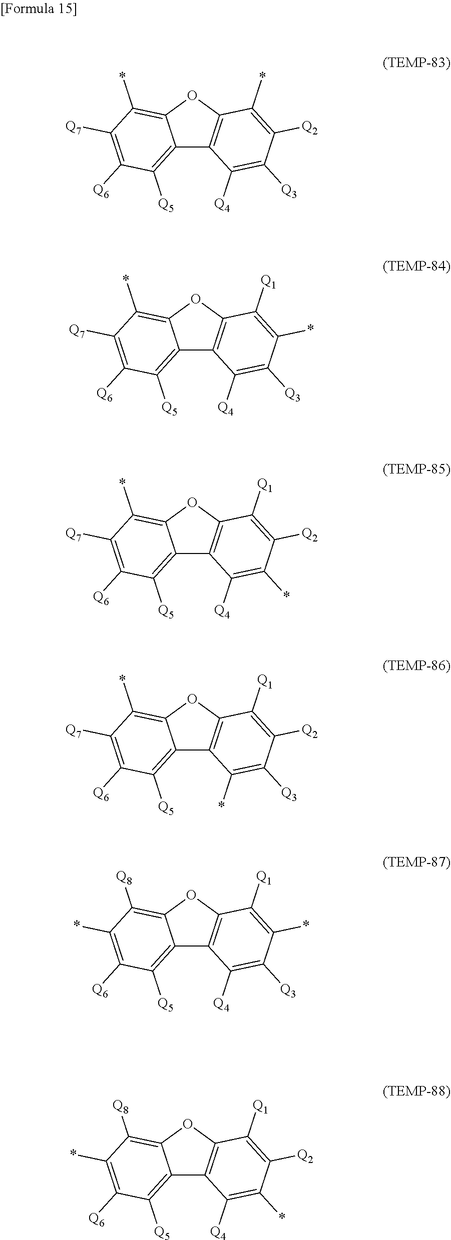

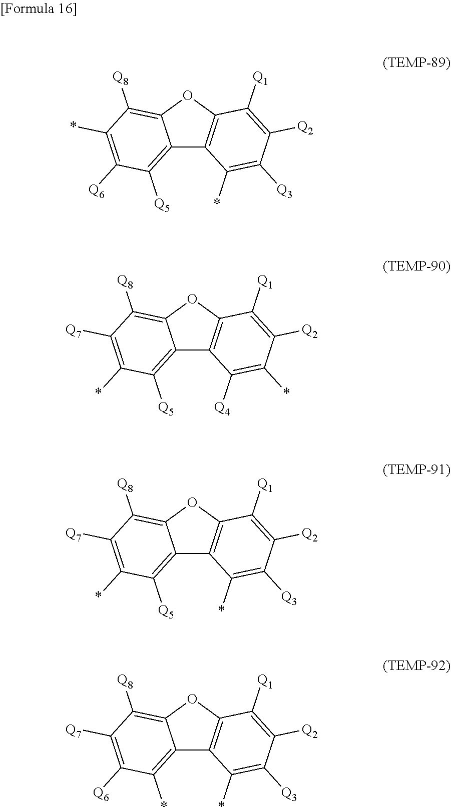

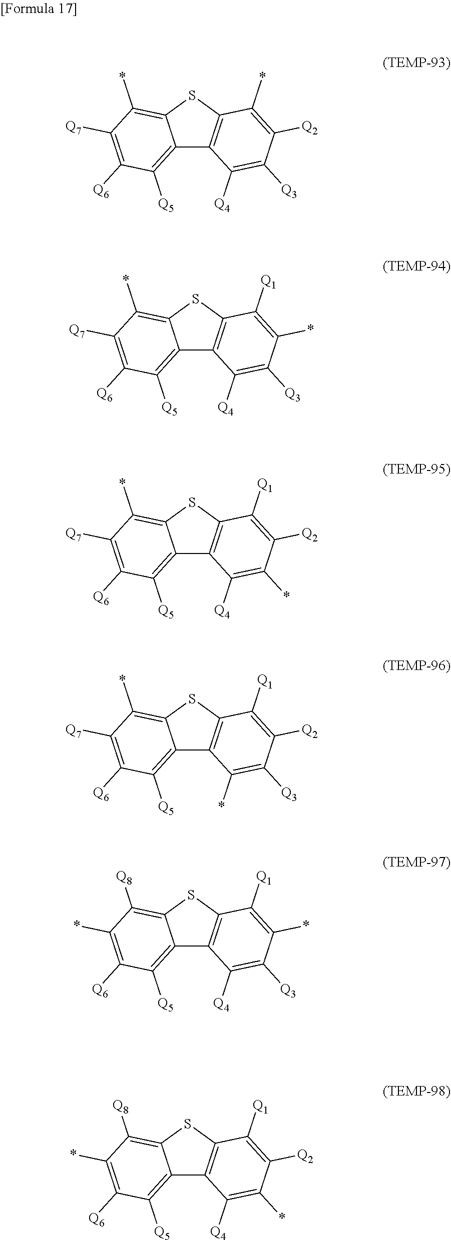

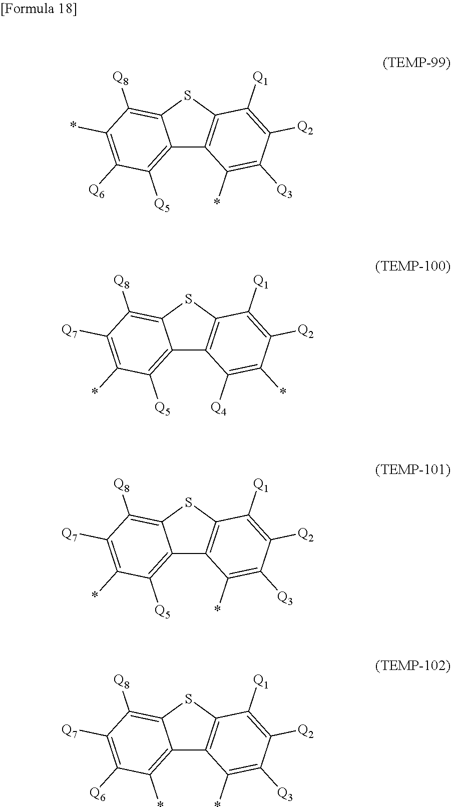

In the formulae (TEMP-83) to (TEMP-102). Q₁ to Q₈ are each independently a hydrogen atom or a substituent.

The substituent mentioned herein has been described above.

### Instance of “Bonded to Form Ring”

instances where “at least one combination of adjacent two or more (of . . . ) are mutually bonded to form a substituted or unsubstituted monocyclic ring, mutually bonded to form a substituted or unsubstituted fused ring, or not mutually bonded” mentioned herein refer to instances where “at least one combination of adjacent two or more (of . . . ) are mutually bonded to form a substituted or unsubstituted monocyclic ring. “at least one combination of adjacent two or more (of . . . ) are mutually bonded to form a substituted or unsubstituted fused ring,” and “at least one combination of adjacent two or more (of . . . ) are not mutually bonded.”

Instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (these instances will be sometimes collectively referred to as an instance of “bonded to form a ring” hereinafter) will be described below. An anthracene compound having a basic skeleton in a form of an anthracene ring and represented by a formula (TEMP-103) below will be used as an example for the description.

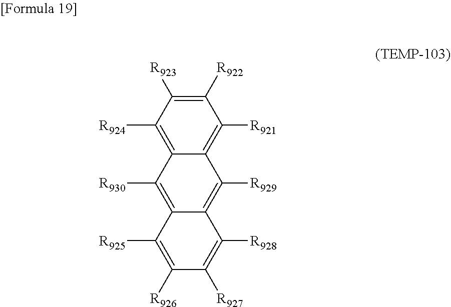

For instance, when “at least one combination of adjacent two or more of R₉₂₁ to R₉₃₀ are mutually bonded to form a ring,” the combination of adjacent ones of R₉₂₁ to R₉₃₀ (i.e, the combination at issue) is a combination of R₉₂₁ and R₉₂₂, a combination of R₉₂₂ and R₉₂₃, a combination of R₉₂₃ and R₉₂₄, a combination of R₉₂₄ and R₉₃₀, a combination of R₉₃₀ and R₉₂₅, a combination of R₉₂₅ and R₉₂₆, a combination of R₉₂₆ and R₉₂₇, a combination of R₉₂₇ and R₉₂₈, a combination of R₉₂₈ and R₉₂₉, or a combination of R₉₂₉ and R₉₂₁.

The term “at least one combination” means that two or more of the above combinations of adjacent two or more of R₉₂₁ to R₉₃₀ may simultaneously form rings. For instance, when R₉₂₁ and R₉₃₀ are mutually bonded to form a ring Q_{A} and R₉₂₅ and R₉₂₆ are simultaneously mutually bonded to form a ring Q_{B}, the anthracene compound represented by the formula (TEMP-103) is represented by a formula (TEMP-104) below.

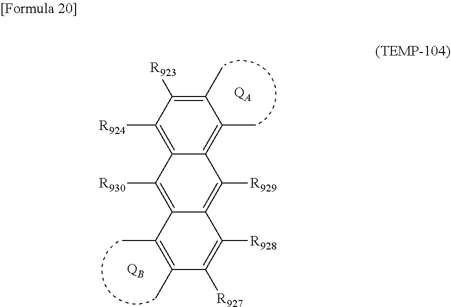

The instance where the “combination of adjacent two or more” form a ring means not only an instance where the “two” adjacent components are bonded but also an instance where adjacent “three or more” are bonded. For instance, R₉₂₁ and R₉₂₂ are mutually bonded to form a ring Q_{A} and R₉₂₂ and R₉₂₃ are mutually bonded to form a ring Q_{C}, and mutually adjacent three components (R₉₂₁, R₉₂₂ and R₉₂₃) are mutually bonded to form a ring fused to the anthracene basic skeleton. In this case, the anthracene compound represented by the formula (TEMP-103) is represented by a formula (TEMP-105) below. In the formula (TEMP-105) below, the ring Q_{A} and the ring Q_{C} share R₉₂₂.

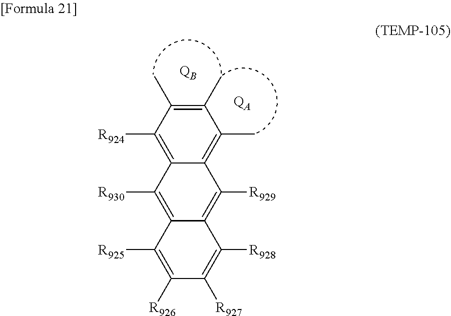

The formed “monocyclic ring” or “fused ring” may be, in terms of the formed ring in itself, a saturated ring or an unsaturated ring. When the “combination of adjacent two” form a “monocyclic ring” or a “fused ring,” the “monocyclic ring” or “fused ring” may be a saturated ring or an unsaturated ring. For instance, the ring Q_{A} and the ring Q_{B} formed in the formula (TEMP-104) are each independently a “monocyclic ring” or a “fused ring.” Further, the ring Q_{A} and the ring Q_{C} formed in the formula (TEMP-105) are each a “fused ring.” The ring Q_{A} and the ring Q_{C} in the formula (TEMP-105) are fused to form a fused ring. When the ring Q_{A} in the formula (TEMP-104) is a benzene ring, the ring Q_{A} is a monocyclic ring. When the ring Q_{A} in the formula (TEMP-104) is a naphthalene ring, the ring Q_{A} fs a fused ring.

The “unsaturated ring” represents an aromatic hydrocarbon ring or an aromatic heterocycle. The “saturated ring” represents an aliphatic hydrocarbon ring or a non-aromatic heterocycle.

Specific examples of the aromatic hydrocarbon ring include a ring formed by terminating a bond of a group in the specific example of the specific example group G1 with a hydrogen atom.

Specific examples of the aromatic heterocycle include a ring formed by terminating a bond of an aromatic heterocyclic group in the specific example of the specific example group G2 with a hydrogen atom.

Specific examples of the aliphatic hydrocarbon ring include a ring formed by terminating a bond of a group in the specific example of the specific example group G6 with a hydrogen atom.

The phrase “to form a ring” herein means that a ring is formed only by a plurality of atoms of a basic skeleton, or by a combination of a plurality of atoms of the basic skeleton and one or more optional atoms. For instance, the ring Q_{A} formed by mutually bonding R₉₂₁ and R₉₂₂ shown in the formula (TEMP-104) is a ring formed by a carbon atom of the anthracene skeleton bonded to R₉₂₁, a carbon atom of the anthracene skeleton bonded to R₉₂₂, and one or more optional atoms. Specifically, when the ring Q_{A} is a monocyclic unsaturated ring formed by R₉₂₁ and Rare, the ring formed by a carbon atom of the anthracene skeleton bonded to R₉₂₁, a carbon atom of the anthracene skeleton bonded to R₉₂₂, and four carbon atoms is a benzene ring.

The “optional atom” is, unless otherwise specified herein, preferably at least one atom selected from the group consisting of a carbon atom, nitrogen atom, oxygen atom, and sulfur atom. A bond of the optional atom (e.g, a carbon atom and a nitrogen atom) not forming a ring may be terminated by a hydrogen atom or the like or may be substituted by an “optional substituent” described later. When the ring includes any other optional element than the carbon atom, the resultant ring is a heterocycle.

The number of “one or more optional atoms” forming the monocyclic ring or fused ring is, unless otherwise specified herein, preferably in a range from 2 to 15, more preferably in a range from 3 to 12, further preferably in a range from 3 to 5.

Unless otherwise specified herein, the ring, which may be a “monocyclic ring” or “fused ring,” is preferably a “monocyclic ring.”

Unless otherwise specified herein, the ring, which may be a “saturated ring” or “unsaturated ring,” is preferably an “unsaturated ring.”

Unless otherwise specified herein, the “monocyclic ring” is preferably a benzene ring.

Unless otherwise specified herein, the “unsaturated ring” is preferably a benzene ring.

When “at least one combination of adjacent two or more” (of . . . ) are “mutually bonded to form a substituted or unsubstituted monocyclic ring” or “mutually bonded to form a substituted or unsubstituted fused ring,” unless otherwise specified herein, at least one combination of adjacent two or more of components are preferably mutually bonded to form a substituted or unsubstituted “unsaturated ring” formed of a plurality of atoms of the basic skeleton, and 1 to 15 atoms of at least one element selected from the group consisting of carbon, nitrogen, oxygen and sulfur.

When the “monocyclic ring” or the “fused ring” has a substituent, the substituent is the substituent described in later-described “optional substituent.” When the “monocyclic ring” or the “fused ring” has a substituent, specific examples of the substituent are the substituents described above under the subtitle “Substituent Mentioned Herein.”

When the “saturated ring” or the “unsaturated ring” has a substituent, the substituent is the substituent described in later-described “optional substituent.” When the “monocyclic ring” or the “fused ring” has a substituent, specific examples of the substituent are the substituents described above under the subtitle “Substituent Mentioned Herein.”

The above is the description for the instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (sometimes referred to as an instance of “bonded to form a ring”).

### Substituent for Substituted or Unsubstituted Group

In an exemplary embodiment herein, the substituent for the substituted or unsubstituted group (hereinafter occasionally referred to as an “optional substituent”), is for instance, a group selected from the group consisting of an unsubstituted alkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, —Si(R₉₀₁)(R₉₀₂)(R₉₀₃), —O—(R₉₀₄), —S—(R₉₀₅), —N(R₉₀₆)(R₉₀₇), a halogen atom, a cyano group, a nitro group, an unsubstituted aryl group having 6 to 50 ring carbon atoms, and an unsubstituted heterocyclic group having 5 to 50 ring atoms;
R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when two or more R₉₀₁ are present, the two or more R₉₀₁ are mutually the same or different;
when two or more R₉₀₂ are present, the two or more R₉₀₂ are mutually the same or different;
when two or more R₉₀₃ are present, the two or more R₉₀₃ are mutually the same or different;
when two or more R₉₀₄ are present, the two or more R₉₀₄ are mutually the same or different;
when two or more R₉₀₅ are present, the two or more R₉₀₅ are mutually the same or different;
when two or more R₉₀₆ are present, the two or more R₉₀₆ are mutually the same or different; and
when two or more R₉₀₇ are present, the two or more R₉₀₇ are mutually the same or different.

In an exemplary embodiment, the substituent for the substituted or unsubstituted group is a group selected from the group consisting of an alkyl group having 1 to 50 carbon atoms, an aryl group having 6 to 50 ring carbon atoms, and a heterocyclic group having 5 to 50 ring atoms.

In an exemplary embodiment, the substituent for the substituted or unsubstituted group is a group selected from the group consisting of an alkyl group having 1 to 18 carbon atoms, an aryl group having 6 to 18 ring carbon atoms, and a heterocyclic group having 5 to 18 ring atoms.

Specific examples of the above optional substituent are the same as the specific examples of the substituent described above under the subtitle “Substituent Mentioned Herein.”

Unless otherwise specified herein, adjacent ones of the optional substituents may form a “saturated ring” or an “unsaturated ring,” preferably a substituted or unsubstituted saturated five-membered ring, a substituted or unsubstituted saturated six-membered ring, a substituted or unsubstituted unsaturated five-membered ring, or a substituted or unsubstituted unsaturated six-membered ring, more preferably a benzene ring.

Unless otherwise specified herein, the optional substituent may further include a substituent. Examples of the substituent for the optional substituent are the same as the examples of the optional substituent.

Herein, numerical ranges represented by “AA to BB” represent a range whose lower limit is the value (AA) recited before “to” and whose upper limit is the value (BB) recited after “to.”

### First Exemplary Embodiment

An arrangement of an organic EL device according to a first exemplary embodiment of the invention will be described below.

The organic EL device according to the exemplary embodiment includes an organic layer between an anode and a cathode. The organic layer includes at least one layer formed from an organic compound. Or, the organic layer is provided by layering a plurality of layers formed from an organic compound(s). The organic layer may further contain an inorganic compound(s).

In the exemplary embodiment, at least two layers included in the organic layer are an emitting layer disposed between the anode and the cathode, and a first layer disposed between the emitting layer and the anode. For instance, the organic layer may be constituted by the emitting layer and the first layer, or may further include a layer(s) usable in the organic EL device. The layer usable in the organic EL device, which is not particularly limited, is exemplified by at least one selected from the group consisting of a hole injecting layer, a hole transporting layer, an electron blocking layer, an electron injecting layer, an electron transporting layer, and a hole blocking layer.

The organic EL device according to the exemplary embodiment includes: an anode; a cathode; an emitting layer disposed between the anode and the cathode; and a first layer disposed between the anode and the emitting layer, in which the emitting layer contains a delayed fluorescent compound, the first layer contains a first compound, an ionization potential of the first compound Ip(HT1) satisfies a numerical formula (Numerical Formula 1) below, a hole mobility of the first compound μh(HT1) satisfies a numerical formula (Numerical Formula 2j below, and the first layer has a film thickness of 15 nm or more.

$$Ip ( HT 1 ) \geq 5.7 eV \qquad ( Numerical Formula 1 )$$

$$μ h ( H T 1 ) \geq 1 \times 1 {0}^{- 5} {cm}^{2} / Vs \qquad ( Numerical Formula 2 )$$

Herein, a region formed by a plurality of organic layers disposed between the anode and the emitting region is occasionally referred to as a hole transporting zone. Herein, a layer provided in a shared manner across a plurality of devices is occasionally referred to as a common layer, and a layer not provided in a shared manner across a plurality of devices is occasionally referred to as a non-common layer.

In the organic EL device using the TADF mechanism, there is a demand for a large total film thickness of the hole transporting zone according to the embodiment of usage. The reason thereof is as follows.

When the organic EL devices are mounted as red, green, and blue pixels (RGB pixels) in an organic EL display device, the hole transporting layer is typically formed as a common layer using the same material and thickness across the RGB pixels from the viewpoint of improving mass productivity and reducing manufacturing costs.

In the organic EL display device including the RGB pixels, it is necessary to optimize the total film thickness of the hole transporting zone according to the emission wavelength for each pixel in order to perform cavity adjustment. Specifically, according to the pixel whose wavelength is not the longest among the RGB pixels, the total film thickness of the hole transporting zone of the remaining pixels needs to be determined.

When the pixel for which cavity adjustment is performed is an organic EL device that emits phosphorescence, a thick layer (e.g., an electron blocking layer) has been separately provided as a non-common layer. The non-common layer is required to be thick also when the pixel for which cavity adjustment is performed is an organic EL device that emits light using the TADF mechanism.

However, when the non-common layer is simply thicker in the organic EL device that emits light using the TADF mechanism, the transportability of holes to the emitting layer is reduced, resulting in lower device performance. This problem may be caused by the fact that an absolute value of the ionization potential Ip of the delayed fluorescent layer is larger than an absolute value of the ionization potential Ip of the phosphorescent layer. Although the total film thickness of the hole transporting zone may be increased by providing a plurality of non-common layers, this method reduces mass productivity.

The inventors have found out that the injectability of holes to the delayed fluorescent layer in which the absolute value of the ionization potential Ip is large is improvable by increasing the film thickness of the first layer (e.g., an electron blocking layer) disposed between the emitting layer and the anode (the film thickness being 15 nm or more), and containing, in the first layer with a large film thickness, a compound satisfying a specific parameter (Numerical Formula 1 and Numerical Formula 2), in the organic EL device that emits light using the TADF mechanism. This would inhibit the decrease in device performance even when the first layer has a large film thickness.

Accordingly, the organic EL device according to the exemplary embodiment achieves at least one of low voltage, high efficiency, or long lifetime even when the first layer has a large film thickness.

When the organic EL device according to the exemplary embodiment is mounted in an organic EL display device in which at least one of the RGB pixels emits light by the TADF mechanism, cavity adjustment can be easily performed by simply increasing the film thickness of the first layer. The organic EL display device can thus have improved mass productivity.

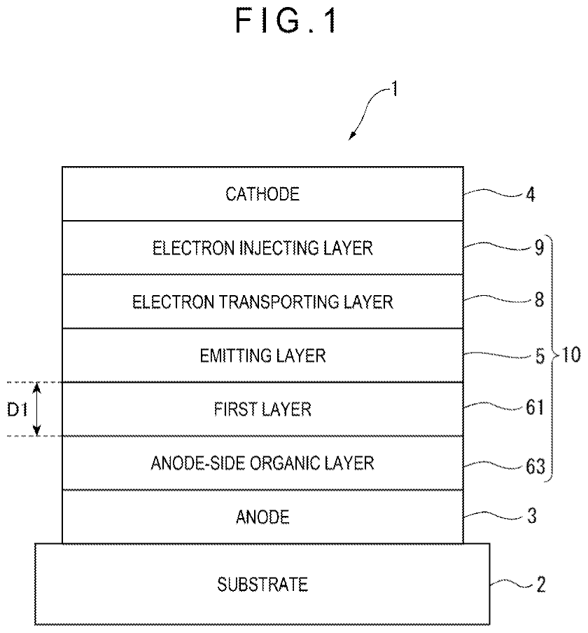

FIG. 1 schematically depicts an exemplary arrangement of the organic EL device of the exemplary embodiment.

An organic EL device 1 includes a light-transmissive substrate 2, an anode 3, a cathode 4, and organic layers 10 provided between the anode 3 and the cathode 4. The organic layers 10 include an anode-side organic layer 63, a first layer 61, an emitting layer 5, an electron transporting layer 8, and an electron injecting layer 9, which are layered on the anode 3 in this order. In FIG. 1, D1 denotes a film thickness of the first layer 61. D1 is 15 nm or more.

In the organic EL device 1 of FIG. 1, the hole transporting zone includes the anode-side organic layer 63 and the first layer 61.

The first layer 61 is preferably adjacent to the emitting layer 5.

The first layer 61 is also preferably adjacent to the anode-side organic layer 63.

The first layer 61 is preferably a hole transporting layer or an electron blocking layer, more preferably an electron blocking layer.

The anode-side organic layer 63 is preferably adjacent to the first layer 61.

The anode-side organic layer 63 is also preferably adjacent to the anode 3.

The anode-side organic layer 63 is preferably a hole injecting layer or a hole transporting layer, more preferably a hole injecting layer.

The anode-side organic layer 63 can be provided by using, for instance, materials for the hole injecting layer and hole transporting layer described in later-described Arrangement of Organic EL Device.

The emitting layer 5 preferably contains no phosphorescent material (dopant material).

The emitting layer 5 preferably contains no phosphorescent metal complex.

The emitting layer 5 preferably contains no heavy metal complex. Examples of the heavy metal complex include an iridium complex, osmium complex, and platinum complex.

The emitting layer 5 preferably contains no phosphorescent rare-earth metal complex.

The emitting layer 5 may contain a metal complex, but preferably contains no metal complex.

In an exemplary arrangement of the exemplary embodiment, the first layer has a film thickness of 20 nm or more.

In an exemplary arrangement of the exemplary embodiment, the first layer has a film thickness of 25 nm or more.

In an exemplary arrangement of the exemplary embodiment, the first layer has a film thickness of 30 nm or more.

### First Layer

The first layer contains the first compound. The first compound may be any compound having an ionization potential Ip(HT1) of 5.70 eV or more (Numerical Formula 1) and a hole mobility μh(HT1) of 1×10⁻⁵ cm²/Vs or more (Numerical Formula 2). The first compound is preferably an amine compound. For instance, the first compound is preferably a compound represented by a formula (31), (32), or (33) below.

### Compound Represented by Formula (31), (32), or (33)

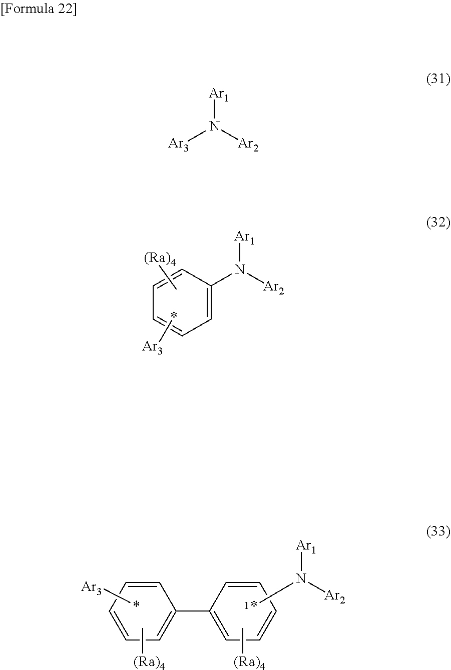

In the formulae (31) to (33):

Ar₁ and Ar₂ are each independently a substituted or unsubstituted aryl group having 6 to 50 ring carbon atoms, or a substituted or unsubstituted heterocyclic group having 5 to 50 ring atoms;
Ar₃ are each independently a group represented by a formula (3A) or (3B) below; * in the formula (32) represents a bonding position to a carbon atom in a six-membered ring having Ra; * in the formula (33) represents a bonding position to a carbon atom in a six-membered ring having Ra; and 1* in the formula (33) represents a bonding position to a carbon atom in a six-membered ring having Ra:
at least one combination of adjacent two or more of a plurality of Ra are mutually bonded to form a substituted or unsubstituted monocyclic ring, mutually bonded to form a substituted or unsubstituted fused ring, or not mutually bonded;
Ra forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a halogen atom, a cyano group, a nitro group, a group represented by —P(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having to 50 ring atoms; and
the plurality of Ra are mutually the same or different.

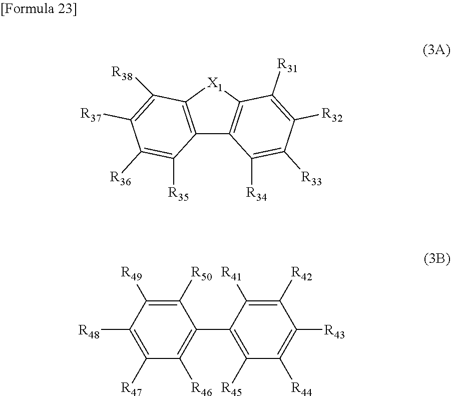

In the formulae (3A) and (3B).
X₁ is an oxygen atom, a sulfur atom, CR₃₀₁R₃₀₂, or NR₃₀₃;
a combination of R₃₀₁ and R₃₀₂ are mutually bonded to form a substituted or unsubstituted monocyclic ring, mutually bonded to form a substituted or unsubstituted fused ring, or not mutually bonded;
at least one combination of adjacent two or more of R₃₁ to R₃₄ are mutually bonded to form a substituted or unsubstituted monocyclic ring, mutually bonded to form a substituted or unsubstituted fused ring, or not mutually bonded,
at least one combination of adjacent two or more of R₃₅ to R₃₆ are mutually bonded to form a substituted or unsubstituted monocyclic ring, mutually bonded to form a substituted or unsubstituted fused ring, or not mutually bonded.
at least one combination of adjacent two or more of R₄₁ to R₅₀ are mutually bonded to form a substituted or unsubstituted monocyclic ring, mutually bonded to form a substituted or unsubstituted fused ring, or not mutually bonded;
R₃₀₃, and R₃₀₁, R₃₀₂, R₃₁ to R₃₈ and R₄₁ to R₅₀ forming neither the substituted or unsubstituted monocyclic ring nor the substituted or unsubstituted fused ring each independently represent the same as Ra in the formula (32); and
any one of R₃₀₁ to R₃₀₃ and R₃₁, to R₃₆ in the formula (3A) is a single bond bonded to a nitrogen atom in the formula (31), a single bond bonded to a carbon atom in a six-membered ring in the formula (32), or a single bond bonded to a carbon atom in a six-membered ring in the formula (33): and any one of R₄₁ to R₅₀ in the formula (3B) is a single bond bonded to a nitrogen atom in the formula (31), a single bond bonded to a carbon atom in a six-membered ring in the formula (32), or a single bond bonded to a carbon atom in a six-membered ring in the formula (33).

In the first compound, R₉₀₁, R₉₀₂, R₉₀₃, R₉₀₄, R₉₀₅, R₉₀₆, R₉₀₇, R₉₀₈, R₉₀₉, R₉₃₁, R₉₃₂, R₉₃₃, R₉₃₄, R₉₃₅, R₉₃₆, and R₉₃₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms,
when a plurality of R₉₀₁ of are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₉₀₈ are present, the plurality of R₉₀₈ are mutually the same or different;
when a plurality of R₉₀₉ are present, the plurality of R₉₀₉ are mutually the same or different;
when a plurality of R₉₃₁ are present, the plurality of R₉₃₁ are mutually the same or different;
when a plurality of R₉₃₂ are present, the plurality of R₉₃₂ are mutually the same or different;
when a plurality of R₉₃₃ are present, the plurality of R₉₃₃ are mutually the same or different;
when a plurality of R₉₃₄ are present, the plurality of R₉₃₄ are mutually the same or different;
when a plurality of R₉₃₅ are present, the plurality of R₉₃₅ are mutually the same or different;
when a plurality of R₉₃₆ are present, the plurality of R₉₃₆ are mutually the same or different; and
when a plurality of R₉₃₇ are present, the plurality of R₉₃₇ are mutually the same or different.

For instance, the first compound is also preferably a compound represented by a formula (X) below.

### Compound Represented by Formula (X)

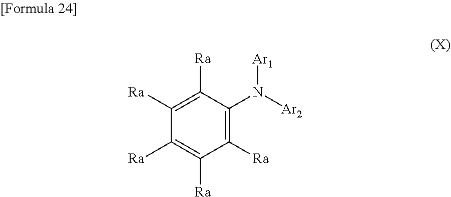

In the formula (X): Ar₁ and Ar₂ each independently represent the same as Ar₁ and Ar₂ in the formula (32);
at least one combination of adjacent two or more of a plurality of Ra are mutually bonded to form a substituted or unsubstituted monocyclic ring, mutually bonded to form a substituted or unsubstituted fused ring, or not mutually bonded,
Ra forming neither the substituted or unsubstituted monocyclic ring nor the substituted or unsubstituted fused ring each independently represent the same as Ra forming neither the substituted or unsubstituted monocyclic ring nor the substituted or unsubstituted fused ring in the formula (32); and
the plurality of Ra are mutually the same or different.

When the first compound is a compound represented by the formula (31), it is preferable that Ar₃ are each independently a group represented by one of formulae (30A) to (30G) below.

When the first compound is a compound represented by the formula (32) or (33), it is preferable that Ar₂ are each independently a group represented by one of formulae (30A) to (30H) below.

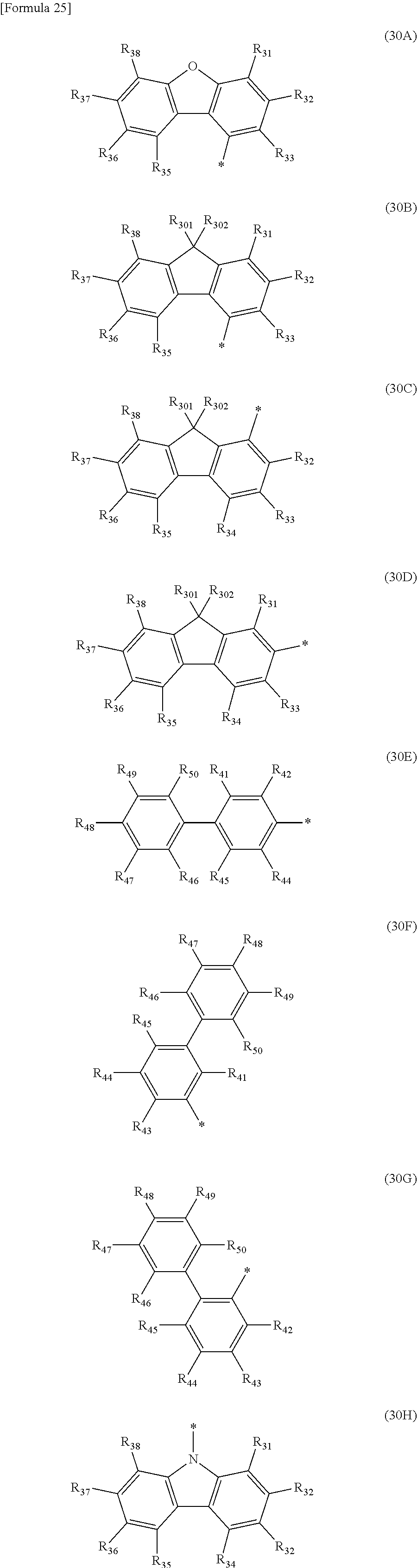

In the formulae (30A) to (30D), R₃₀₁, R₃₀₂, and R₃₁ to R₃₈ each independently represent the same as R₃₀₁, R₃₀₂, and R₃₁ to R₃₈ in the formula (3A); in the formulae (30E) to (30G), R₄₁ to R₅₀ each independently represent the same as R₄₁ to R₅₀ in the formula (3B); in the formula (30H), R₃₁ to R₃₈ each independently represent the same as R₃₁ to R₃₈ in the formula (3A); and * each represent a bonding position.

In the first compound, it is preferable that Ar₁ and Ar₂ are each independently a substituted or unsubstituted phenyl group, a substituted or unsubstituted biphenyl group, a substituted or unsubstituted terphenyl group, a substituted or unsubstituted dibenzofuranyl group, a substituted or unsubstituted dibenzothienyl group, a substituted or unsubstituted fluorenyl group, a substituted or unsubstituted carbazolyl group, a substituted or unsubstituted naphthyl group, or a substituted or unsubstituted phenanthrenyl group.

In the first compound, it is more preferable that Ar₁ and Ar₂ are each independently an unsubstituted phenyl group, an unsubstituted biphenyl group, an unsubstituted terphenyl group, an unsubstituted dibenzofuranyl group, an unsubstituted dibenzothienyl group, a substituted or unsubstituted fluorenyl group, a substituted or unsubstituted carbazolyl group, an unsubstituted naphthyl group, or an unsubstituted phenanthrenyl group.

The first compound is preferably a compound represented by one of formulae (301) to (310) below.

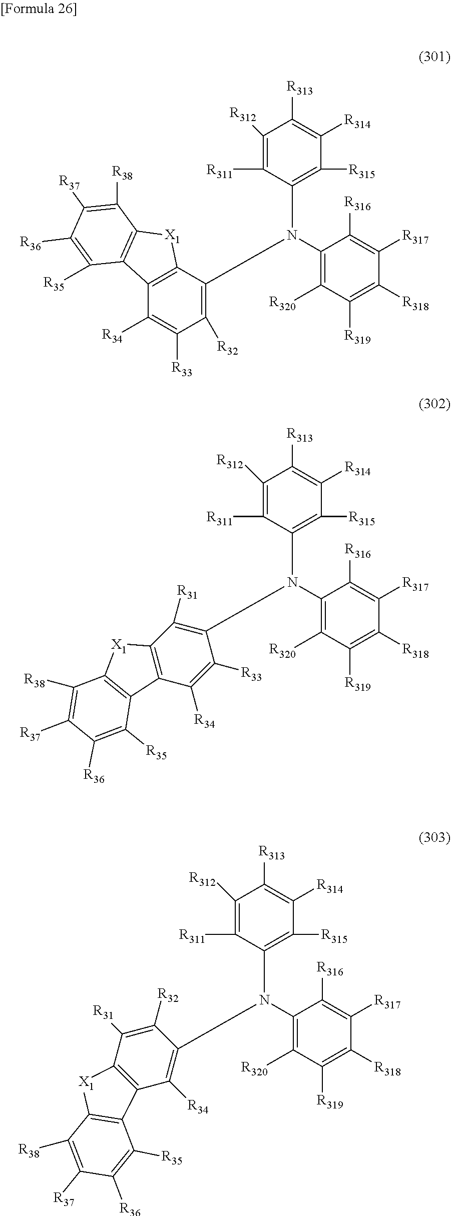

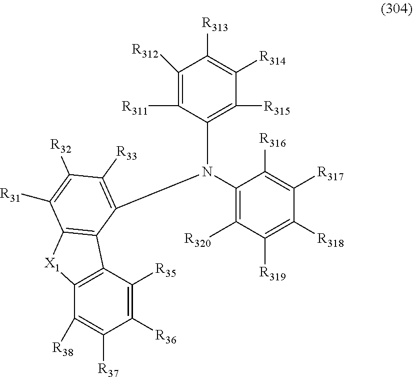

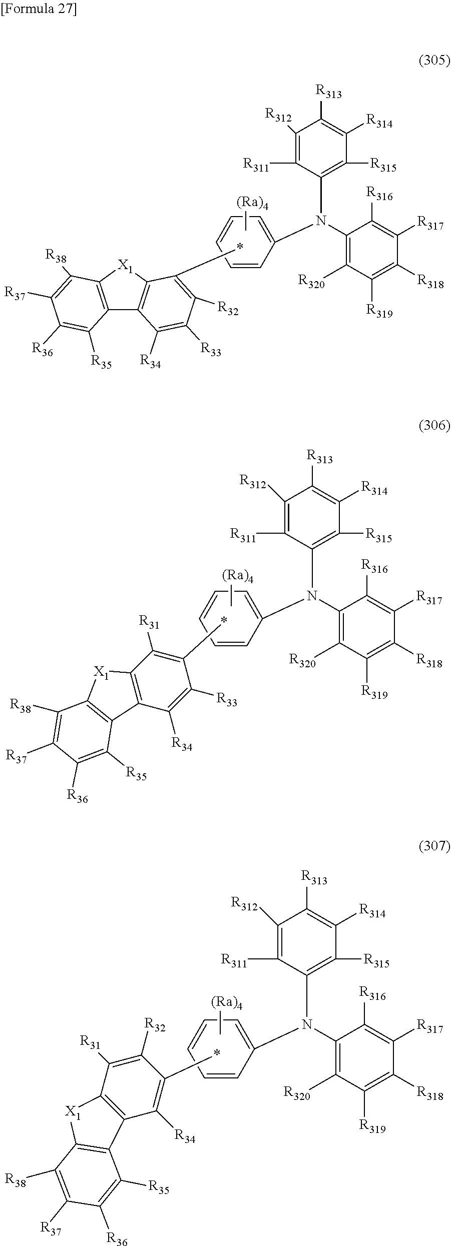

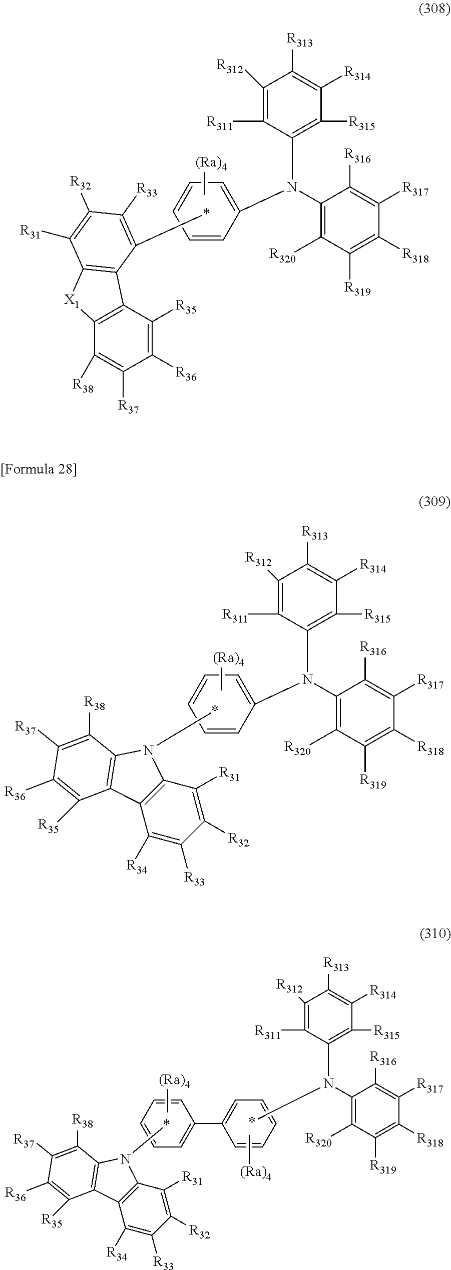

In the formulae (301) to (310):
X₁ and R₃₁ to R₃₈ each independently represent the same as X₁ and R₃₁ to R₃₆ in the formula (3A), and Ra each independently represent the same as Ra in the formula (32);
at least one combination of adjacent two or more of R₃₁₁ to R₃₁₅ are mutually bonded to form a substituted or unsubstituted monocyclic ring, mutually bonded to form a substituted or unsubstituted fused ring, or not mutually bonded;
at least one combination of adjacent two or more of R₃₁₆ to R₃₂₀ are mutually bonded to form a substituted or unsubstituted monocyclic ring, mutually bonded to form a substituted or unsubstituted fused ring, or not mutually bonded; and
R₃₁₁ to R₃₂₀ forming neither the substituted or unsubstituted monocyclic ring nor the substituted or unsubstituted fused ring each independently represent the same as Ra in the formula (32); * each represent a bonding position to a carbon atom in a six-membered ring having Ra; and 1* represents a bonding position to a carbon atom in a six-membered ring having Ra.

In the first compound, it is preferable that R₃₁ to R₃₈, R₄₁ to R₅₀, R₃₀₁ to R₃₀₃ and Ra are each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In the first compound, it is preferable that R₃₁ to R₃₈ and R₄₁ to R₅₀ are each independently a hydrogen atom, or a substituted or unsubstituted phenyl group.

In the first compound, it is preferable that R₃₁ to R₃₈ and R₄₁ to R₅₀ are each a hydrogen atom.

In the first compound, R₃₀₁ to R₃₀₃ are preferably each independently a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In the first compound, it is preferable that R₃₀₁ and R₃₀₂ are each independently a substituted or unsubstituted alkyl group having 1 to 50 carbon atoms, or a substituted or unsubstituted aryl group having 6 to 50 ring carbon atoms.

In the first compound, it is more preferable that R₃₀₁ and R₃₀₂ are each independently a methyl group, or a substituted or unsubstituted phenyl group.

In the first compound, it is also preferable that a combination of R₃₀₁ and R₃₀₂ are mutually bonded to form a substituted or unsubstituted monocyclic ring, or mutually bonded to form a substituted or unsubstituted fused ring.

In the first compound, it is preferable that Ra are each independently a hydrogen atom, an unsubstituted alkyl group having 1 to 50 carbon atoms, an unsubstituted aryl group having 6 to 50 ring carbon atoms, or an unsubstituted heterocyclic group having 5 to 50 ring atoms; and
it is more preferable that Ra are each independently a hydrogen atom.

In the first compound, it is preferable that R₃₁₁, to R₃₂₀ are each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In the first compound, it is also preferable that at least one combination of adjacent two or more of R₃₁₁ to Reis are mutually bonded to form a substituted or unsubstituted monocyclic ring, or mutually bonded to form a substituted or unsubstituted fused ring.

In the first compound, it is also preferable that at least one combination of adjacent two or more of R₃₁₆ to R₃₁₅ are mutually bonded to form a substituted or unsubstituted monocyclic ring, or mutually bonded to form a substituted or unsubstituted fused ring.

It is preferable that each substituent for the “substituted or unsubstituted” group for Ar₁ and Ar₂ is independently a substituted or unsubstituted phenyl group, a substituted or unsubstituted biphenyl group, a substituted or unsubstituted terphenyl group, a substituted or unsubstituted dibenzofuranyl group, a substituted or unsubstituted dibenzothienyl group, a substituted or unsubstituted fluorenyl group, a substituted or unsubstituted carbazolyl group, a substituted or unsubstituted naphthyl group, or a substituted or unsubstituted phenanthrenyl group.

It is more preferable that each substituent for the “substituted or unsubstituted” group for Ar₁ and Ar₂ is independently an unsubstituted phenyl group, an unsubstituted biphenyl group, an unsubstituted dibenzofuranyl group, an unsubstituted dibenzothienyl group, a substituted or unsubstituted fluorenyl group, a substituted or unsubstituted carbazolyl group, an unsubstituted naphthyl group, or an unsubstituted phenanthrenyl group.

In the first compound, it is preferable that each substituent for the “substituted or unsubstituted” group is independently the same as a substituent for the “substituted or unsubstituted” group for Ar₁ and Ar₂.

Ionization Potential Ip(HT1) of First Compound

The ionization potential Ip(HT1) of the first compound preferably satisfies a numerical formula (Numerical Formula 1A) below.

A method for measuring the ionization potential Ip is as described in Examples.

Ip(HT1)≥5.73 eV (Numerical Formula 1A)

Hole Mobility of First Compound μh(HT1)

The hole mobility of the first compound μh(HT1) preferably satisfies a numerical formula (Numerical Formula 2A) below.

$$μ h ( H T 1 ) \geq 5. \times {10}^{- 5} {cm}^{2} / Vs \qquad ( Numerical Formula 2 A )$$

Preferably, the ionization potential of the first compound Ip(HT1) satisfies the numerical formula (Numerical Formula 1A) and the hole mobility of the first compound μh(HT1) satisfies the numerical formula (Numerical Formula 2A).

### Method of Measuring Hole Mobility

The hole mobility can be measured according to impedance measurement using a mobility evaluation device produced by the following steps. The mobility evaluation device is, for instance, produced by the following steps.

A compound HA-2 below is vapor-deposited on a glass substrate having an ITO transparent electrode (anode) so as to cover the transparent electrode, thereby forming a hole injecting layer. A compound HT-A below is vapor-deposited on this formed hole injecting layer to form a hole transporting layer. Subsequently, a compound Target, which is to be measured for a hole mobility, is vapor-deposited to form a measurement target layer. Metal aluminum (Al) is vapor-deposited on this measurement target layer to form a metal cathode.

An arrangement of the mobility evaluation device above is roughly shown as follows.

ITO(130)/HA-2(5)/HT-A(10)/Target(200)/Al(80)

Numerals in parentheses represent a film thickness (nm).

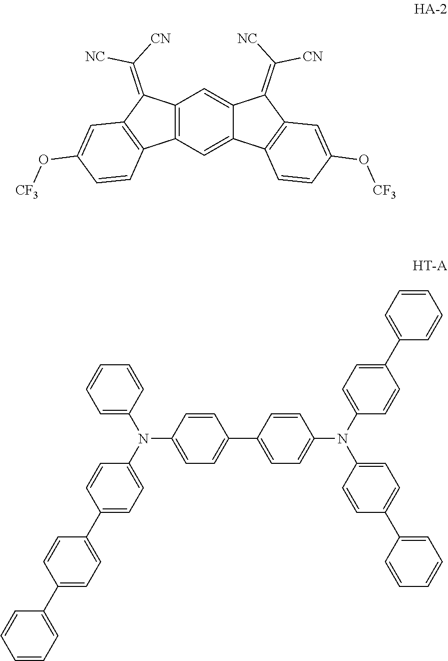 [SMILES: N#CC(C#N)=C1c2cc(OC(F)(F)F)ccc2-c2cc3c(cc21)C(=C(C#N)C#N)c1cc(OC(F)(F)F)ccc1-3 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

The mobility evaluation device for the hole mobility is set in an impedance measurement apparatus to perform impedance measurement. In the impedance measurement, a measurement frequency is swept from 1 Hz to 1 MHz. At this time, an alternating current amplitude of 0.1 V and a direct current voltage V are applied to the device. A modulus M is calculated from a measured impedance Z using the relationship of the calculation formula (C1).

In a bode plot in which an imaginary part of the modulus M is represented by an ordinate axis and the frequency [Hz] is represented by an abscissa axis, an electrical time constant τ of the mobility evaluation device is obtained from a frequency fmax showing a peak using the calculation formula (C2).

A hole mobility μh is calculated from a relationship of a calculation formula (C3-2) below using τ obtained from the calculation formula (C2).

μh=d²/(V_{τ}) Calculation Formula (C3-2):
d in the calculation formula (C3-2) is a total film thickness of organic thin film(s) forming the device In a case of the arrangement of the mobility evaluation device for the hole mobility, d=215 [nm] is satisfied.

The hole mobility herein is a value obtained in a case where a square root of an electric field intensity meets E^{1/2}=500 [V^{1/2}/cm^{1/2}]. The square root of the electric field intensity. E_{1/2}, can be calculated from a relationship of a calculation formula (C4) below.

E^{1/2}=V^{1/2} /d^{1/2} Calculation formula (C4).

For the impedance measurement, a 1260 type by Solartron Analytical is used as the impedance measurement apparatus, and for a higher accuracy, a 1296 type dielectric constant measurement interface by Solartron Analytical can be used together therewith.

### Method for Producing First Compound

The first compound can be produced by a known method.

Specific examples of the first compound include the following compounds. It should however be noted that the invention is not limited to the specific examples of the compound.

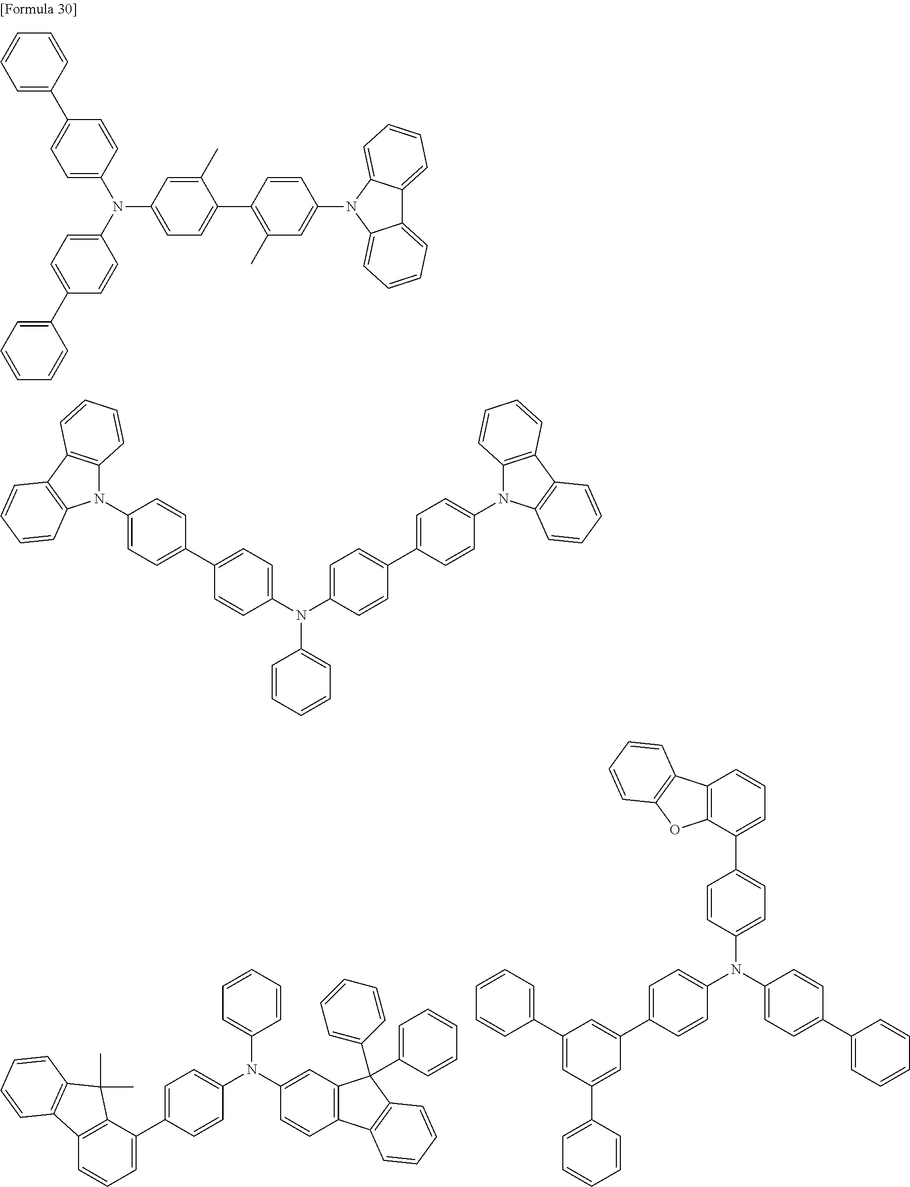

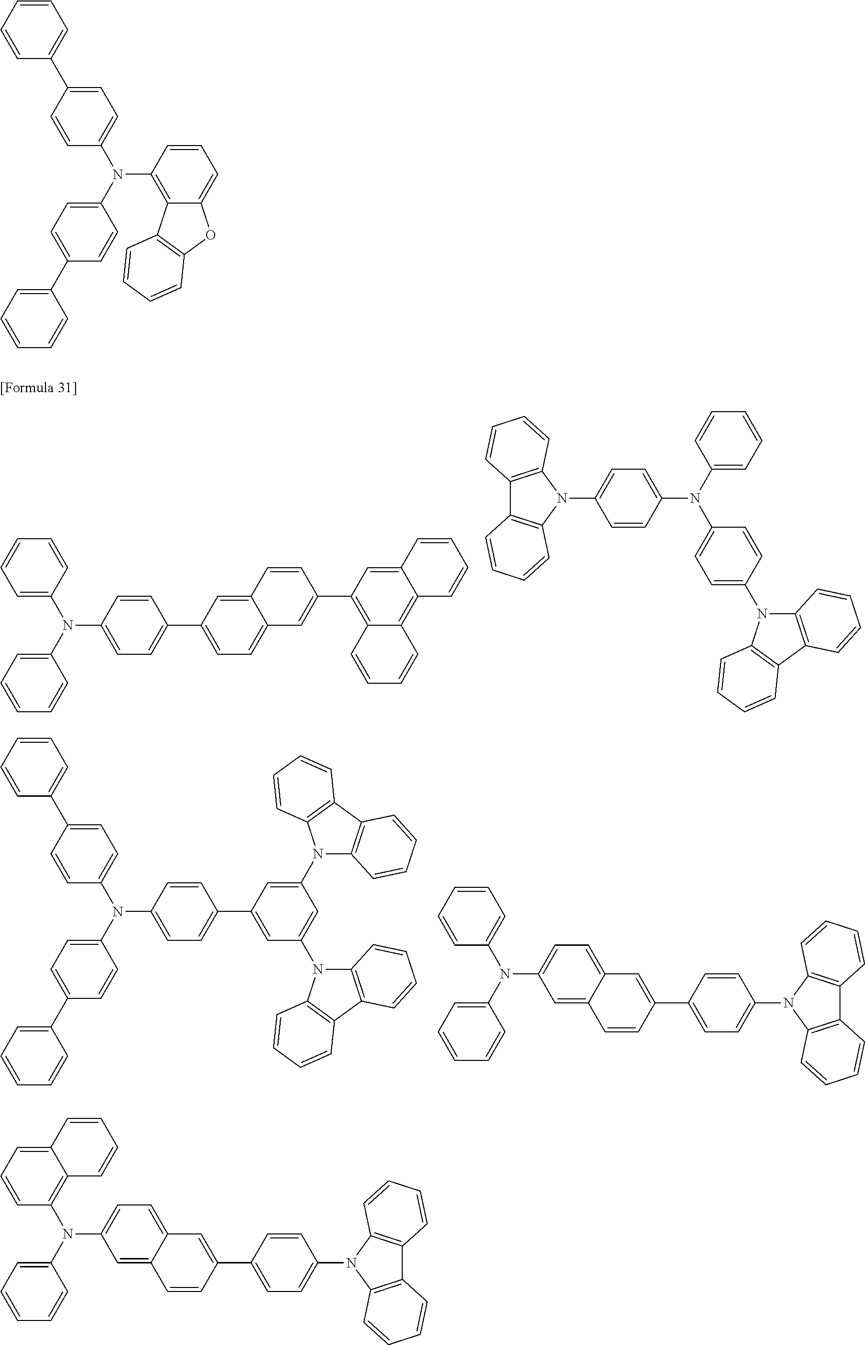

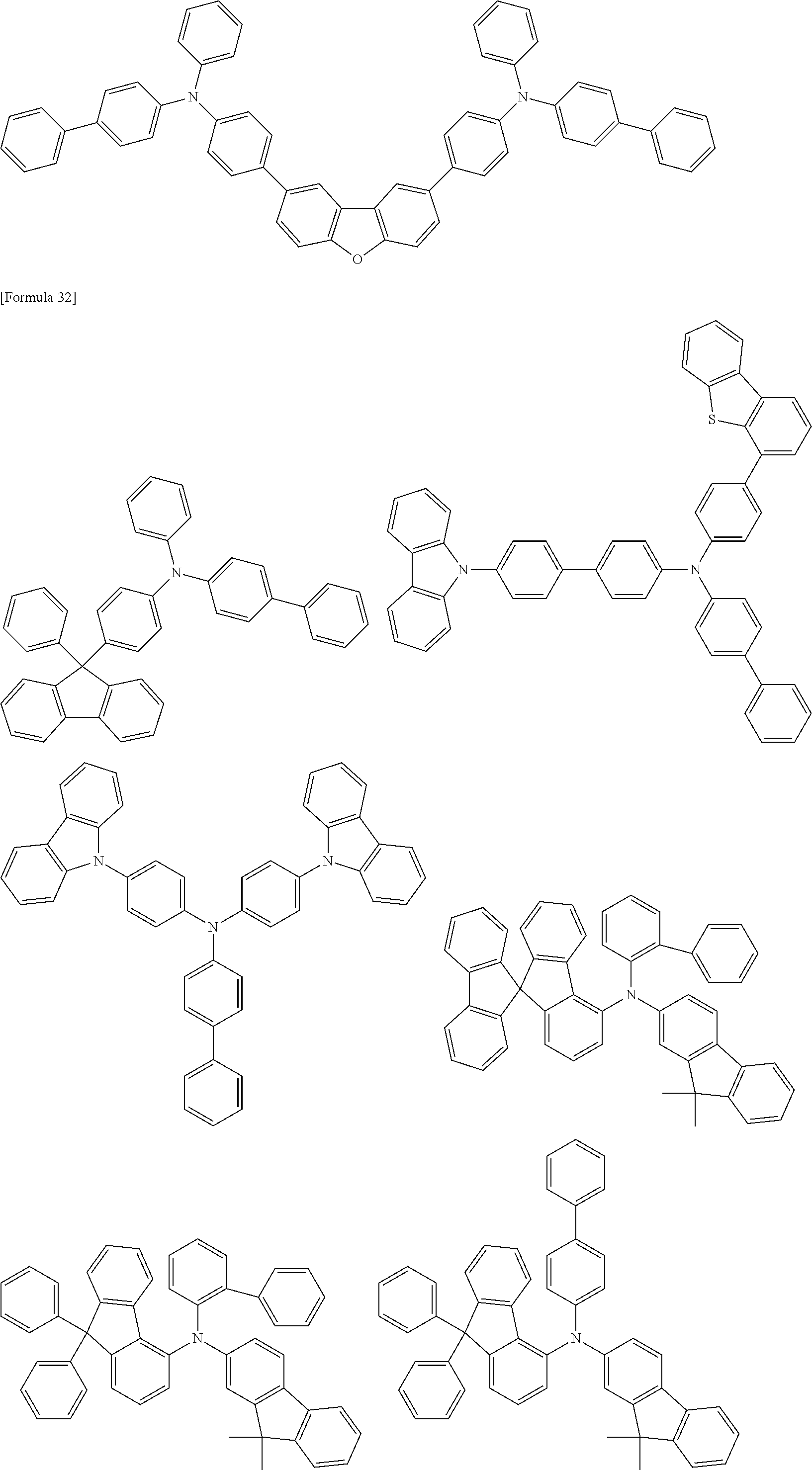

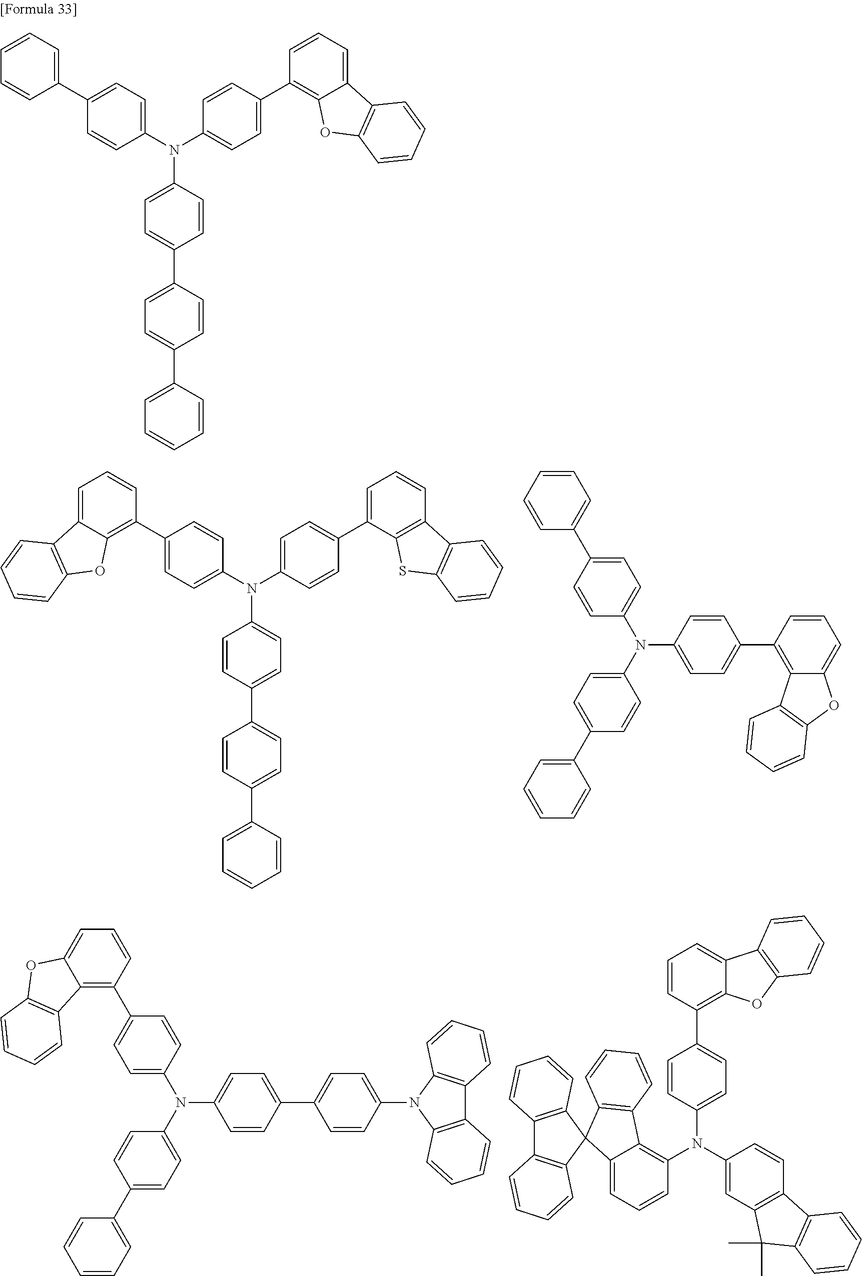

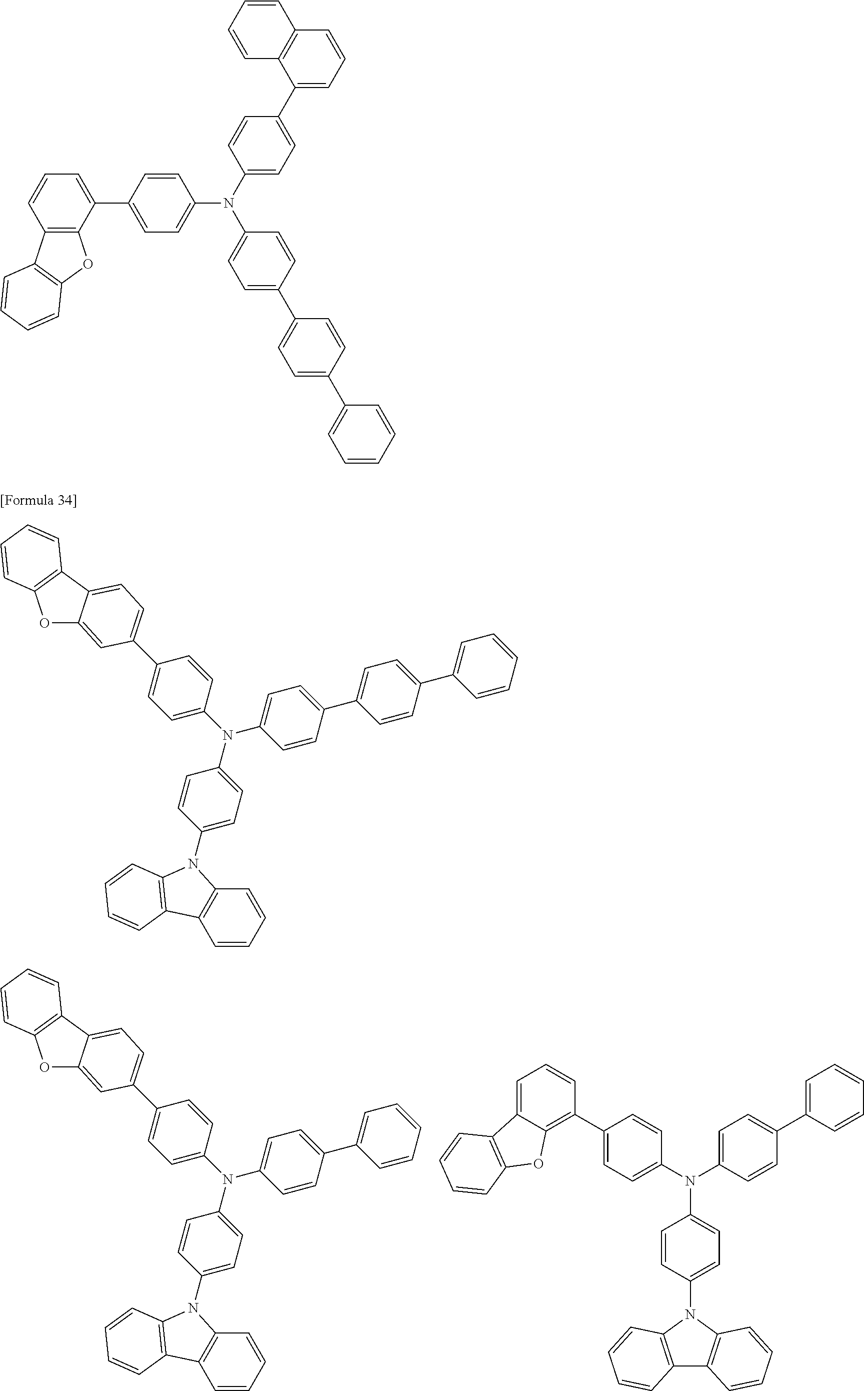

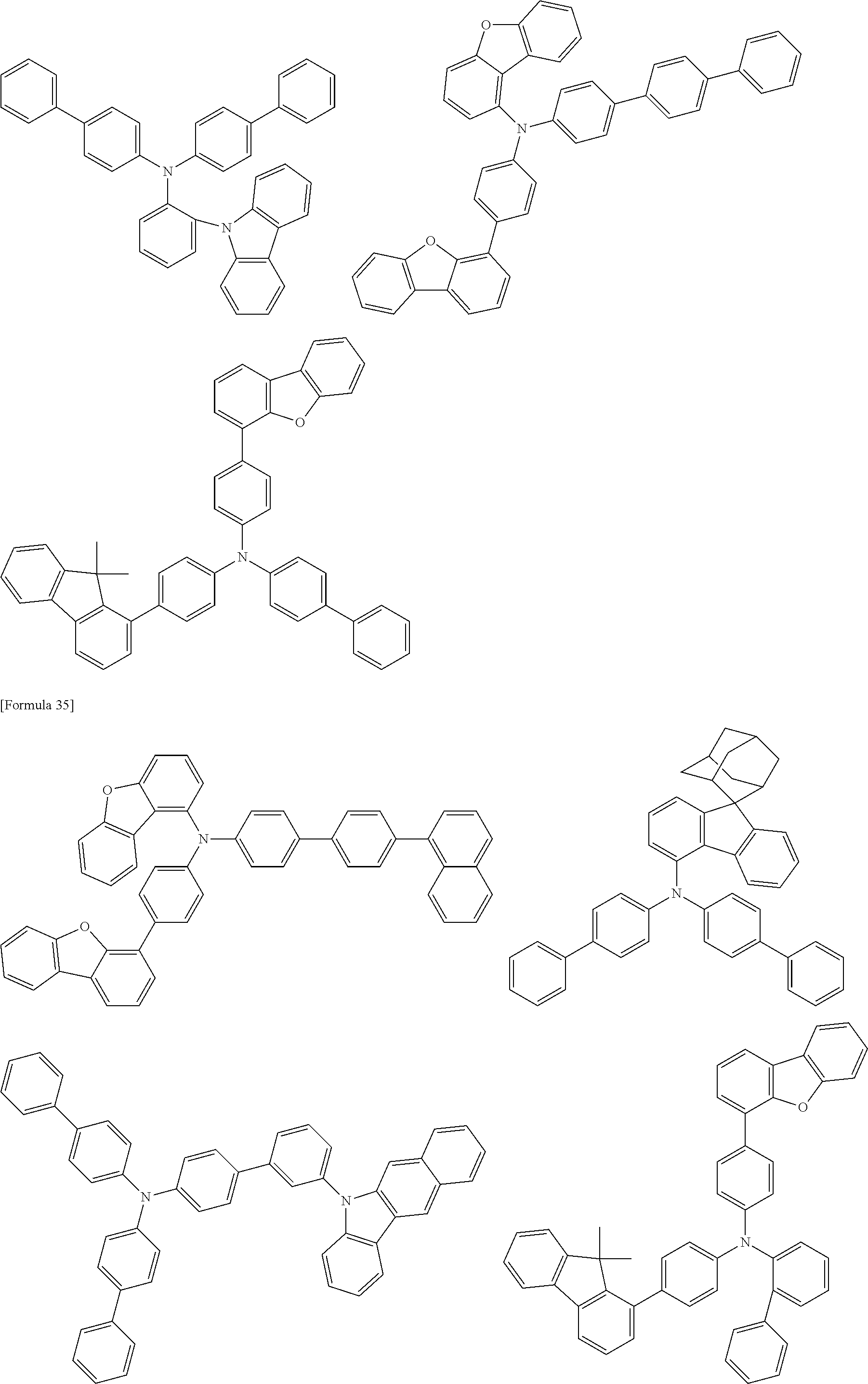

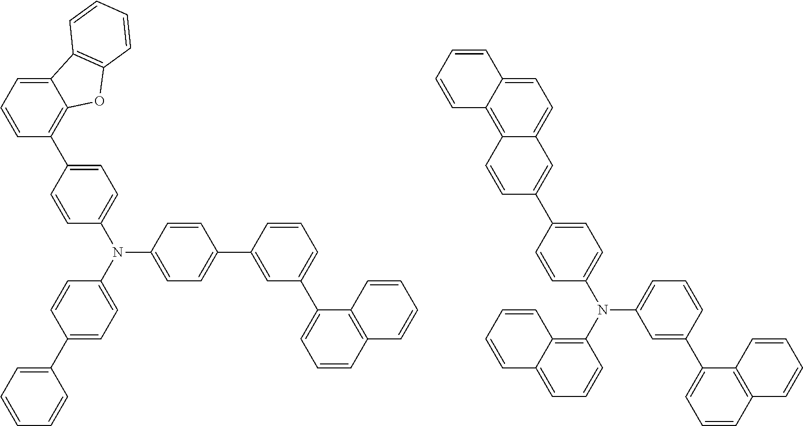 [SMILES: c1ccc(-c2ccc(N(c3ccc(-c4cccc(-c5cccc6ccccc56)c4)cc3)c3ccc(-c4cccc5c4oc4ccccc45)cc3)cc2)cc1 ; c1cc(-c2cccc3ccccc23)cc(N(c2ccc(-c3ccc4c(ccc5ccccc54)c3)cc2)c2cccc3ccccc23)c1]

The emitting layer according to the first exemplary embodiment contains at least a delayed fluorescent compound.

An arrangement of the first exemplary embodiment, in which the emitting layer contains a fluorescent compound M1 and a compound M2 as the delayed fluorescent compound, will be described below.

### Emitting Layer

The emitting layer of the organic EL device according to the exemplary embodiment contains the fluorescent compound M1 and the compound M2 as the delayed fluorescent compound.

In this arrangement, the compound M2 is preferably a host material (occasionally also referred to as a matrix material). The compound M1 is preferably a dopant material (occasionally also referred to as a guest material, emitter or luminescent material).

### Compound M2

### Delayed Fluorescence

Delayed fluorescence is explained in “Yuki Hando-tai no Debaisu Bussei (Device Physics of Organic Semiconductors)” (edited by ADACHI, Chihaya, published by Kodansha, on pages 261-268). This document describes that, if an energy difference ΔE₁₃ of a fluorescent material between a singlet state and a triplet state is reducible, a reverse energy transfer from the triplet state to the singlet state, which usually occurs at a low transition probability, would occur at a high efficiency to express thermally activated delayed fluorescence (TADF). Further, a generation mechanism of delayed fluorescence is explained in FIG. 10.38 in the document. The compound M2 of the exemplary embodiment is preferably a compound exhibiting thermally activated delayed fluorescence generated by such a mechanism.

In general, emission of delayed fluorescence can be confirmed by measuring the transient PL (Photo Luminescence).

The behavior of delayed fluorescence can also be analyzed based on the decay curve obtained from the transient PL measurement. The transient PL measurement is a method of irradiating a sample with a pulse laser to excite the sample, and measuring the decay behavior (transient characteristics) of PL emission after the irradiation is stopped. PL emission in TADF materials is classified into a light emission component from a singlet exciton generated by the first PL excitation and a light emission component from a singlet exciton generated via a triplet exciton. The lifetime of the singlet exciton generated by the first PL excitation is on the order of nanoseconds and is very short. Therefore, light emission from the singlet exciton rapidly attenuates after irradiation with the pulse laser.

On the other hand, the delayed fluorescence is gradually attenuated due to light emission from a singlet exciton generated via a triplet exciton having a long lifetime. As described above, there is a large temporal difference between the light emission from the singlet exciton generated by the first PL excitation and the light emission from the singlet exciton generated via the triplet exciton Therefore, the luminous intensity derived from delayed fluorescence can be determined.

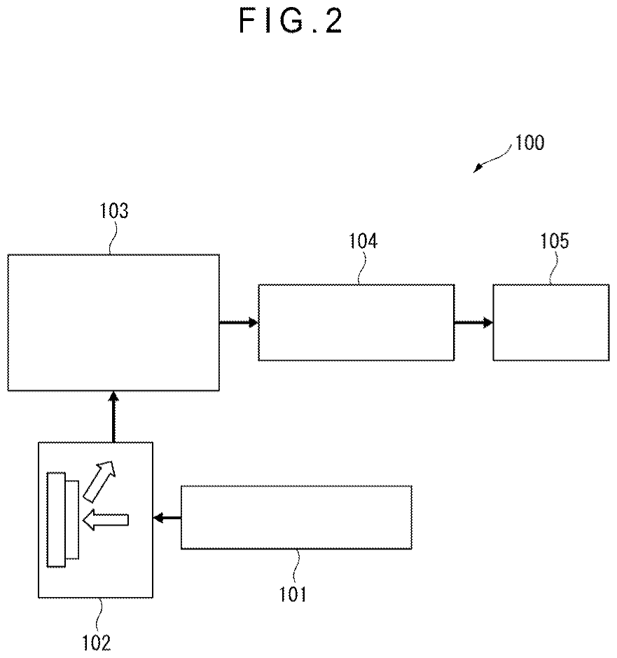

FIG. 2 is a schematic diagram of an exemplary apparatus for measuring the transient PL. An example of a method of measuring a transient PL using FIG. 2 and an example of behavior analysis of delayed fluorescence will be described.

A transient PL measuring apparatus 100 in FIG. 2 includes: a pulse laser 101 capable of radiating light having a predetermined wavelength, a sample chamber 102 configured to house a measurement sample; a spectrometer 103 configured to divide light radiated from the measurement sample; a streak camera 104 configured to provide a two-dimensional image; and a personal computer 105 configured to import and analyze the two-dimensional image. An apparatus for measuring the transient PL is not limited to the apparatus depicted in FIG. 2.

The sample housed in the sample chamber 102 is obtained by forming a thin film, in which a matrix material is doped with a doping material at a concentration of 12 mass %, on the quartz substrate.

The thin film sample housed in the sample chamber 102 is irradiated with the pulse laser from the pulse laser 101 to excite the doping material. Emission is extracted in a direction of 90 degrees with respect to a radiation direction of the excited light. The extracted emission is divided by the spectrometer 103 to form a two-dimensional image in the streak camera 104. As a result, the two-dimensional image is obtainable in which the ordinate axis represents a time, the abscissa axis represents a wavelength, and a bright spot represents a luminous intensity. When this two-dimensional image is taken out at a predetermined time axis, an emission spectrum in which the ordinate axis represents the luminous intensity and the abscissa axis represents the wavelength is obtainable. Moreover, when this two-dimensional image is taken out at the wavelength axis, a decay curve (transient PL) in which the ordinate axis represents a logarithm of the luminous intensity and the abscissa axis represents the time is obtainable.

(0178)

For instance, a thin film sample A was prepared as described above from a reference compound H1 as the matrix material and a reference compound D1 as the doping material and was measured in terms of the transient PL.

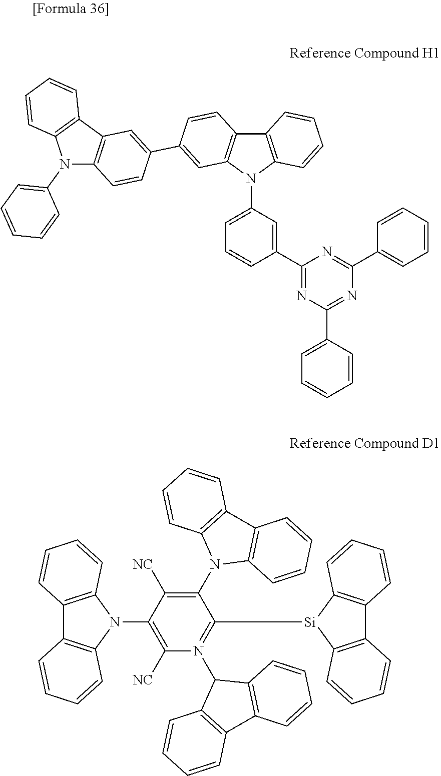

The decay curve was analyzed for the above thin film sample A and a thin film sample B. The thin film sample B was produced in the same manner as described above from a reference compound H2 as the matrix material and the reference compound D1 as the doping material.

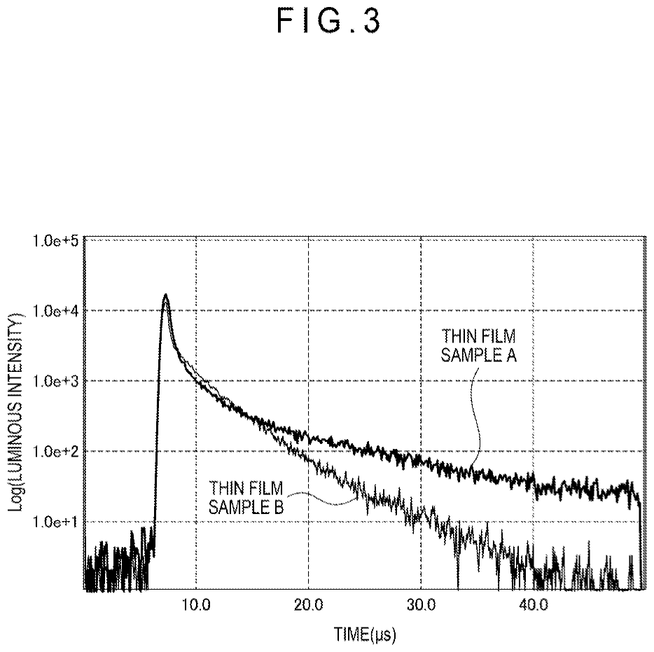

FIG. 3 illustrates decay curves obtained from the transient PL obtained by measuring the thin film samples A and B.

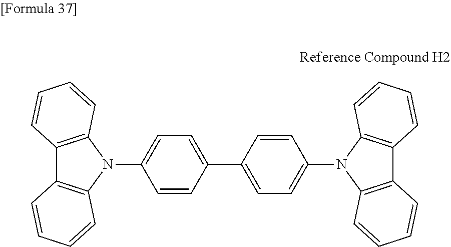 [SMILES: c1ccc2c(c1)c1ccccc1n2-c1ccc(-c2ccc(-n3c4ccccc4c4ccccc43)cc2)cc1]

As described above, an emission decay curve in which the ordinate axis represents the luminous intensity and the abscissa axis represents the time can be obtained by the transient PL measurement. Based on the emission decay curve, a fluorescence intensity ratio between fluorescence emitted from a singlet state generated by photo-excitation and delayed fluorescence emitted from a singlet state generated by reverse energy transfer via a triplet state can be estimated, in a delayed fluorescent material, a ratio of the intensity of the slowly decaying delayed fluorescence to the intensity of the promptly decaying fluorescence is relatively large.

Specifically, Prompt emission and Delay emission are present as emission from the delayed fluorescent material. Prompt emission is observed promptly when the excited state is achieved by exciting the compound of the exemplary embodiment with a pulse beam (i.e., a beam emitted from a pulse laser) having a wavelength absorbable by the delayed fluorescent material. Delay emission is observed not promptly when the excited state is achieved but after the excited state is achieved.

An amount of Prompt emission, an amount of Delay emission and a ratio between the amounts thereof can be obtained according to the method as described in “Nature 492, 234-238, 2012” (Reference Document 1). The amount of Prompt emission and the amount of Delay emission may be calculated using an apparatus different from one described in Reference Document 1 or one depicted in FIG. 2.

Herein, a sample produced by the following method is used for measuring delayed fluorescence of the compound M2. For instance, the compound M2 is dissolved in toluene to prepare a dilute solution with an absorbance of 0.05 or less at the excitation wavelength to eliminate the contribution of self-absorption. In order to prevent quenching due to oxygen, the sample solution is frozen and degassed and then sealed in a cell with a lid under an argon atmosphere to obtain an oxygen-free sample solution saturated with argon.

The fluorescence spectrum of the sample solution is measured with a spectrofluorometer FP-8600 (produced by JASCO Corporation), and the fluorescence spectrum of a 9,10-diphenylanthracene ethanol solution is measured under the same conditions. Using the fluorescence area intensities of both spectra, the total fluorescence quantum yield is calculated by an equation (1) in Morris et al. J. Phys. Chem. 80 (1976) 969.

In the exemplary embodiment, provided that an amount of Prompt emission of a measurement target compound (compound M2) is denoted by X_{P} and an amount of Delay emission is denoted by X_{D}, a value of X_{D}/X_{P} is preferably 0.05 or more.

The amounts of Prompt emission and Delay emission and a ratio of the amounts thereof in any other compounds than the compound M2 herein are measured in the same manner as those of the compound M2

### Compound Represented by Formula (2)

In the exemplary embodiment, the delayed fluorescent compound M2 is preferably a compound represented by a formula (2) below.

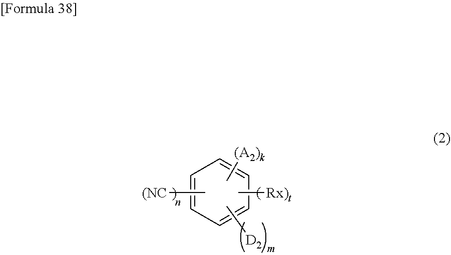

In the formula (2):
k is 1, 2, 3 or 4;
m is 1, 2, 3 or 4;
n is 1 or 2;
t is 0, 1, 2 or 3;
k+m+n+t=6 is satisfied.
when t is 2 or 3, a plurality of Rx are mutually the same or different;
A₂ is a group represented by a formula (21) below;
when k is 2, 3, or 4, a plurality of A2 are mutually the same or different;
D2 is a group represented by a formula (22) below;
when m is 2, 3, 4, a plurality of D2 are mutually the same or different; and CN is a cyano group.

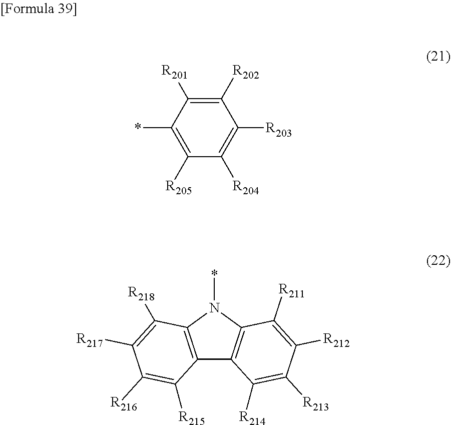

In the formula (21):
at least one combination of adjacent two or more of R₂₀₁ to R₂₀₅ are mutually bonded to form a substituted or unsubstituted monocyclic ring, mutually bonded to form a substituted or unsubstituted fused ring, or not mutually bonded, in the formula (22)
at least one combination of adjacent two or more of R₂₁₁ to R₂₁₈ are mutually bonded to form a substituted or unsubstituted monocyclic ring, mutually bonded to form a substituted or unsubstituted fused ring, or not mutually bonded; and
* in the formulae (21) and (22) each represent a bonding position to a benzene ring in the formula (2).
Rx in the formula (2), R₂₀₁ to R₂₀₆ in the formula (21) forming neither the substituted or unsubstituted monocyclic ring nor the substituted or unsubstituted fused ring, and R₂₁₁ to R₂₁₈ in the formula (22) forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by COOR₉₀₉, a halogen atom, a cyano group, a nitro group, a group represented by —P(═O)(R₉₃₁)(R₉₃₇), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms.

In the compound M2 and the compound M3, R₉₀₁, R₉₀₂, R₉₀₃, R₉₀₄, R₉₀₅, R₉₀₆, R₉₀₇, R₉₀₈, R₉₀₉, R₉₃₁, R₉₃₂, R₉₃₃, R₉₃₄, R₉₃₅, R₉₃₆ and R₉₃₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different,
when a plurality of R₉₀₇ are present, the plurality of R₉₀₇ are mutually the same or different;
when a plurality of R₉₀₈ are present, the plurality of R₉₀₈ are mutually the same or different;
when a plurality of R₉₀₉ are present, the plurality of R₉₀₉ are mutually the same or different;
when a plurality of R₉₃₁ are present, the plurality of R₉₃₁ are mutually the same or different;
when a plurality of R₉₃₂ are present, the plurality of R₉₃₂ are mutually the same or different;
when a plurality of R₉₃₃ are present, the plurality of R₉₃₃ are mutually the same or different;
when a plurality of R₉₃₄ are present, the plurality of R₉₃₄ are mutually the same or different,
when a plurality of R₉₃₅ are present, the plurality of R₉₃₅ are mutually the same or different;
when a plurality of R₉₃₆ are present, the plurality of R₉₃₆ are mutually the same or different; and
when a plurality of R₉₃₇ are present, the plurality of R₉₃₇ are mutually the same or different.

In the formula (2), n is preferably 2. The compound M2 is also preferably a dicyanobenzene compound in which two cyano groups are bonded to a benzene ring.

The compound M2 is also preferably a compound represented by a formula (201) below.

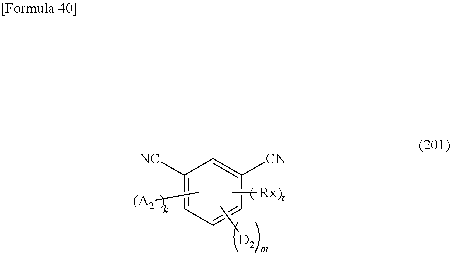

In the formulae (201):
A₂, D₂ and Rx respectively represent the same as A₂, D₂ and Rx in the formula (2);
k is 1, 2, or 3,
m is 1, 2, or 3;
t is 0, 1, or 2; and
k+m+t=4 is satisfied.

The compound M2 is also preferably a compound represented by a formula (210) or a formula (230) below.

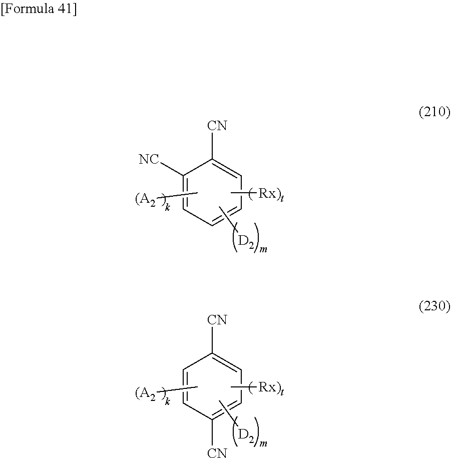

In the formulae (210) and (230):
A₂, O₂ and Rx respectively represent the same as A₂, O₂ and Rx in the formula (2);
k is 1, 2, or 3;
m is 1, 2, or 3;
t is 0, 1, or 2; and
k+m+t=4 is satisfied.

In the compound M2, m is preferably 2.

The compound M2 is also preferably a compound represented by a formula (211) below.

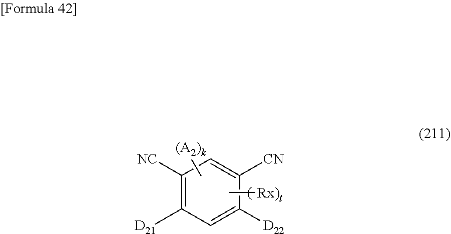

In the formula (211):
D₂₁ and D₂₂ each independently represent the same as D₂;
A₂ and Rx respectively represent the same as A₂ and Rx in the formula (2),
k is 1 or 2;
t is 0 or 1; and
k+t=2 is satisfied.

In the compound M2, D₂₁ and D₂₂ are mutually the same or different.

In the compound M2, k is preferably 1 or 2, more preferably 2.

The compound M2 is also preferably a compound represented by a formula (202) or a formula (203) below.

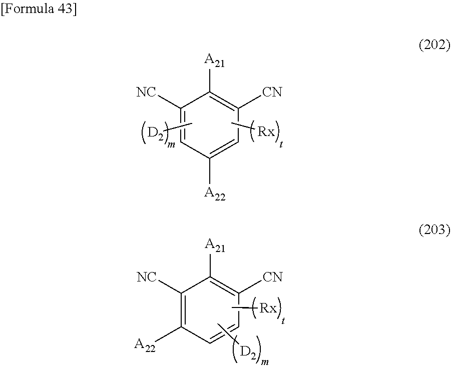

In the formula (202) or (203):
A₂₁ and A₂₂ each independently represent the same as A₂;
D₂ and Rx respectively represent the same as D₂ and Rx in the formula (2);
m is 1 or 2;
t is 0 or 1; and
m+t=2 is satisfied.

In the compound M2, A₂₁ and A₂₂ are mutually the same or different.

The compound M2 is also preferably a compound represented by a formula (221) below.

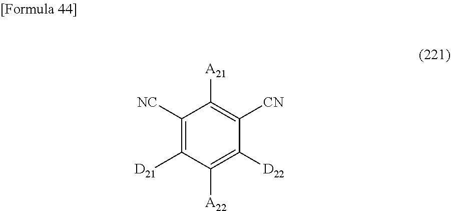

In the formula (221):
A₂₁ and A₂₂ each independently represent the same as A₂; and
D₂₁ and D₂₂ each independently represent the same as D₂

The compound M2 is also preferably a compound represented by a formula (222) below.

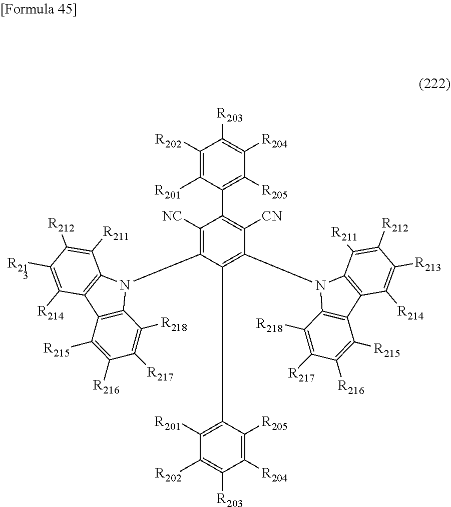

In the formula (222), R₂₀₁ to R₂₀₅ each independently represent the same as R₂₀₁ to R₂₀₅ in the formula (21), and R₂₁₁ to R₂₁₈ each independently represent the same as R₂₁₁ to R₂₂₈ the formula (22).

In the compound M2, a plurality of R₂₀₁ are mutually the same or different, a plurality of R₂₀₂ are mutually the same or different, a plurality of R₂₀₃ are mutually the same or different, a plurality of R₂₀₄ are mutually the same or different, a plurality of R₂₀₅ are mutually the same or different, a plurality of R₂₁₁ are mutually the same or different, a plurality of R₂₁₂ are mutually the same or different, a plurality of R₂₁₃ are mutually the same or different, a plurality of R₂₁₄ are mutually the same or different, a plurality of R₂₁₅ are mutually the same or different, a plurality of R₂₁₆ are mutually the same or different, a plurality of R₂₁₇ are mutually the same or different, and a plurality of R₂₁₈ are mutually the same or different.

In the compound M2. Rx, R₂₀₁ to R₂₀₆ forming neither the substituted or unsubstituted monocyclic ring nor the substituted or unsubstituted fused ring, and R₂₁₁ to R₂₁₈ forming neither the substituted or unsubstituted monocyclic ring nor the substituted or unsubstituted fused ring are preferably each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In the compound M2, Rx, R₂₀₁ to R₂₀₅ forming neither the substituted or unsubstituted monocyclic ring nor the substituted or unsubstituted fused ring, and R₂₁₁ to R₂₁₈ forming neither the substituted or unsubstituted monocyclic ring nor the substituted or unsubstituted fused ring are preferably each independently a hydrogen atom, or a substituted or unsubstituted aryl group having 6 to 50 ring carbon atoms.

In the compound M2, Rx. R₂₀₁ to R₂₀₅ forming neither the substituted or unsubstituted monocyclic ring nor the substituted or unsubstituted fused ring, and R₂₁₁ to R₂₁₈ forming neither the substituted or unsubstituted monocyclic ring nor the substituted or unsubstituted fused ring are each preferably a hydrogen atom.

In the compound M2, A₂ is preferably a group selected from the group consisting of groups represented by formulae (A21) to (A25) below.

In the compound M2, A₂₁ and A₁₂ are preferably each independently a group selected from the group consisting of groups represented by the formulae (A21) to (A25).

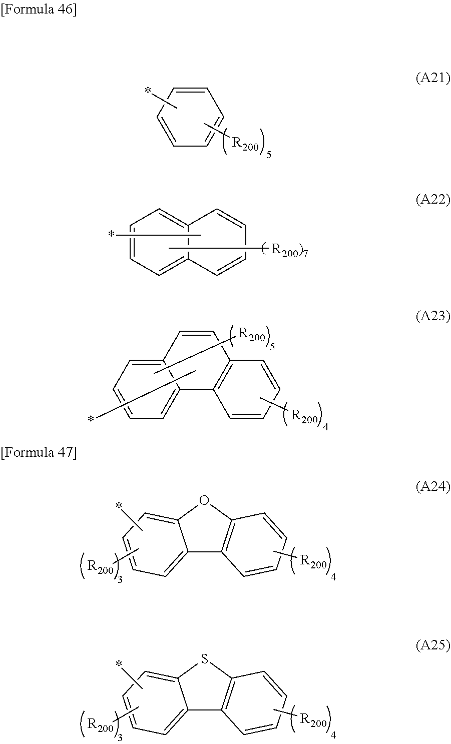

In the formulae (A21) to (A25):
at least one combination of adjacent two or more of a plurality of R₂₀₀ are mutually bonded to form a substituted or unsubstituted monocyclic ring, mutually bonded to form a substituted or unsubstituted fused ring, or not mutually bonded;
each R₂₀₀ forming neither the substituted or unsubstituted monocyclic ring nor the substituted or unsubstituted fused ring is independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a halogen atom, a cyano group, a nitro group, a substituted or unsubstituted aryl group having 6 to 50 ring carbon atoms, or a substituted or unsubstituted heterocyclic group having 5 to 50 ring atoms; and
* in the formulae (A21) to (A25) each represent a bonding position to a benzene ring in the formula (2).

In the compound M2, A₂ is preferably a group selected from the group consisting of groups represented by the formulae (A21), (A24), and (A25).

In the compound M2, A₂₁ and A₂₂ are preferably each independently a group selected from the group consisting of groups represented by the formulae (A21). (A24), and (A25).

In the compound M2, A₂ is preferably a group represented by the formula (A21).

In the compound M2, A₂₁ and A₂₂ are each preferably a group represented by the formula (A21).

In the compound M2, none of a combination(s) of adjacent two or more of a plurality of R₂₀₀ are also preferably bonded to each other.

In the compound M2, A₂ is preferably a group represented by the formula (A21) in which R₂₀₀ is a hydrogen atom.

In the compound M2, A₂₁ and A₂₂ are each preferably a group represented by the formula (A21) in which R₂₀₀ in the formula (A21) is a hydrogen atom.

R₂₀₀ in the formulae (A21) to (A25) are preferably each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

R₂₀₀ in the formulae (A21) to (A25) are preferably each independently a hydrogen atom, or a substituted or unsubstituted aryl group having 6 to 50 ring carbon atoms.

R₂₀₀ in the formulae (A21) to (A25) are each preferably a hydrogen atom.

In the compound M2, D₂ is preferably a group selected from the group consisting of groups represented by formulae (B21) to (B23) below.

In the compound M2, D₂₁ and D₂₂ are preferably each independently a group selected from the group consisting of groups represented by the formula (B21) to (B23).

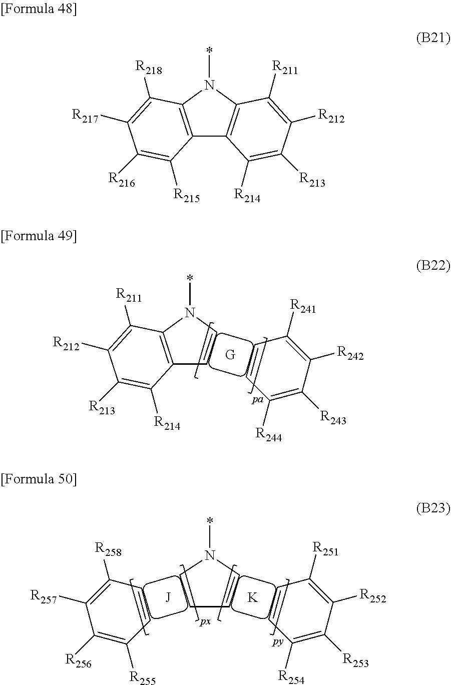

in the formula (B22), at least one combination of adjacent two or more of R₂₁₁ to R₂₁₄ and R₂₄₁ to R₂₄₄ are mutually bonded to form a substituted or unsubstituted monocyclic ring, mutually bonded to form a substituted or unsubstituted fused ring, or not mutually bonded;
in the formula (23), at least one combination of adjacent two or more of R₂₅₁ to R₂₅₈ are mutually bonded to form a substituted or unsubstituted monocyclic ring, mutually bonded to form a substituted or unsubstituted fused ring, or not mutually bonded; and
R₂₁₁ to R₂₁₈ in the formula (B21), R₂₁₁ to R₂₁₄ and R₂₄₁ to R₂₄₄ in the formula (B22) forting neither the substituted or unsubstituted monocyclic ring nor the substituted or unsubstituted fused ring, and R₂₅₁ to R₂₅₈ in the formula (B23) forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)₉₀₈, a group represented by —COO₉₀₉, a halogen atom, a cyano group, a nitro group, a group represented by —P(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms; in the formulae (B22j and (B23):
a ring G, a ring J, and a ring K are each independently a cyclic structure selected from the group consisting of cyclic structures represented by a formula (B24) and a formula (B25) below;
the ring G, the ring J, and the ring K are fused with adjacent rings at any positions;
pa, px, and py are each independently 1, 2, 3 or 4;
when pa is 2, 3, or 4, a plurality of rings G are mutually the same or different;
when px is 2, 3, or 4, a plurality of rings J are mutually the same or different;
when py is 2, 3, or 4, a plurality of rings K are mutually the same or different; and
* in the formulae (B21) to (B23) each represent a bonding position to a benzene ring in the formula (2).

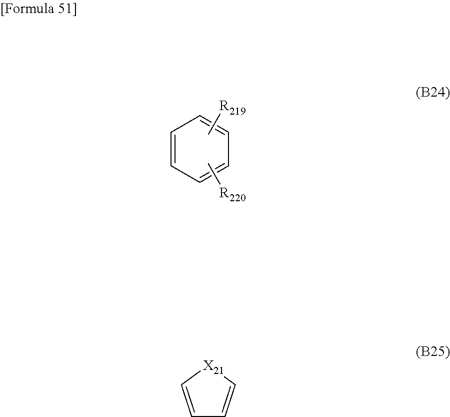

In the formula (B24):
a combination of R₂₁₉ and R₂₂₀ are mutually bonded to form a substituted or unsubstituted monocyclic ring, mutually bonded to form a substituted or unsubstituted fused ring, or not mutually bonded:
in the formula (B25)
X₂₁ is a sulfur atom, an oxygen atom, NR₂₆₁, or CR₂₆₂R₂₅₃;
a combination of R₂₆₂ and R₂₆₃ are mutually bonded to form a substituted or unsubstituted monocyclic ring, mutually bonded to form a substituted or unsubstituted fused ring, or not mutually bonded; and
R₂₆₁, R₂₁₉ and R₂₂₀ forming neither the substituted or unsubstituted monocyclic ring nor the substituted or unsubstituted fused ring, and R₂₆₂ and R₂₆₃ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a halogen atom, a cyano group, a nitro group, a group represented by —P(═O)(R₉₃₁)(R₉₃₄), a group represented by —Ge(R₉₃₃)(R₉₃₄)(R₉₃₅), a group represented by —B(R₉₆₆)(R₉₃₇), a substituted or unsubstituted aryl group having 6 to 50 ring carbon atoms, or a substituted or unsubstituted heterocyclic group having 5 to 50 ring atoms.

In the compounds according to the exemplary embodiment, the benzene ring in the formula (2) bonded to groups represented by the formulae (B21) to (B23) or the like is not benzene rings contained in A₂, D₂, and Rx, but a benzene ring itself expressly shown in the formula (2). Also in compounds represented by formulae (201), (210), (230), (211), (202), (203), and (221) below, the groups represented by the formulae (B21) to (B23) or the like are bonded to benzene rings themselves expressly shown in these formulae, as with a case of the formula (2).

None of combinations of adjacent two or more of R₂₁₁ to R₂₁₈ in the formula (B21) are bonded to each other.

In the compound M2, R₂₁₁ to R₂₁₈ in the formula (B21), R₂₁₁ to R₂₁₄ and R₂₄₁ to R₂₄₄ in the formula (B22), R₂₅₁ to R₂₅₈ in the formula (B23), and R₂₁₉ and R₂₂₀ in the formula (B24) are preferably each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In compound M2, R₂₁₁ to R₂₁₈ is in the formula (B21), R₂₁₁ to R₂₁₄ and R₂₄₁ to R₂₄₄ in the formula (B22), R₂₅₁ to R₂₅₈ in the formula (B23), and R₂₁₉ and R₂₂₀ in the formula (B24) are preferably each independently a hydrogen atom, or a substituted or unsubstituted aryl group having 6 to 50 ring carbon atoms.

In compound M2, R₂₁₁ to R₂₁₈ in the formula (B21), R₂₁₁ to R₂₁₄ and R₂₄₁ to R₂₄₄ in the formula (B22), R₂₅₁ to R₂₅₈ in the formula (B23), and R₂₁₉ and R₂₂₀ in the formula (B24) are each preferably a hydrogen atom.

in the compound M2, R₂₆₁ is preferably a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In the compound M2, it is preferable that:
a combination of R₂₆₂ and R₂₆₃ are mutually bonded to form a substituted or unsubstituted monocyclic ring, mutually bonded to form a substituted or unsubstituted fused ring, or not mutually bonded; and
R₂₆₂ and R₂₆₃ forming neither the substituted or unsubstituted monocyclic ring nor the substituted or unsubstituted fused ring are each independently a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In compound M2, it is preferable that:
the formula (B22) is a cyclic structure selected from the group consisting of formulae (a1) to (a6) below; and
in the formula (B23), px and py are each independently 2, at least one ring J is a cyclic structure represented by the formula (B25), and at least one ring K is a cyclic structure represented by the formula (B25).

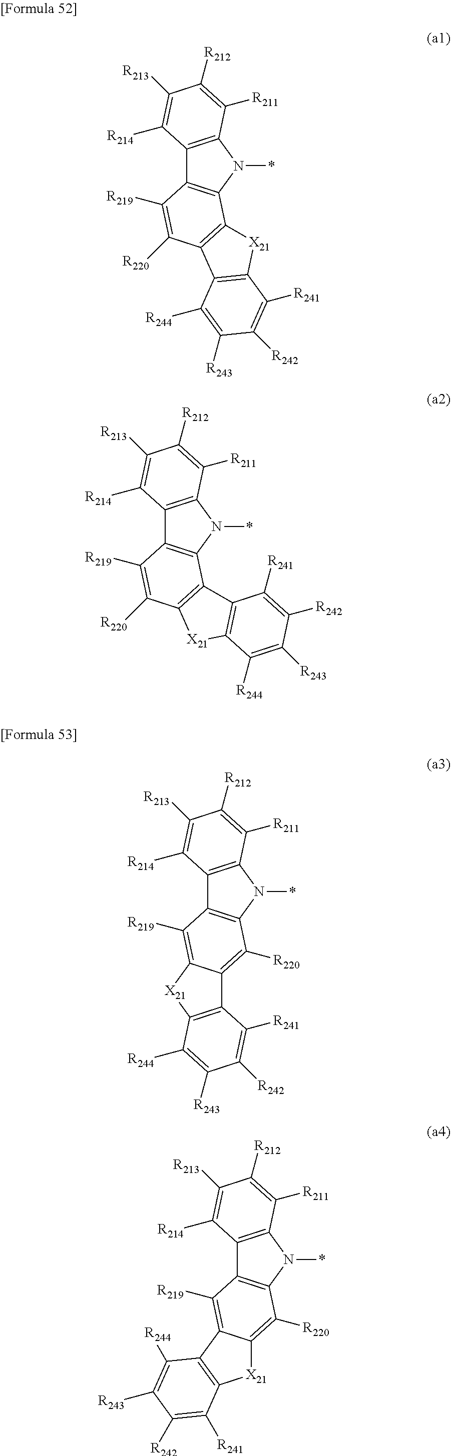

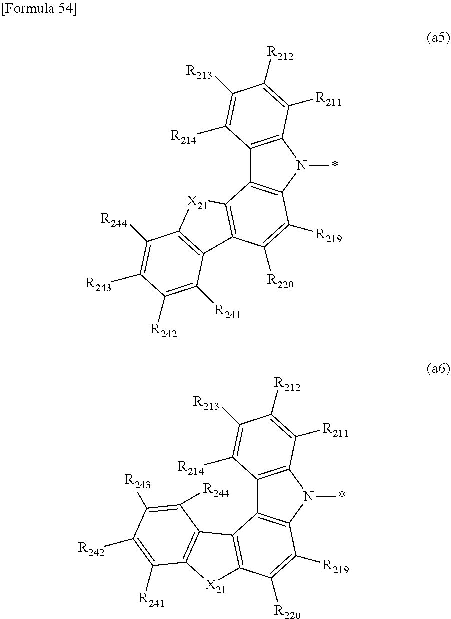

In the formulae (a1) to (a6):
R₂₁₁ to R₂₁₄ and R₂₄₁ to R₂₄₄ respectively represent the same as R₂₁₁ to R₂₁₄ and R₂₄₁ to R₂₄₄ in the formula (B22);
X₂₁, R₂₁₉, and R₂₂₀ respectively represent the same as X₂₁, R₂₁₉, and R₂₂₀ in the formula (B25); and
* in the formulae (a1) to (a6) each represent a bonding position to a benzene ring in the formula (2).

In the compound M2, D₂ is preferably the formula (B22) or the formula (B23).

In the compound M2, D₂₁ and D₂₂ are preferably each independently the formula (B22) or the formula (B23).

In the compound M2, D₂ is also preferably a group represented by a formula (121), (122), or (131) below.

In the compound M2, it is also preferable that D₂₁ and D₂₂ are each independently a group represented by the formula (121), (122), or (131).

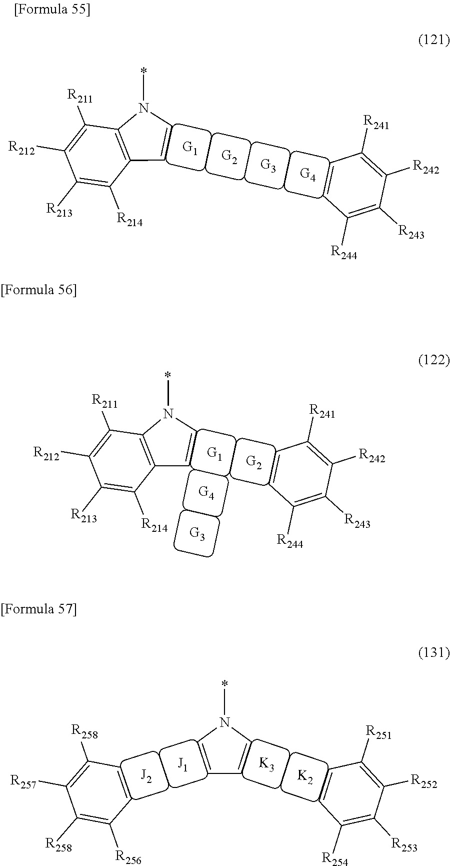

In the formulae (121) and (122),
R₂₁₁ to R₂₁₄ and R₂₄₁ to R₂₄₄ represent the same as R₂₁₁ to R₂₁₄ and R₂₄₁ to R₂₄₄ in the formula (B22); and
two of a ring G₁, a ring G₂, a ring G₃, and a ring G₄ are each a cyclic structure represented by the formula (B24) and the remaining two of the rings G₁, G₂, G₃, and G₄ are each a cyclic structure represented by the formula (B25) in the formula (131),
R₂₅₁ to R₂₅₆ represent the same as R₂₅₁ to R₂₅₈ in the formula (B23);
one of a ring J₁ and a ring J₂ is a cyclic structure represented by the formula (B24) and the other of the ring J₁ and the ring J₂ is a cyclic structure represented by the formula (B25);
one of a ring K₁ and a ring K₂ is a cyclic structure represented by the formula (B24) and the other of the ring K₁ and the ring K₂ is a cyclic structure represented by the formula (B25); and
* in the formulae (121), (122), and (131) each represent a bonding position to a benzene ring in the formula (2).

In the compound M2, preferably, the ring G₁ and the ring G₃ are each a cyclic structure represented by the formula (B24) and the ring G₂ and the ring G₄ are each a cyclic structure represented by the formula (B25).

In the compound M2, preferably, the ring J₁ is a cyclic structure represented by the formula (B24), the ring J₂ is a cyclic structure represented by the formula (B25), the ring K₁ is a cyclic structure represented by the formula (B24), and the ring K₂ is a cyclic structure represented by the formula (B25).

In the compound M2, D₂, D₂₁, and D₂₂ are preferably each independently a group represented by the formula (131).

In the compound M2, D₂, D₂₁, and D₂₂ are preferably each independently a group represented by a formula (123), (124), (125), or (132) below.

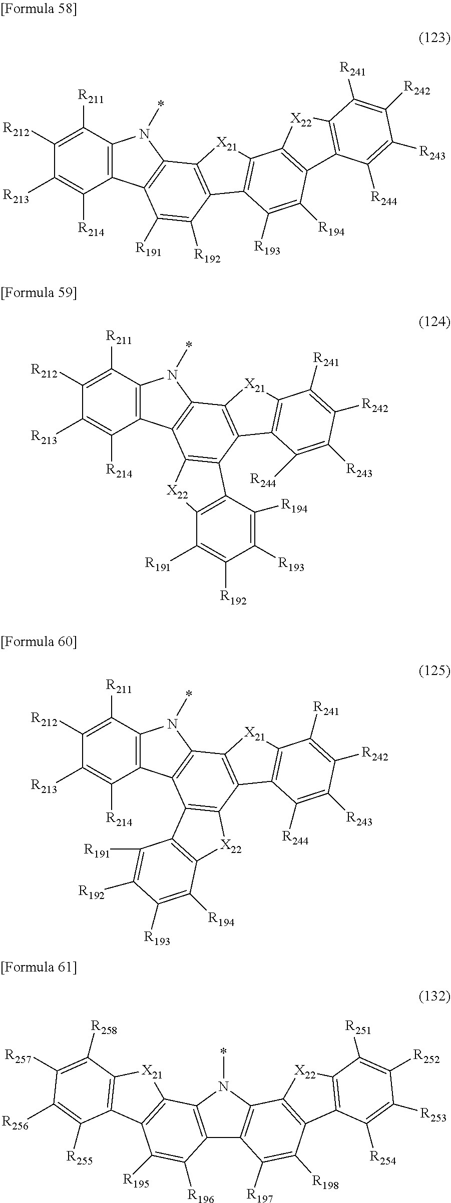

In the formulae (123), (124), and (125): R₂₁₁ to R₂₁₄ and R₂₄₁ to R₂₄₄ each independently represent the same as R₂₁₁ to R₂₁₄ and R₂₄₁ to R₂₄₄ in the formula (B22), and R₁₉₁ to R₁₉₄ each independently represent the same as R₂₁₉ and R₂₂₀ in the formula (B24):
in the formula (132), R₂₅₁ to R₂₅₆ each independently represent the same as R₂₅₁ to R₂₅₈ in the formula (B23), and R₁₉₅ to R₁₉₆ each independently represent the same as R₂₁₉ and R₂₂₀ in the formula (B24); and
in the formulae (123), (124), (125), and (132), X₂₁ and X₂₂ each independently represent the same as X₂₁ in the formula (B25), and * each represent a bonding position to a benzene ring in the formula (2).

In the formulae (123), (124), and (125), none of combinations of adjacent two or more of R₁₉₁ to R₁₉₄ are preferably bonded to each other.

In the formula (132), none of combinations of adjacent two or more of R₁₉₆ to R₁₉₈ are preferably bonded to each other.

In the compound M2, D₂, D₂₁, and D₂₂ preferably each independently a group represented by the formula (132).

In the compound M2, X₂₁ in the group represented by the formula (132) is preferably a sulfur atom. In the compound M2, it is more preferable that X₂₁ in the group represented by the formula (132) is a sulfur atom and X₂₂ in the group represented by the formula (132) is a sulfur atom or an oxygen atom.

In the compound M2, X₂₁ is preferably a sulfur atom, an oxygen atom, or CR₂₆₂R₂₆₃.

In the compound M2. X₂₁ is preferably a sulfur atom or an oxygen atom.

In the compound M2, it is preferable that the substituent for “the substituted or unsubstituted” group is an unsubstituted alkyl group having 1 to 25 carbon atoms, an unsubstituted alkenyl group having 2 to 25 carbon atoms, an unsubstituted alkynyl group having 2 to 25 carbon atoms, an unsubstituted cycloalkyl group having 3 to 25 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), an unsubstituted aralkyl group having 7 to 50 carbon atoms, a group represented by —C(═O)R₉₀₈, a group represented by —COOR₉₀₉, a group represented by —P(═O)(R₉₃₁)(R₉₃₂), a group represented by —Ge(R₉₃₃)(R₉₃₄)(R₉₃₅), a group represented by —B(R₉₃₆)(R₉₃₇), a group represented by —S(═O)₂R₉₃₈, a halogen atom, a cyano group, a nitro group, an unsubstituted aryl group having 6 to 25 ring carbon atoms, or an unsubstituted heterocyclic group having 5 to 25 ring atoms, and
R₉₀₁ to R₉₀₉ and R₉₃₁ to R₉₃₆ are each independently a hydrogen atom, an unsubstituted alkyl group having 1 to 25 carbon atoms, an unsubstituted aryl group having 6 to 25 ring carbon atoms, or an unsubstituted heterocyclic group having 5 to 25 ring atoms.

In the compound M2, the substituent for the substituted or unsubstituted group is preferably a halogen atom, an unsubstituted alkyl group having 1 to 25 carbon atoms, an unsubstituted aryl group having 6 to 25 ring carbon atoms, or an unsubstituted heterocyclic group having 5 to 25 ring atoms.

In the compound M2, the substituent for “the substituted or unsubstituted” group is preferably an unsubstituted alkyl group having 1 to 10 carbon atoms, an unsubstituted aryl group having 6 to 12 ring carbon atoms, or an unsubstituted heterocyclic group having 5 to 12 ring atoms.

In the compound M2, it is also preferable that the groups specified to be “substituted or unsubstituted” are each an “unsubstituted” group.

A group represented by —O—(R₉₀₄) herein in which R₉₀₄ is a hydrogen atom is a hydroxy group.

A group represented by —S—(R₉₀₅) herein in which R₉₀₅ is a hydrogen atom is a thiol group.

A group represented by —P(═O)(R₉₃₁)(R₉₃₂) herein is a substituted phosphine oxide group when R₉₃₁ and R₉₃₂ are each a substituent, and an aryl phosphoryl group when R₉₃₁ and R₉₃₂ are each an aryl group.

ON A group represented by —Ge(R₉₃₃)(R₉₃₄)(R₉₃₅) herein in which R₉₃₃, R₉₃₄, and R₉₃₅ are each a substituent is a substituted germanium group.

A group represented by —B(R₉₃₆)(R₉₃₇) herein in which R₉₃₆ and R₉₃₇ are each a substituent is a substituted boryl group.

### Method of Producing Compound M2

The compound M2 can be produced by a known method.

The compound M2 can be produced, for instance, by a method described in Examples below.

Specific examples of the compound M2 include the following compounds. It should however be noted that the invention is not limited to the specific examples of the compound.

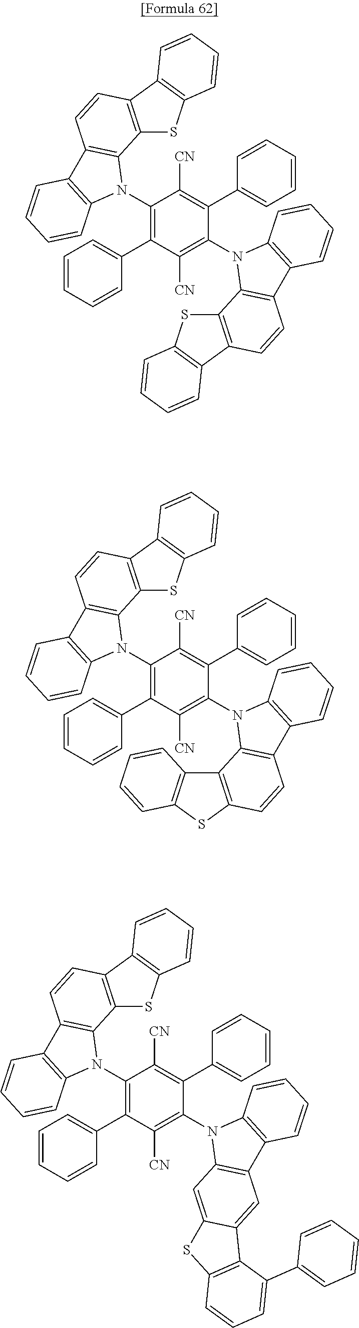 [SMILES: N#Cc1c(-c2ccccc2)c(-n2c3ccccc3c3ccc4c5ccccc5sc4c32)c(C#N)c(-c2ccccc2)c1-n1c2ccccc2c2ccc3c4ccccc4sc3c21 ; N#Cc1c(-c2ccccc2)c(-n2c3ccccc3c3ccc4sc5ccccc5c4c32)c(C#N)c(-c2ccccc2)c1-n1c2ccccc2c2ccc3c4ccccc4sc3c21 ; N#Cc1c(-c2ccccc2)c(-n2c3ccccc3c3ccc4c5ccccc5sc4c32)c(C#N)c(-c2ccccc2)c1-n1c2ccccc2c2cc3c(cc21)sc1cccc(-c2ccccc2)c13]

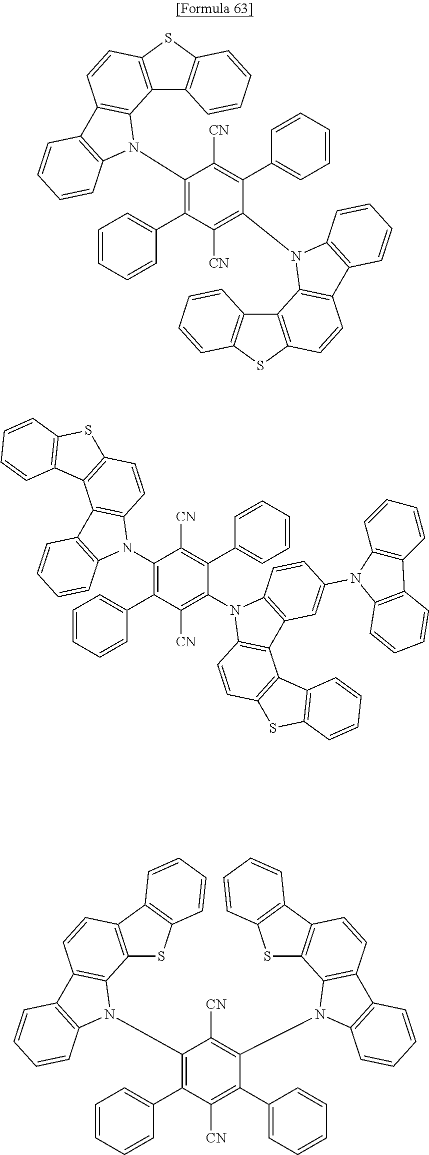 [SMILES: N#Cc1c(-c2ccccc2)c(-n2c3ccccc3c3ccc4sc5ccccc5c4c32)c(C#N)c(-c2ccccc2)c1-n1c2ccccc2c2ccc3sc4ccccc4c3c21 ; N#Cc1c(-c2ccccc2)c(-n2c3ccc(-n4c5ccccc5c5ccccc54)cc3c3c4c(ccc32)sc2ccccc24)c(C#N)c(-c2ccccc2)c1-n1c2ccccc2c2c3c(ccc21)sc1ccccc13 ; N#Cc1c(-c2ccccc2)c(-n2c3ccccc3c3ccc4c5ccccc5sc4c32)c(C#N)c(-n2c3ccccc3c3ccc4c5ccccc5sc4c32)c1-c1ccccc1]

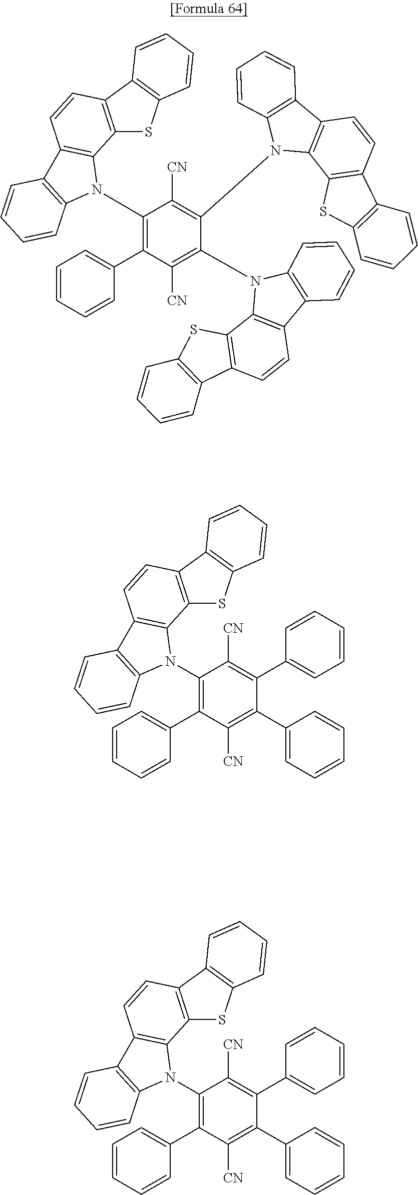 [SMILES: N#Cc1c(-c2ccccc2)c(-n2c3ccccc3c3ccc4c5ccccc5sc4c32)c(C#N)c(-n2c3ccccc3c3ccc4c5ccccc5sc4c32)c1-n1c2ccccc2c2ccc3c4ccccc4sc3c21 ; N#Cc1c(-c2ccccc2)c(-c2ccccc2)c(C#N)c(-n2c3ccccc3c3ccc4c5ccccc5sc4c32)c1-c1ccccc1 ; N#Cc1c(-c2ccccc2)c(-c2ccccc2)c(C#N)c(-n2c3ccccc3c3ccc4c5ccccc5sc4c32)c1-c1ccccc1]

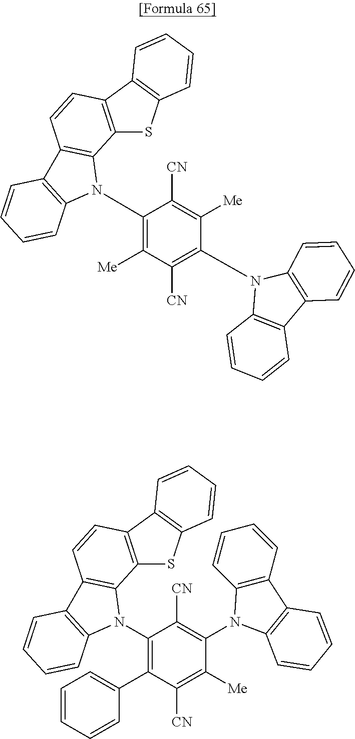 [SMILES: Cc1c(C#N)c(-n2c3ccccc3c3ccc4c5ccccc5sc4c32)c(C)c(C#N)c1-n1c2ccccc2c2ccccc21 ; Cc1c(C#N)c(-c2ccccc2)c(-n2c3ccccc3c3ccc4c5ccccc5sc4c32)c(C#N)c1-n1c2ccccc2c2ccccc21]

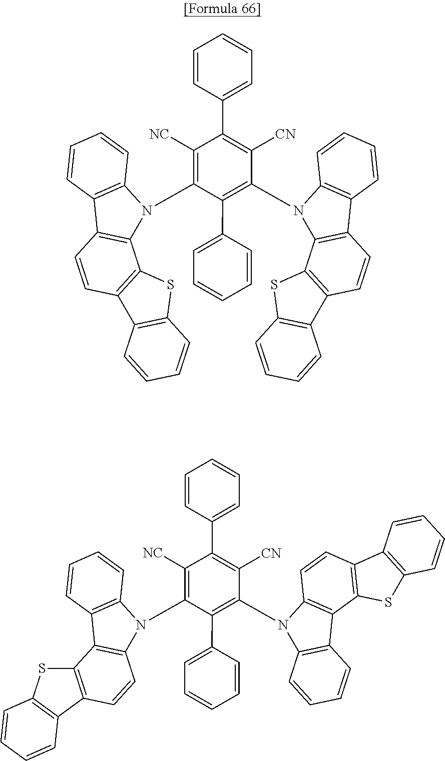 [SMILES: N#Cc1c(-c2ccccc2)c(C#N)c(-n2c3ccccc3c3ccc4c5ccccc5sc4c32)c(-c2ccccc2)c1-n1c2ccccc2c2ccc3c4ccccc4sc3c21 ; N#Cc1c(-c2ccccc2)c(C#N)c(-n2c3ccccc3c3c4sc5ccccc5c4ccc32)c(-c2ccccc2)c1-n1c2ccccc2c2c3sc4ccccc4c3ccc21]

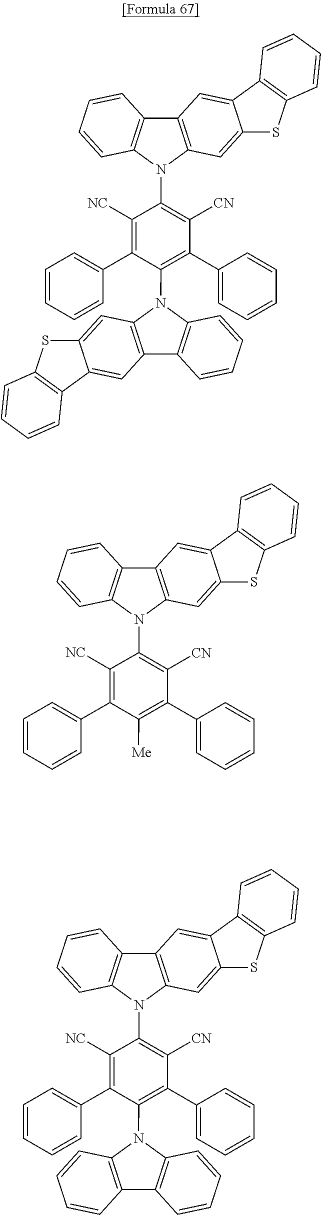 [SMILES: N#Cc1c(-c2ccccc2)c(-n2c3ccccc3c3cc4c(cc32)sc2ccccc24)c(-c2ccccc2)c(C#N)c1-n1c2ccccc2c2cc3c(cc21)sc1ccccc13 ; Cc1c(-c2ccccc2)c(C#N)c(-n2c3ccccc3c3cc4c(cc32)sc2ccccc24)c(C#N)c1-c1ccccc1 ; N#Cc1c(-c2ccccc2)c(-n2c3ccccc3c3ccccc32)c(-c2ccccc2)c(C#N)c1-n1c2ccccc2c2cc3c(cc21)sc1ccccc13]

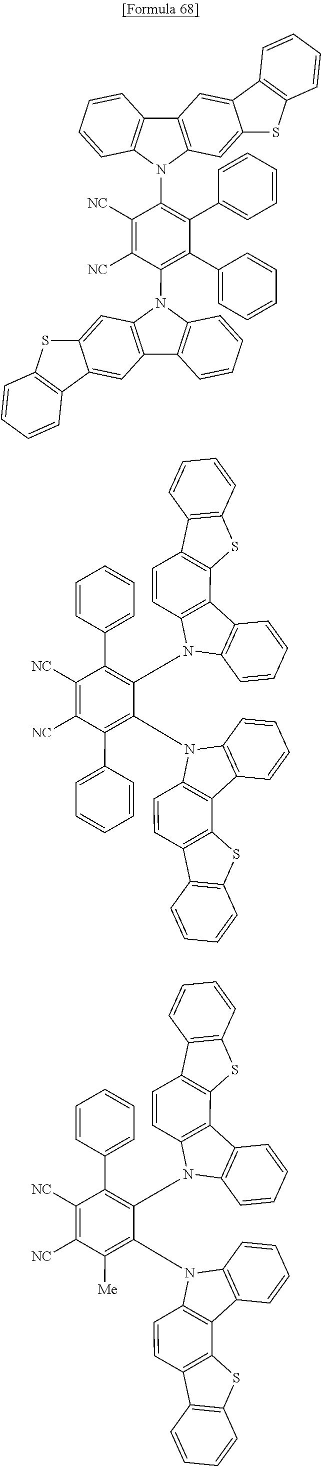

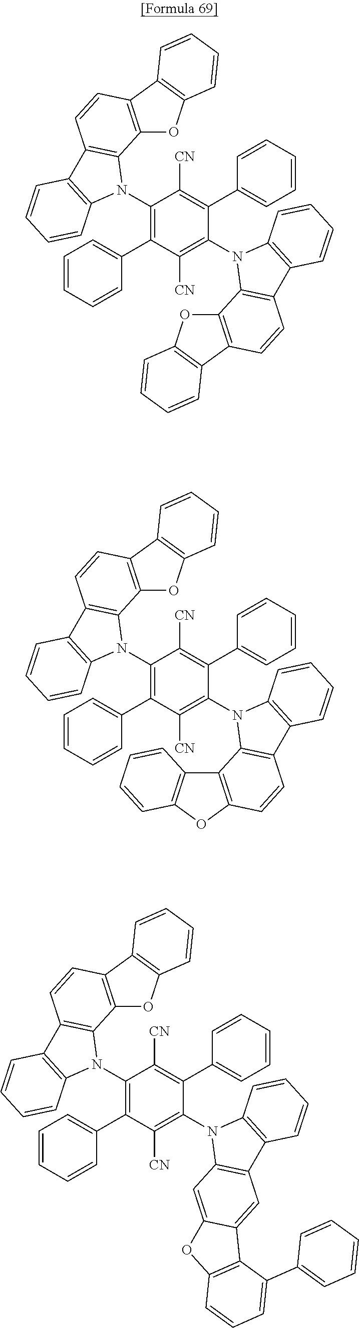 [SMILES: N#Cc1c(-c2ccccc2)c(-n2c3ccccc3c3ccc4c5ccccc5oc4c32)c(C#N)c(-c2ccccc2)c1-n1c2ccccc2c2ccc3c4ccccc4oc3c21 ; N#Cc1c(-c2ccccc2)c(-n2c3ccccc3c3ccc4oc5ccccc5c4c32)c(C#N)c(-c2ccccc2)c1-n1c2ccccc2c2ccc3c4ccccc4oc3c21 ; N#Cc1c(-c2ccccc2)c(-n2c3ccccc3c3ccc4c5ccccc5oc4c32)c(C#N)c(-c2ccccc2)c1-n1c2ccccc2c2cc3c(cc21)oc1cccc(-c2ccccc2)c13]

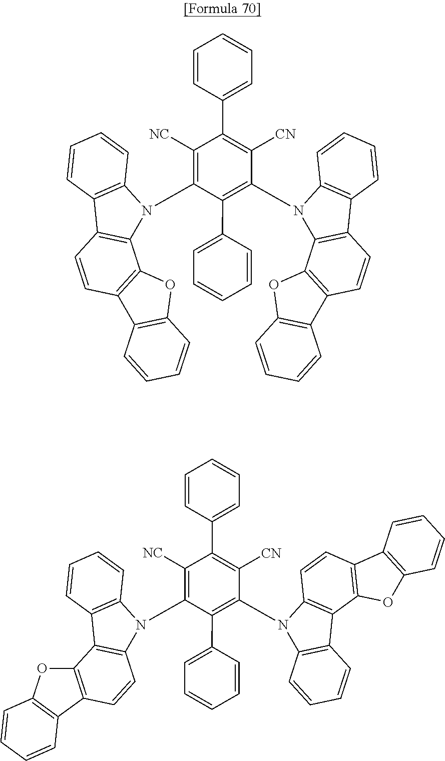 [SMILES: N#Cc1c(-c2ccccc2)c(C#N)c(-n2c3ccccc3c3ccc4c5ccccc5oc4c32)c(-c2ccccc2)c1-n1c2ccccc2c2ccc3c4ccccc4oc3c21 ; N#Cc1c(-c2ccccc2)c(C#N)c(-n2c3ccccc3c3c4oc5ccccc5c4ccc32)c(-c2ccccc2)c1-n1c2ccccc2c2c3oc4ccccc4c3ccc21]

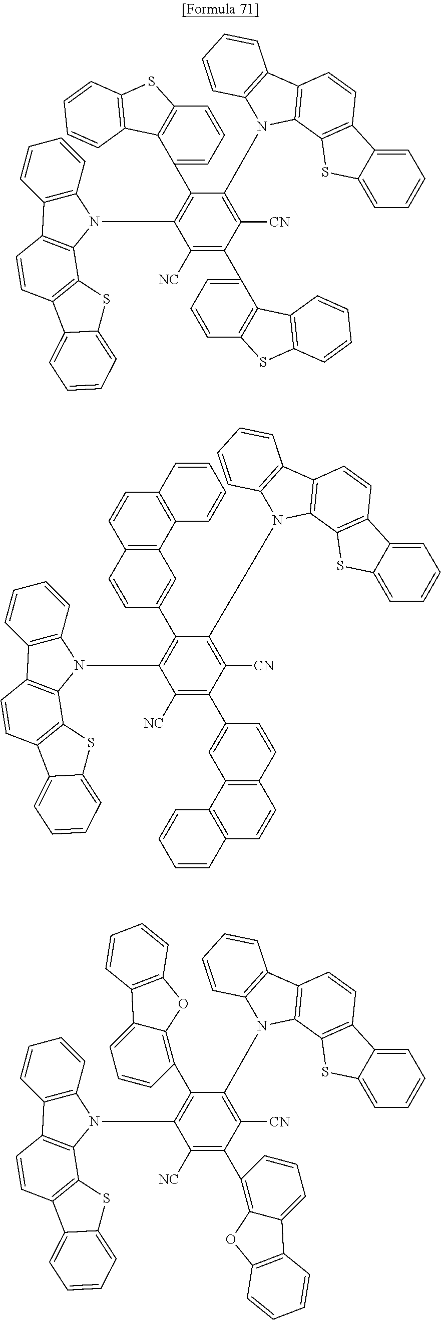 [SMILES: N#Cc1c(-c2cccc3sc4ccccc4c23)c(C#N)c(-n2c3ccccc3c3ccc4c5ccccc5sc4c32)c(-c2cccc3sc4ccccc4c23)c1-n1c2ccccc2c2ccc3c4ccccc4sc3c21 ; N#Cc1c(-c2ccc3ccc4ccccc4c3c2)c(C#N)c(-n2c3ccccc3c3ccc4c5ccccc5sc4c32)c(-c2ccc3ccc4ccccc4c3c2)c1-n1c2ccccc2c2ccc3c4ccccc4sc3c21 ; N#Cc1c(-c2cccc3c2oc2ccccc23)c(C#N)c(-n2c3ccccc3c3ccc4c5ccccc5sc4c32)c(-c2cccc3c2oc2ccccc23)c1-n1c2ccccc2c2ccc3c4ccccc4sc3c21]

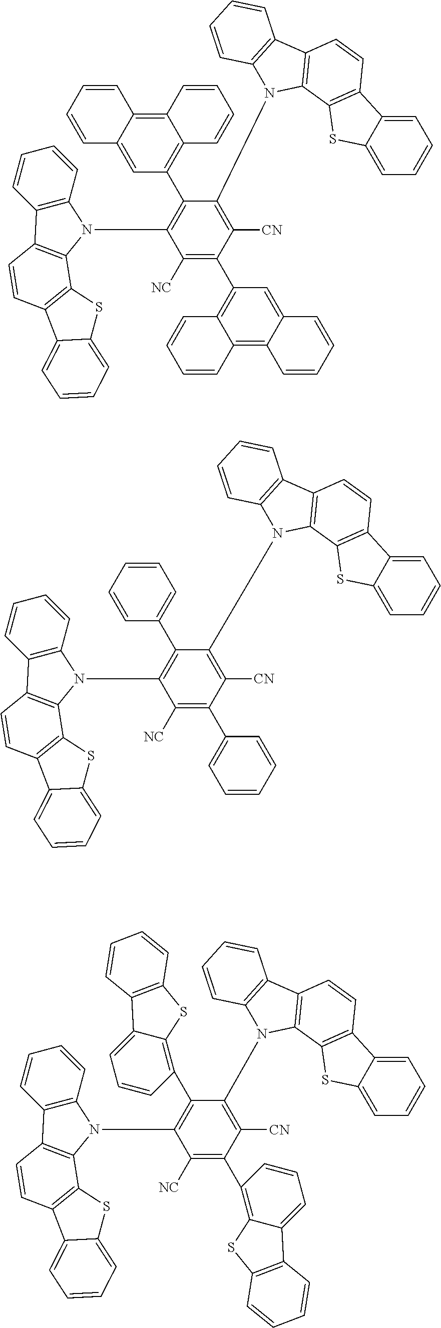 [SMILES: N#Cc1c(-c2cc3ccccc3c3ccccc23)c(C#N)c(-n2c3ccccc3c3ccc4c5ccccc5sc4c32)c(-c2cc3ccccc3c3ccccc23)c1-n1c2ccccc2c2ccc3c4ccccc4sc3c21 ; N#Cc1c(-c2ccccc2)c(C#N)c(-n2c3ccccc3c3ccc4c5ccccc5sc4c32)c(-c2ccccc2)c1-n1c2ccccc2c2ccc3c4ccccc4sc3c21 ; N#Cc1c(-c2cccc3c2sc2ccccc23)c(C#N)c(-n2c3ccccc3c3ccc4c5ccccc5sc4c32)c(-c2cccc3c2sc2ccccc23)c1-n1c2ccccc2c2ccc3c4ccccc4sc3c21]

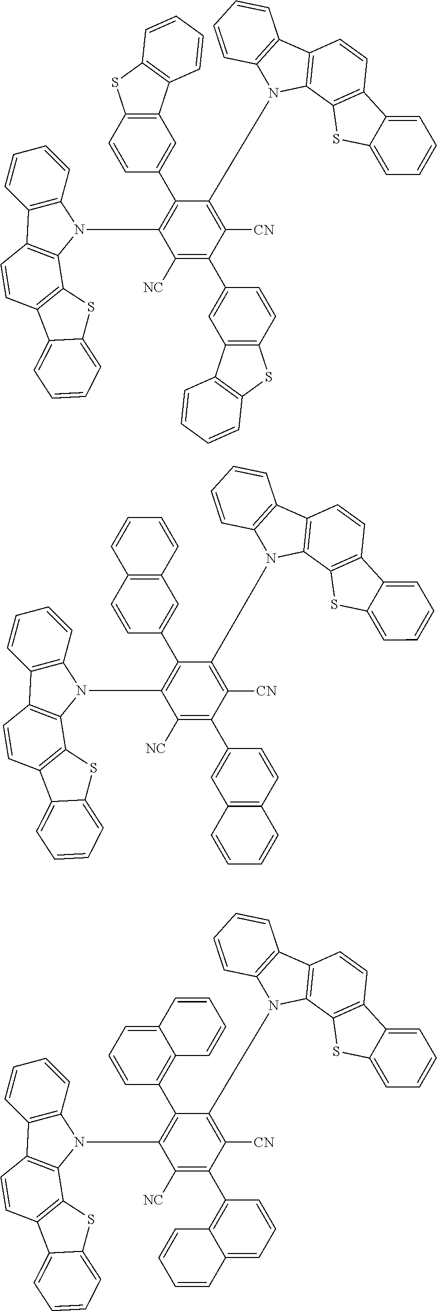

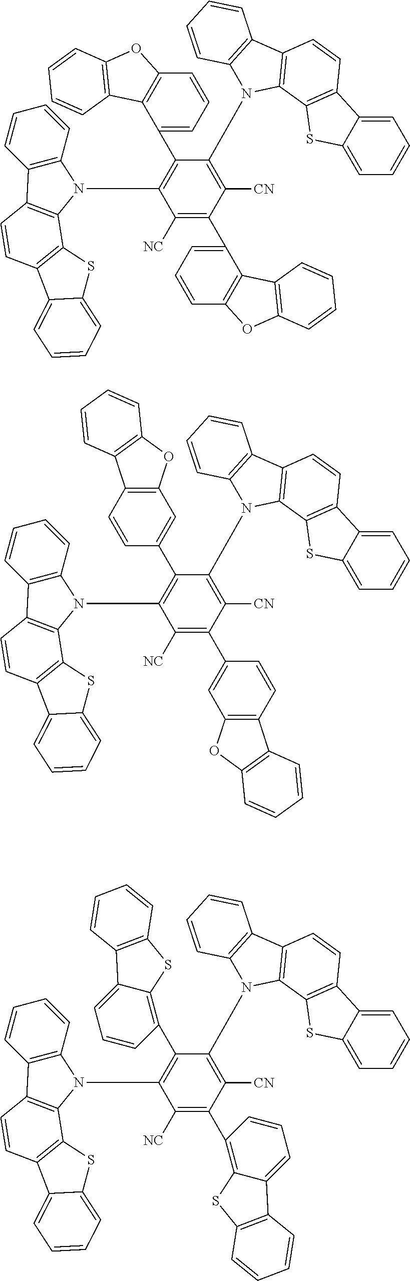

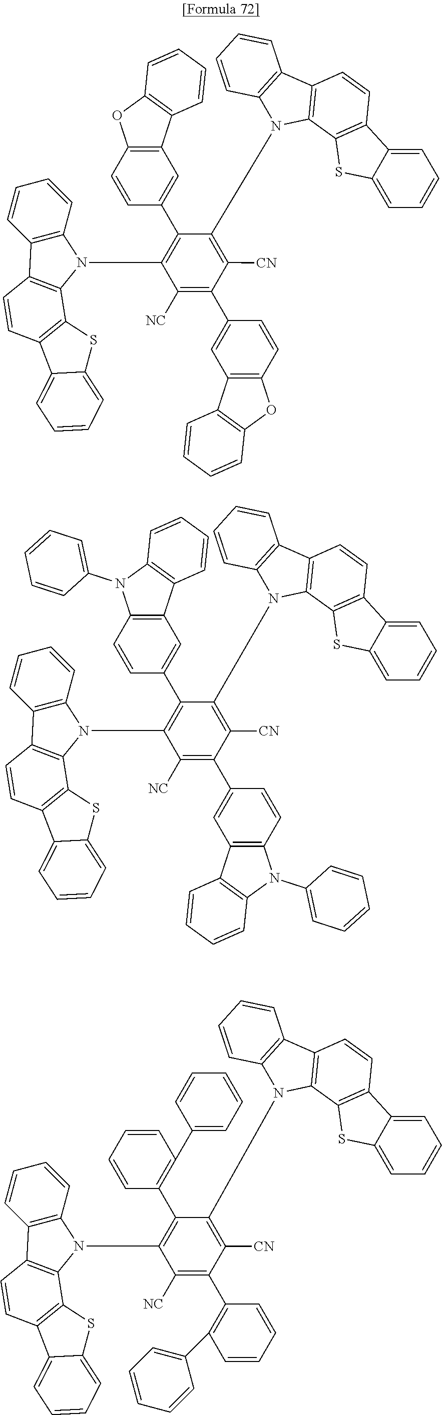

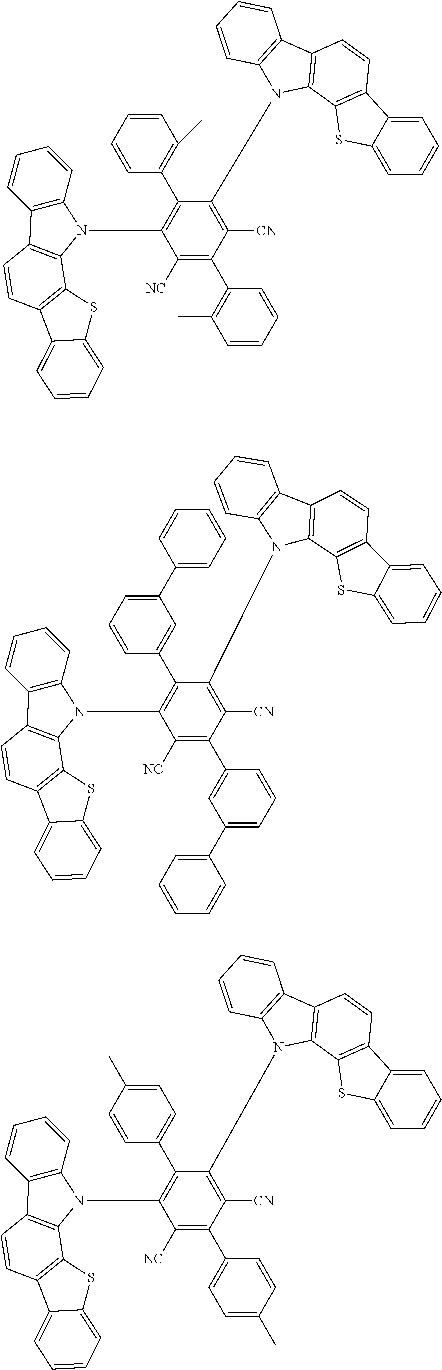 [SMILES: Cc1ccccc1-c1c(C#N)c(-n2c3ccccc3c3ccc4c5ccccc5sc4c32)c(-c2ccccc2C)c(-n2c3ccccc3c3ccc4c5ccccc5sc4c32)c1C#N ; N#Cc1c(-c2cccc(-c3ccccc3)c2)c(C#N)c(-n2c3ccccc3c3ccc4c5ccccc5sc4c32)c(-c2cccc(-c3ccccc3)c2)c1-n1c2ccccc2c2ccc3c4ccccc4sc3c21 ; Cc1ccc(-c2c(C#N)c(-n3c4ccccc4c4ccc5c6ccccc6sc5c43)c(-c3ccc(C)cc3)c(-n3c4ccccc4c4ccc5c6ccccc6sc5c43)c2C#N)cc1]

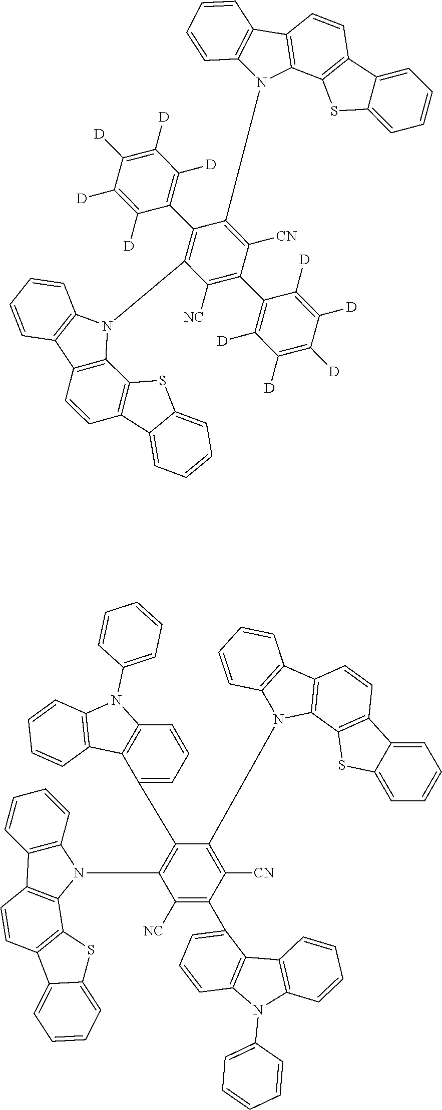 [SMILES: [2H]c1c([2H])c([2H])c(-c2c(C#N)c(-n3c4ccccc4c4ccc5c6ccccc6sc5c43)c(-c3c([2H])c([2H])c([2H])c([2H])c3[2H])c(-n3c4ccccc4c4ccc5c6ccccc6sc5c43)c2C#N)c([2H])c1[2H] ; N#Cc1c(-c2cccc3c2c2ccccc2n3-c2ccccc2)c(C#N)c(-n2c3ccccc3c3ccc4c5ccccc5sc4c32)c(-c2cccc3c2c2ccccc2n3-c2ccccc2)c1-n1c2ccccc2c2ccc3c4ccccc4sc3c21]

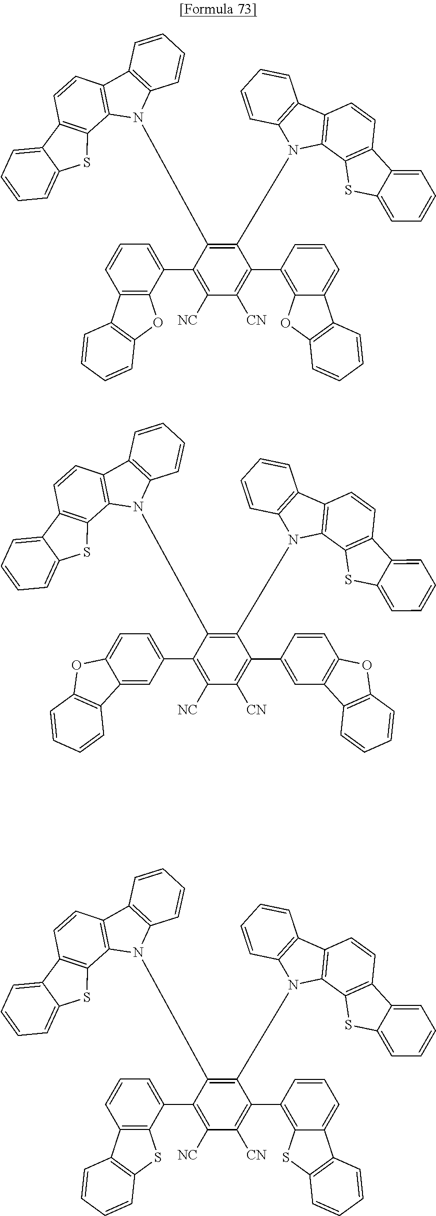 [SMILES: N#Cc1c(C#N)c(-c2cccc3c2oc2ccccc23)c(-n2c3ccccc3c3ccc4c5ccccc5sc4c32)c(-n2c3ccccc3c3ccc4c5ccccc5sc4c32)c1-c1cccc2c1oc1ccccc12 ; N#Cc1c(C#N)c(-c2ccc3oc4ccccc4c3c2)c(-n2c3ccccc3c3ccc4c5ccccc5sc4c32)c(-n2c3ccccc3c3ccc4c5ccccc5sc4c32)c1-c1ccc2oc3ccccc3c2c1 ; N#Cc1c(C#N)c(-c2cccc3c2sc2ccccc23)c(-n2c3ccccc3c3ccc4c5ccccc5sc4c32)c(-n2c3ccccc3c3ccc4c5ccccc5sc4c32)c1-c1cccc2c1sc1ccccc12]

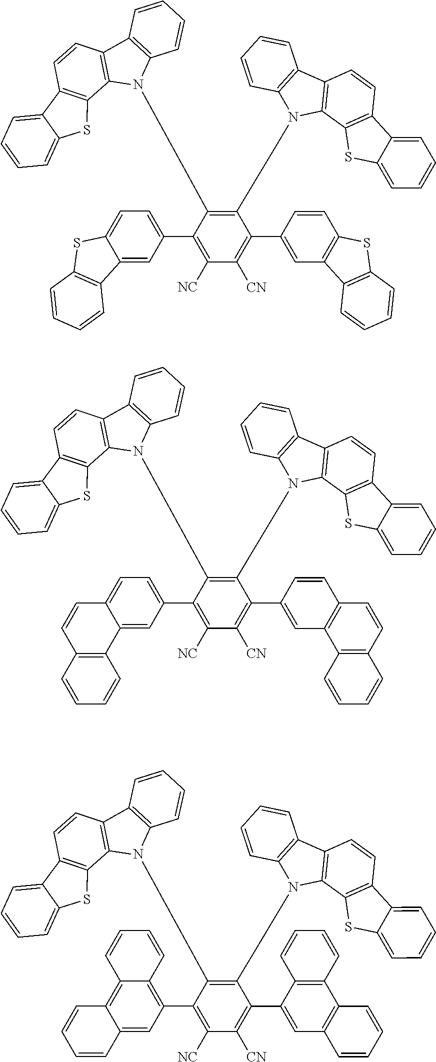 [SMILES: N#Cc1c(C#N)c(-c2ccc3sc4ccccc4c3c2)c(-n2c3ccccc3c3ccc4c5ccccc5sc4c32)c(-n2c3ccccc3c3ccc4c5ccccc5sc4c32)c1-c1ccc2sc3ccccc3c2c1 ; N#Cc1c(C#N)c(-c2ccc3ccc4ccccc4c3c2)c(-n2c3ccccc3c3ccc4c5ccccc5sc4c32)c(-n2c3ccccc3c3ccc4c5ccccc5sc4c32)c1-c1ccc2ccc3ccccc3c2c1 ; N#Cc1c(C#N)c(-c2cc3ccccc3c3ccccc23)c(-n2c3ccccc3c3ccc4c5ccccc5sc4c32)c(-n2c3ccccc3c3ccc4c5ccccc5sc4c32)c1-c1cc2ccccc2c2ccccc12]

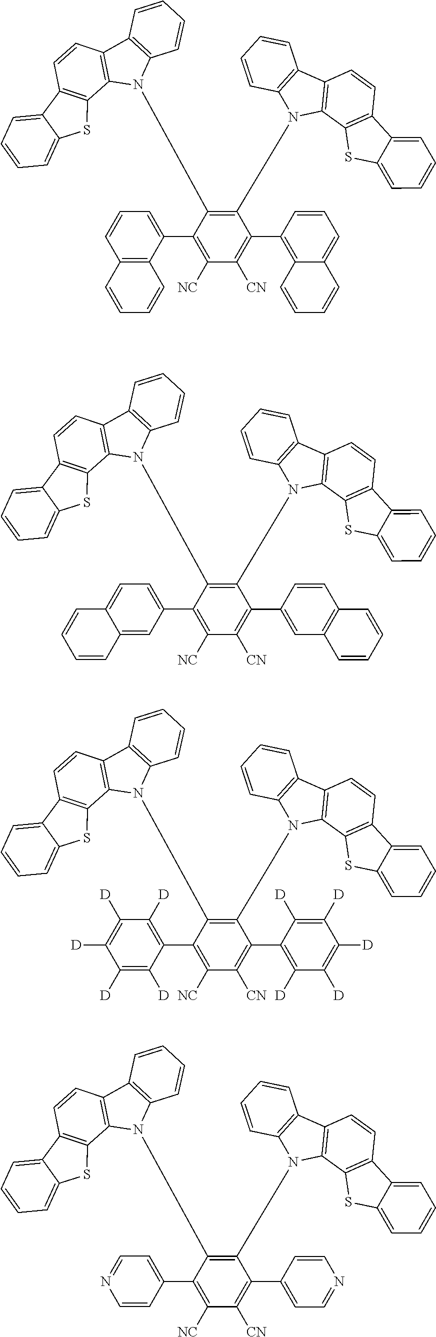 [SMILES: N#Cc1c(C#N)c(-c2cccc3ccccc23)c(-n2c3ccccc3c3ccc4c5ccccc5sc4c32)c(-n2c3ccccc3c3ccc4c5ccccc5sc4c32)c1-c1cccc2ccccc12 ; N#Cc1c(C#N)c(-c2ccc3ccccc3c2)c(-n2c3ccccc3c3ccc4c5ccccc5sc4c32)c(-n2c3ccccc3c3ccc4c5ccccc5sc4c32)c1-c1ccc2ccccc2c1 ; [2H]c1c([2H])c([2H])c(-c2c(C#N)c(C#N)c(-c3c([2H])c([2H])c([2H])c([2H])c3[2H])c(-n3c4ccccc4c4ccc5c6ccccc6sc5c43)c2-n2c3ccccc3c3ccc4c5ccccc5sc4c32)c([2H])c1[2H] ; N#Cc1c(C#N)c(-c2ccncc2)c(-n2c3ccccc3c3ccc4c5ccccc5sc4c32)c(-n2c3ccccc3c3ccc4c5ccccc5sc4c32)c1-c1ccncc1]

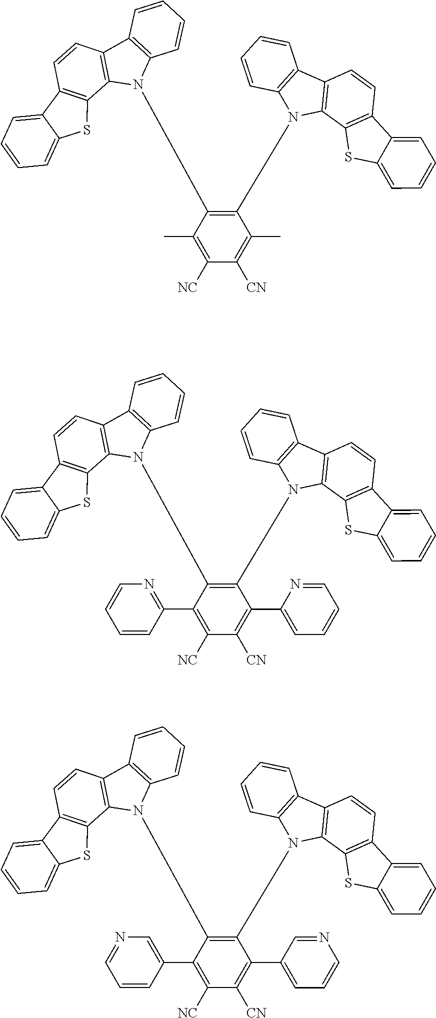 [SMILES: Cc1c(C#N)c(C#N)c(C)c(-n2c3ccccc3c3ccc4c5ccccc5sc4c32)c1-n1c2ccccc2c2ccc3c4ccccc4sc3c21 ; N#Cc1c(C#N)c(-c2ccccn2)c(-n2c3ccccc3c3ccc4c5ccccc5sc4c32)c(-n2c3ccccc3c3ccc4c5ccccc5sc4c32)c1-c1ccccn1 ; N#Cc1c(C#N)c(-c2cccnc2)c(-n2c3ccccc3c3ccc4c5ccccc5sc4c32)c(-n2c3ccccc3c3ccc4c5ccccc5sc4c32)c1-c1cccnc1]

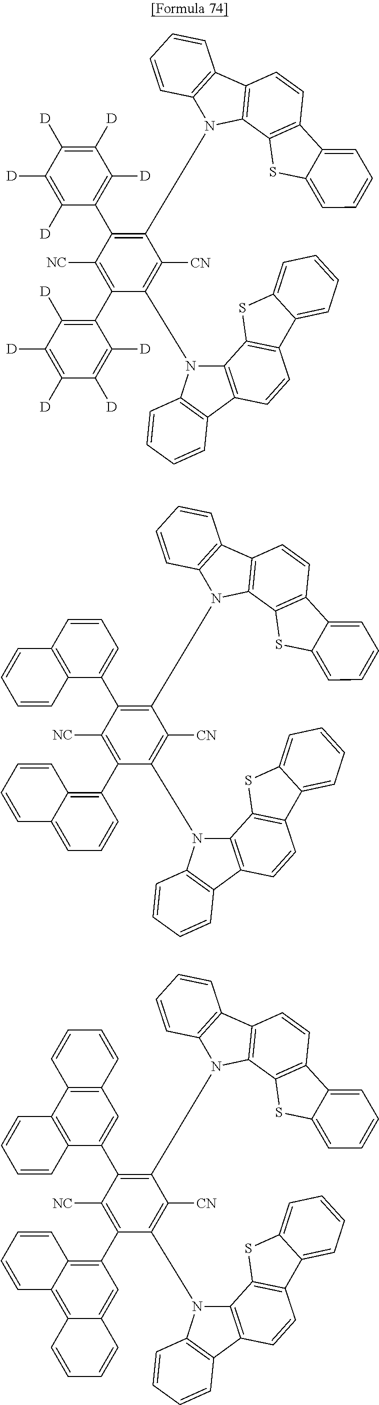

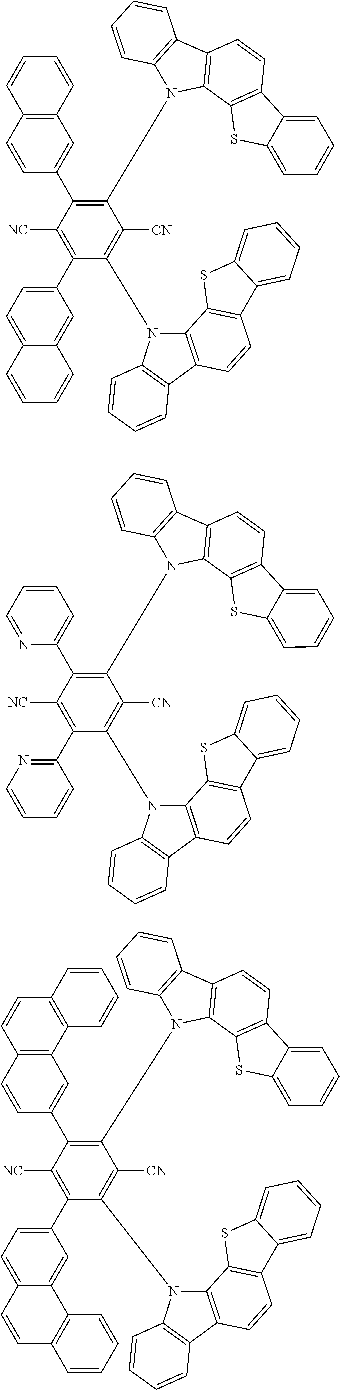

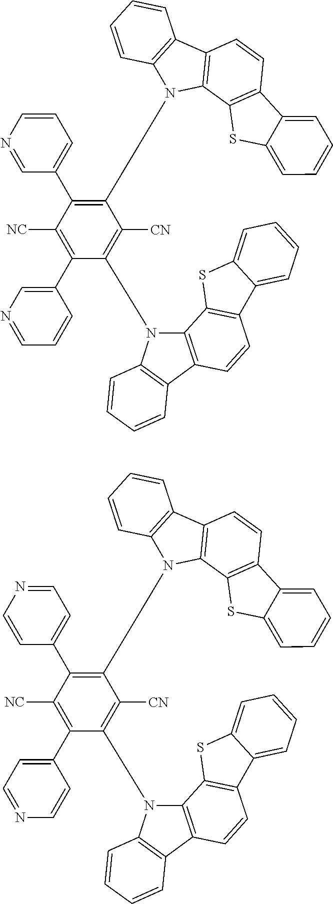

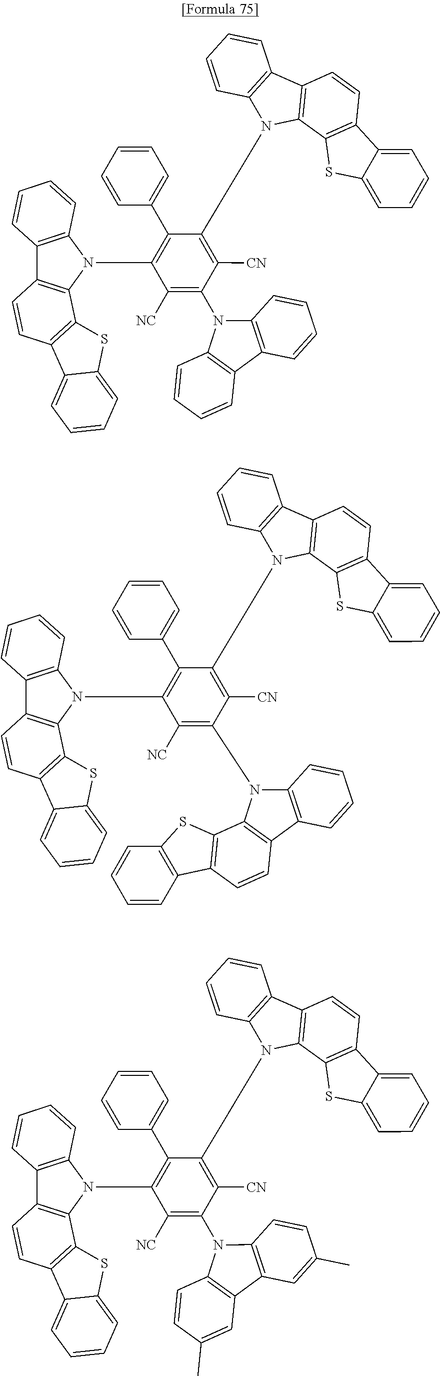 [SMILES: N#Cc1c(-n2c3ccccc3c3ccccc32)c(C#N)c(-n2c3ccccc3c3ccc4c5ccccc5sc4c32)c(-c2ccccc2)c1-n1c2ccccc2c2ccc3c4ccccc4sc3c21 ; N#Cc1c(-n2c3ccccc3c3ccc4c5ccccc5sc4c32)c(C#N)c(-n2c3ccccc3c3ccc4c5ccccc5sc4c32)c(-c2ccccc2)c1-n1c2ccccc2c2ccc3c4ccccc4sc3c21 ; Cc1ccc2c(c1)c1cc(C)ccc1n2-c1c(C#N)c(-n2c3ccccc3c3ccc4c5ccccc5sc4c32)c(-c2ccccc2)c(-n2c3ccccc3c3ccc4c5ccccc5sc4c32)c1C#N]

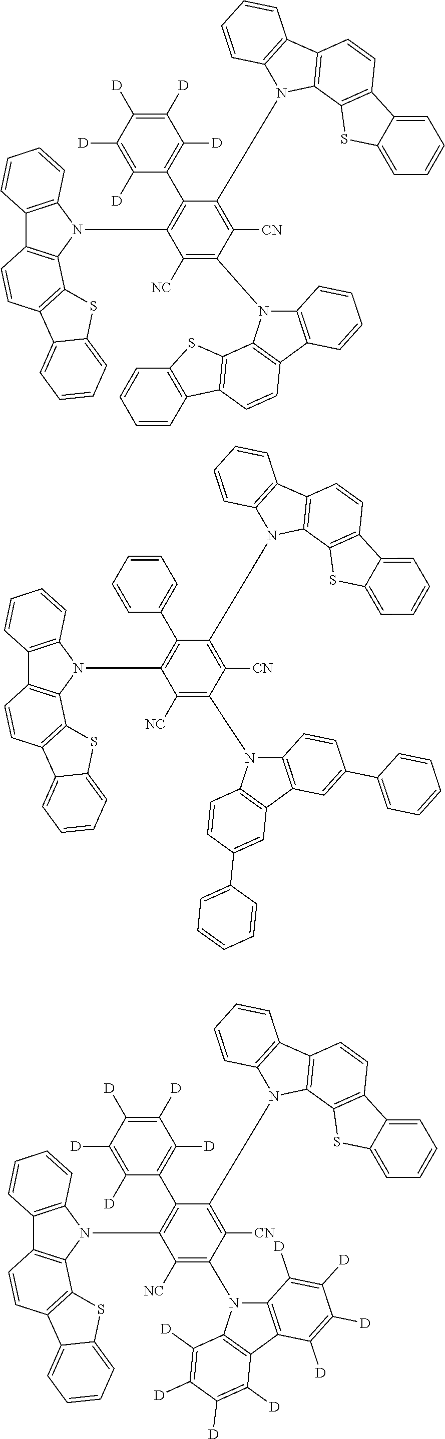

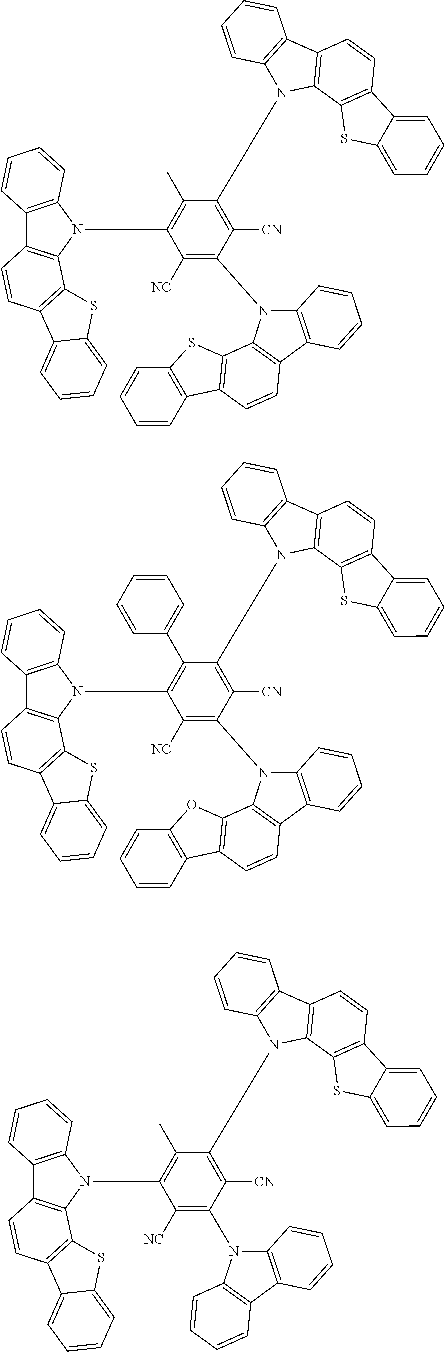 [SMILES: Cc1c(-n2c3ccccc3c3ccc4c5ccccc5sc4c32)c(C#N)c(-n2c3ccccc3c3ccc4c5ccccc5sc4c32)c(C#N)c1-n1c2ccccc2c2ccc3c4ccccc4sc3c21 ; N#Cc1c(-n2c3ccccc3c3ccc4c5ccccc5oc4c32)c(C#N)c(-n2c3ccccc3c3ccc4c5ccccc5sc4c32)c(-c2ccccc2)c1-n1c2ccccc2c2ccc3c4ccccc4sc3c21 ; Cc1c(-n2c3ccccc3c3ccc4c5ccccc5sc4c32)c(C#N)c(-n2c3ccccc3c3ccccc32)c(C#N)c1-n1c2ccccc2c2ccc3c4ccccc4sc3c21]

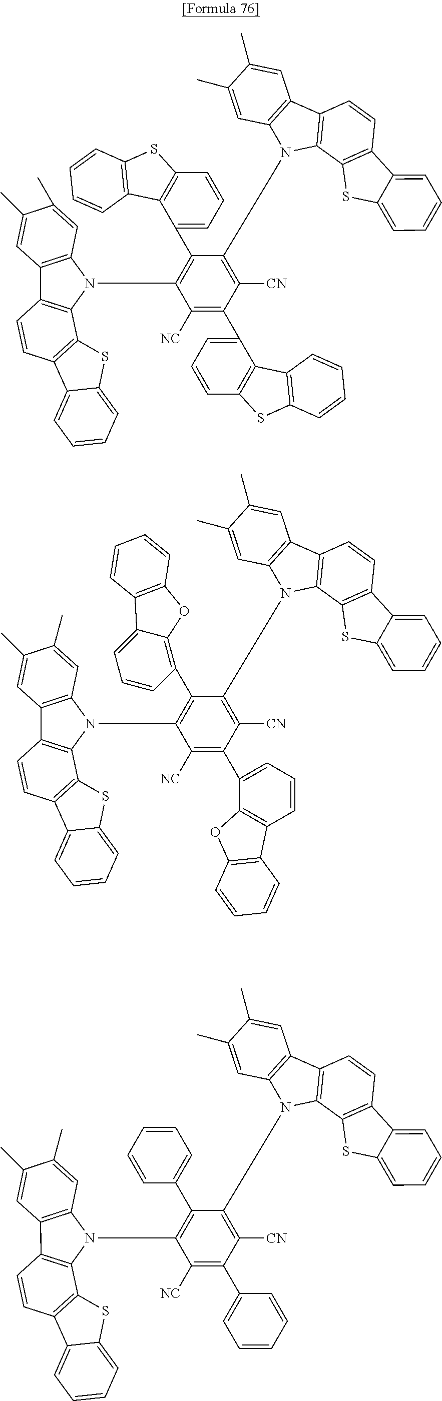 [SMILES: Cc1cc2c3ccc4c5ccccc5sc4c3n(-c3c(C#N)c(-c4cccc5sc6ccccc6c45)c(C#N)c(-n4c5cc(C)c(C)cc5c5ccc6c7ccccc7sc6c54)c3-c3cccc4sc5ccccc5c34)c2cc1C ; Cc1cc2c3ccc4c5ccccc5sc4c3n(-c3c(C#N)c(-c4cccc5c4oc4ccccc45)c(C#N)c(-n4c5cc(C)c(C)cc5c5ccc6c7ccccc7sc6c54)c3-c3cccc4c3oc3ccccc34)c2cc1C ; Cc1cc2c3ccc4c5ccccc5sc4c3n(-c3c(C#N)c(-c4ccccc4)c(C#N)c(-n4c5cc(C)c(C)cc5c5ccc6c7ccccc7sc6c54)c3-c3ccccc3)c2cc1C]

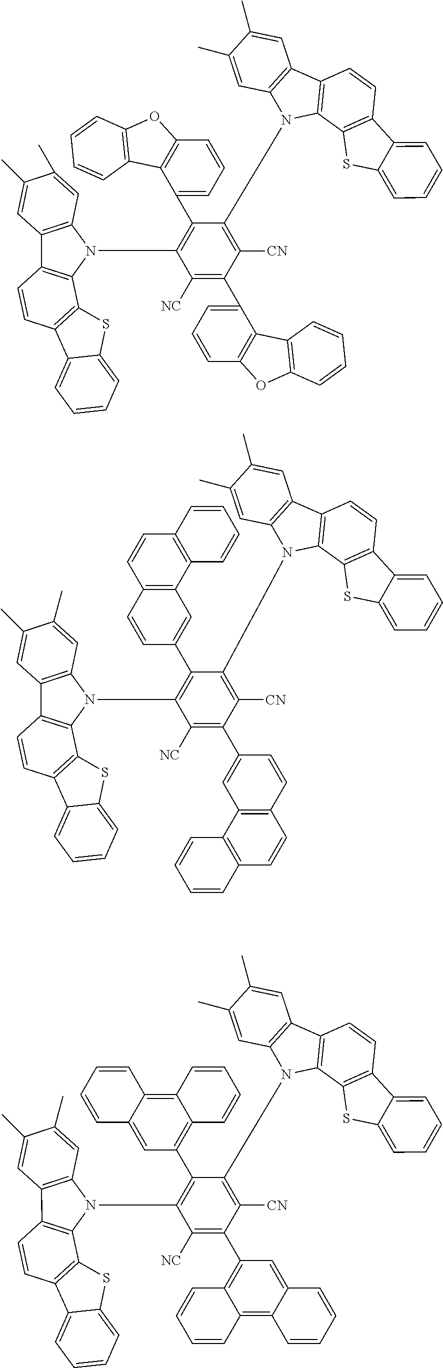 [SMILES: Cc1cc2c3ccc4c5ccccc5sc4c3n(-c3c(C#N)c(-c4cccc5oc6ccccc6c45)c(C#N)c(-n4c5cc(C)c(C)cc5c5ccc6c7ccccc7sc6c54)c3-c3cccc4oc5ccccc5c34)c2cc1C ; Cc1cc2c3ccc4c5ccccc5sc4c3n(-c3c(C#N)c(-c4ccc5ccc6ccccc6c5c4)c(C#N)c(-n4c5cc(C)c(C)cc5c5ccc6c7ccccc7sc6c54)c3-c3ccc4ccc5ccccc5c4c3)c2cc1C ; Cc1cc2c3ccc4c5ccccc5sc4c3n(-c3c(C#N)c(-c4cc5ccccc5c5ccccc45)c(C#N)c(-n4c5cc(C)c(C)cc5c5ccc6c7ccccc7sc6c54)c3-c3cc4ccccc4c4ccccc34)c2cc1C]

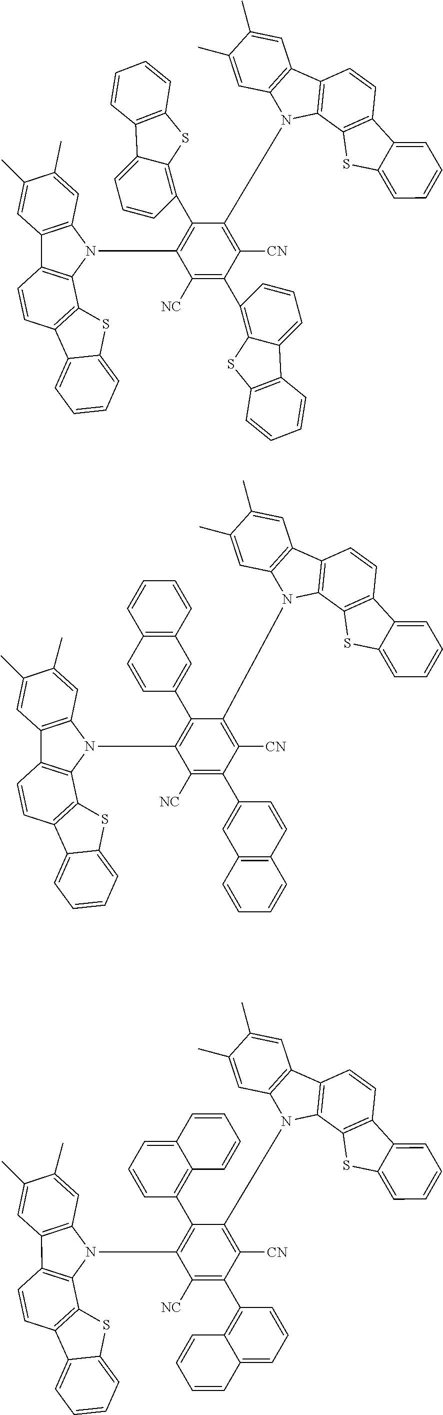 [SMILES: Cc1cc2c3ccc4c5ccccc5sc4c3n(-c3c(C#N)c(-c4cccc5c4sc4ccccc45)c(C#N)c(-n4c5cc(C)c(C)cc5c5ccc6c7ccccc7sc6c54)c3-c3cccc4c3sc3ccccc34)c2cc1C ; Cc1cc2c3ccc4c5ccccc5sc4c3n(-c3c(C#N)c(-c4ccc5ccccc5c4)c(C#N)c(-n4c5cc(C)c(C)cc5c5ccc6c7ccccc7sc6c54)c3-c3ccc4ccccc4c3)c2cc1C ; Cc1cc2c3ccc4c5ccccc5sc4c3n(-c3c(C#N)c(-c4cccc5ccccc45)c(C#N)c(-n4c5cc(C)c(C)cc5c5ccc6c7ccccc7sc6c54)c3-c3cccc4ccccc34)c2cc1C]

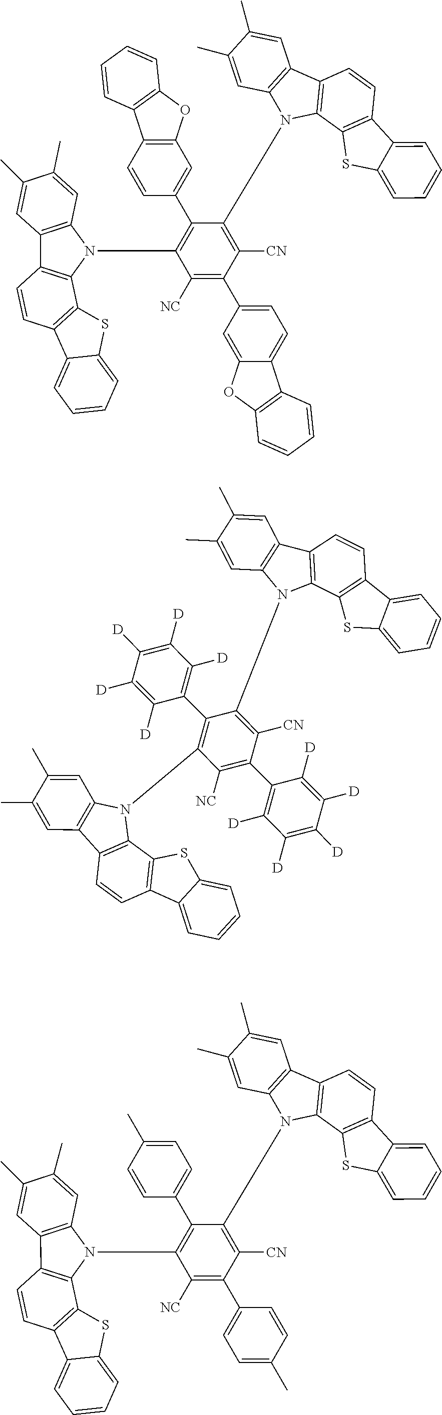 [SMILES: Cc1cc2c3ccc4c5ccccc5sc4c3n(-c3c(C#N)c(-c4ccc5c(c4)oc4ccccc45)c(C#N)c(-n4c5cc(C)c(C)cc5c5ccc6c7ccccc7sc6c54)c3-c3ccc4c(c3)oc3ccccc34)c2cc1C ; [2H]c1c([2H])c([2H])c(-c2c(C#N)c(-n3c4cc(C)c(C)cc4c4ccc5c6ccccc6sc5c43)c(-c3c([2H])c([2H])c([2H])c([2H])c3[2H])c(-n3c4cc(C)c(C)cc4c4ccc5c6ccccc6sc5c43)c2C#N)c([2H])c1[2H] ; Cc1ccc(-c2c(C#N)c(-n3c4cc(C)c(C)cc4c4ccc5c6ccccc6sc5c43)c(-c3ccc(C)cc3)c(-n3c4cc(C)c(C)cc4c4ccc5c6ccccc6sc5c43)c2C#N)cc1]

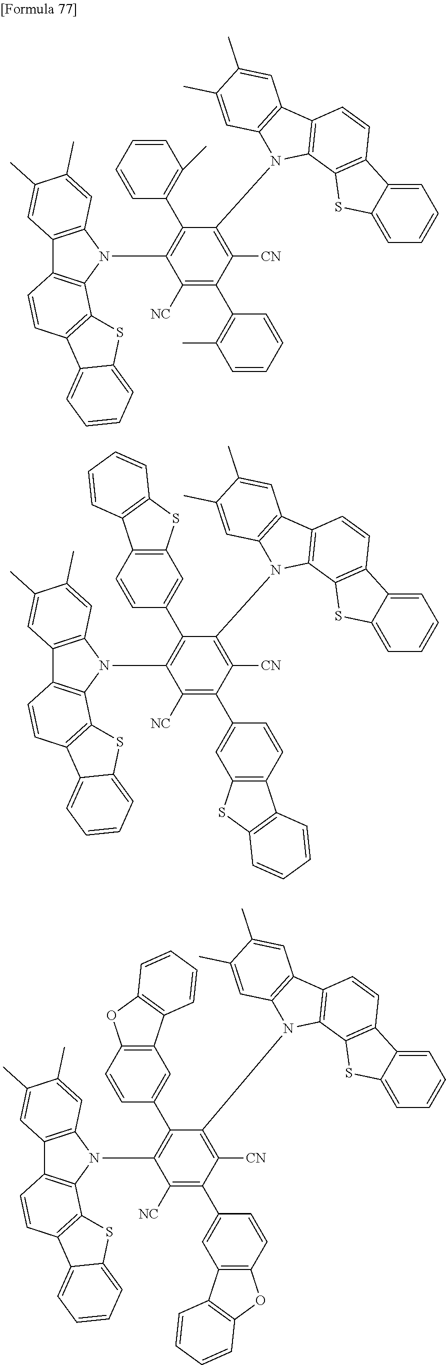

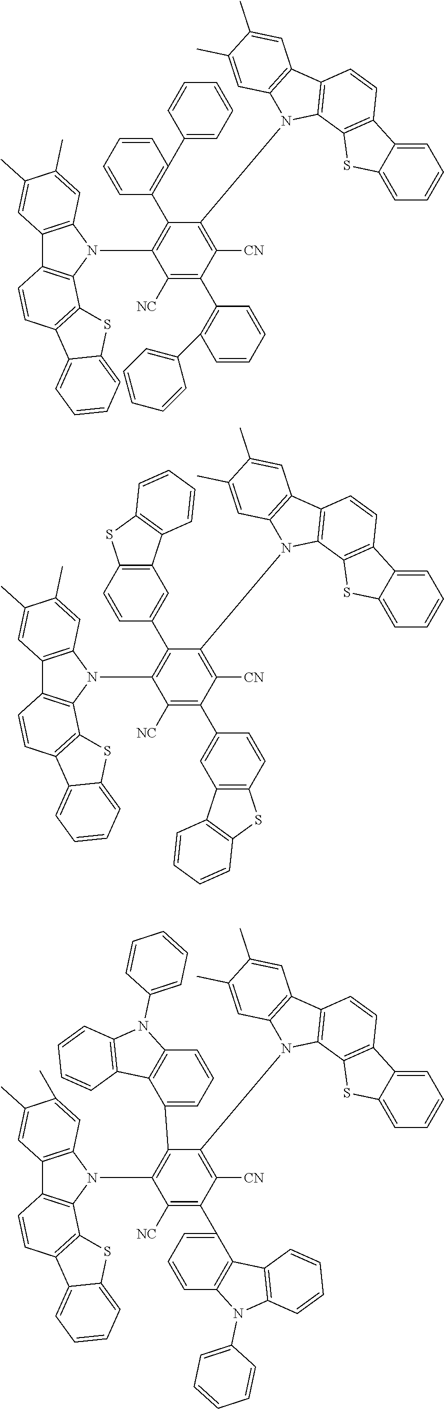 [SMILES: Cc1cc2c3ccc4c5ccccc5sc4c3n(-c3c(C#N)c(-c4ccccc4-c4ccccc4)c(C#N)c(-n4c5cc(C)c(C)cc5c5ccc6c7ccccc7sc6c54)c3-c3ccccc3-c3ccccc3)c2cc1C ; Cc1cc2c3ccc4c5ccccc5sc4c3n(-c3c(C#N)c(-c4ccc5sc6ccccc6c5c4)c(C#N)c(-n4c5cc(C)c(C)cc5c5ccc6c7ccccc7sc6c54)c3-c3ccc4sc5ccccc5c4c3)c2cc1C ; Cc1cc2c3ccc4c5ccccc5sc4c3n(-c3c(C#N)c(-c4cccc5c4c4ccccc4n5-c4ccccc4)c(C#N)c(-n4c5cc(C)c(C)cc5c5ccc6c7ccccc7sc6c54)c3-c3cccc4c3c3ccccc3n4-c3ccccc3)c2cc1C]

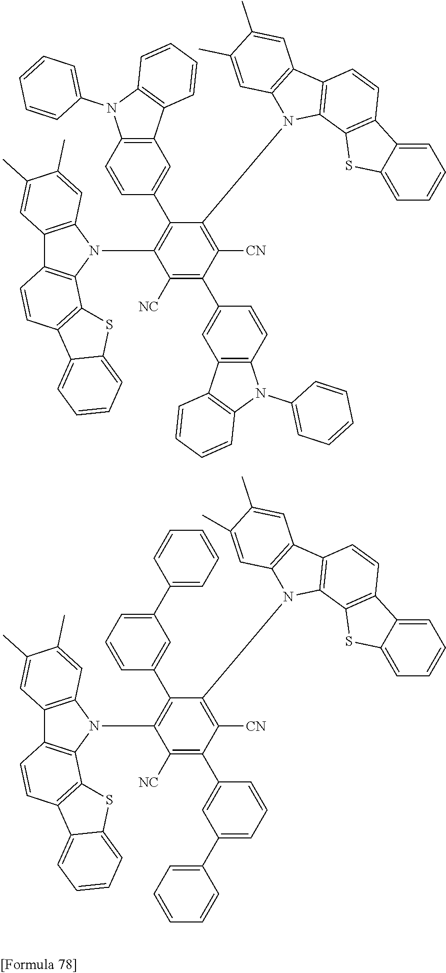

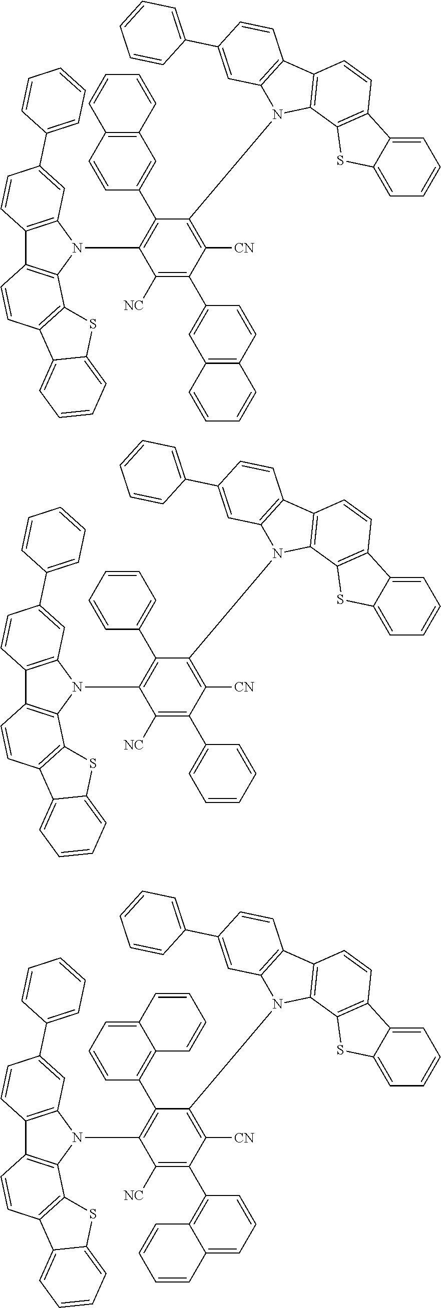

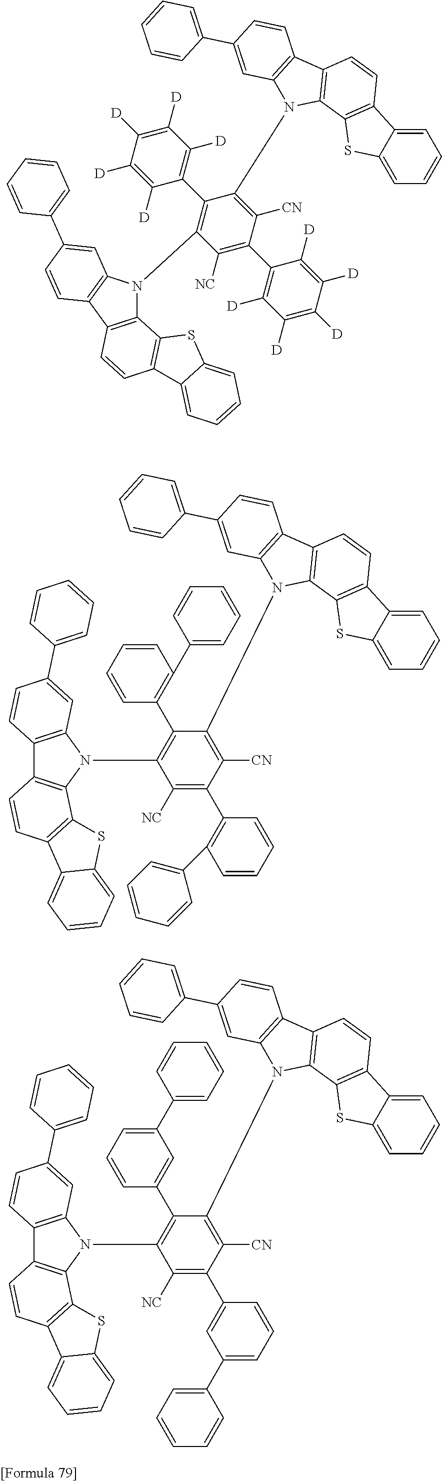

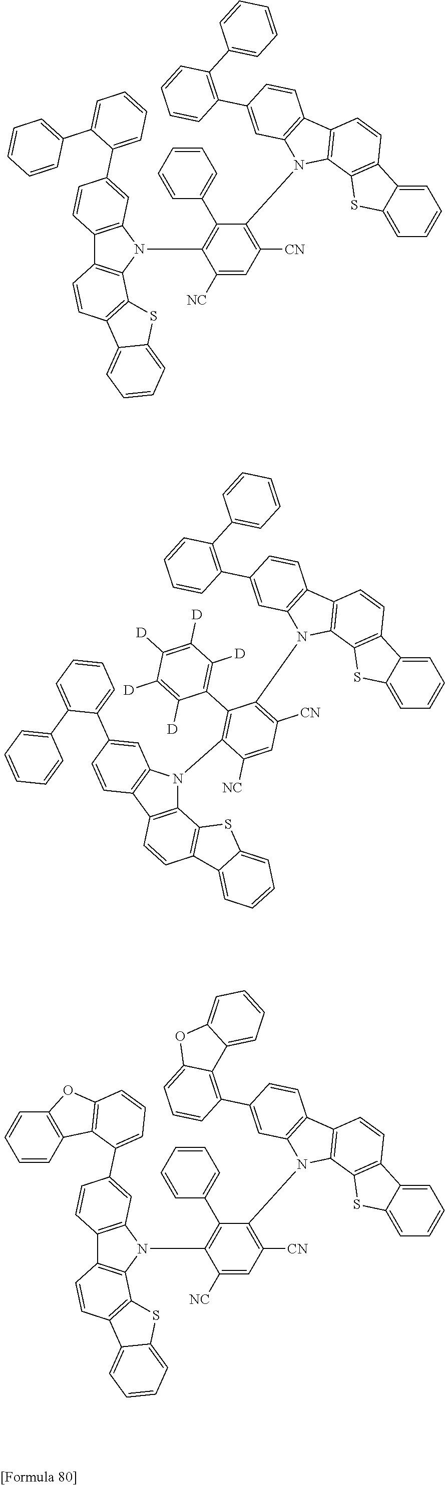 [SMILES: N#Cc1cc(C#N)c(-n2c3cc(-c4ccccc4-c4ccccc4)ccc3c3ccc4c5ccccc5sc4c32)c(-c2ccccc2)c1-n1c2cc(-c3ccccc3-c3ccccc3)ccc2c2ccc3c4ccccc4sc3c21 ; [2H]c1c([2H])c([2H])c(-c2c(-n3c4cc(-c5ccccc5-c5ccccc5)ccc4c4ccc5c6ccccc6sc5c43)c(C#N)cc(C#N)c2-n2c3cc(-c4ccccc4-c4ccccc4)ccc3c3ccc4c5ccccc5sc4c32)c([2H])c1[2H] ; N#Cc1cc(C#N)c(-n2c3cc(-c4cccc5oc6ccccc6c45)ccc3c3ccc4c5ccccc5sc4c32)c(-c2ccccc2)c1-n1c2cc(-c3cccc4oc5ccccc5c34)ccc2c2ccc3c4ccccc4sc3c21]

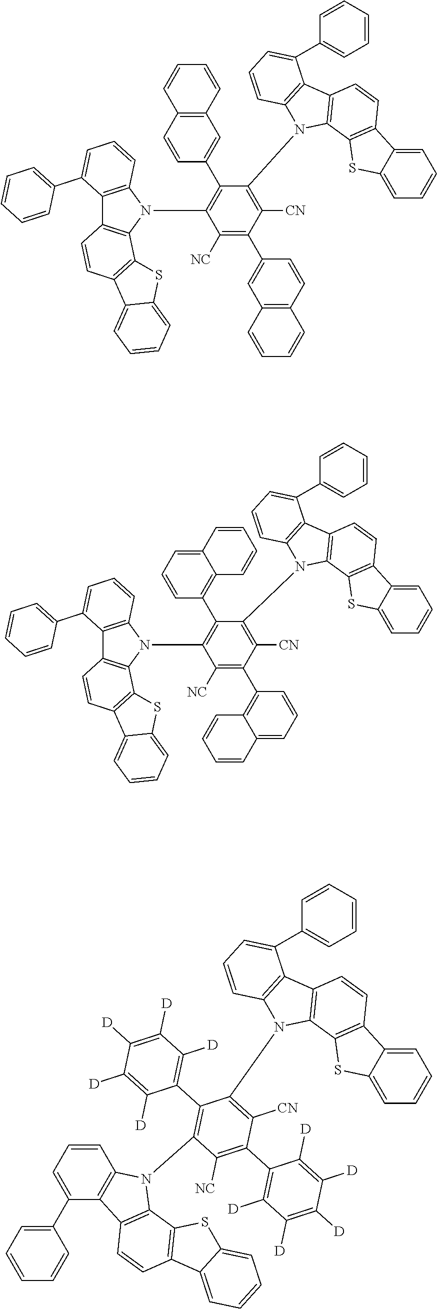 [SMILES: N#Cc1c(-c2ccc3ccccc3c2)c(C#N)c(-n2c3cccc(-c4ccccc4)c3c3ccc4c5ccccc5sc4c32)c(-c2ccc3ccccc3c2)c1-n1c2cccc(-c3ccccc3)c2c2ccc3c4ccccc4sc3c21 ; N#Cc1c(-c2cccc3ccccc23)c(C#N)c(-n2c3cccc(-c4ccccc4)c3c3ccc4c5ccccc5sc4c32)c(-c2cccc3ccccc23)c1-n1c2cccc(-c3ccccc3)c2c2ccc3c4ccccc4sc3c21 ; [2H]c1c([2H])c([2H])c(-c2c(C#N)c(-n3c4cccc(-c5ccccc5)c4c4ccc5c6ccccc6sc5c43)c(-c3c([2H])c([2H])c([2H])c([2H])c3[2H])c(-n3c4cccc(-c5ccccc5)c4c4ccc5c6ccccc6sc5c43)c2C#N)c([2H])c1[2H]]

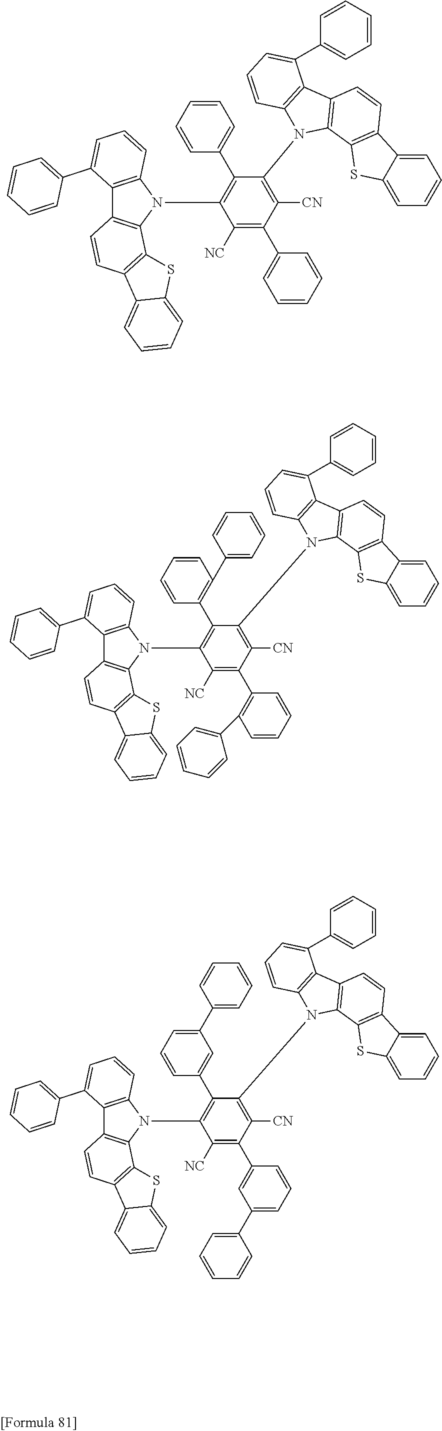 [SMILES: N#Cc1c(-c2ccccc2)c(C#N)c(-n2c3cccc(-c4ccccc4)c3c3ccc4c5ccccc5sc4c32)c(-c2ccccc2)c1-n1c2cccc(-c3ccccc3)c2c2ccc3c4ccccc4sc3c21 ; N#Cc1c(-c2ccccc2-c2ccccc2)c(C#N)c(-n2c3cccc(-c4ccccc4)c3c3ccc4c5ccccc5sc4c32)c(-c2ccccc2-c2ccccc2)c1-n1c2cccc(-c3ccccc3)c2c2ccc3c4ccccc4sc3c21 ; N#Cc1c(-c2cccc(-c3ccccc3)c2)c(C#N)c(-n2c3cccc(-c4ccccc4)c3c3ccc4c5ccccc5sc4c32)c(-c2cccc(-c3ccccc3)c2)c1-n1c2cccc(-c3ccccc3)c2c2ccc3c4ccccc4sc3c21]

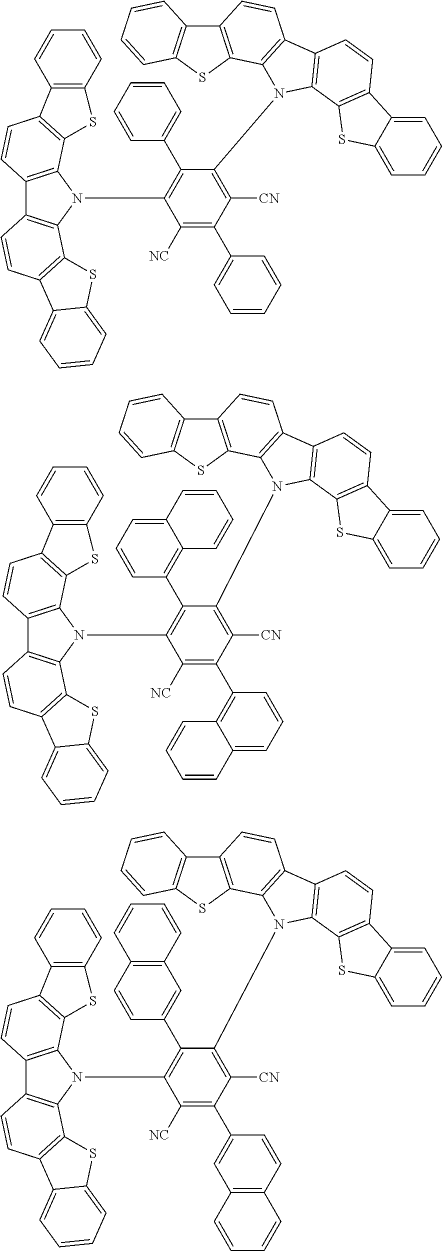 [SMILES: N#Cc1c(-c2ccccc2)c(C#N)c(-n2c3c(ccc4c5ccccc5sc43)c3ccc4c5ccccc5sc4c32)c(-c2ccccc2)c1-n1c2c(ccc3c4ccccc4sc32)c2ccc3c4ccccc4sc3c21 ; N#Cc1c(-c2cccc3ccccc23)c(C#N)c(-n2c3c(ccc4c5ccccc5sc43)c3ccc4c5ccccc5sc4c32)c(-c2cccc3ccccc23)c1-n1c2c(ccc3c4ccccc4sc32)c2ccc3c4ccccc4sc3c21 ; N#Cc1c(-c2ccc3ccccc3c2)c(C#N)c(-n2c3c(ccc4c5ccccc5sc43)c3ccc4c5ccccc5sc4c32)c(-c2ccc3ccccc3c2)c1-n1c2c(ccc3c4ccccc4sc32)c2ccc3c4ccccc4sc3c21]

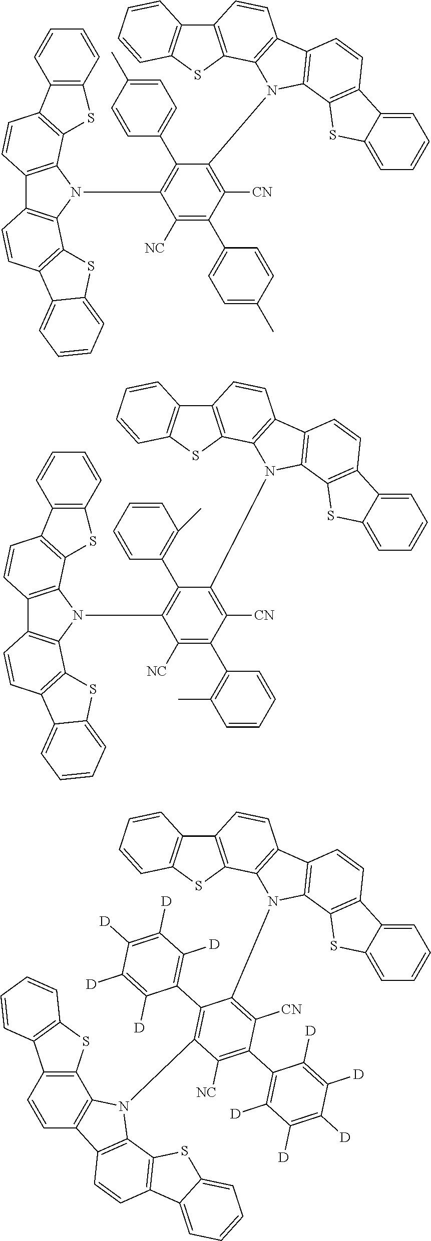 [SMILES: Cc1ccc(-c2c(C#N)c(-n3c4c(ccc5c6ccccc6sc54)c4ccc5c6ccccc6sc5c43)c(-c3ccc(C)cc3)c(-n3c4c(ccc5c6ccccc6sc54)c4ccc5c6ccccc6sc5c43)c2C#N)cc1 ; Cc1ccccc1-c1c(C#N)c(-n2c3c(ccc4c5ccccc5sc43)c3ccc4c5ccccc5sc4c32)c(-c2ccccc2C)c(-n2c3c(ccc4c5ccccc5sc43)c3ccc4c5ccccc5sc4c32)c1C#N ; [2H]c1c([2H])c([2H])c(-c2c(C#N)c(-n3c4c(ccc5c6ccccc6sc54)c4ccc5c6ccccc6sc5c43)c(-c3c([2H])c([2H])c([2H])c([2H])c3[2H])c(-n3c4c(ccc5c6ccccc6sc54)c4ccc5c6ccccc6sc5c43)c2C#N)c([2H])c1[2H]]

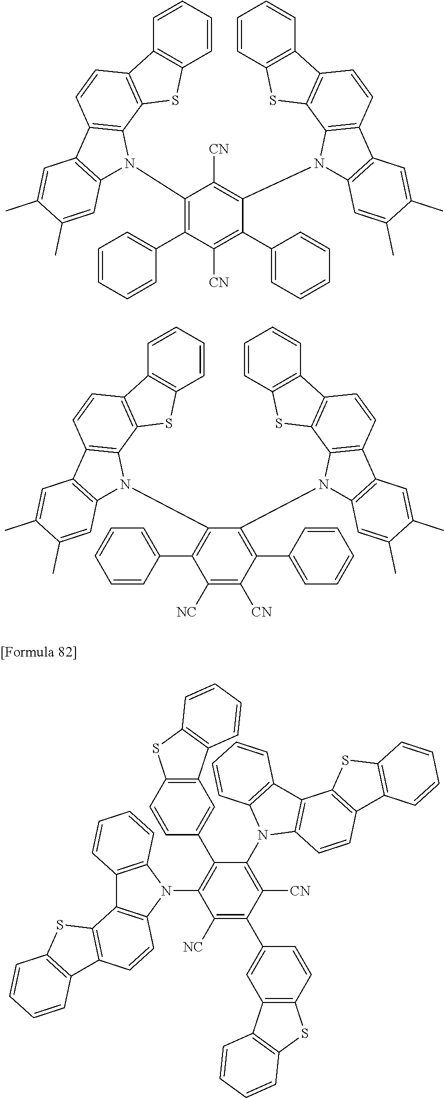

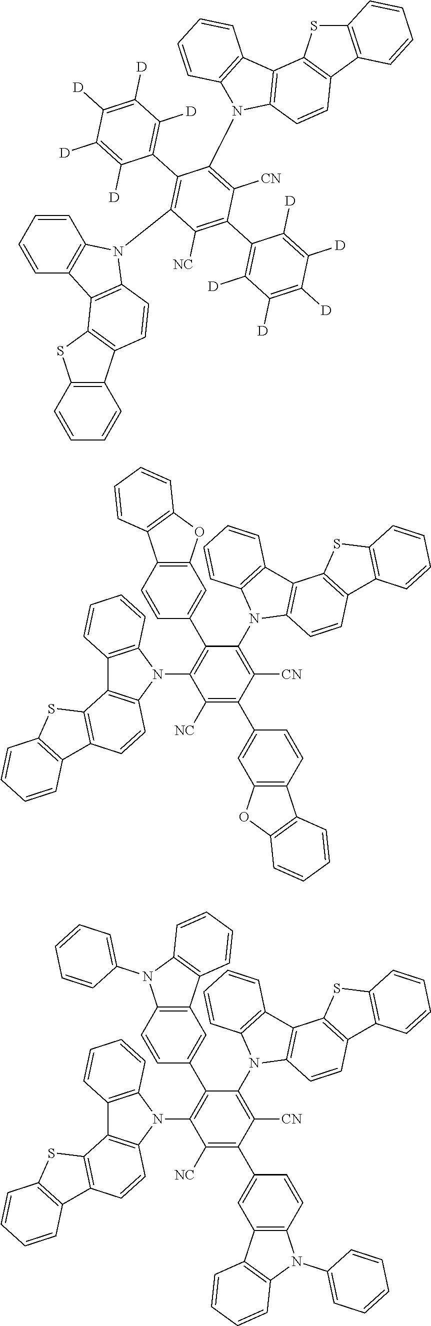 [SMILES: [2H]c1c([2H])c([2H])c(-c2c(C#N)c(-n3c4ccccc4c4c5sc6ccccc6c5ccc43)c(-c3c([2H])c([2H])c([2H])c([2H])c3[2H])c(-n3c4ccccc4c4c5sc6ccccc6c5ccc43)c2C#N)c([2H])c1[2H] ; N#Cc1c(-c2ccc3c(c2)oc2ccccc23)c(C#N)c(-n2c3ccccc3c3c4sc5ccccc5c4ccc32)c(-c2ccc3c(c2)oc2ccccc23)c1-n1c2ccccc2c2c3sc4ccccc4c3ccc21 ; N#Cc1c(-c2ccc3c(c2)c2ccccc2n3-c2ccccc2)c(C#N)c(-n2c3ccccc3c3c4sc5ccccc5c4ccc32)c(-c2ccc3c(c2)c2ccccc2n3-c2ccccc2)c1-n1c2ccccc2c2c3sc4ccccc4c3ccc21]

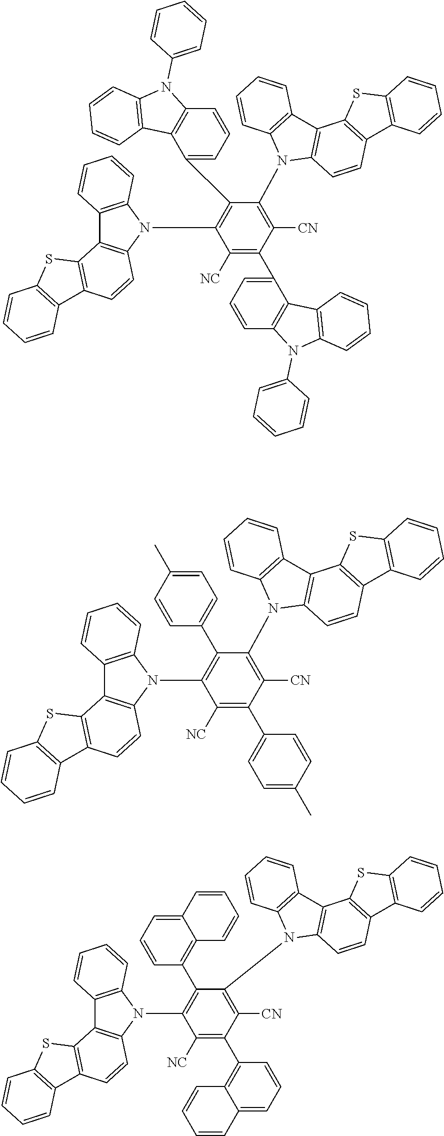 [SMILES: N#Cc1c(-c2cccc3c2c2ccccc2n3-c2ccccc2)c(C#N)c(-n2c3ccccc3c3c4sc5ccccc5c4ccc32)c(-c2cccc3c2c2ccccc2n3-c2ccccc2)c1-n1c2ccccc2c2c3sc4ccccc4c3ccc21 ; Cc1ccc(-c2c(C#N)c(-n3c4ccccc4c4c5sc6ccccc6c5ccc43)c(-c3ccc(C)cc3)c(-n3c4ccccc4c4c5sc6ccccc6c5ccc43)c2C#N)cc1 ; N#Cc1c(-c2cccc3ccccc23)c(C#N)c(-n2c3ccccc3c3c4sc5ccccc5c4ccc32)c(-c2cccc3ccccc23)c1-n1c2ccccc2c2c3sc4ccccc4c3ccc21]

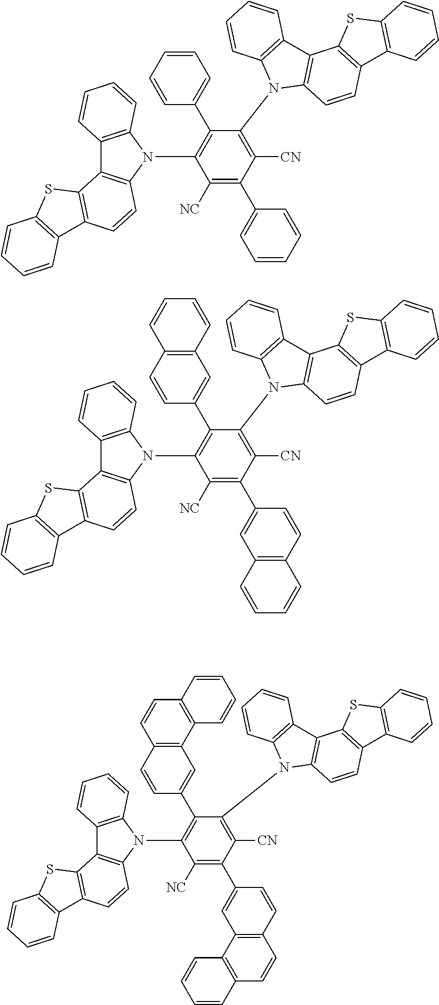

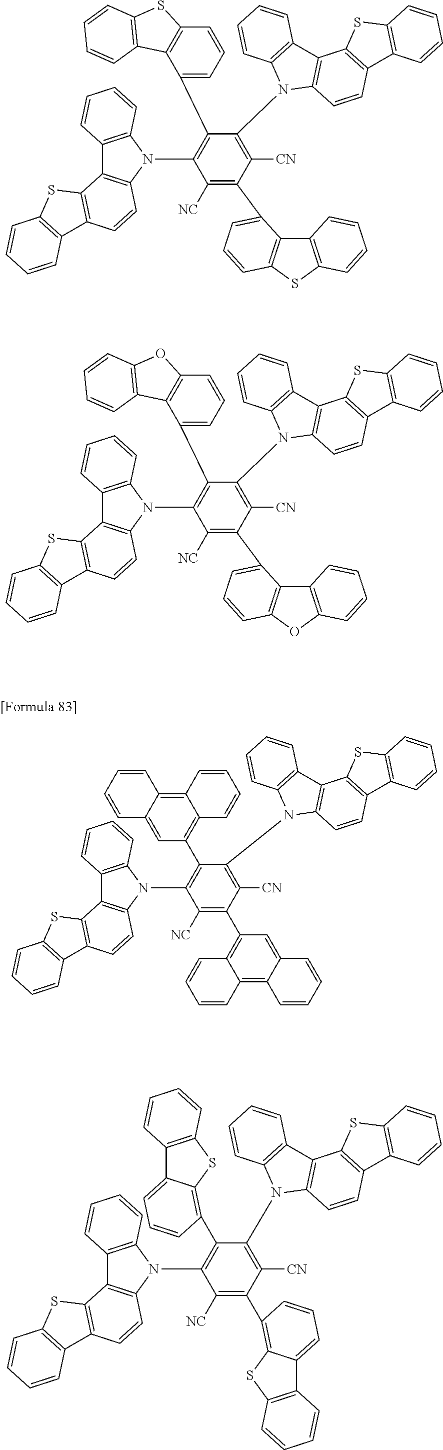

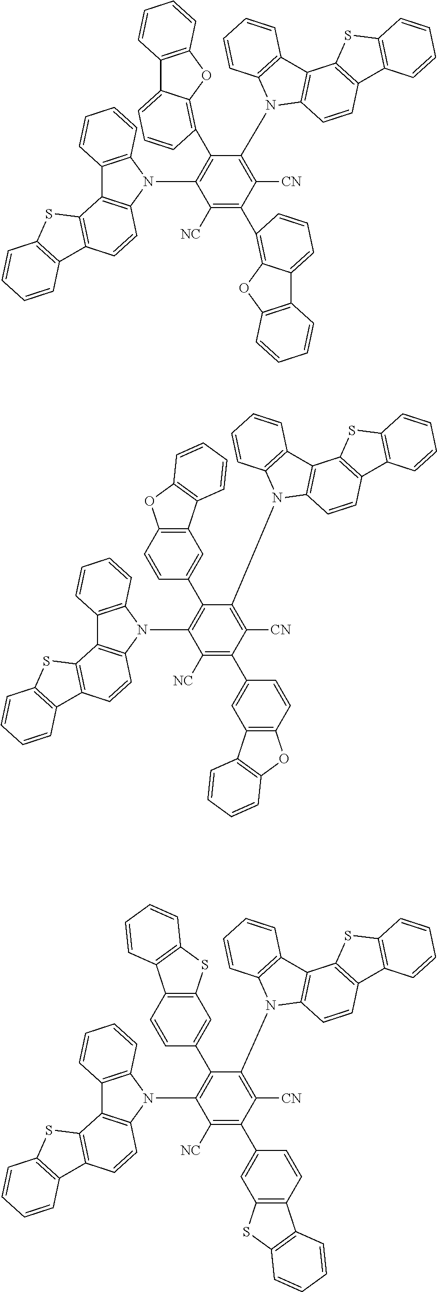 [SMILES: N#Cc1c(-c2cccc3c2oc2ccccc23)c(C#N)c(-n2c3ccccc3c3c4sc5ccccc5c4ccc32)c(-c2cccc3c2oc2ccccc23)c1-n1c2ccccc2c2c3sc4ccccc4c3ccc21 ; N#Cc1c(-c2ccc3oc4ccccc4c3c2)c(C#N)c(-n2c3ccccc3c3c4sc5ccccc5c4ccc32)c(-c2ccc3oc4ccccc4c3c2)c1-n1c2ccccc2c2c3sc4ccccc4c3ccc21 ; N#Cc1c(-c2ccc3c(c2)sc2ccccc23)c(C#N)c(-n2c3ccccc3c3c4sc5ccccc5c4ccc32)c(-c2ccc3c(c2)sc2ccccc23)c1-n1c2ccccc2c2c3sc4ccccc4c3ccc21]

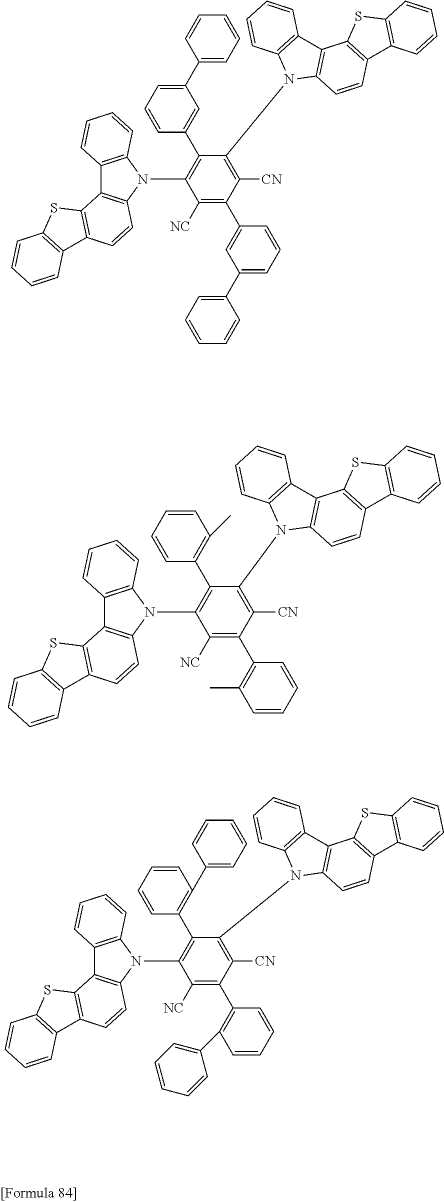 [SMILES: N#Cc1c(-c2cccc(-c3ccccc3)c2)c(C#N)c(-n2c3ccccc3c3c4sc5ccccc5c4ccc32)c(-c2cccc(-c3ccccc3)c2)c1-n1c2ccccc2c2c3sc4ccccc4c3ccc21 ; Cc1ccccc1-c1c(C#N)c(-n2c3ccccc3c3c4sc5ccccc5c4ccc32)c(-c2ccccc2C)c(-n2c3ccccc3c3c4sc5ccccc5c4ccc32)c1C#N ; N#Cc1c(-c2ccccc2-c2ccccc2)c(C#N)c(-n2c3ccccc3c3c4sc5ccccc5c4ccc32)c(-c2ccccc2-c2ccccc2)c1-n1c2ccccc2c2c3sc4ccccc4c3ccc21]

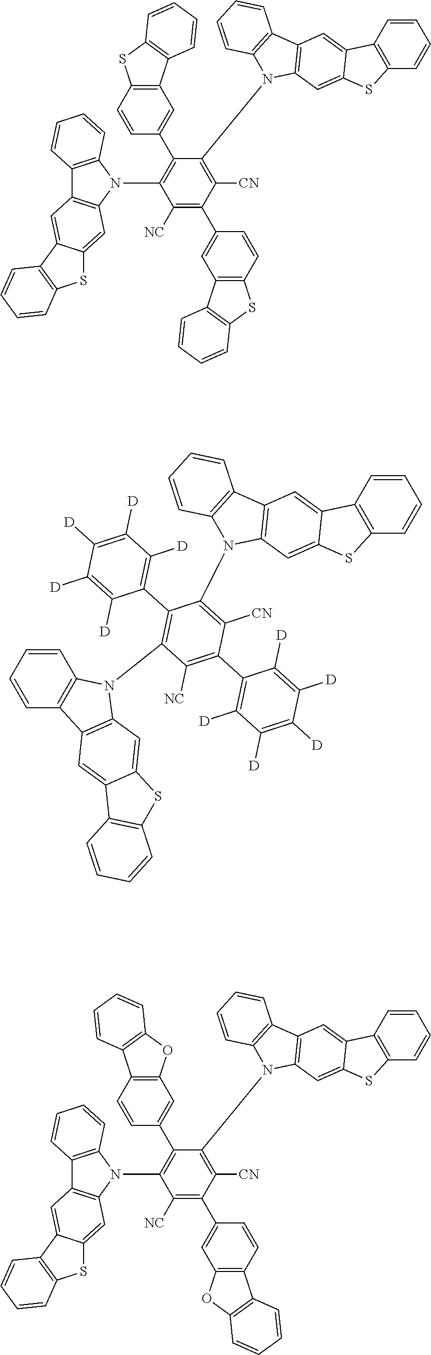 [SMILES: N#Cc1c(-c2ccc3sc4ccccc4c3c2)c(C#N)c(-n2c3ccccc3c3cc4c(cc32)sc2ccccc24)c(-c2ccc3sc4ccccc4c3c2)c1-n1c2ccccc2c2cc3c(cc21)sc1ccccc13 ; [2H]c1c([2H])c([2H])c(-c2c(C#N)c(-n3c4ccccc4c4cc5c(cc43)sc3ccccc35)c(-c3c([2H])c([2H])c([2H])c([2H])c3[2H])c(-n3c4ccccc4c4cc5c(cc43)sc3ccccc35)c2C#N)c([2H])c1[2H] ; N#Cc1c(-c2ccc3c(c2)oc2ccccc23)c(C#N)c(-n2c3ccccc3c3cc4c(cc32)sc2ccccc24)c(-c2ccc3c(c2)oc2ccccc23)c1-n1c2ccccc2c2cc3c(cc21)sc1ccccc13]

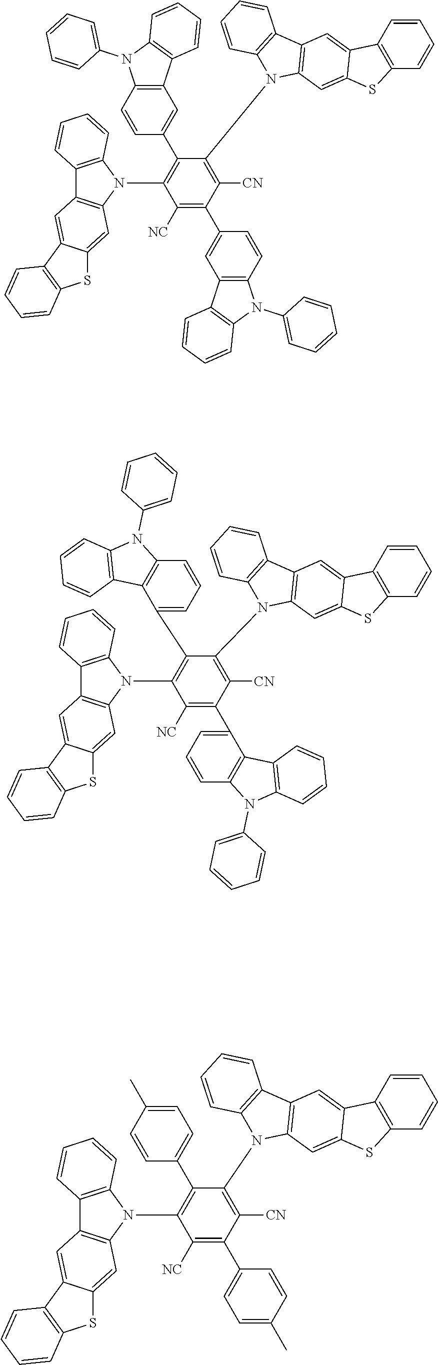 [SMILES: N#Cc1c(-c2ccc3c(c2)c2ccccc2n3-c2ccccc2)c(C#N)c(-n2c3ccccc3c3cc4c(cc32)sc2ccccc24)c(-c2ccc3c(c2)c2ccccc2n3-c2ccccc2)c1-n1c2ccccc2c2cc3c(cc21)sc1ccccc13 ; N#Cc1c(-c2cccc3c2c2ccccc2n3-c2ccccc2)c(C#N)c(-n2c3ccccc3c3cc4c(cc32)sc2ccccc24)c(-c2cccc3c2c2ccccc2n3-c2ccccc2)c1-n1c2ccccc2c2cc3c(cc21)sc1ccccc13 ; Cc1ccc(-c2c(C#N)c(-n3c4ccccc4c4cc5c(cc43)sc3ccccc35)c(-c3ccc(C)cc3)c(-n3c4ccccc4c4cc5c(cc43)sc3ccccc35)c2C#N)cc1]

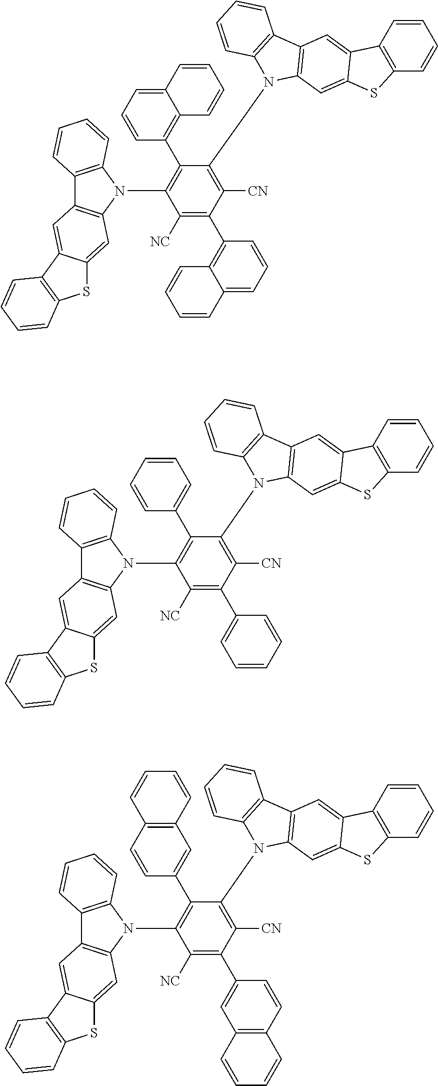 [SMILES: N#Cc1c(-c2cccc3ccccc23)c(C#N)c(-n2c3ccccc3c3cc4c(cc32)sc2ccccc24)c(-c2cccc3ccccc23)c1-n1c2ccccc2c2cc3c(cc21)sc1ccccc13 ; N#Cc1c(-c2ccccc2)c(C#N)c(-n2c3ccccc3c3cc4c(cc32)sc2ccccc24)c(-c2ccccc2)c1-n1c2ccccc2c2cc3c(cc21)sc1ccccc13 ; N#Cc1c(-c2ccc3ccccc3c2)c(C#N)c(-n2c3ccccc3c3cc4c(cc32)sc2ccccc24)c(-c2ccc3ccccc3c2)c1-n1c2ccccc2c2cc3c(cc21)sc1ccccc13]

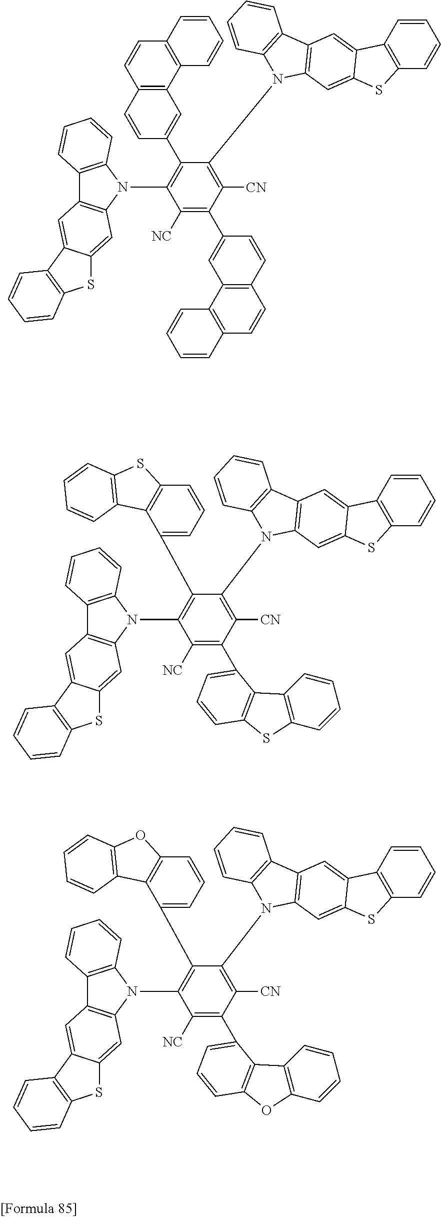 [SMILES: N#Cc1c(-c2ccc3ccc4ccccc4c3c2)c(C#N)c(-n2c3ccccc3c3cc4c(cc32)sc2ccccc24)c(-c2ccc3ccc4ccccc4c3c2)c1-n1c2ccccc2c2cc3c(cc21)sc1ccccc13 ; N#Cc1c(-c2cccc3sc4ccccc4c23)c(C#N)c(-n2c3ccccc3c3cc4c(cc32)sc2ccccc24)c(-c2cccc3sc4ccccc4c23)c1-n1c2ccccc2c2cc3c(cc21)sc1ccccc13 ; N#Cc1c(-c2cccc3oc4ccccc4c23)c(C#N)c(-n2c3ccccc3c3cc4c(cc32)sc2ccccc24)c(-c2cccc3oc4ccccc4c23)c1-n1c2ccccc2c2cc3c(cc21)sc1ccccc13]

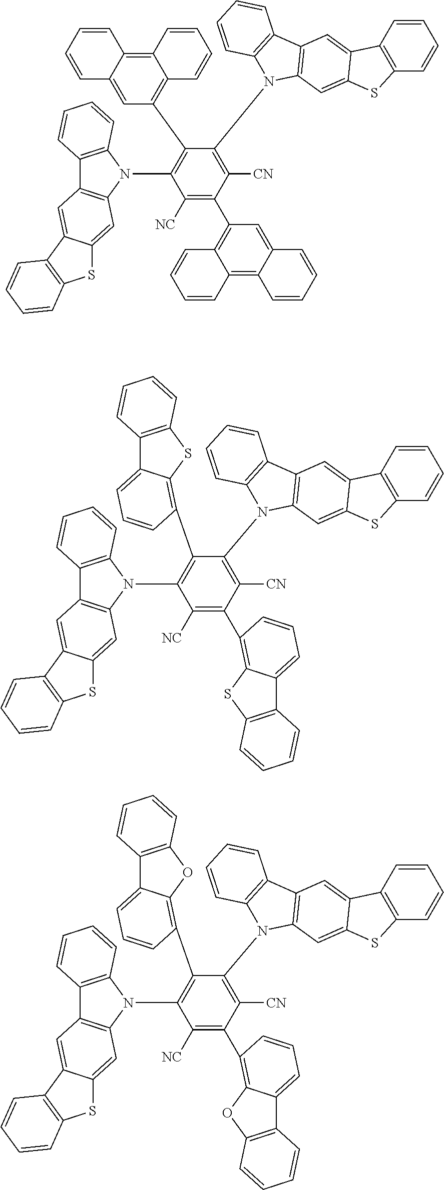 [SMILES: N#Cc1c(-c2cc3ccccc3c3ccccc23)c(C#N)c(-n2c3ccccc3c3cc4c(cc32)sc2ccccc24)c(-c2cc3ccccc3c3ccccc23)c1-n1c2ccccc2c2cc3c(cc21)sc1ccccc13 ; N#Cc1c(-c2cccc3c2sc2ccccc23)c(C#N)c(-n2c3ccccc3c3cc4c(cc32)sc2ccccc24)c(-c2cccc3c2sc2ccccc23)c1-n1c2ccccc2c2cc3c(cc21)sc1ccccc13 ; N#Cc1c(-c2cccc3c2oc2ccccc23)c(C#N)c(-n2c3ccccc3c3cc4c(cc32)sc2ccccc24)c(-c2cccc3c2oc2ccccc23)c1-n1c2ccccc2c2cc3c(cc21)sc1ccccc13]

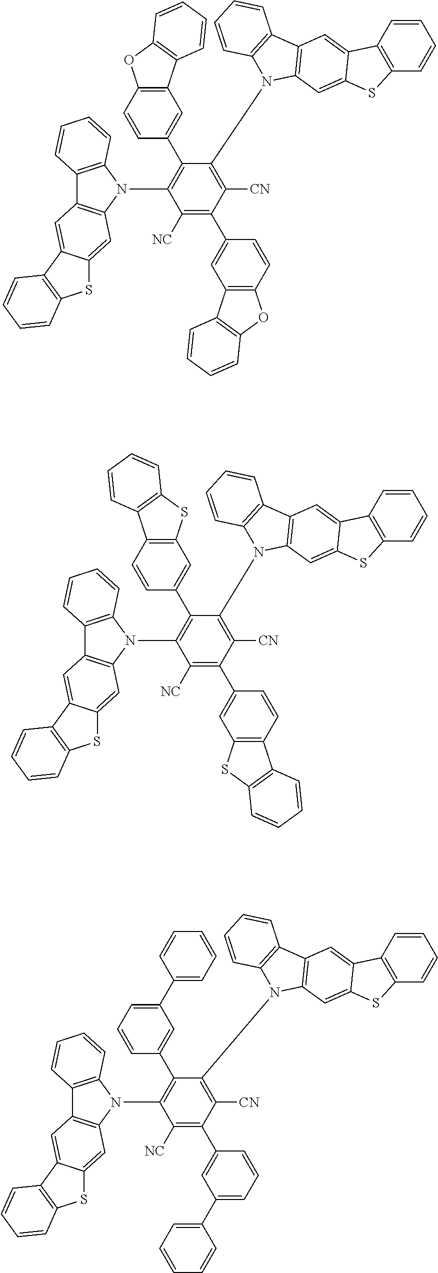 [SMILES: N#Cc1c(-c2ccc3oc4ccccc4c3c2)c(C#N)c(-n2c3ccccc3c3cc4c(cc32)sc2ccccc24)c(-c2ccc3oc4ccccc4c3c2)c1-n1c2ccccc2c2cc3c(cc21)sc1ccccc13 ; N#Cc1c(-c2ccc3c(c2)sc2ccccc23)c(C#N)c(-n2c3ccccc3c3cc4c(cc32)sc2ccccc24)c(-c2ccc3c(c2)sc2ccccc23)c1-n1c2ccccc2c2cc3c(cc21)sc1ccccc13 ; N#Cc1c(-c2cccc(-c3ccccc3)c2)c(C#N)c(-n2c3ccccc3c3cc4c(cc32)sc2ccccc24)c(-c2cccc(-c3ccccc3)c2)c1-n1c2ccccc2c2cc3c(cc21)sc1ccccc13]

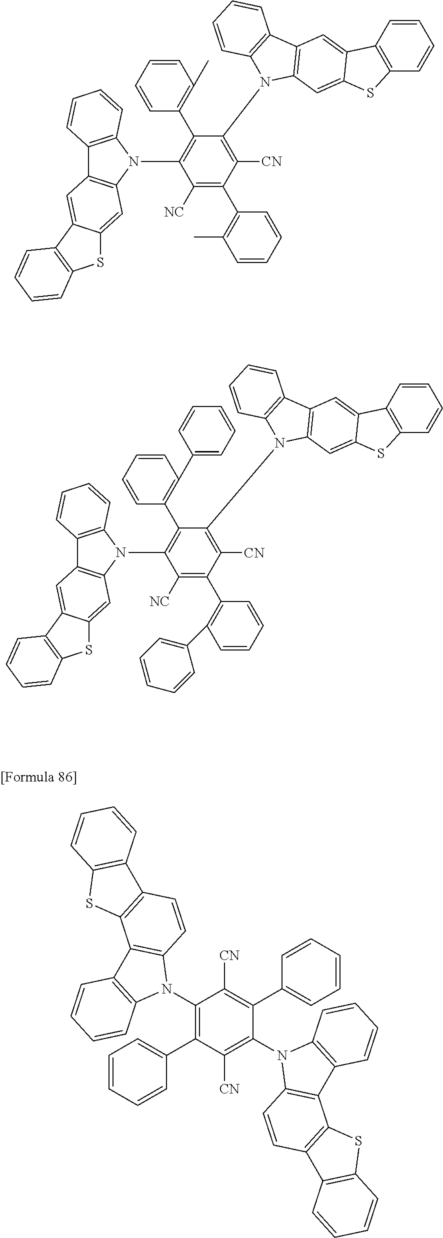 [SMILES: Cc1ccccc1-c1c(C#N)c(-n2c3ccccc3c3cc4c(cc32)sc2ccccc24)c(-c2ccccc2C)c(-n2c3ccccc3c3cc4c(cc32)sc2ccccc24)c1C#N ; N#Cc1c(-c2ccccc2-c2ccccc2)c(C#N)c(-n2c3ccccc3c3cc4c(cc32)sc2ccccc24)c(-c2ccccc2-c2ccccc2)c1-n1c2ccccc2c2cc3c(cc21)sc1ccccc13 ; N#Cc1c(-c2ccccc2)c(-n2c3ccccc3c3c4sc5ccccc5c4ccc32)c(C#N)c(-c2ccccc2)c1-n1c2ccccc2c2c3sc4ccccc4c3ccc21]

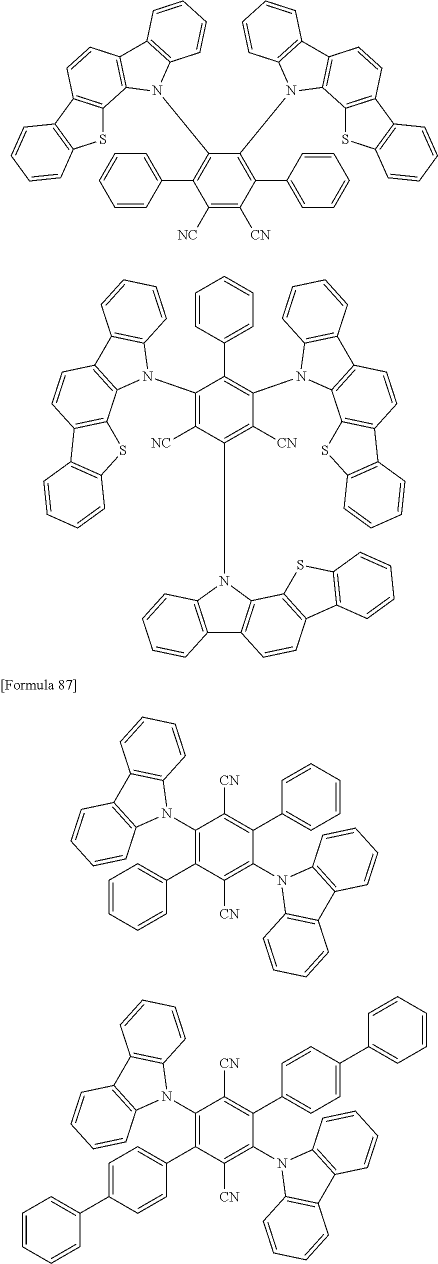 [SMILES: N#Cc1c(C#N)c(-c2ccccc2)c(-n2c3ccccc3c3ccc4c5ccccc5sc4c32)c(-n2c3ccccc3c3ccc4c5ccccc5sc4c32)c1-c1ccccc1 ; N#Cc1c(-n2c3ccccc3c3ccc4c5ccccc5sc4c32)c(C#N)c(-n2c3ccccc3c3ccc4c5ccccc5sc4c32)c(-c2ccccc2)c1-n1c2ccccc2c2ccc3c4ccccc4sc3c21 ; N#Cc1c(-c2ccccc2)c(-n2c3ccccc3c3ccccc32)c(C#N)c(-c2ccccc2)c1-n1c2ccccc2c2ccccc21 ; N#Cc1c(-c2ccc(-c3ccccc3)cc2)c(-n2c3ccccc3c3ccccc32)c(C#N)c(-c2ccc(-c3ccccc3)cc2)c1-n1c2ccccc2c2ccccc21]

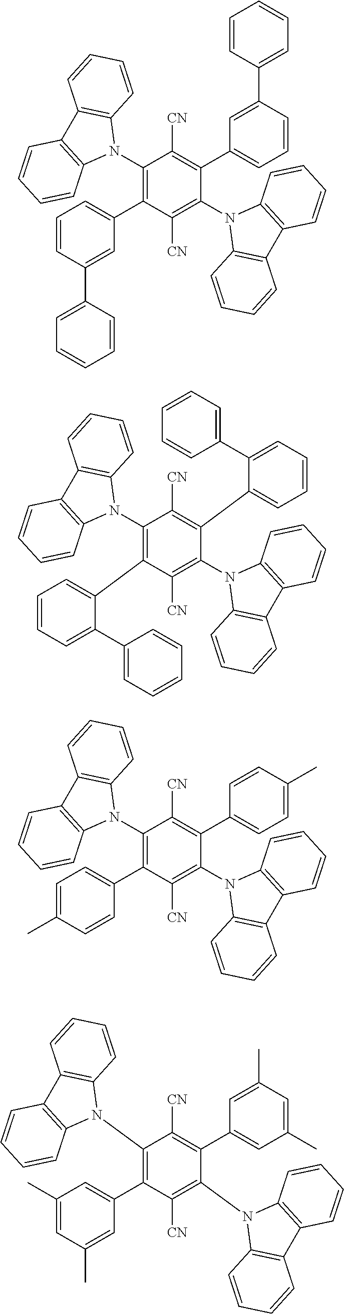

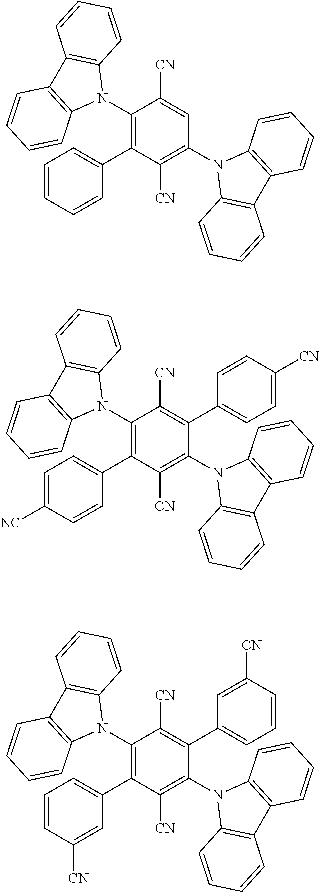 [SMILES: N#Cc1cc(-n2c3ccccc3c3ccccc32)c(C#N)c(-c2ccccc2)c1-n1c2ccccc2c2ccccc21 ; N#Cc1ccc(-c2c(C#N)c(-n3c4ccccc4c4ccccc43)c(-c3ccc(C#N)cc3)c(C#N)c2-n2c3ccccc3c3ccccc32)cc1 ; N#Cc1cccc(-c2c(C#N)c(-n3c4ccccc4c4ccccc43)c(-c3cccc(C#N)c3)c(C#N)c2-n2c3ccccc3c3ccccc32)c1]

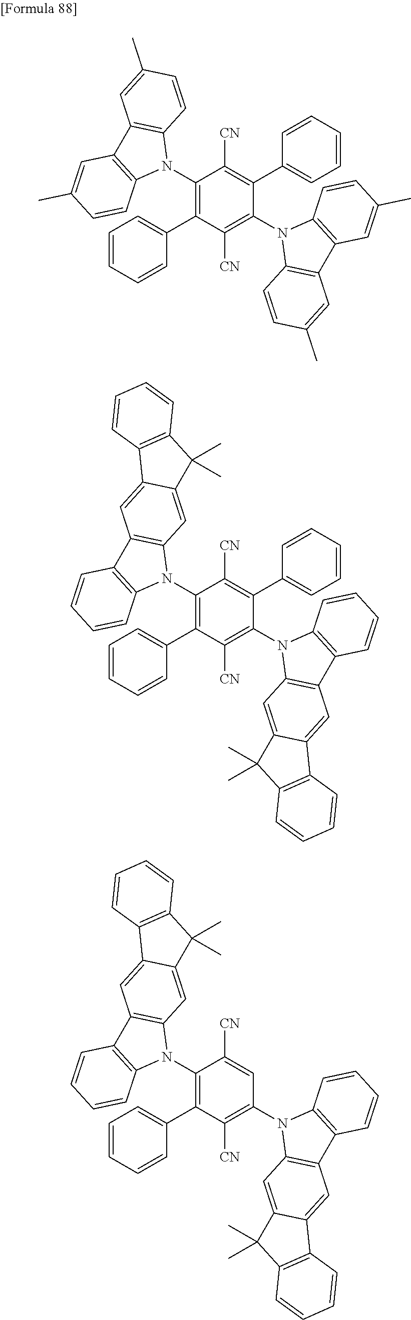

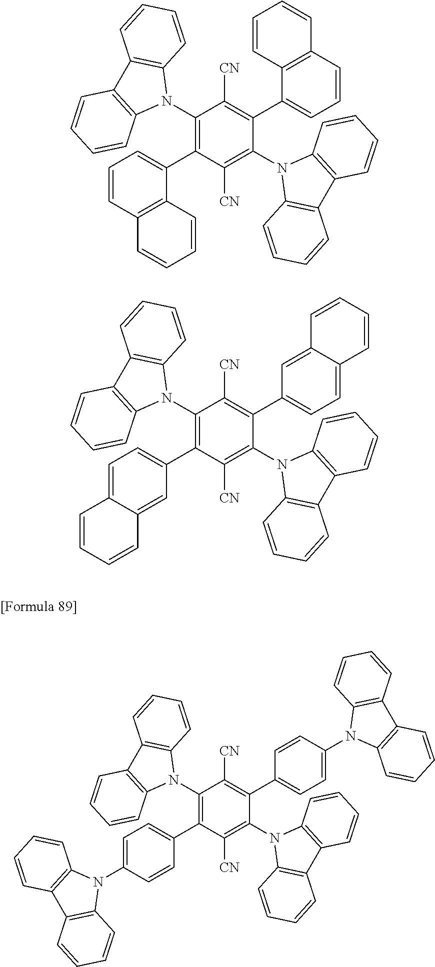

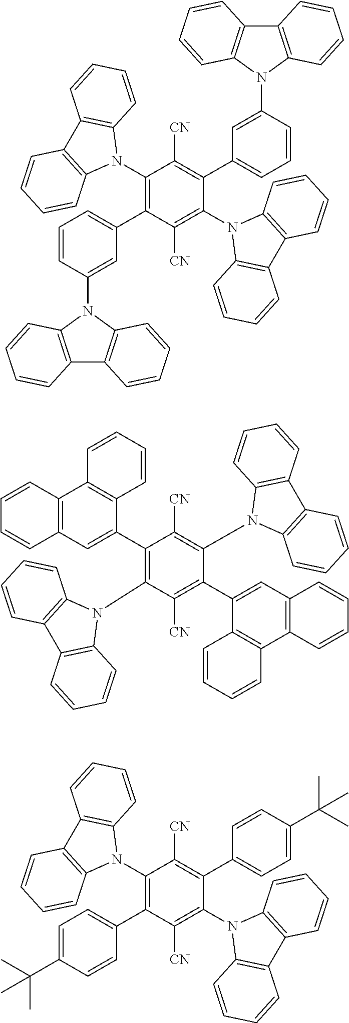

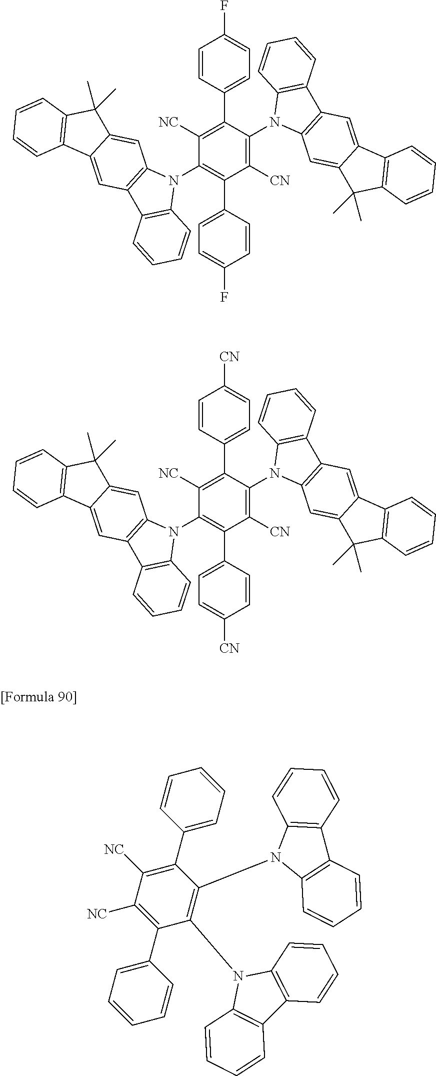 [SMILES: CC1(C)c2ccccc2-c2cc3c4ccccc4n(-c4c(C#N)c(-c5ccc(F)cc5)c(-n5c6ccccc6c6cc7c(cc65)C(C)(C)c5ccccc5-7)c(C#N)c4-c4ccc(F)cc4)c3cc21 ; CC1(C)c2ccccc2-c2cc3c4ccccc4n(-c4c(C#N)c(-c5ccc(C#N)cc5)c(-n5c6ccccc6c6cc7c(cc65)C(C)(C)c5ccccc5-7)c(C#N)c4-c4ccc(C#N)cc4)c3cc21 ; N#Cc1c(C#N)c(-c2ccccc2)c(-n2c3ccccc3c3ccccc32)c(-n2c3ccccc3c3ccccc32)c1-c1ccccc1]

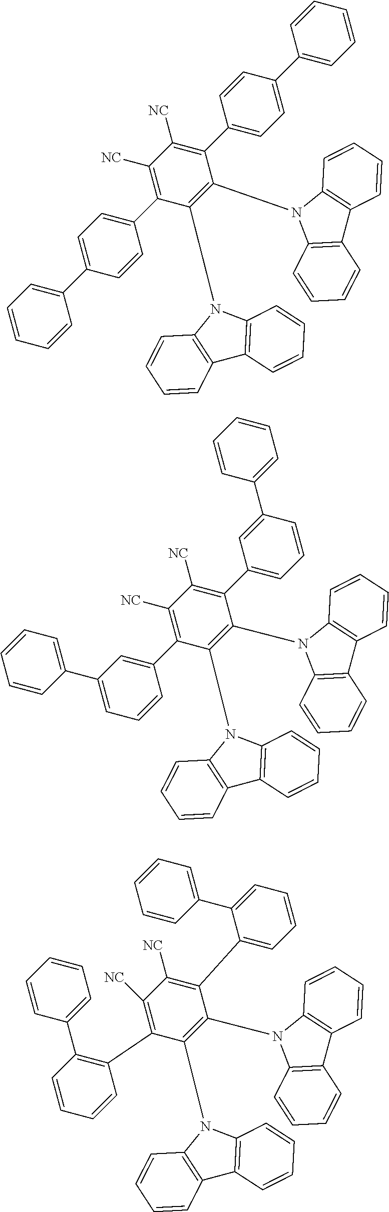

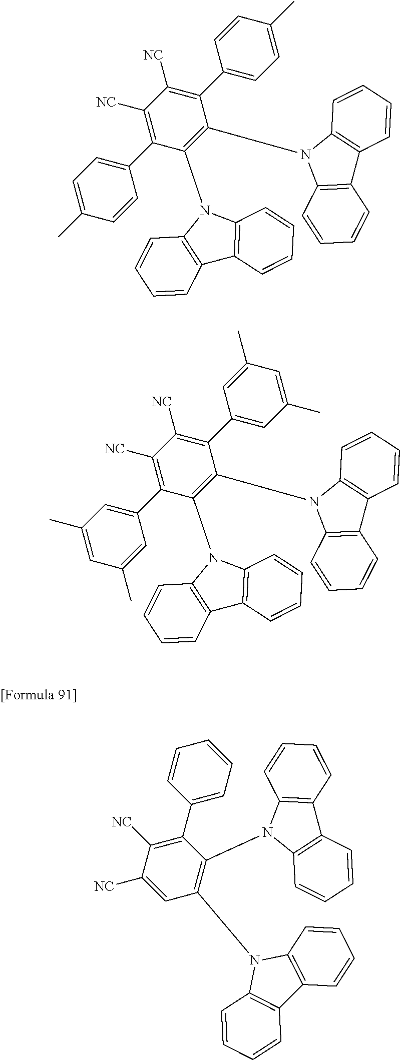 [SMILES: Cc1ccc(-c2c(C#N)c(C#N)c(-c3ccc(C)cc3)c(-n3c4ccccc4c4ccccc43)c2-n2c3ccccc3c3ccccc32)cc1 ; Cc1cc(C)cc(-c2c(C#N)c(C#N)c(-c3cc(C)cc(C)c3)c(-n3c4ccccc4c4ccccc43)c2-n2c3ccccc3c3ccccc32)c1 ; N#Cc1cc(-n2c3ccccc3c3ccccc32)c(-n2c3ccccc3c3ccccc32)c(-c2ccccc2)c1C#N]

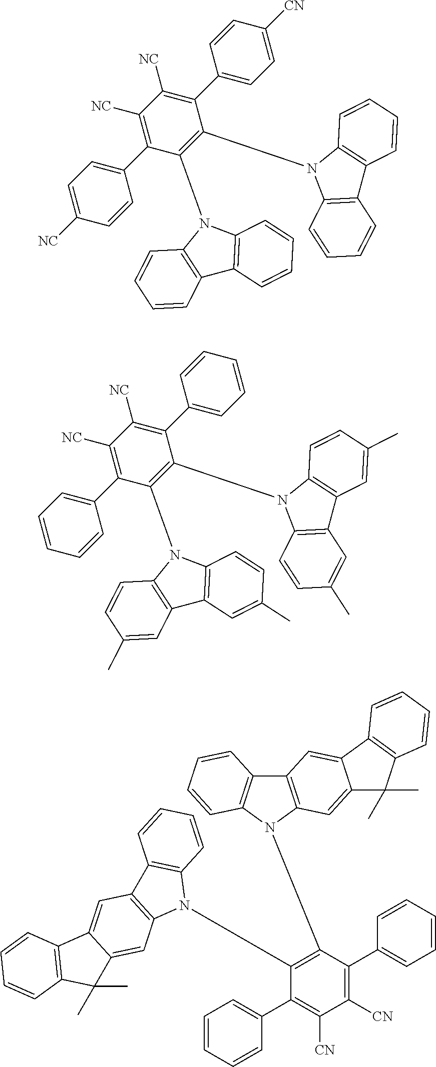 [SMILES: N#Cc1ccc(-c2c(C#N)c(C#N)c(-c3ccc(C#N)cc3)c(-n3c4ccccc4c4ccccc43)c2-n2c3ccccc3c3ccccc32)cc1 ; Cc1ccc2c(c1)c1cc(C)ccc1n2-c1c(-c2ccccc2)c(C#N)c(C#N)c(-c2ccccc2)c1-n1c2ccc(C)cc2c2cc(C)ccc21 ; CC1(C)c2ccccc2-c2cc3c4ccccc4n(-c4c(-c5ccccc5)c(C#N)c(C#N)c(-c5ccccc5)c4-n4c5ccccc5c5cc6c(cc54)C(C)(C)c4ccccc4-6)c3cc21]

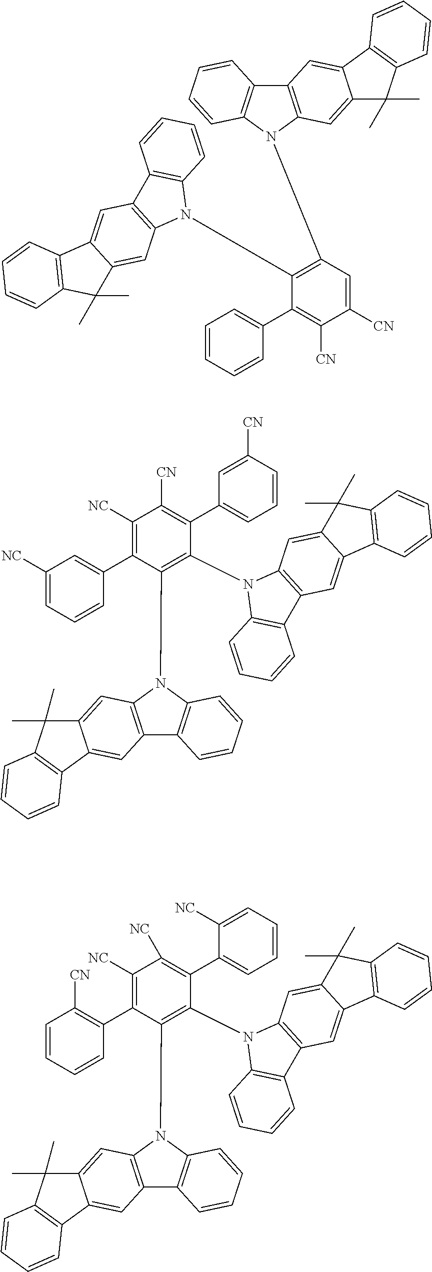 [SMILES: CC1(C)c2ccccc2-c2cc3c4ccccc4n(-c4cc(C#N)c(C#N)c(-c5ccccc5)c4-n4c5ccccc5c5cc6c(cc54)C(C)(C)c4ccccc4-6)c3cc21 ; CC1(C)c2ccccc2-c2cc3c4ccccc4n(-c4c(-c5cccc(C#N)c5)c(C#N)c(C#N)c(-c5cccc(C#N)c5)c4-n4c5ccccc5c5cc6c(cc54)C(C)(C)c4ccccc4-6)c3cc21 ; CC1(C)c2ccccc2-c2cc3c4ccccc4n(-c4c(-c5ccccc5C#N)c(C#N)c(C#N)c(-c5ccccc5C#N)c4-n4c5ccccc5c5cc6c(cc54)C(C)(C)c4ccccc4-6)c3cc21]

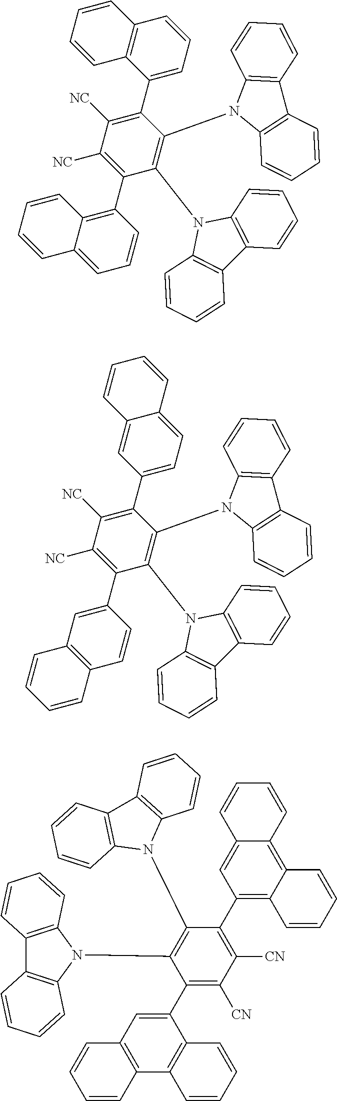

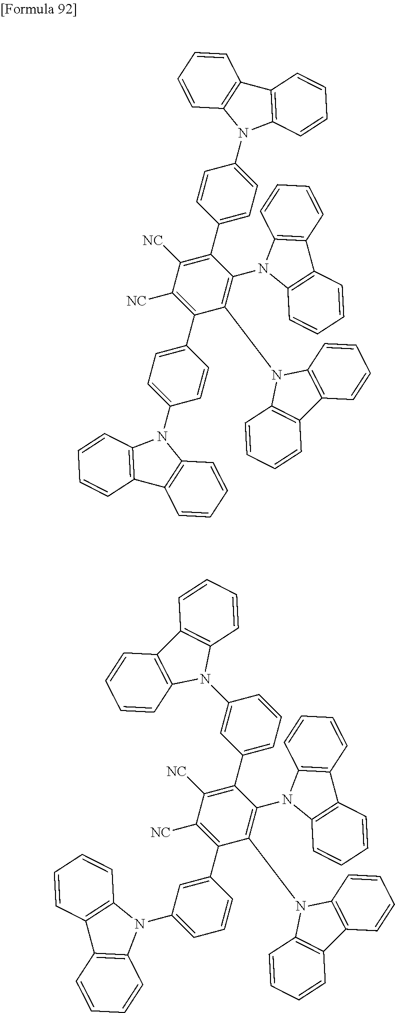 [SMILES: N#Cc1c(C#N)c(-c2ccc(-n3c4ccccc4c4ccccc43)cc2)c(-n2c3ccccc3c3ccccc32)c(-n2c3ccccc3c3ccccc32)c1-c1ccc(-n2c3ccccc3c3ccccc32)cc1 ; N#Cc1c(C#N)c(-c2cccc(-n3c4ccccc4c4ccccc43)c2)c(-n2c3ccccc3c3ccccc32)c(-n2c3ccccc3c3ccccc32)c1-c1cccc(-n2c3ccccc3c3ccccc32)c1]

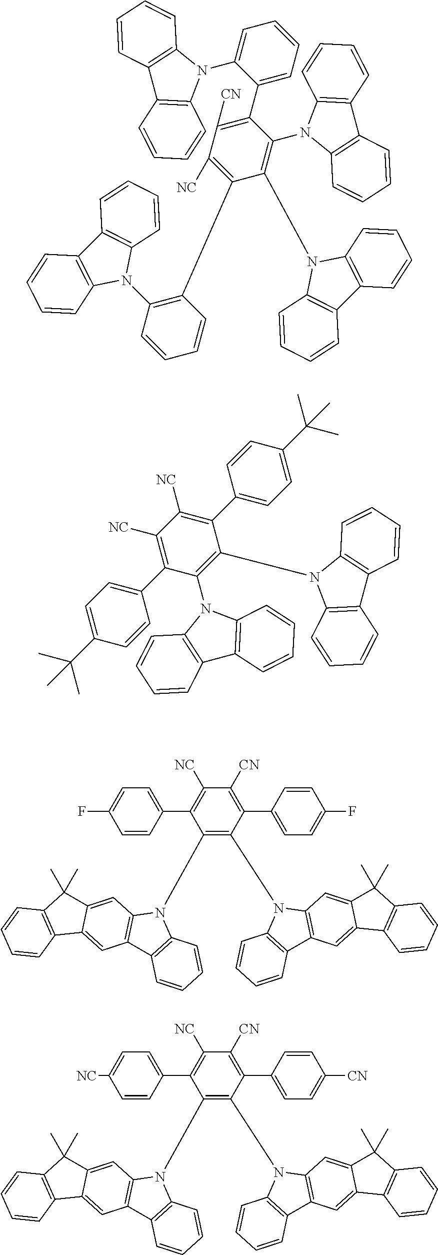

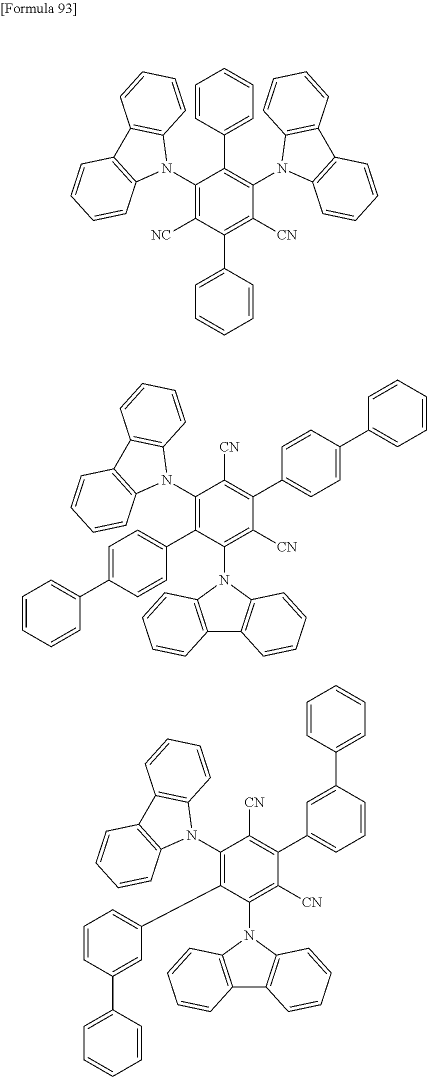 [SMILES: N#Cc1c(-c2ccccc2)c(C#N)c(-n2c3ccccc3c3ccccc32)c(-c2ccccc2)c1-n1c2ccccc2c2ccccc21 ; N#Cc1c(-c2ccc(-c3ccccc3)cc2)c(C#N)c(-n2c3ccccc3c3ccccc32)c(-c2ccc(-c3ccccc3)cc2)c1-n1c2ccccc2c2ccccc21 ; N#Cc1c(-c2cccc(-c3ccccc3)c2)c(C#N)c(-n2c3ccccc3c3ccccc32)c(-c2cccc(-c3ccccc3)c2)c1-n1c2ccccc2c2ccccc21]

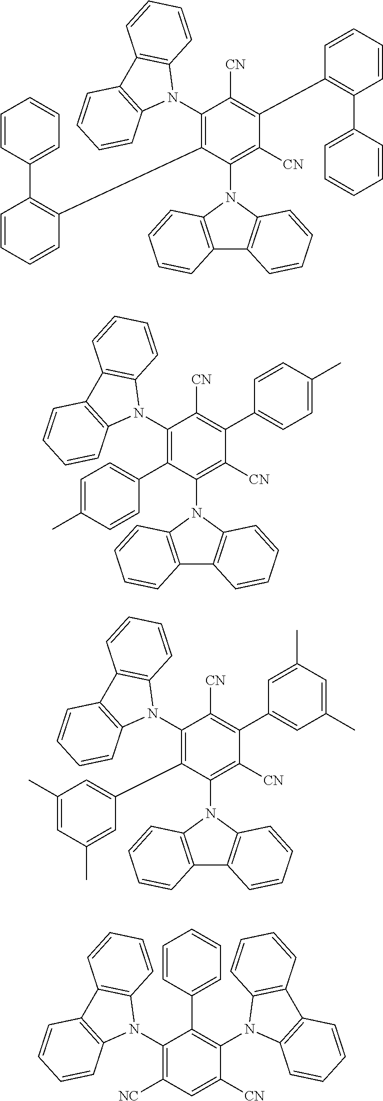

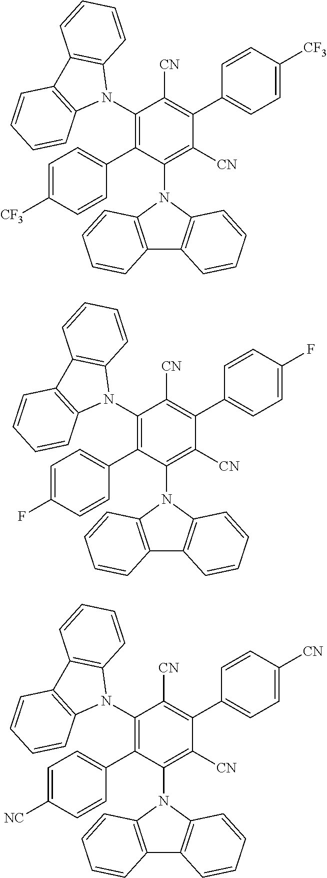

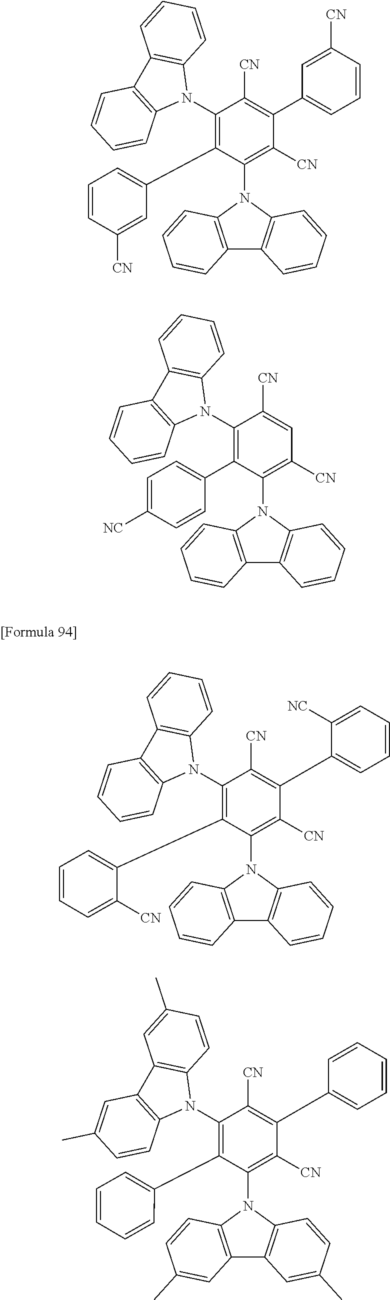

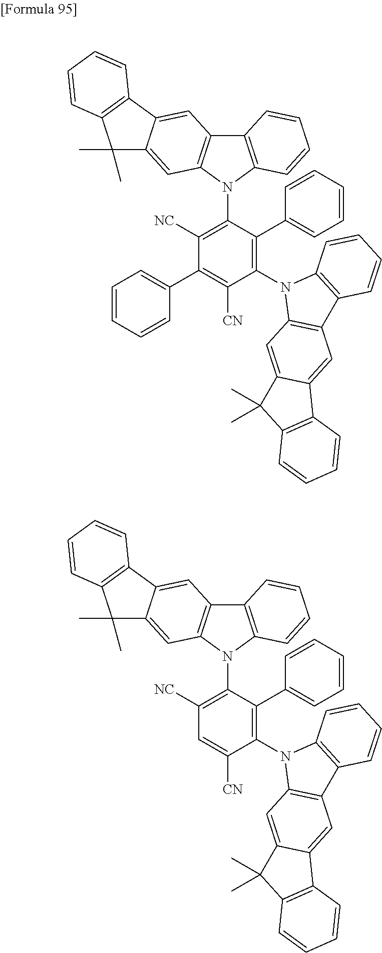 [SMILES: CC1(C)c2ccccc2-c2cc3c4ccccc4n(-c4c(C#N)c(-c5ccccc5)c(C#N)c(-n5c6ccccc6c6cc7c(cc65)C(C)(C)c5ccccc5-7)c4-c4ccccc4)c3cc21 ; CC1(C)c2ccccc2-c2cc3c4ccccc4n(-c4c(C#N)cc(C#N)c(-n5c6ccccc6c6cc7c(cc65)C(C)(C)c5ccccc5-7)c4-c4ccccc4)c3cc21]

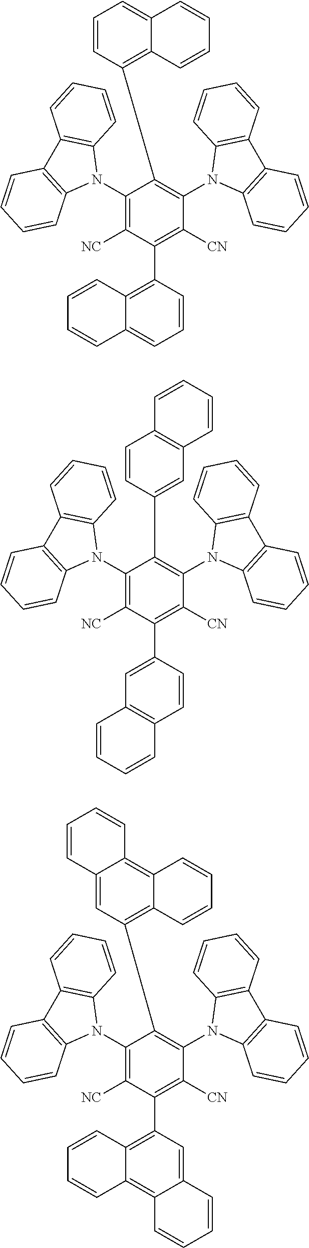

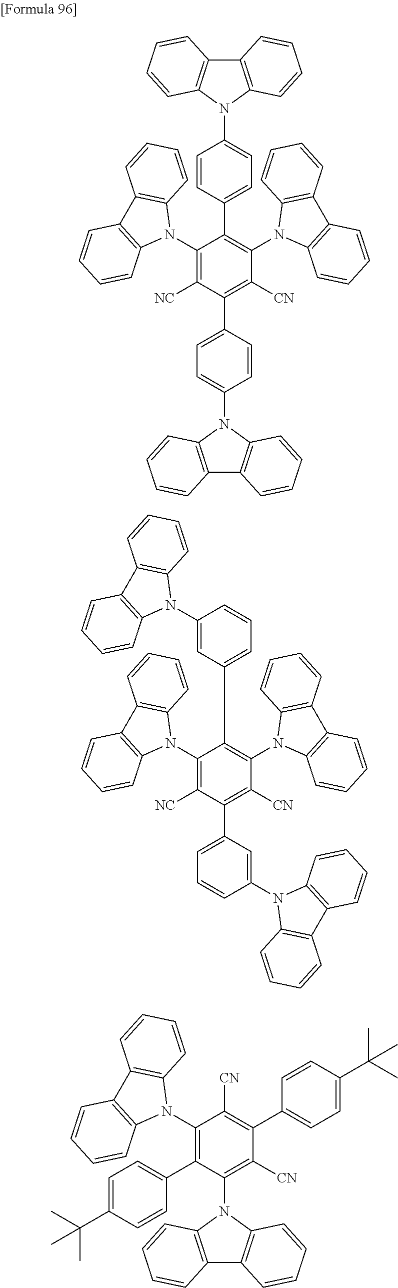

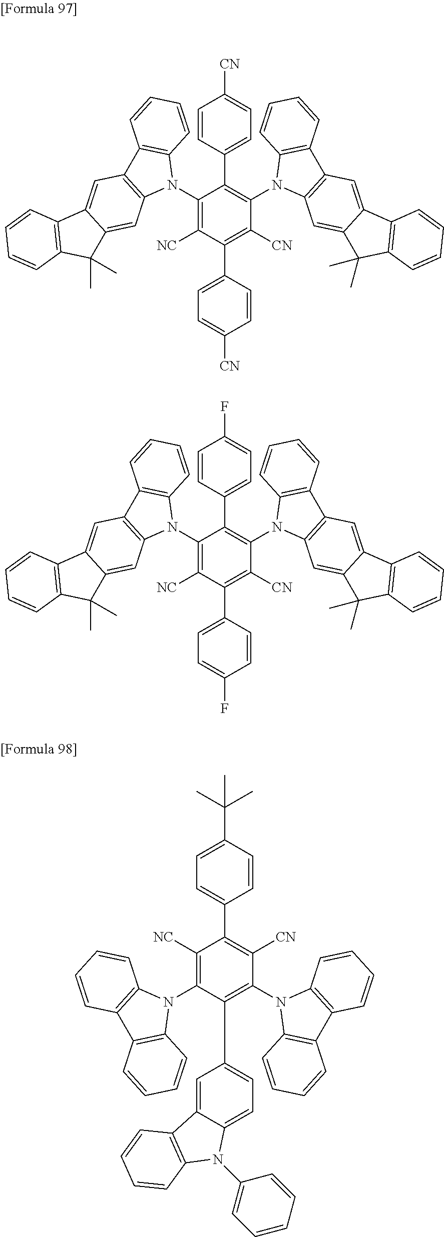

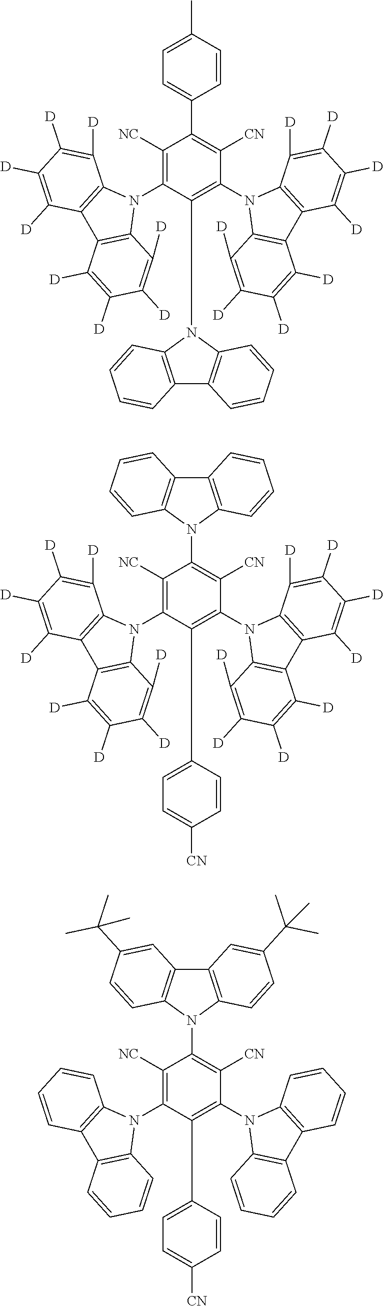

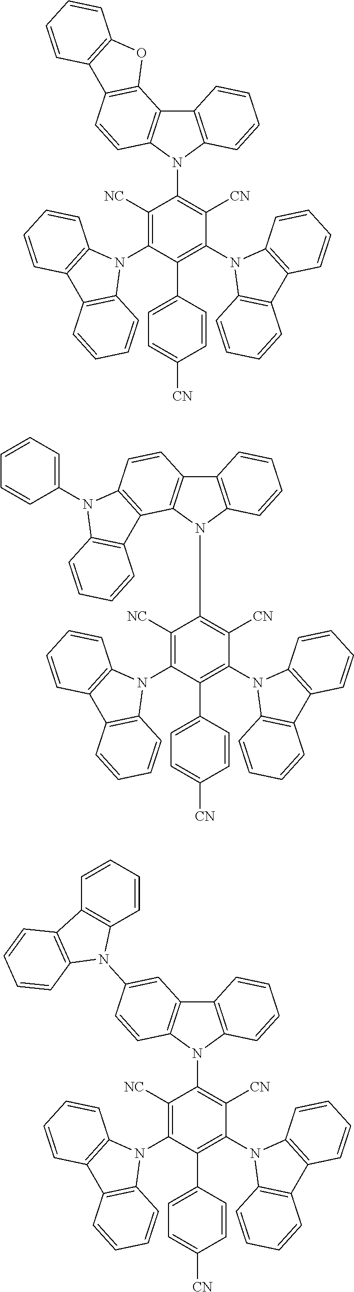 [SMILES: N#Cc1ccc(-c2c(-n3c4ccccc4c4ccccc43)c(C#N)c(-n3c4ccccc4c4c5oc6ccccc6c5ccc43)c(C#N)c2-n2c3ccccc3c3ccccc32)cc1 ; N#Cc1ccc(-c2c(-n3c4ccccc4c4ccccc43)c(C#N)c(-n3c4ccccc4c4ccc5c(c6ccccc6n5-c5ccccc5)c43)c(C#N)c2-n2c3ccccc3c3ccccc32)cc1 ; N#Cc1ccc(-c2c(-n3c4ccccc4c4ccccc43)c(C#N)c(-n3c4ccccc4c4cc(-n5c6ccccc6c6ccccc65)ccc43)c(C#N)c2-n2c3ccccc3c3ccccc32)cc1]

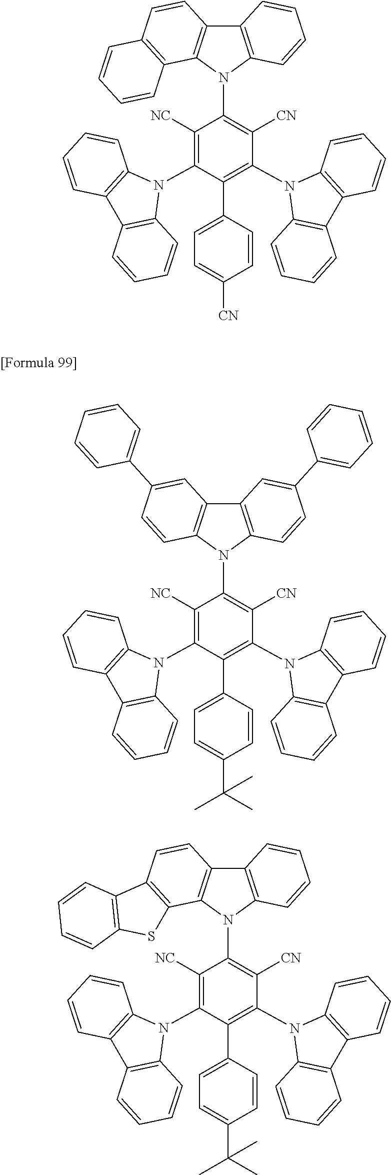

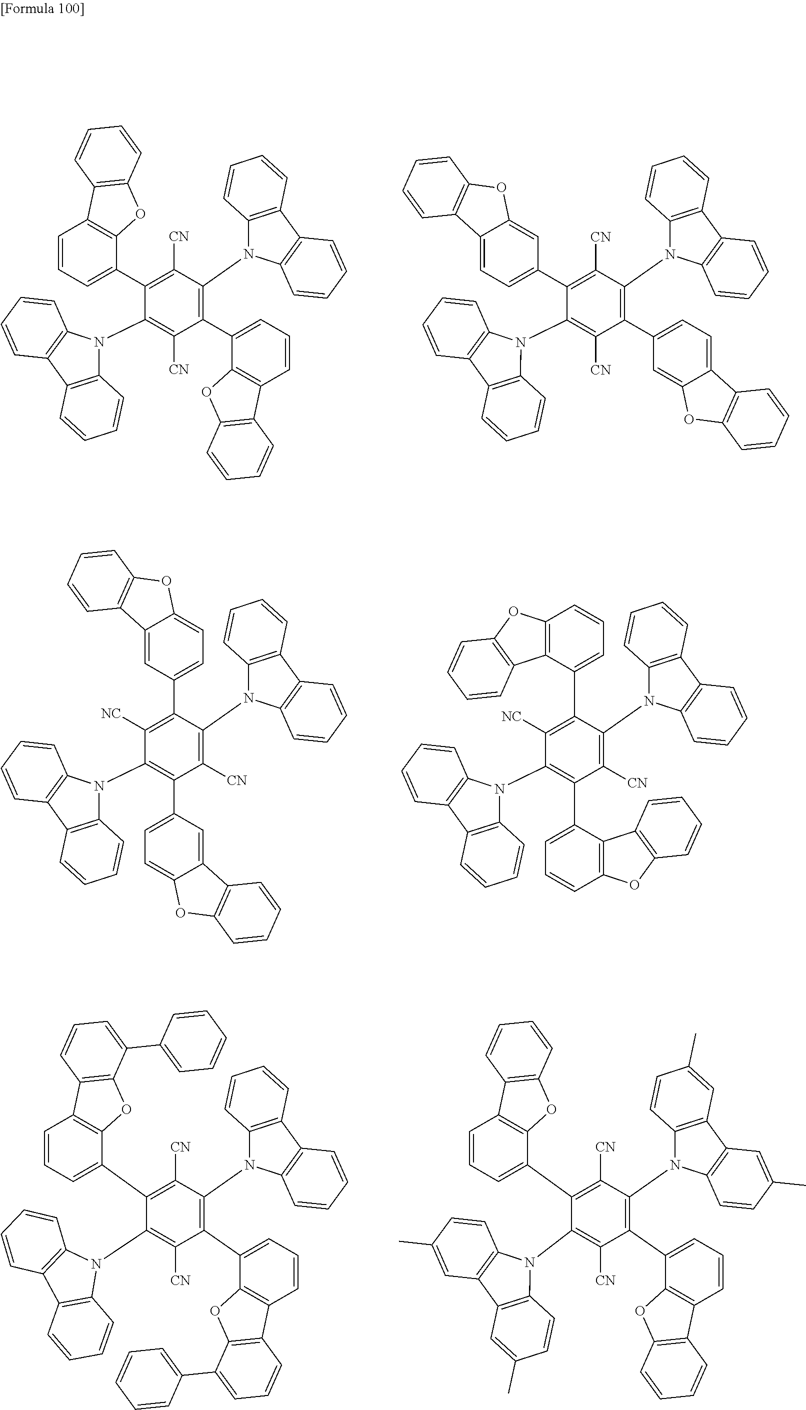

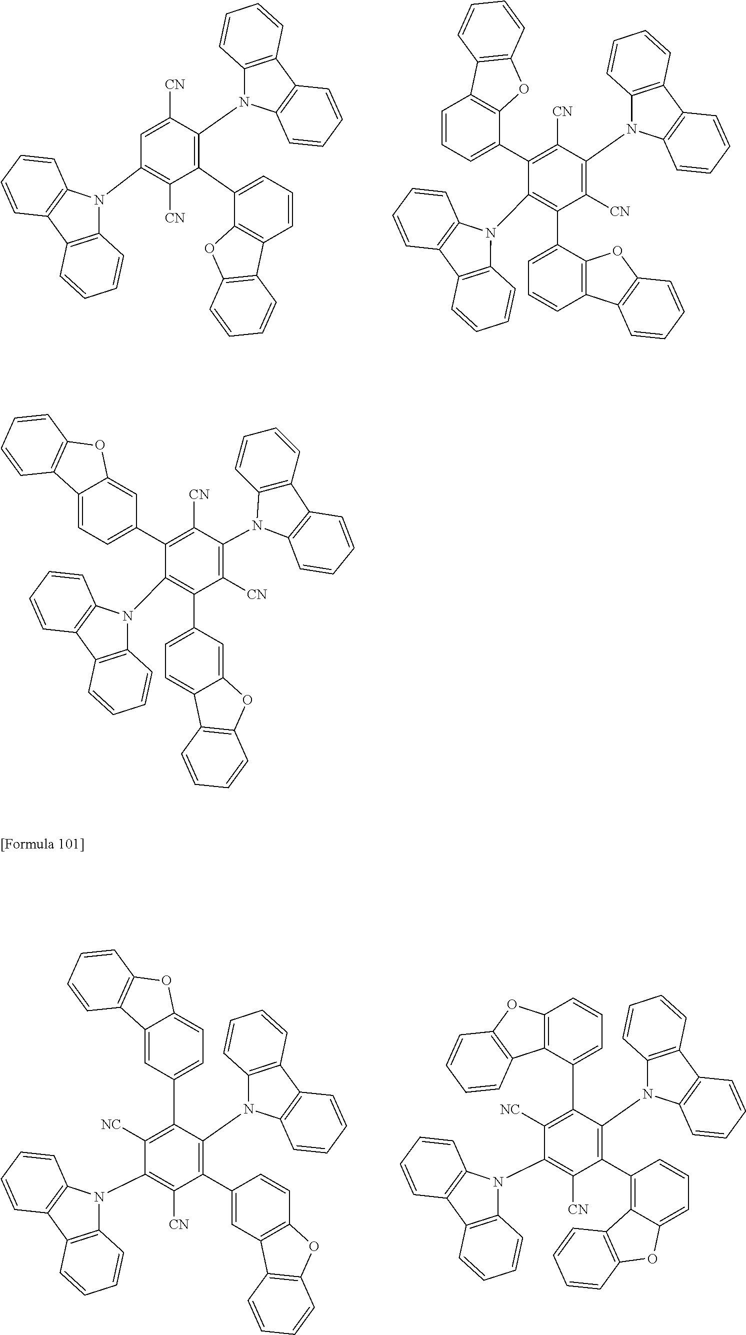

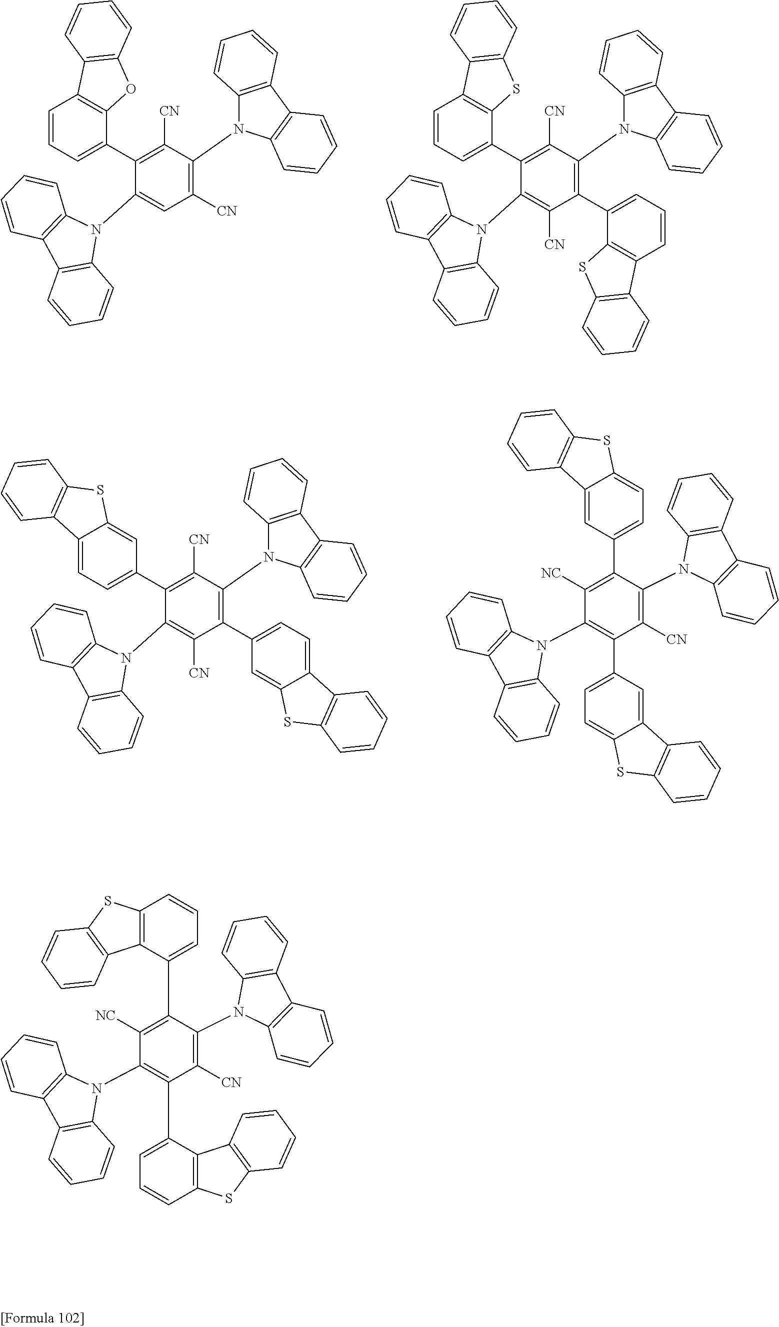

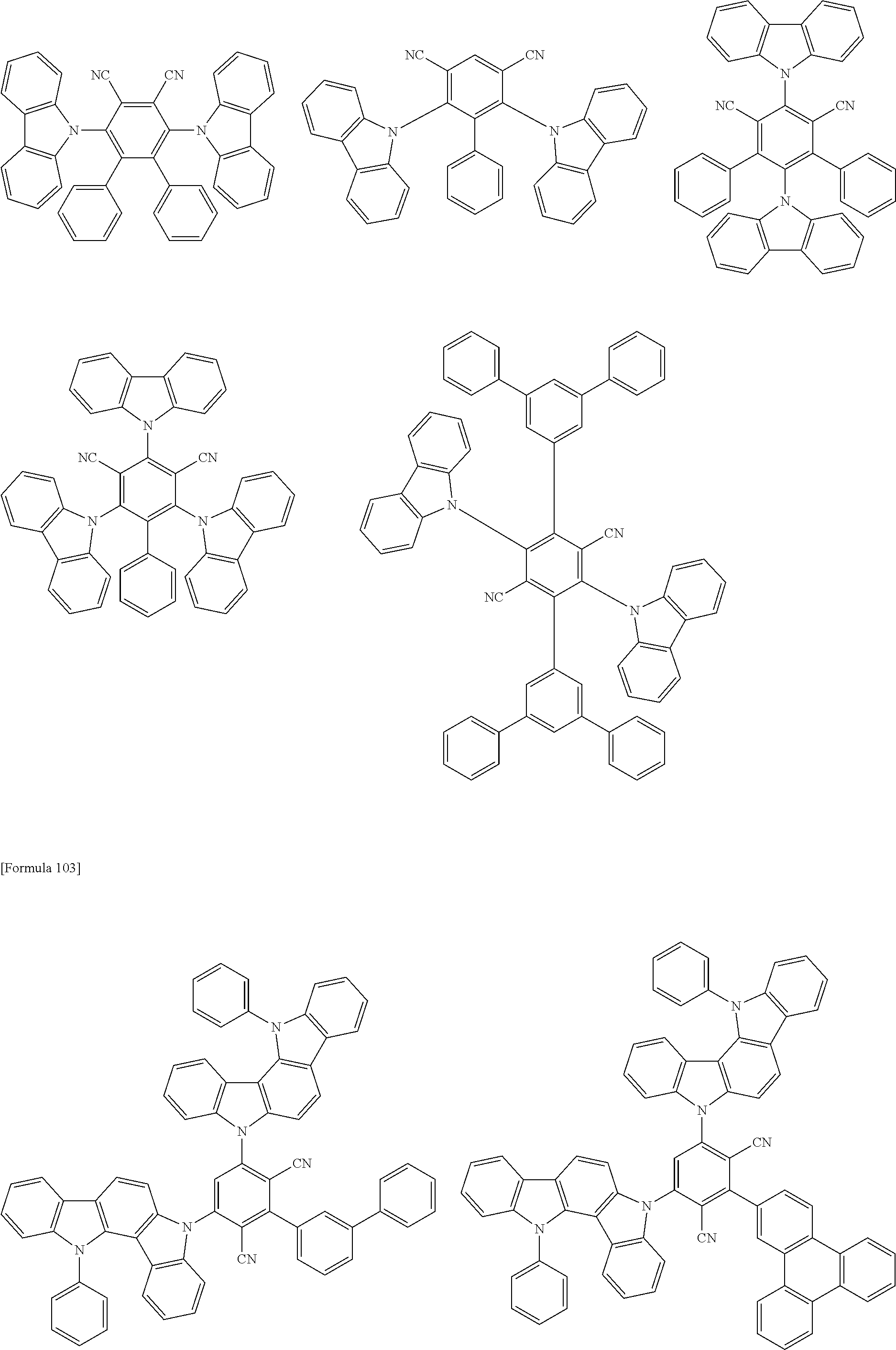

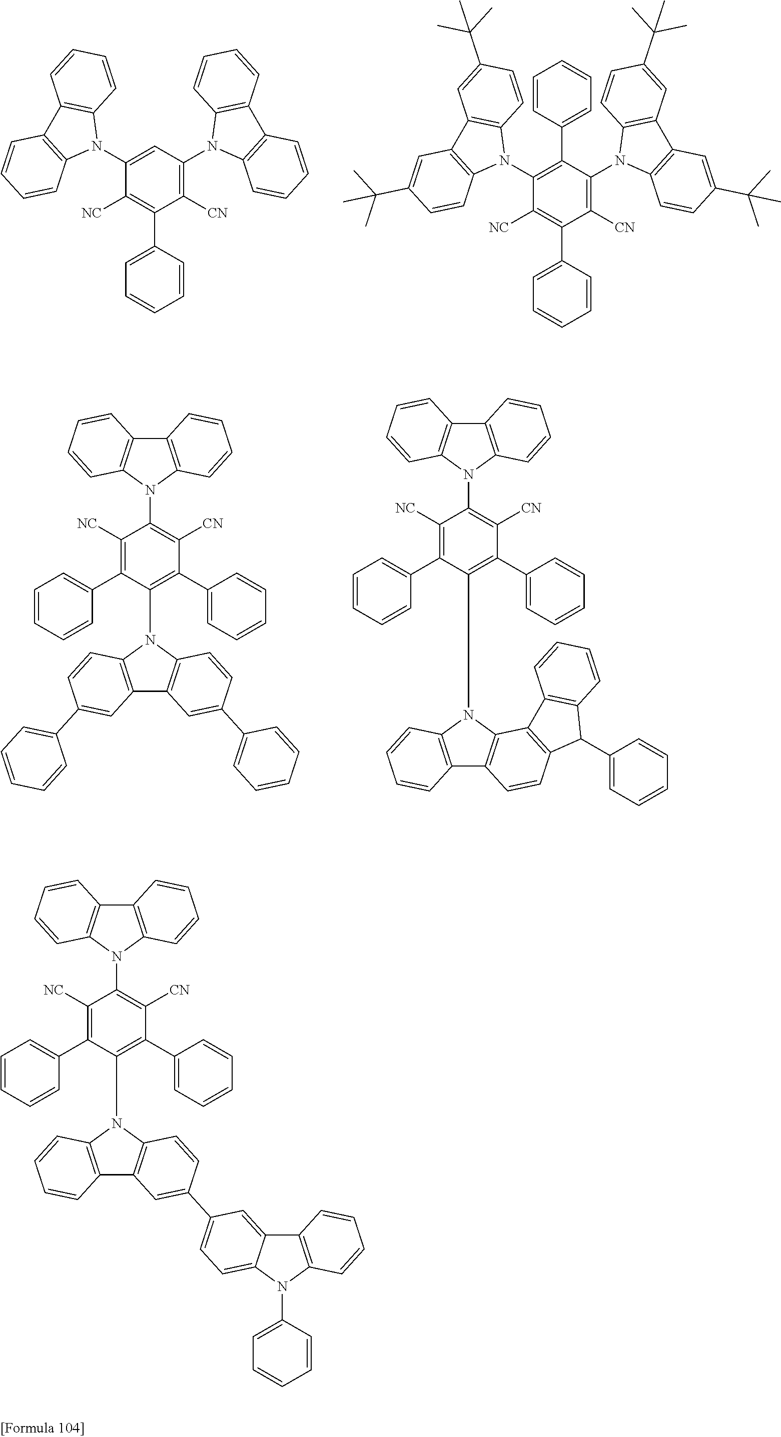

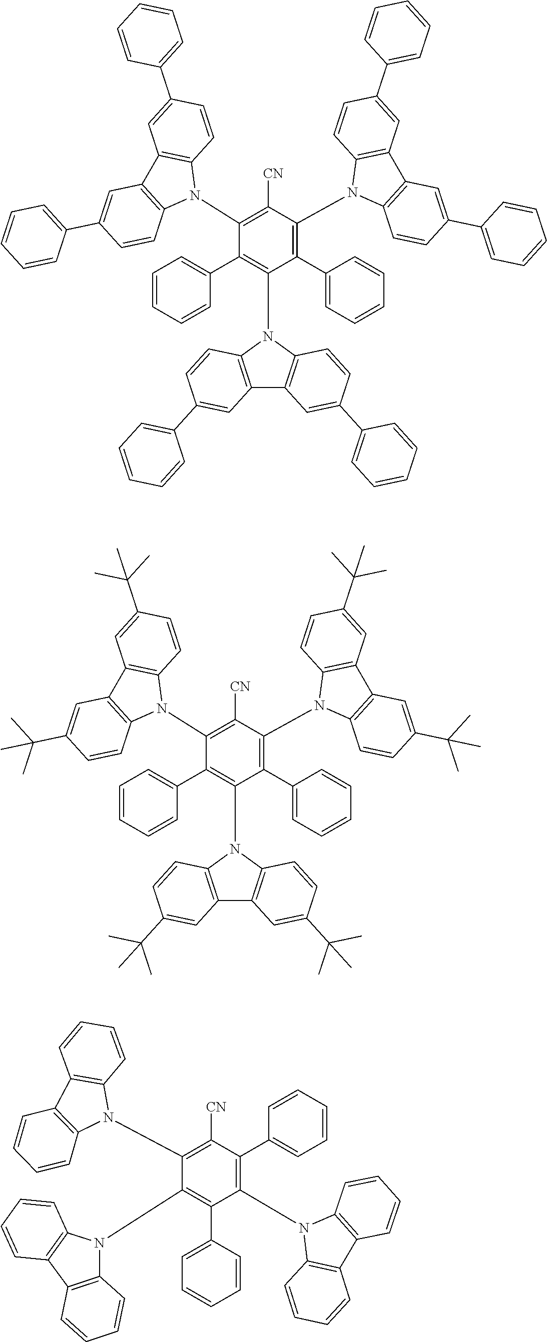 [SMILES: N#Cc1c(-n2c3ccc(-c4ccccc4)cc3c3cc(-c4ccccc4)ccc32)c(-c2ccccc2)c(-n2c3ccc(-c4ccccc4)cc3c3cc(-c4ccccc4)ccc32)c(-c2ccccc2)c1-n1c2ccc(-c3ccccc3)cc2c2cc(-c3ccccc3)ccc21 ; CC(C)(C)c1ccc2c(c1)c1cc(C(C)(C)C)ccc1n2-c1c(C#N)c(-n2c3ccc(C(C)(C)C)cc3c3cc(C(C)(C)C)ccc32)c(-c2ccccc2)c(-n2c3ccc(C(C)(C)C)cc3c3cc(C(C)(C)C)ccc32)c1-c1ccccc1 ; N#Cc1c(-c2ccccc2)c(-n2c3ccccc3c3ccccc32)c(-c2ccccc2)c(-n2c3ccccc3c3ccccc32)c1-n1c2ccccc2c2ccccc21]

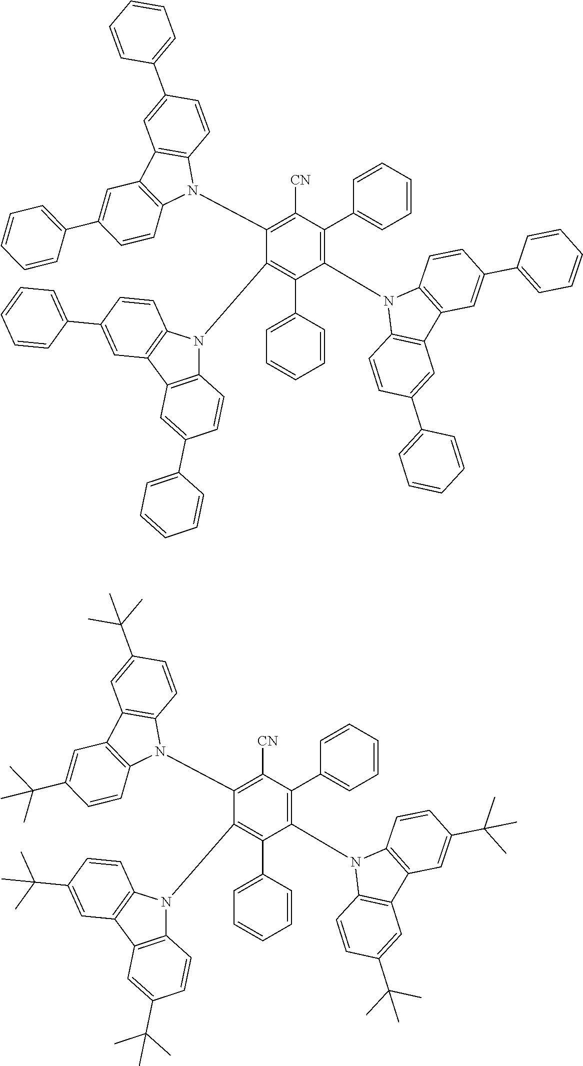 [SMILES: N#Cc1c(-c2ccccc2)c(-n2c3ccc(-c4ccccc4)cc3c3cc(-c4ccccc4)ccc32)c(-c2ccccc2)c(-n2c3ccc(-c4ccccc4)cc3c3cc(-c4ccccc4)ccc32)c1-n1c2ccc(-c3ccccc3)cc2c2cc(-c3ccccc3)ccc21 ; CC(C)(C)c1ccc2c(c1)c1cc(C(C)(C)C)ccc1n2-c1c(-c2ccccc2)c(C#N)c(-n2c3ccc(C(C)(C)C)cc3c3cc(C(C)(C)C)ccc32)c(-n2c3ccc(C(C)(C)C)cc3c3cc(C(C)(C)C)ccc32)c1-c1ccccc1]

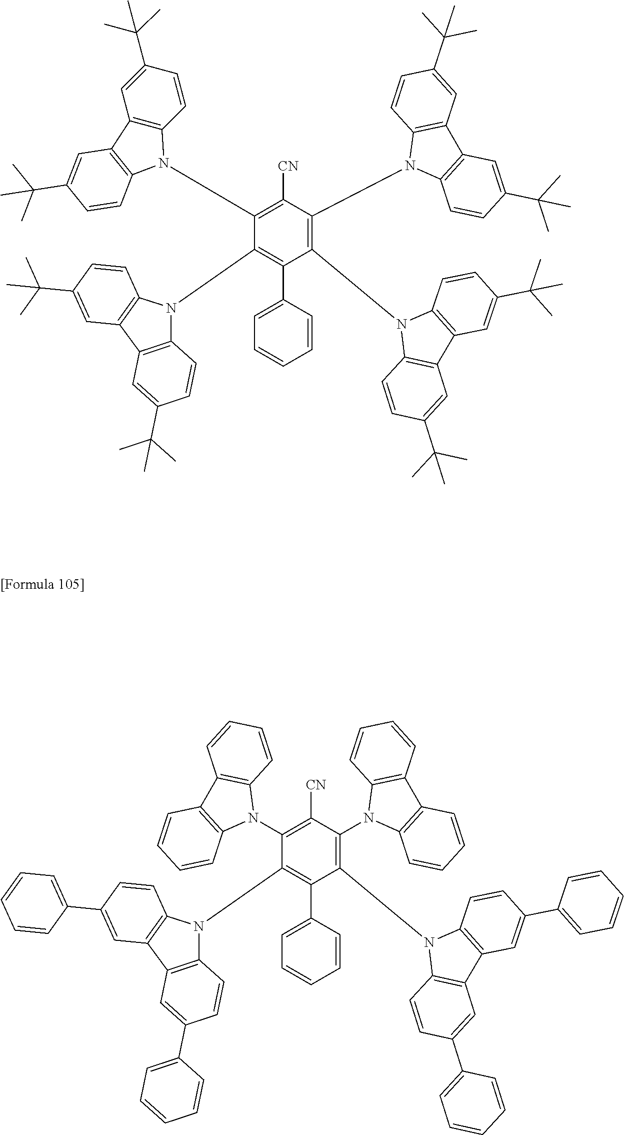 [SMILES: CC(C)(C)c1ccc2c(c1)c1cc(C(C)(C)C)ccc1n2-c1c(C#N)c(-n2c3ccc(C(C)(C)C)cc3c3cc(C(C)(C)C)ccc32)c(-n2c3ccc(C(C)(C)C)cc3c3cc(C(C)(C)C)ccc32)c(-c2ccccc2)c1-n1c2ccc(C(C)(C)C)cc2c2cc(C(C)(C)C)ccc21 ; N#Cc1c(-n2c3ccccc3c3ccccc32)c(-n2c3ccc(-c4ccccc4)cc3c3cc(-c4ccccc4)ccc32)c(-c2ccccc2)c(-n2c3ccc(-c4ccccc4)cc3c3cc(-c4ccccc4)ccc32)c1-n1c2ccccc2c2ccccc21]

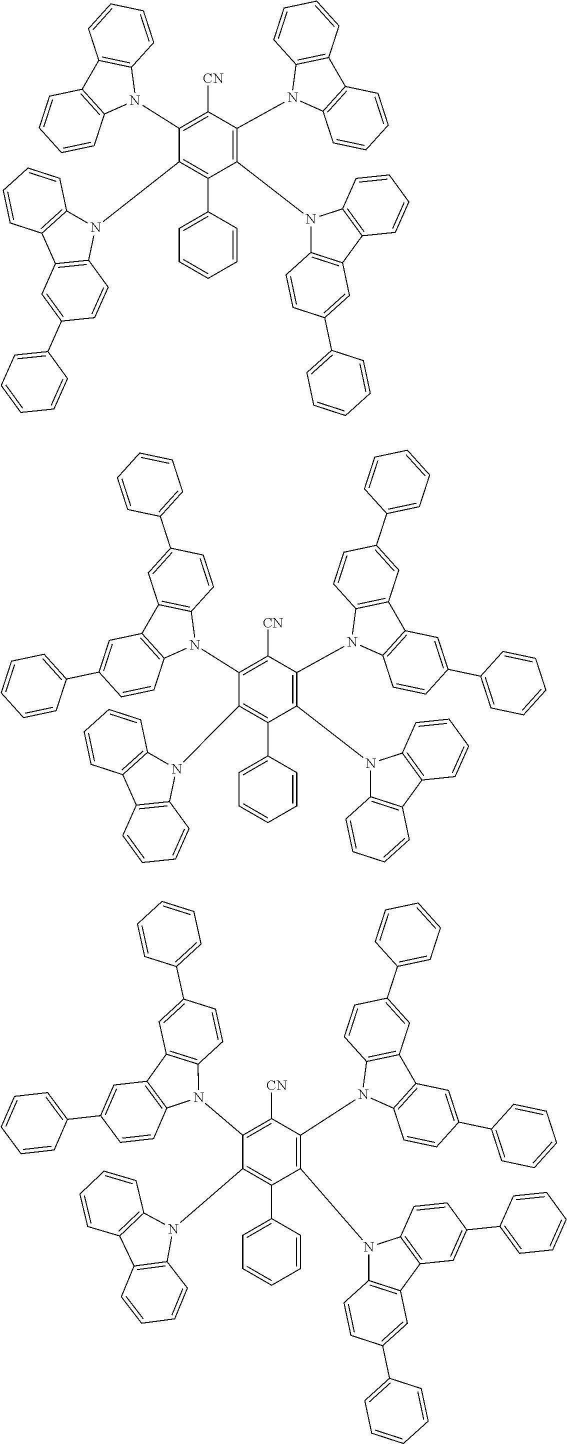

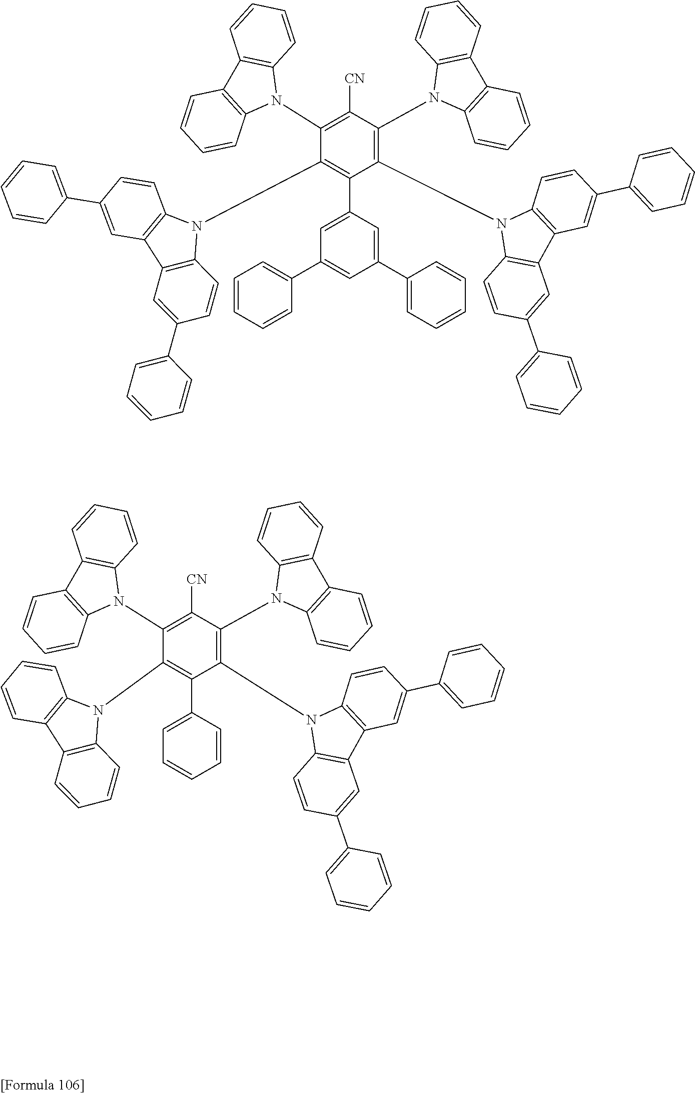 [SMILES: N#Cc1c(-n2c3ccccc3c3ccccc32)c(-n2c3ccc(-c4ccccc4)cc3c3cc(-c4ccccc4)ccc32)c(-c2cc(-c3ccccc3)cc(-c3ccccc3)c2)c(-n2c3ccc(-c4ccccc4)cc3c3cc(-c4ccccc4)ccc32)c1-n1c2ccccc2c2ccccc21 ; N#Cc1c(-n2c3ccccc3c3ccccc32)c(-n2c3ccccc3c3ccccc32)c(-c2ccccc2)c(-n2c3ccc(-c4ccccc4)cc3c3cc(-c4ccccc4)ccc32)c1-n1c2ccccc2c2ccccc21]

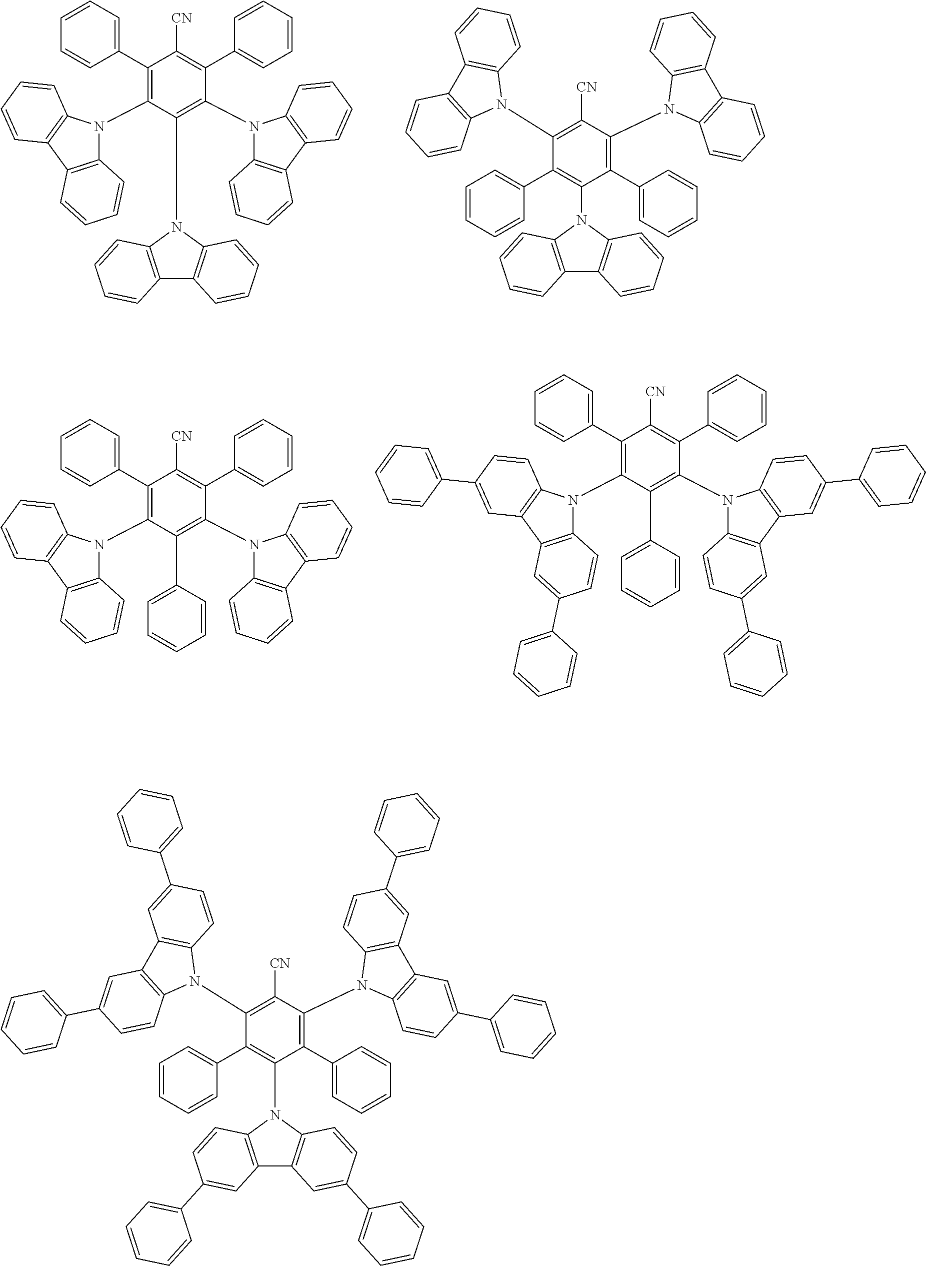

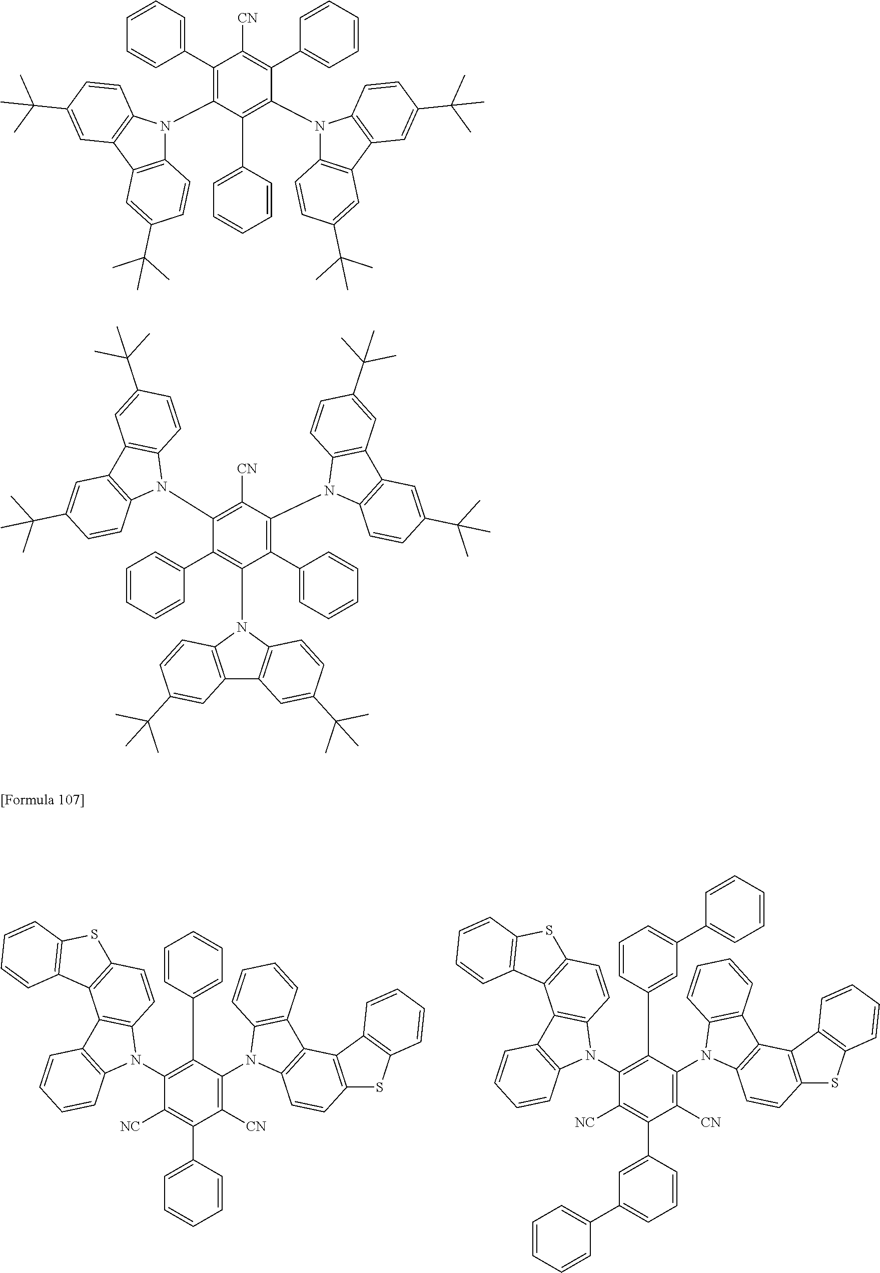

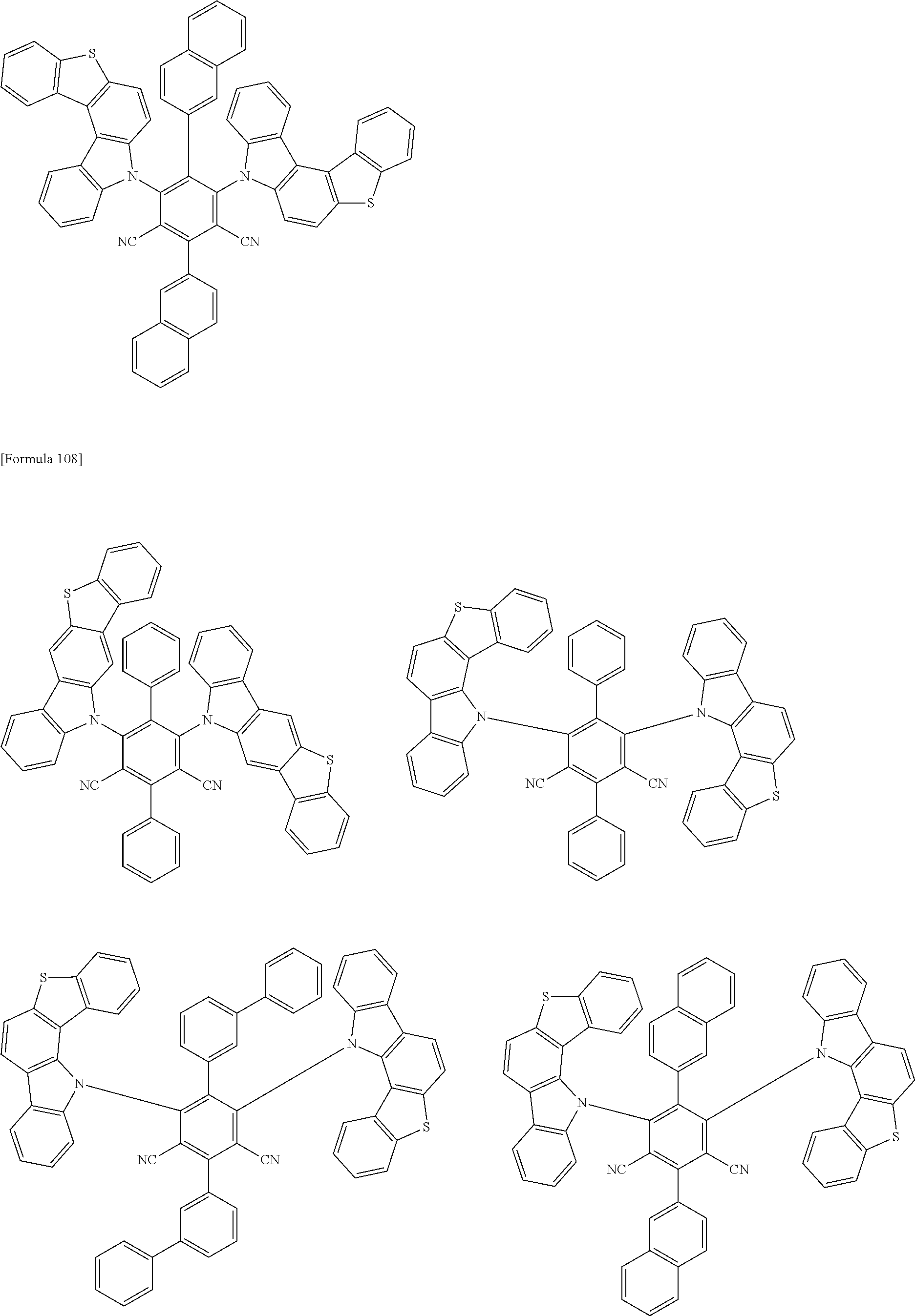

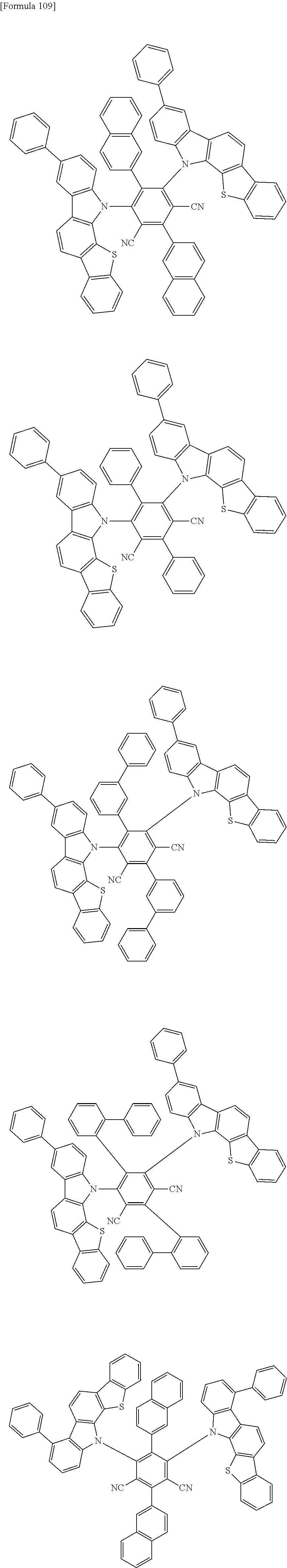

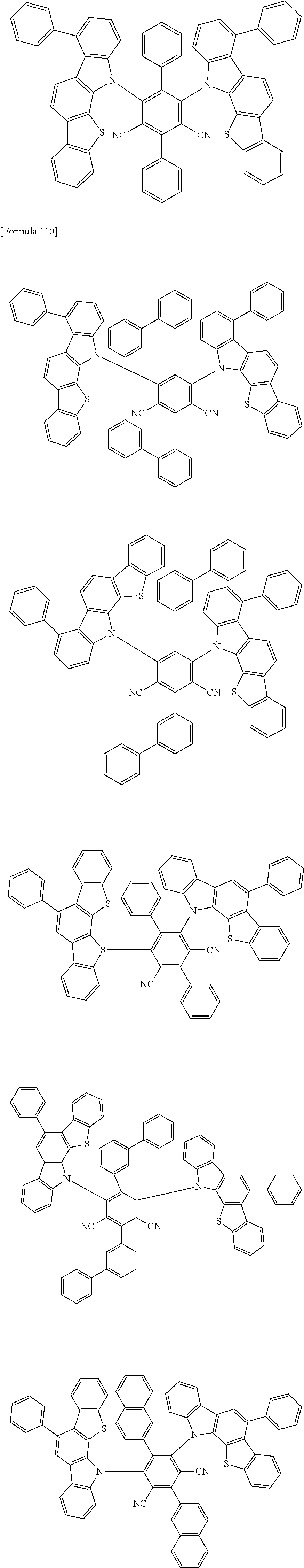

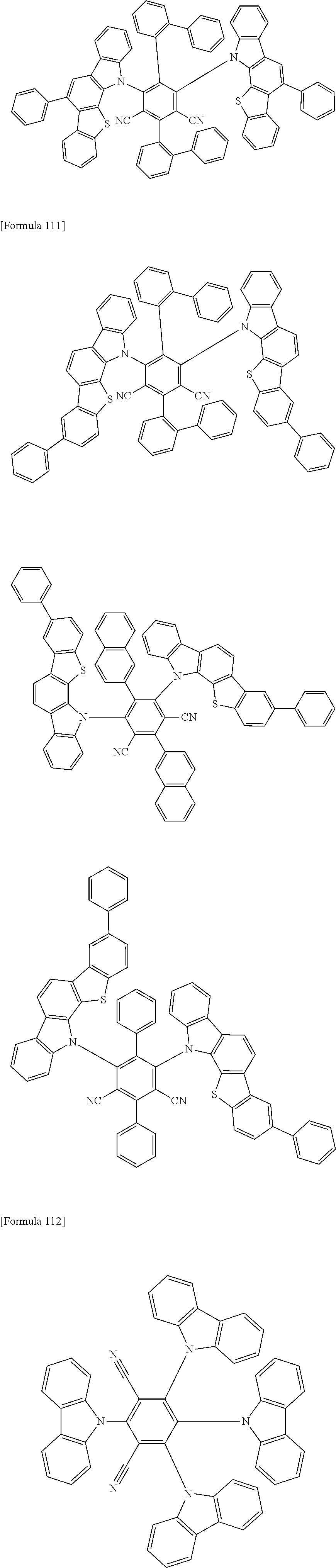

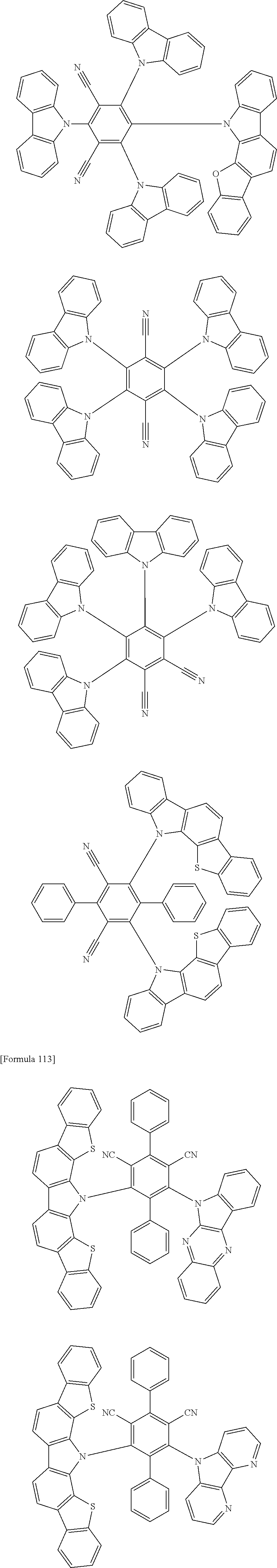

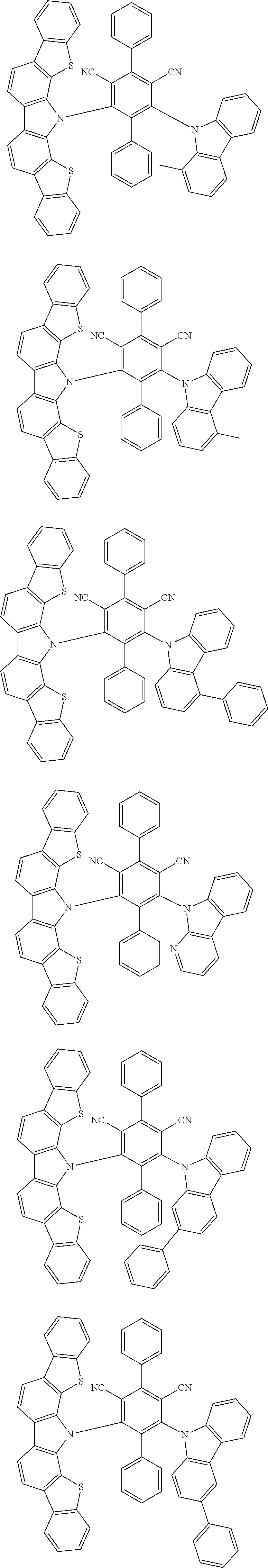

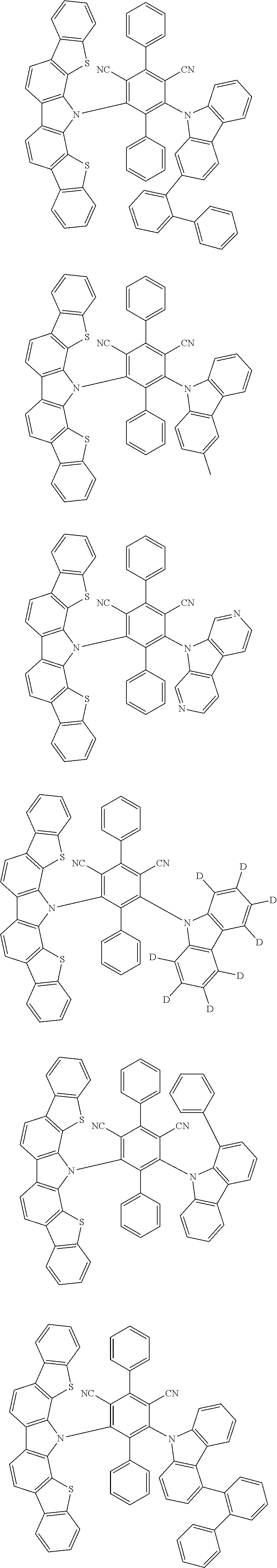

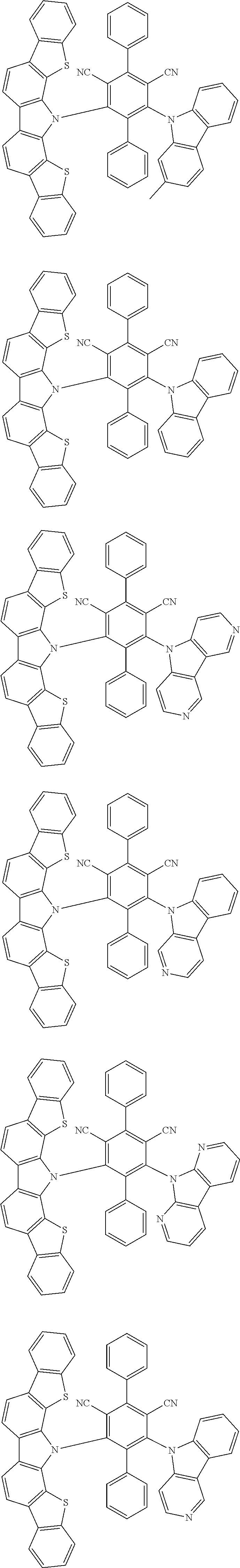

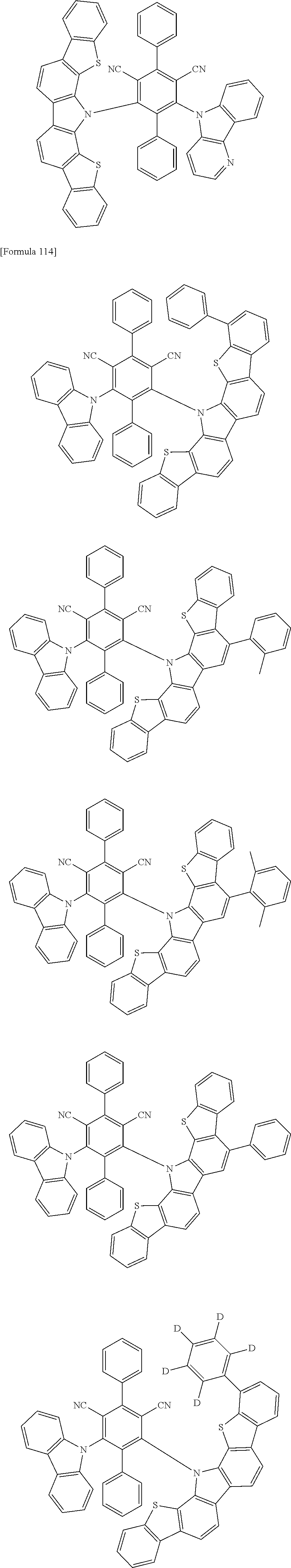

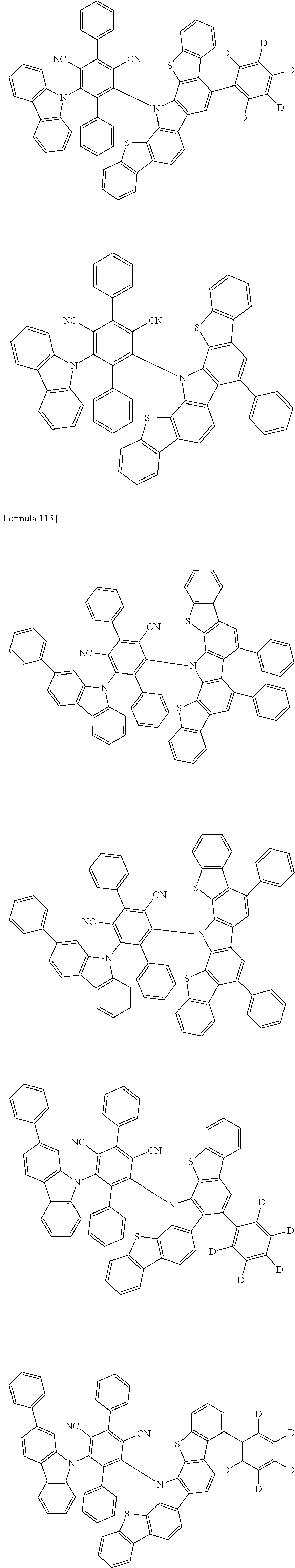

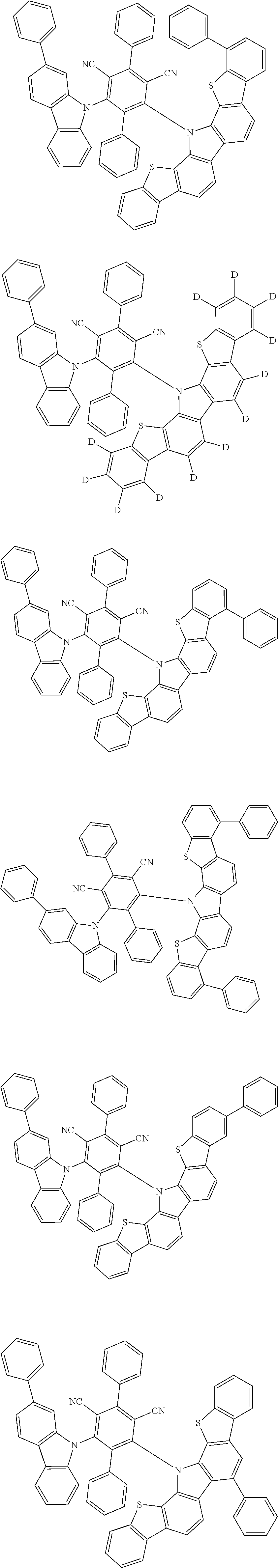

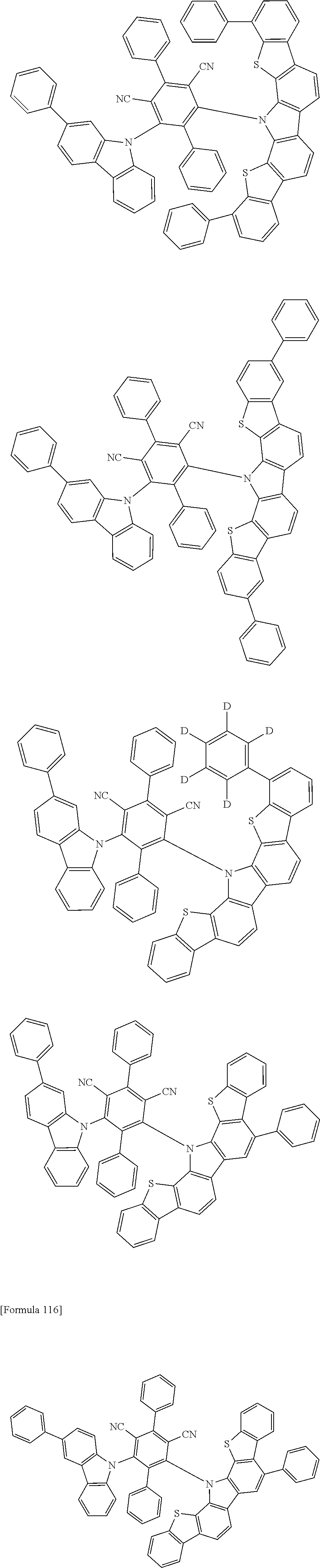

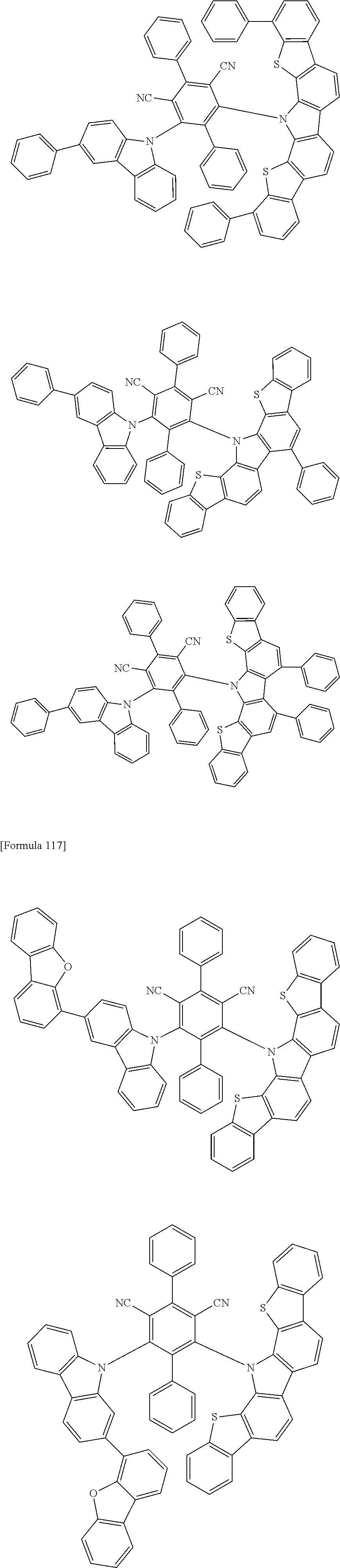

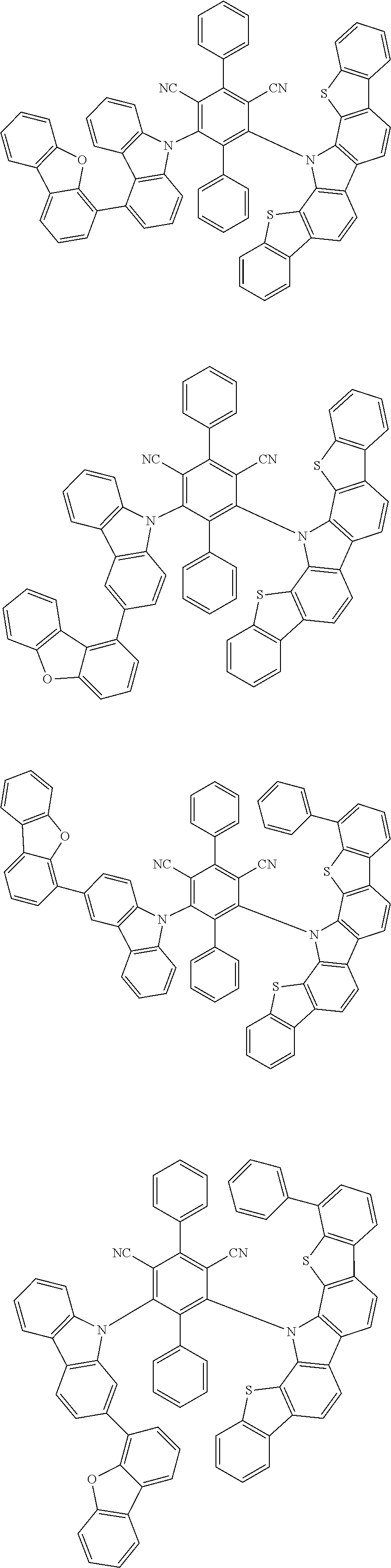

### Compound M1

In the exemplary embodiment, the compound M1 is not a phosphorescent metal complex. The compound M1 is preferably not a heavy-metal complex. The compound M1 is preferably not a metal complex.

The compound M1 is preferably a compound not exhibiting thermally activated delayed fluorescence.

A fluorescent material is usable as the compound M1. Specific examples of the fluorescent material include a bisarylaminonaphthalene derivative, aryl-substituted naphthalene derivative, bisarylaminoanthracene derivative, aryl-substituted anthracene derivative, bisarylaminopyrene derivative, aryl-substituted pyrene derivative, bisarylamino chrysene derivative, aryl-substituted chrysene derivative, bisarylaminofluoranthene derivative, aryl-substituted fluoranthene derivative, indenoperylene derivative, acenaphthofluoranthene derivative, compound including a boron atom, pyromethene boron complex compound, compound having a pyromethene skeleton, metal complex of the compound having a pyrromethene skeleton, diketopyrrolopyrrole derivative, perylene derivative, and naphthacene derivative.

In the exemplary embodiment, the fluorescent compound M1 is preferably a compound represented by a formula (1) below.

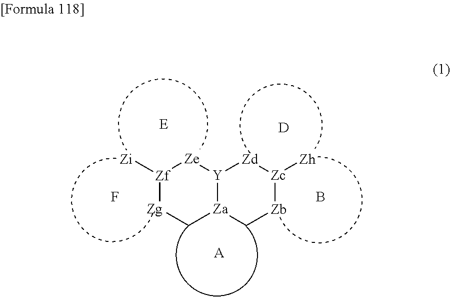

In the formula (1)
a ring A, a ring B, a ring D, a ring E, and a ring F are each independently a cyclic structure selected from the group consisting of a substituted or unsubstituted aryl ring having 6 to 30 ring carbon atoms, and a substituted or unsubstituted heterocycle having 5 to 30 ring atoms;
one of the ring B and the ring D is present or both of the ring B and the ring D are present;
when both of the ring B and the ring D are present, the ring B and the ring D share a bond connecting Zc to Zh;
one of the ring E and the ring F is present or both of the ring E and the ring F are present;
when both of the ring E and the ring F are present, the ring E and the ring F share a bond connecting Zf to Zi;
Za is a nitrogen atom or a carbon atom;
Zb is a nitrogen atom or a carbon atom when the ring B is present;
Zb is an oxygen atom, a sulfur atom, NRb, C(Rb₁)(Rb₂), or Si(Rb₃)(Rb₄) when the ring B is not present;
Zc is a nitrogen atom or a carbon atom;
Zd is a nitrogen atom or a carbon atom when the ring D is present;
Zd is an oxygen atom, a sulfur atom, or NRd when the ring D is not present;
Ze is a nitrogen atom or a carbon atom when the ring E is present;
Ze is an oxygen atom, a sulfur atom, or NRe when the ring E is not present;
Zf is a nitrogen atom or a carbon atom;
Zg is a nitrogen atom or a carbon atom when the ring F is present;
Zg is an oxygen atom, a sulfur atom, NRg, C(Rg₁)(Rg₂), or Si(Rg₃)(Rg₄) when the ring F is not present;
Zh is a nitrogen atom or a carbon atom;
Zi is a nitrogen atom or a carbon atom;
Y is a boron atom, a phosphorus atom, SiRh, P═O, or P═S;
Rb, Rb₁, Rb₂, Rb₃, Rb₄, Rd, Re, Rg, Rg₁, Rg₂, Rg₃, Rg₄, and Rh are each independently a hydrogen atom or a substituent;
Rb, Rb₁, Rb₂, Rb₃, Rb₄, Rd, Re, Rg, Rg₁, Rg₂, Rg₃, Rg₄, and Rh as a substituent are each independently a substituted or unsubstituted aryl group having 6 to 30 ring carbon atoms; a substituted or unsubstituted heterocyclic group having 5 to 30 ring atoms, a substituted or unsubstituted alkyl group having 1 to 30 carbon atoms, a substituted or unsubstituted cycloakyl group having 3 to 30 ring carbon atoms, a group represented by —Si(R₉₁₁)(R₉₁₂)(R₉₁₃), a group represented by —O—(R₉₁₄), a group represented by —S—(R₉₁₅), or a group represented by —N(R₉₁₅)(R₉₁₇); and
a bond between Y and Za, a bond between Y and Zd, and a bond between Y and Ze are each a single bond.

A bond between Y and Za, a bond between Y and Zd, and a bond between Y and Ze are each a single bond and the single bond is not a coordinate bond but a covalent bond.

Herein, a heterocycle is exemplified by a cyclic structure (heterocycle) obtained by removing a bond from a “heterocyclic group” exemplified by the above “Substituent Mentioned Herein.” The heterocycle may be substituted or unsubstituted.

Herein, an aryl ring is exemplified by a cyclic structure (aryl ring) obtained by removing a bond from an “aryl group” exemplified by the above “Substituent Mentioned Herein.” The aryl ring may be substituted or unsubstituted.

The compound M1 of the exemplary embodiment is also preferably a compound represented by a formula (11) below.

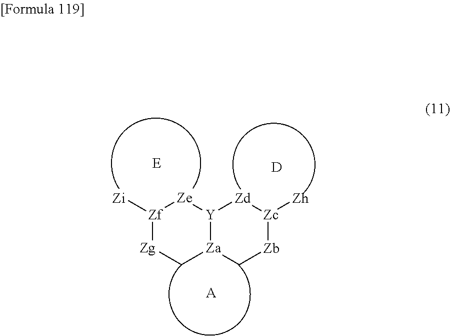

In the formula (11):
a ring A, a ring D, and a ring E are each independently a cyclic structure selected from the group consisting of a substituted or unsubstituted aryl ring having 6 to 30 ring carbon atoms, and a substituted or unsubstituted heterocycle having 5 to 30 ring atoms;
Za is a nitrogen atom or a carbon atom;
Zb is an oxygen atom, a sulfur atom, NRb, C(Rb₁)(Rb₂), or Si(Rb₃)(Rb₄);
Zc is a nitrogen atom or a carbon atom;
Zd is a nitrogen atom or a carbon atom;
Ze is a nitrogen atom or a carbon atom;
Zf is a nitrogen atom or a carbon atom;
Zg is an oxygen atom, a sulfur atom, NRg, C(Rg₁)(Rg₂), or Si(Rg₃)(Rg₄);
Zh is a nitrogen atom or a carbon atom;
Zi is a nitrogen atom or a carbon atom;
Y is a boron atom, a phosphorus atom, SiRh, P═O, or P═S; and
Rb, Rb₁, Rb₂, Rb₃, Rb₄, Rg, Rg₁, Rg₂, Rg₃, Rg₄, and Rh each independently represent the same as Rb, Rb₁, Rb₂, Rb₃, Rb₄, Rg, Rg₁, Rg₂, Rg₃, Rg₄, and Rh in the formula (1).

The compound M1 of the exemplary embodiment is also preferably a compound represented by a formula (16) below.

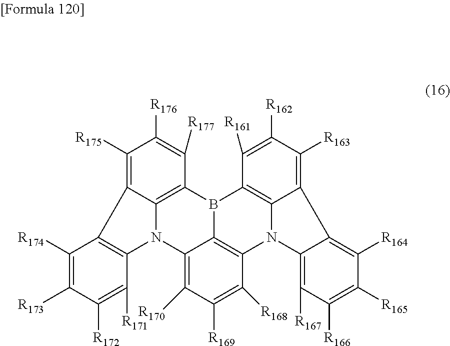

In the formula (16):
at least one combination of adjacent two or more of R₁₆₁ to R₁₇₇ are mutually bonded to form a substituted or unsubstituted monocyclic ring, mutually bonded to form a substituted or unsubstituted fused ring, or not mutually bonded;
R₁₆₁ to R₁₇₇ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aralkyl group having 7 to 50 carbon atoms, a group represented by —Si(R₉₆₁)(R₉₆₂)(R₉₆₃), a group represented by —O— (R₉₆₄), a group represented by —S—(R₉₆₅), a group represented by —N(R₉₆₆)(R₉₆₇), a group represented by —C(═O)R₉₆₈, a group represented by —COORS, a halogen atom, a cyano group, a nitro group, a substituted or unsubstituted aryl group having 6 to 50 ring carbon atoms, or a substituted or unsubstituted heterocyclic group having 5 to 50 ring atoms;
R₉₆₁ to R₉₆₉ are each independently a hydrogen atom; a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms;
when a plurality of R₉₆₁ are present, the plurality of R₉₆₁ are mutually the same or different;
when a plurality of R₉₆₂ are present, the plurality of R₉₆₂ are mutually the same or different;
when a plurality of R₉₆₃ are present, the plurality of R₉₆₃ are mutually the same or different;
when a plurality of R₉₆₄ are present, the plurality of R₉₆₄ are mutually the same or different;
when a plurality of R₉₆₅ are present, the plurality of R₉₆₅ are mutually the same or different;
when a plurality of R₉₆₆ are present, the plurality of R₉₆₆ are mutually the same or different;
when a plurality of R₉₆₇ are present, the plurality of R₉₆₇ are mutually the same or different;
when a plurality of R₉₆₈ are present, the plurality of R₉₆₈ are mutually the same or different; and
when a plurality of R₉₆₉ are present, the plurality of R₉₆₉ are mutually the same or different.

In the exemplary embodiment, the fluorescent compound M1 is also preferably a compound represented by a formula (20) below.

### Compound Represented by Formula (D10)

The compound M1 of the exemplary embodiment is also preferably a compound represented by a formula (D10) below. The compound represented by the formula (1) is also preferably a compound represented by the formula (D10).

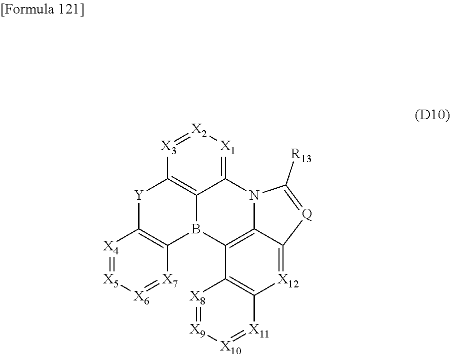

In the formula (D10):
X₁ is CR₁ or a nitrogen atom;
X₂ is CR₂ or a nitrogen atom;
X₃ is CR₃ or a nitrogen atom;
X₄ is CR₄ or a nitrogen atom;
X₅ is CR₅ or a nitrogen atom;
X₆ is CR₆ or a nitrogen atom;
X₇ is CR₇, a nitrogen atom, or a carbon atom bonded to X₈ with a single bond;
X₈ is CR₈, a nitrogen atom, or a carbon atom bonded to X₇ with a single bond;
X₉ is CR₉ or a nitrogen atom;
X₁₀ is CR₁₀ or a nitrogen atom;
X₁₁ is CR₁₁ or a nitrogen atom;
X₁₂ is CR₁₂ or a nitrogen atom;
Q is CR_{Q} or a nitrogen atom;
Y is NR_{Y1}, an oxygen atom, a sulfur atom, C(R_{Y2})(R_{Y3}), or Si(R_{Y4})(R_{Y5});
at least one combination of adjacent two or more of R₁ to R₅ and R₉ to R₁₁ are mutually bonded to form a substituted or unsubstituted monocyclic ring, mutually bonded to form a substituted or unsubstituted fused ring, or not mutually bonded;
at least one combination of adjacent two or more of R₃. R₄, and R_{Y1} are mutually bonded to form a substituted or unsubstituted monocyclic ring, mutually bonded to form a substituted or unsubstituted fused ring, or not mutually bonded;
at least one hydrogen atom in a monocyclic ring or a fused ring formed by mutually bonding at least one combination of adjacent two or more of R₃, R₄ and R_{Y1} is unsubstituted or substituted by at least one substituent selected from the group consisting of an alkyl group having 1 to 50 carbon atoms, an aryl group having 6 to 50 ring carbon atoms, a heterocyclic group having 5 to 50 ring atoms, a group represented by —O—(R₉₂₀), and a group represented by —N(R₉₂₁)(R₉₂₂);
at least one hydrogen atom of the substituent is unsubstituted or substituted by an aryl group having 6 to 50 ring carbon atoms or an alkyl group having 1 to 50 carbon atoms;
R₁ to R₁₁ forming neither the substituted or unsubstituted monocyclic ring nor the substituted or unsubstituted fused ring, and R₁₂ to R₁₃ and R_{Q} are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a substituted or unsubstituted aralkyl group having 7 to 50 carbon atoms, a group represented by —C(═O)R₉₁₈, a group represented by —COOR₉₁₉, a halogen atom, a cyano group, a nitro group, a substituted or unsubstituted aryl group having 6 to 50 ring carbon atoms, or a substituted or unsubstituted heterocyclic group having 5 to 50 ring atoms;
R_{Y1} forming neither the substituted or unsubstituted monocyclic ring nor the substituted or unsubstituted fused ring is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
a combination of R_{Y1} and R_{Y3} are mutually bonded to form a substituted or unsubstituted monocyclic ring, mutually bonded to form a substituted or unsubstituted fused ring, or not mutually bonded;
R_{Y2} and R_{Y3} forming neither the substituted or unsubstituted monocyclic ring nor the substituted or unsubstituted fused ring, R_{Y4}, and R_{Y5} are each independently a hydrogen atom, a halogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms;
R₉₁₁ to R₉₂₂ are each independently a hydrogen atom, a substituted or unsubstituted alkyl group having 9 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₁₁ are present, the plurality of R₉₁₁ are mutually the same or different;
when a plurality of R₉₁₂ are present, the plurality of R₉₁₂ are mutually the same or different;
when a plurality of R₉₁₃ are present, the plurality of R₉₁₃ are mutually the same or different;
when a plurality of R₉₁₄ are present, the plurality of R₉₁₄ are mutually the same or different,
when a plurality of R₉₁₅ are present, the plurality of R₉₁₅ are mutually the same or different;
when a plurality of R₉₁₆ are present, the plurality of R₉₁₆ are mutually the same or different;
when a plurality of R₉₁₇ are present, the plurality of R₉₁₇ are mutually the same or different;
when a plurality of R₉₁₈ are present, the plurality of R₉₁₈ are mutually the same or different;
when a plurality of R₉₁₉ are present, the plurality of R₉₁₉ are mutually the same or different;
when a plurality of R₉₂₀ are present, the plurality of R₉₂₀ are mutually the same or different;
when a plurality of R₉₂₁ are present, the plurality of R₉₂₁ are mutually the same or different; and
when a plurality of R₉₂₂ are present, the plurality of R₉₂₂ are mutually the same or different.

The compound represented by the formula (D10) is also preferably a compound represented by a formula (D12) below.

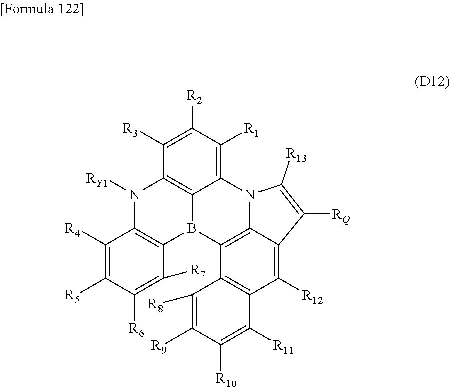

In the formula (D12), R₁ to R₁₃, R_{Y1}, and R_{Q} are each independently defined as in the formula (D10).

The compound represented by the formula (D10) is also preferably represented by a formula (013) below.

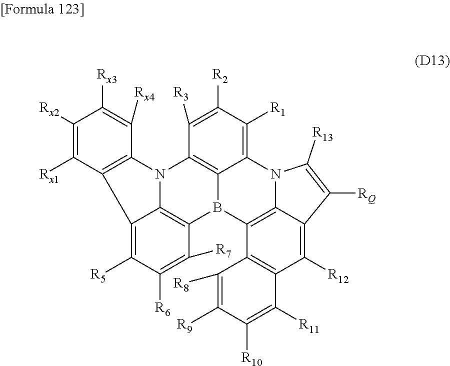

In the formula (D13):
R₁ to R₃, R₅ to R₁₃ and R_{Q} are each independently defined as in the formula (D10);
at least one combination of adjacent two or more of Rₓ₁ to Rₓ₄ are mutually bonded to form a substituted or unsubstituted monocyclic ring, mutually bonded to form a substituted or unsubstituted fused ring, or not mutually bonded;
R_{X1} to Rₓ₄ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aralkyl group having 7 to 50 carbon atoms, a group represented by —Si(R₉₃₁)(R₉₃₂)(R₉₃₃), a group represented by —O—(R₉₃₄), a group represented by —S—(R₉₃₅), a group represented by —N(R₉₃₆)(R₉₃₇), a substituted or unsubstituted aralkyl group having 7 to 50 carbon atoms, a group represented by —C(═O)R₉₃₈, a group represented by —COOR₉₃₉, a halogen atom, a cyano group, a nitro group, a substituted or unsubstituted aryl group having 6 to 50 ring carbon atoms, or a substituted or unsubstituted heterocyclic group having 5 to 50 ring atoms;
R₉₃₁ to R₉₃₉ are each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms;
when a plurality of R₉₃₁ are present, the plurality of R₉₃₁ are mutually the same or different,
when a plurality of R₉₃₂ are present, the plurality of R₉₃₂ are mutually the same or different;
when a plurality of R₉₃₃ are present, the plurality of R₉₃₃ are mutually the same or different;
when a plurality of R₉₃₄ are present, the plurality of R₉₃₄ are mutually the same or different;
when a plurality of R₉₃₅ are present, the plurality of R₉₃₅ are mutually the same or different;
when a plurality of R₉₃₆ are present, the plurality of R₉₃₆ are mutually the same or different;
when a plurality of R₉₃₇ are present, the plurality of R₉₃₇ are mutually the same or different;
when a plurality of R₉₃₈ are present, the plurality of R₉₃₈ are mutually the same or different; and
when a plurality of R₉₃₉ are present, the plurality of R₉₃₉ are mutually the same or different.

In the formula (D13), for instance, a combination of R₅ and R₆ are mutually bonded to form a substituted or unsubstituted monocyclic ring, mutually bonded to form a substituted or unsubstituted fused ring, or not mutually bonded.

In the compounds represented by the formulae (D10) and (D13), also preferably, R₁ to R₃, R₅ to R₁₃, R_{Q}, and Rₓ₁ to Rₓ₄ are each independently a hydrogen atom, a substituted or unsubstituted alkyl group having 1 to 50 carbon atoms, a substituted or unsubstituted aryl group having 1 to 50 ring carbon atoms, or a substituted or unsubstituted heteroaryl group having 5 to 30 ring atoms.

In the compounds represented by the formulae (D10) and (D13), also preferably, R₁ to R₃, R₅ to R₁₃, R_{Q}, and Rₓ₁ to Rₓ₄ are each independently a hydrogen atom, a substituted or unsubstituted alkyl group having 1 to 25 carbon atoms, a substituted or unsubstituted aryl group having 6 to 25 ring carbon atoms, or a substituted or unsubstituted heteroaryl group having 5 to 25 ring atoms.

The compound represented by the formula (D10) is also preferably represented by a formula (D14) below.

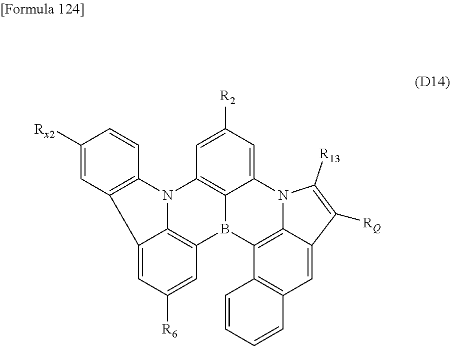

R₂, R₅, R₁₃, R_{Q}, and Rₓ₂ in the formula (D14) are each independently a hydrogen atom, a substituted or unsubstituted alkyl group having 1 to 10 carbon atoms, a substituted or unsubstituted aryl group having 6 to 12 ring carbon atoms, or a substituted or unsubstituted heteroaryl group having 5 to 18 ring carbon atoms.

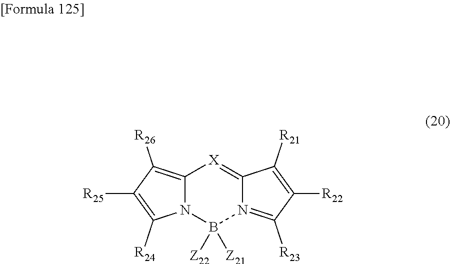

In the formula (20):
X is a nitrogen atom, or a carbon atom bonded to Y;
Y is a hydrogen atom or a substituent;
R₂₁ to R₂₆ are each independently a hydrogen atom or a substituent, or at least one combination of a combination of R₂₁ and R₂₂, a combination of R₂₂ and R₂₃, a combination of R₂₄ and R₂₅, and a combination of R₂₅ and R₂₆ are mutually bonded to forma ring;
Y and R₂₁ to R₂₆ as the substituents are each independently selected from the group consisting of a substituted or unsubstituted alkyl group having 1 to 30 carbon atoms, a substituted or unsubstituted alkyl halide group having 1 to 30 carbon atoms, a substituted or unsubstituted cycloalkyl group having 3 to 30 ring carbon atoms, a substituted or unsubstituted aryl group having 6 to 30 ring carbon atoms, a substituted or unsubstituted alkoxy group having 1 to 30 carbon atoms, a substituted or unsubstituted alkoxy halide group having 1 to 30 carbon atoms, a substituted or unsubstituted alkylthio group having 1 to 30 carbon atoms, a substituted or unsubstituted aryloxy group having 6 to 30 ring carbon atoms, a substituted or unsubstituted arylthio group having 6 to 30 ring carbon atoms, a substituted or unsubstituted alkenyl group having 2 to 30 carbon atoms, a substituted or unsubstituted aralkyl group having 7 to 30 carbon atoms, a substituted or unsubstituted heteroaryl group having 5 to 30 ring atoms, a halogen atom, a carboxy group, a substituted or unsubstituted ester group, a substituted or unsubstituted carbamoyl group, a substituted or unsubstituted amino group, a nitro group, a cyano group, a substituted or unsubstituted silyl group, and a substituted or unsubstituted siloxanyl group;
Z₂₁ and Z₂₂ are each independently a substituent, or are mutually bonded to form a ring; and
Z₂₁ and Z₂₂ as the substituents are each independently selected from the group consisting of a halogen atom, a substituted or unsubstituted alkyl group having 1 to 30 carbon atoms, a substituted or unsubstituted alkyl halide group having 1 to 30 carbon atoms, a substituted or unsubstituted aryl group having 6 to 30 ring carbon atoms, a substituted or unsubstituted alkoxy group having 1 to 30 carbon atoms, a substituted or unsubstituted alkoxy halide group having 1 to 30 carbon atoms, and a substituted or unsubstituted aryloxy group having 6 to 30 ring carbon atoms.

### Method of Producing Compound M1

The compound M1 can be produced by a known method.

Specific examples of the compound M1 are shown below. It should however be noted that the invention is not limited to the specific examples of the compound.

A coordinate bond between a boron atom and a nitrogen atom in a pyrromethene skeleton is shown by various means such as a solid tine, a broken line, an arrow, and omission. Herein, the coordinate bond is shown by a solid line or a broken line, or the description of the coordinate bond is omitted.

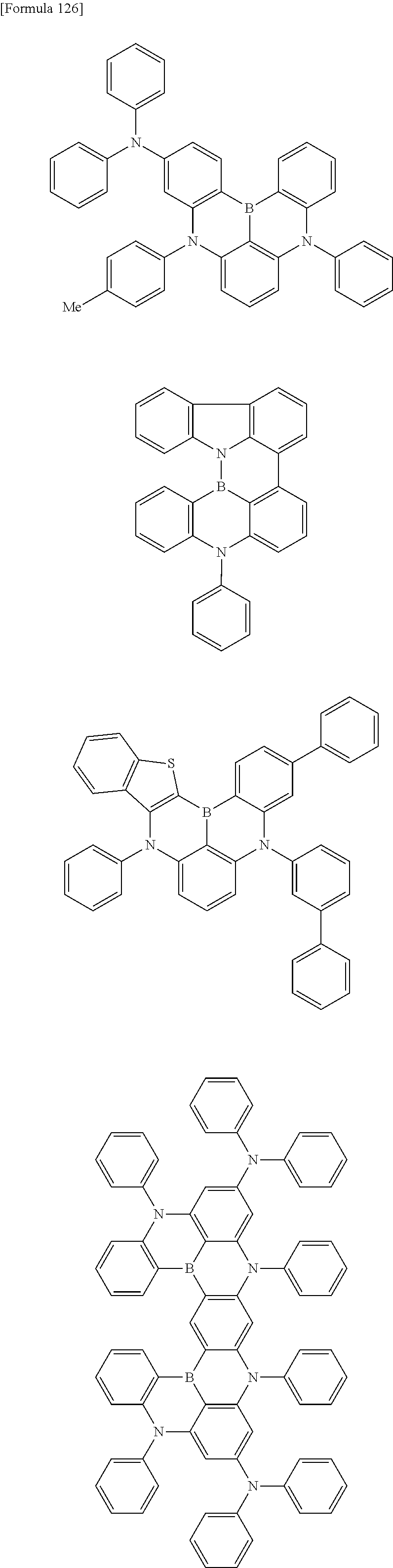 [SMILES: Cc1ccc(N2c3cc(N(c4ccccc4)c4ccccc4)ccc3B3c4ccccc4N(c4ccccc4)c4cccc2c43)cc1 ; c1ccc(N2c3ccccc3B3c4c(cccc42)-c2cccc4c5ccccc5n3c24)cc1 ; c1ccc(-c2cccc(N3c4cc(-c5ccccc5)ccc4B4c5sc6ccccc6c5N(c5ccccc5)c5cccc3c54)c2)cc1 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1]

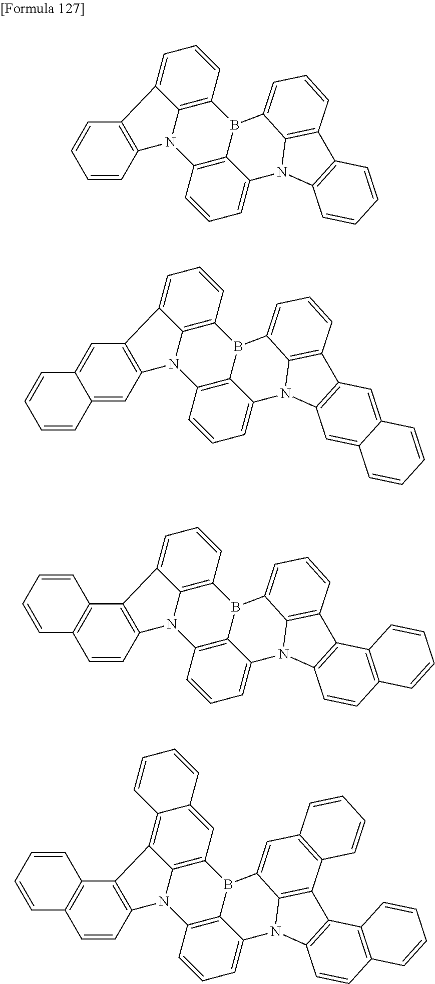

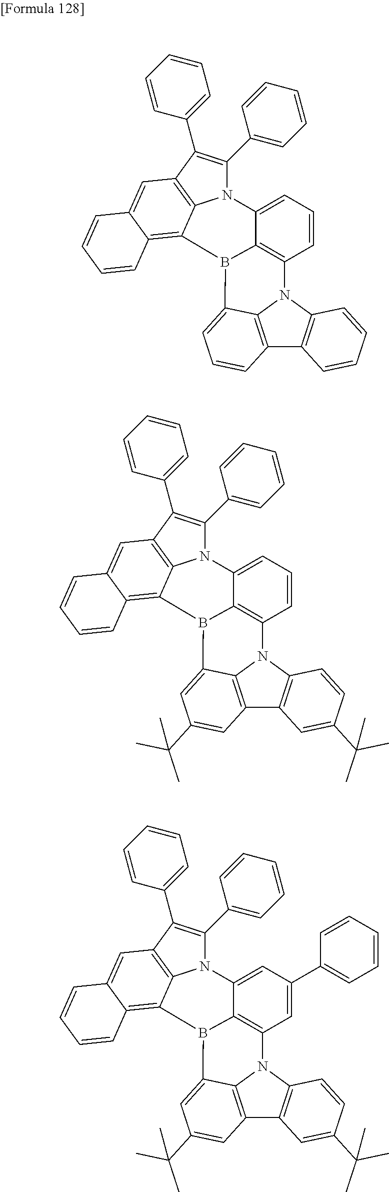 [SMILES: c1ccc(-c2c(-c3ccccc3)n3c4c(c5ccccc5cc24)B2c4c-3cccc4-n3c4ccccc4c4cccc2c43)cc1 ; CC(C)(C)c1ccc2c(c1)c1cc(C(C)(C)C)cc3c1n2-c1cccc2c1B3c1c3ccccc3cc3c(-c4ccccc4)c(-c4ccccc4)n-2c13 ; CC(C)(C)c1ccc2c(c1)c1cc(C(C)(C)C)cc3c1n2-c1cc(-c2ccccc2)cc2c1B3c1c3ccccc3cc3c(-c4ccccc4)c(-c4ccccc4)n-2c13]

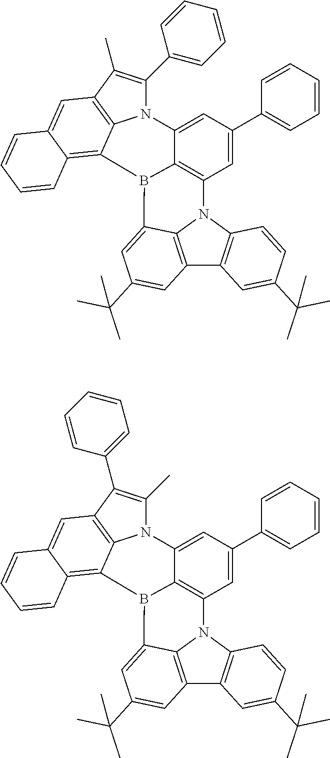 [SMILES: Cc1c(-c2ccccc2)n2c3c(c4ccccc4cc13)B1c3c-2cc(-c2ccccc2)cc3-n2c3ccc(C(C)(C)C)cc3c3cc(C(C)(C)C)cc1c32 ; Cc1c(-c2ccccc2)c2cc3ccccc3c3c2n1-c1cc(-c2ccccc2)cc2c1B3c1cc(C(C)(C)C)cc3c4cc(C(C)(C)C)ccc4n-2c13]

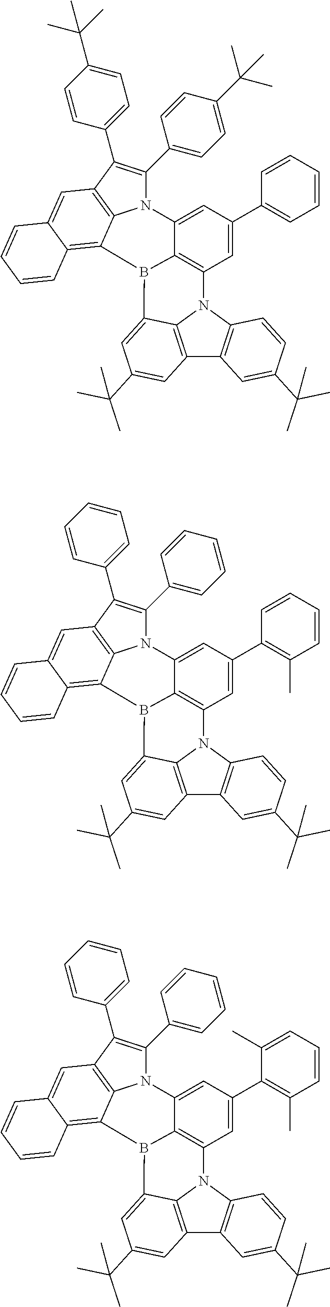 [SMILES: CC(C)(C)c1ccc(-c2c(-c3ccc(C(C)(C)C)cc3)n3c4c(c5ccccc5cc24)B2c4c-3cc(-c3ccccc3)cc4-n3c4ccc(C(C)(C)C)cc4c4cc(C(C)(C)C)cc2c43)cc1 ; Cc1ccccc1-c1cc2c3c(c1)-n1c4ccc(C(C)(C)C)cc4c4cc(C(C)(C)C)cc(c41)B3c1c3ccccc3cc3c(-c4ccccc4)c(-c4ccccc4)n-2c13 ; Cc1cccc(C)c1-c1cc2c3c(c1)-n1c4ccc(C(C)(C)C)cc4c4cc(C(C)(C)C)cc(c41)B3c1c3ccccc3cc3c(-c4ccccc4)c(-c4ccccc4)n-2c13]

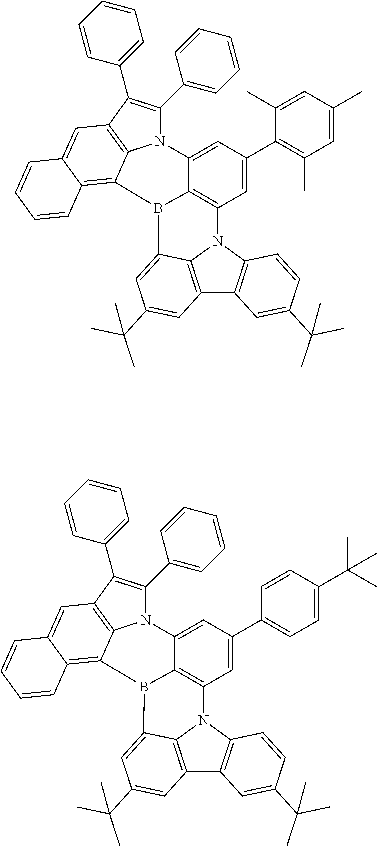 [SMILES: Cc1cc(C)c(-c2cc3c4c(c2)-n2c5ccc(C(C)(C)C)cc5c5cc(C(C)(C)C)cc(c52)B4c2c4ccccc4cc4c(-c5ccccc5)c(-c5ccccc5)n-3c24)c(C)c1 ; CC(C)(C)c1ccc(-c2cc3c4c(c2)-n2c5ccc(C(C)(C)C)cc5c5cc(C(C)(C)C)cc(c52)B4c2c4ccccc4cc4c(-c5ccccc5)c(-c5ccccc5)n-3c24)cc1]

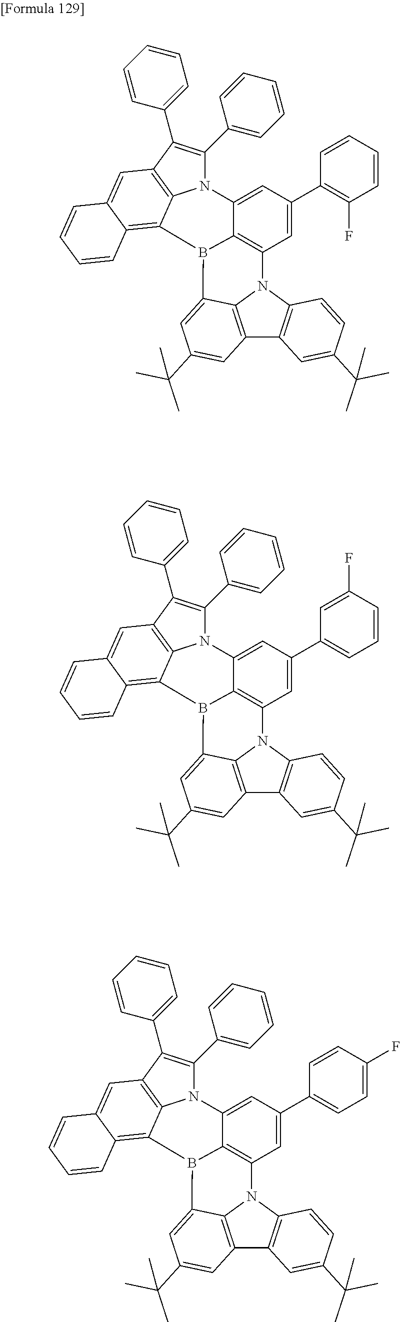 [SMILES: CC(C)(C)c1ccc2c(c1)c1cc(C(C)(C)C)cc3c1n2-c1cc(-c2ccccc2F)cc2c1B3c1c3ccccc3cc3c(-c4ccccc4)c(-c4ccccc4)n-2c13 ; CC(C)(C)c1ccc2c(c1)c1cc(C(C)(C)C)cc3c1n2-c1cc(-c2cccc(F)c2)cc2c1B3c1c3ccccc3cc3c(-c4ccccc4)c(-c4ccccc4)n-2c13 ; CC(C)(C)c1ccc2c(c1)c1cc(C(C)(C)C)cc3c1n2-c1cc(-c2ccc(F)cc2)cc2c1B3c1c3ccccc3cc3c(-c4ccccc4)c(-c4ccccc4)n-2c13]

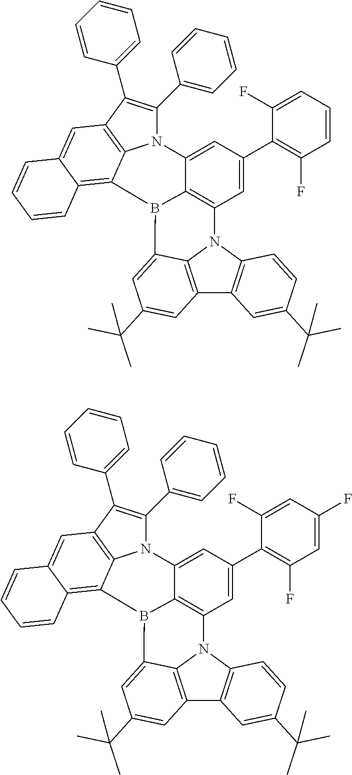 [SMILES: CC(C)(C)c1ccc2c(c1)c1cc(C(C)(C)C)cc3c1n2-c1cc(-c2c(F)cccc2F)cc2c1B3c1c3ccccc3cc3c(-c4ccccc4)c(-c4ccccc4)n-2c13 ; CC(C)(C)c1ccc2c(c1)c1cc(C(C)(C)C)cc3c1n2-c1cc(-c2c(F)cc(F)cc2F)cc2c1B3c1c3ccccc3cc3c(-c4ccccc4)c(-c4ccccc4)n-2c13]

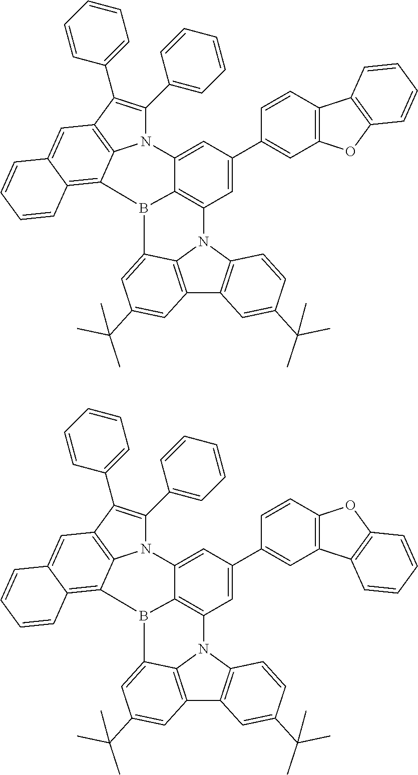 [SMILES: CC(C)(C)c1ccc2c(c1)c1cc(C(C)(C)C)cc3c1n2-c1cc(-c2ccc4c(c2)oc2ccccc24)cc2c1B3c1c3ccccc3cc3c(-c4ccccc4)c(-c4ccccc4)n-2c13 ; CC(C)(C)c1ccc2c(c1)c1cc(C(C)(C)C)cc3c1n2-c1cc(-c2ccc4oc5ccccc5c4c2)cc2c1B3c1c3ccccc3cc3c(-c4ccccc4)c(-c4ccccc4)n-2c13]

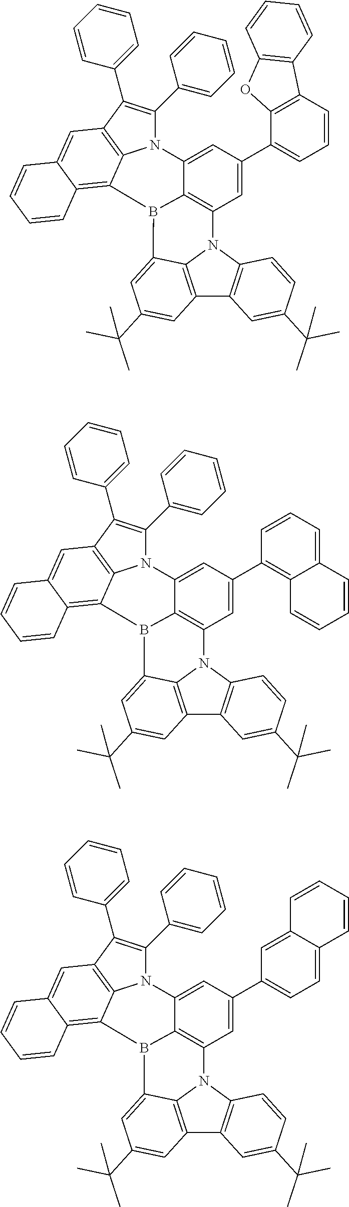 [SMILES: CC(C)(C)c1ccc2c(c1)c1cc(C(C)(C)C)cc3c1n2-c1cc(-c2cccc4c2oc2ccccc24)cc2c1B3c1c3ccccc3cc3c(-c4ccccc4)c(-c4ccccc4)n-2c13 ; CC(C)(C)c1ccc2c(c1)c1cc(C(C)(C)C)cc3c1n2-c1cc(-c2cccc4ccccc24)cc2c1B3c1c3ccccc3cc3c(-c4ccccc4)c(-c4ccccc4)n-2c13 ; CC(C)(C)c1ccc2c(c1)c1cc(C(C)(C)C)cc3c1n2-c1cc(-c2ccc4ccccc4c2)cc2c1B3c1c3ccccc3cc3c(-c4ccccc4)c(-c4ccccc4)n-2c13]

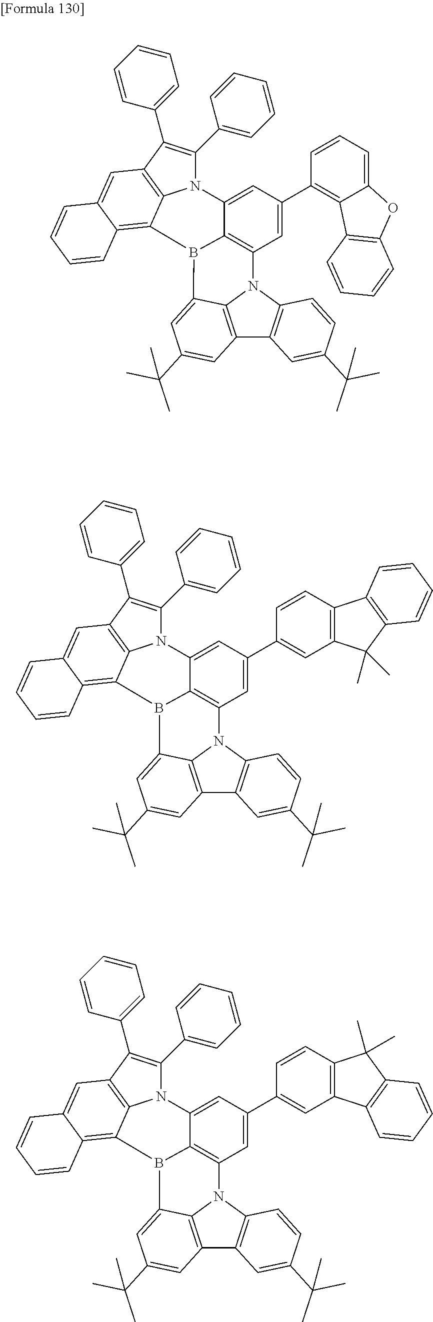 [SMILES: CC(C)(C)c1ccc2c(c1)c1cc(C(C)(C)C)cc3c1n2-c1cc(-c2cccc4oc5ccccc5c24)cc2c1B3c1c3ccccc3cc3c(-c4ccccc4)c(-c4ccccc4)n-2c13 ; CC(C)(C)c1ccc2c(c1)c1cc(C(C)(C)C)cc3c1n2-c1cc(-c2ccc4c(c2)C(C)(C)c2ccccc2-4)cc2c1B3c1c3ccccc3cc3c(-c4ccccc4)c(-c4ccccc4)n-2c13 ; CC(C)(C)c1ccc2c(c1)c1cc(C(C)(C)C)cc3c1n2-c1cc(-c2ccc4c(c2)-c2ccccc2C4(C)C)cc2c1B3c1c3ccccc3cc3c(-c4ccccc4)c(-c4ccccc4)n-2c13]

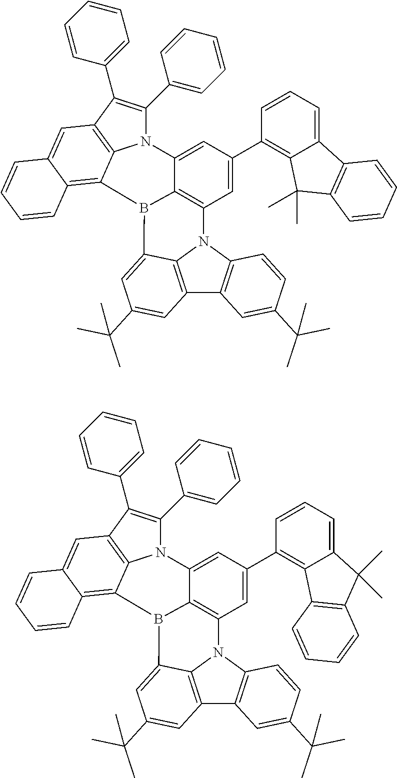 [SMILES: CC(C)(C)c1ccc2c(c1)c1cc(C(C)(C)C)cc3c1n2-c1cc(-c2cccc4c2C(C)(C)c2ccccc2-4)cc2c1B3c1c3ccccc3cc3c(-c4ccccc4)c(-c4ccccc4)n-2c13 ; CC(C)(C)c1ccc2c(c1)c1cc(C(C)(C)C)cc3c1n2-c1cc(-c2cccc4c2-c2ccccc2C4(C)C)cc2c1B3c1c3ccccc3cc3c(-c4ccccc4)c(-c4ccccc4)n-2c13]

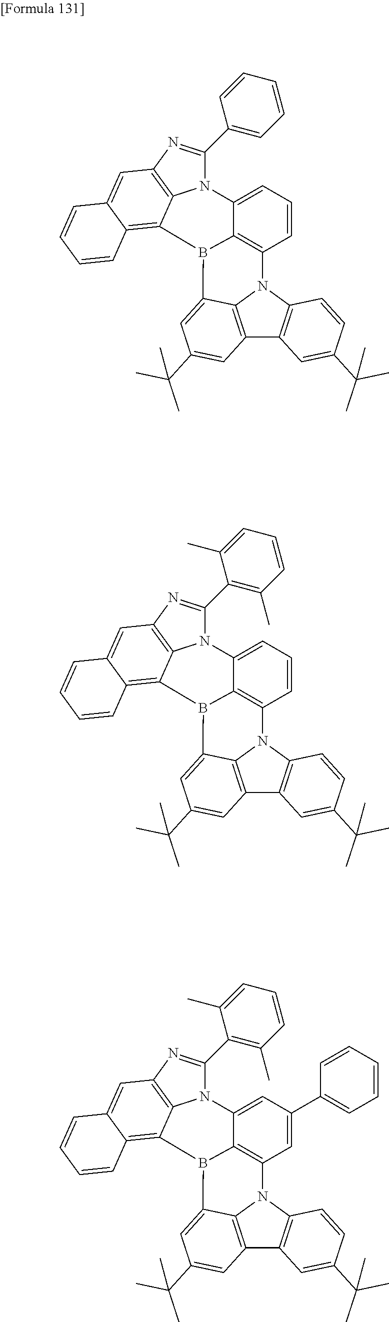 [SMILES: CC(C)(C)c1ccc2c(c1)c1cc(C(C)(C)C)cc3c1n2-c1cccc2c1B3c1c3ccccc3cc3nc(-c4ccccc4)n-2c13 ; Cc1cccc(C)c1-c1nc2cc3ccccc3c3c2n1-c1cccc2c1B3c1cc(C(C)(C)C)cc3c4cc(C(C)(C)C)ccc4n-2c13 ; Cc1cccc(C)c1-c1nc2cc3ccccc3c3c2n1-c1cc(-c2ccccc2)cc2c1B3c1cc(C(C)(C)C)cc3c4cc(C(C)(C)C)ccc4n-2c13]

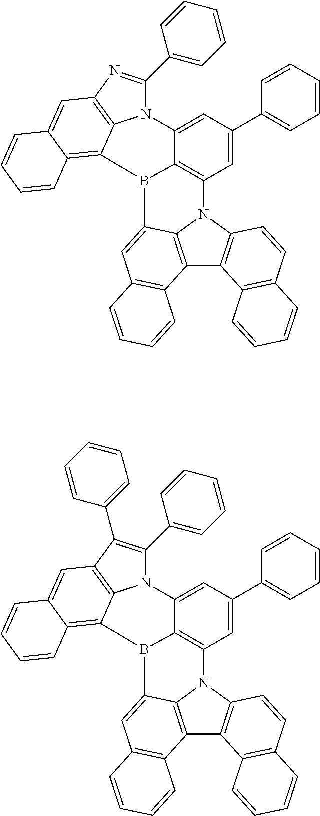 [SMILES: c1ccc(-c2cc3c4c(c2)-n2c5ccc6ccccc6c5c5c6ccccc6cc(c52)B4c2c4ccccc4cc4nc(-c5ccccc5)n-3c24)cc1 ; c1ccc(-c2cc3c4c(c2)-n2c5ccc6ccccc6c5c5c6ccccc6cc(c52)B4c2c4ccccc4cc4c(-c5ccccc5)c(-c5ccccc5)n-3c24)cc1]

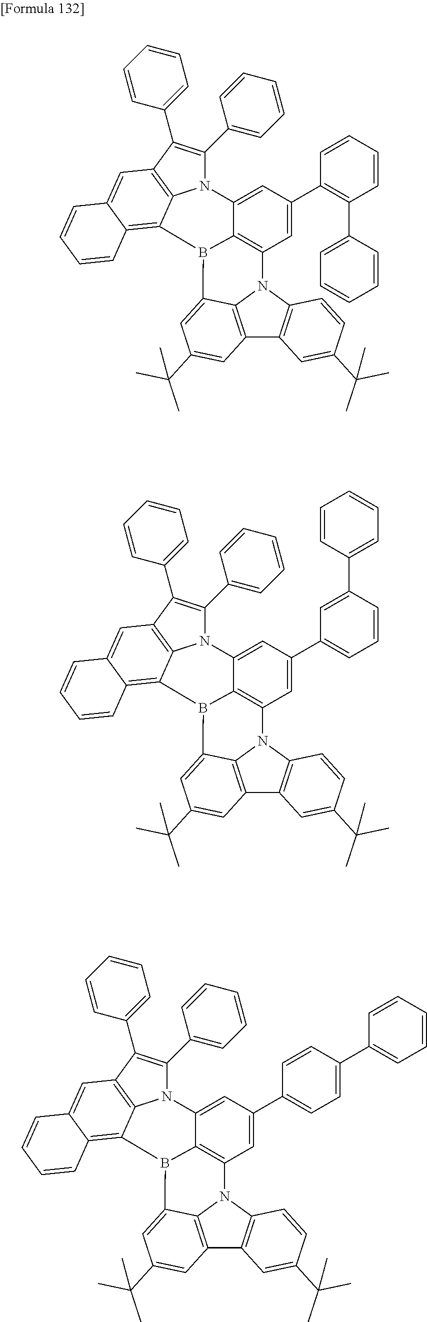 [SMILES: CC(C)(C)c1ccc2c(c1)c1cc(C(C)(C)C)cc3c1n2-c1cc(-c2ccccc2-c2ccccc2)cc2c1B3c1c3ccccc3cc3c(-c4ccccc4)c(-c4ccccc4)n-2c13 ; CC(C)(C)c1ccc2c(c1)c1cc(C(C)(C)C)cc3c1n2-c1cc(-c2cccc(-c4ccccc4)c2)cc2c1B3c1c3ccccc3cc3c(-c4ccccc4)c(-c4ccccc4)n-2c13 ; CC(C)(C)c1ccc2c(c1)c1cc(C(C)(C)C)cc3c1n2-c1cc(-c2ccc(-c4ccccc4)cc2)cc2c1B3c1c3ccccc3cc3c(-c4ccccc4)c(-c4ccccc4)n-2c13]

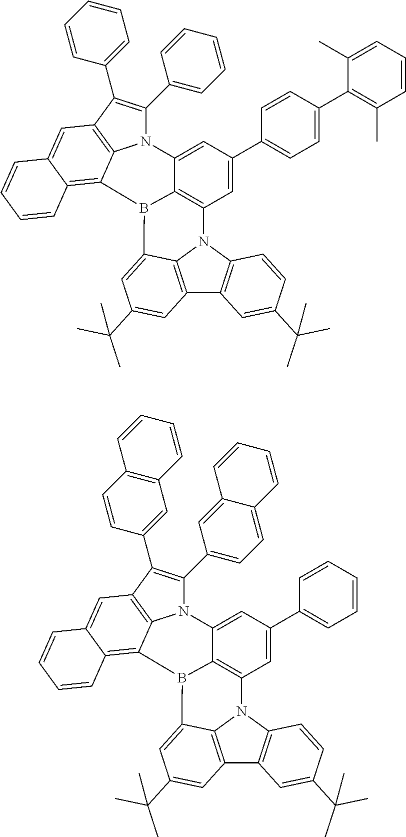 [SMILES: Cc1cccc(C)c1-c1ccc(-c2cc3c4c(c2)-n2c5ccc(C(C)(C)C)cc5c5cc(C(C)(C)C)cc(c52)B4c2c4ccccc4cc4c(-c5ccccc5)c(-c5ccccc5)n-3c24)cc1 ; CC(C)(C)c1ccc2c(c1)c1cc(C(C)(C)C)cc3c1n2-c1cc(-c2ccccc2)cc2c1B3c1c3ccccc3cc3c(-c4ccc5ccccc5c4)c(-c4ccc5ccccc5c4)n-2c13]

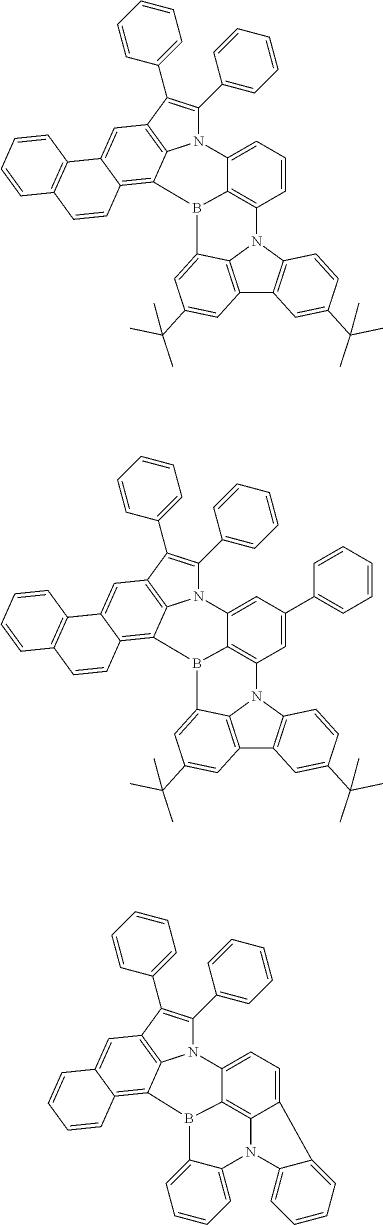 [SMILES: CC(C)(C)c1ccc2c(c1)c1cc(C(C)(C)C)cc3c1n2-c1cccc2c1B3c1c3ccc4ccccc4c3cc3c(-c4ccccc4)c(-c4ccccc4)n-2c13 ; CC(C)(C)c1ccc2c(c1)c1cc(C(C)(C)C)cc3c1n2-c1cc(-c2ccccc2)cc2c1B3c1c3ccc4ccccc4c3cc3c(-c4ccccc4)c(-c4ccccc4)n-2c13 ; c1ccc(-c2c(-c3ccccc3)n3c4c(c5ccccc5cc24)B2c4ccccc4-n4c5ccccc5c5ccc-3c2c54)cc1]

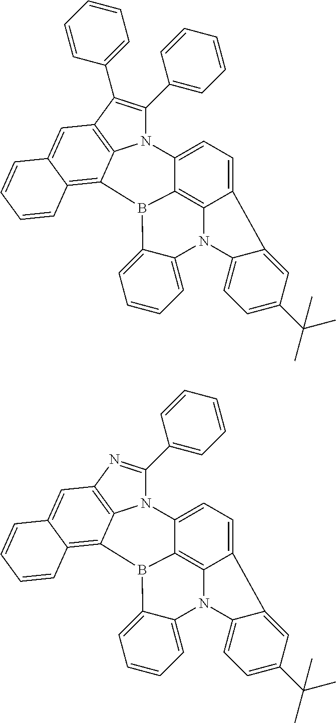 [SMILES: CC(C)(C)c1ccc2c(c1)c1ccc3c4c1n2-c1ccccc1B4c1c2ccccc2cc2c(-c4ccccc4)c(-c4ccccc4)n-3c12 ; CC(C)(C)c1ccc2c(c1)c1ccc3c4c1n2-c1ccccc1B4c1c2ccccc2cc2nc(-c4ccccc4)n-3c12]

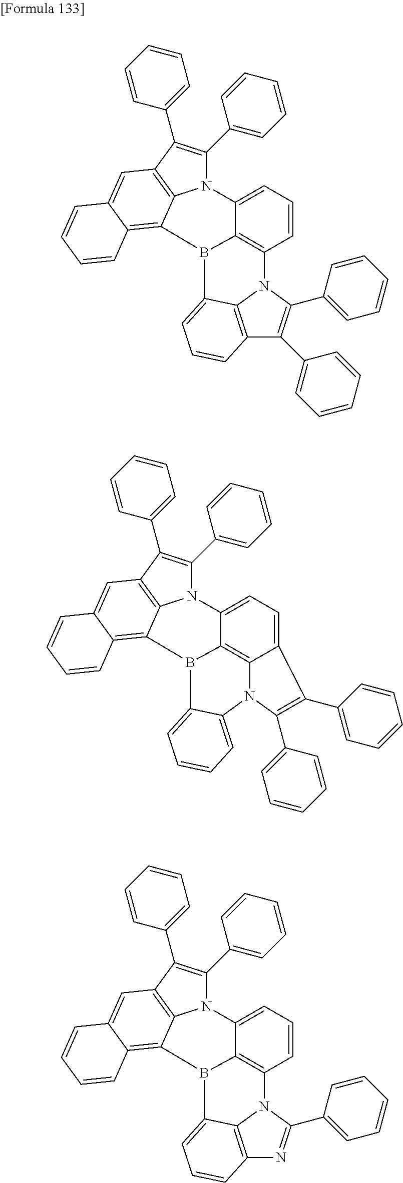 [SMILES: c1ccc(-c2c(-c3ccccc3)n3c4c(cccc24)B2c4c-3cccc4-n3c(-c4ccccc4)c(-c4ccccc4)c4cc5ccccc5c2c43)cc1 ; c1ccc(-c2c(-c3ccccc3)n3c4c5c(ccc24)-n2c(-c4ccccc4)c(-c4ccccc4)c4cc6ccccc6c(c42)B5c2ccccc2-3)cc1 ; c1ccc(-c2c(-c3ccccc3)n3c4c(c5ccccc5cc24)B2c4c(cccc4-3)-n3c(-c4ccccc4)nc4cccc2c43)cc1]

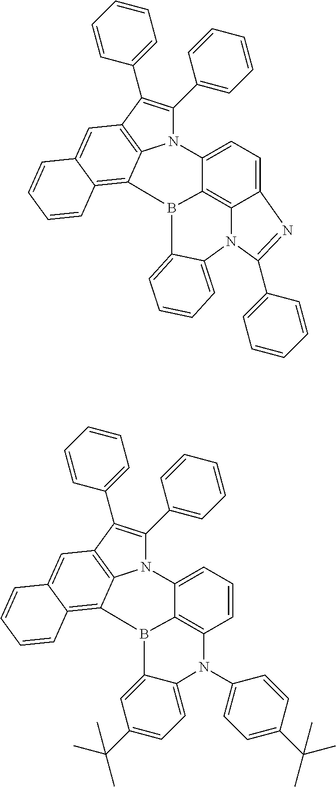 [SMILES: c1ccc(-c2c(-c3ccccc3)n3c4c(c5ccccc5cc24)B2c4ccccc4-n4c(-c5ccccc5)nc5ccc-3c2c54)cc1 ; CC(C)(C)c1ccc(N2c3ccc(C(C)(C)C)cc3B3c4c2cccc4-n2c(-c4ccccc4)c(-c4ccccc4)c4cc5ccccc5c3c42)cc1]

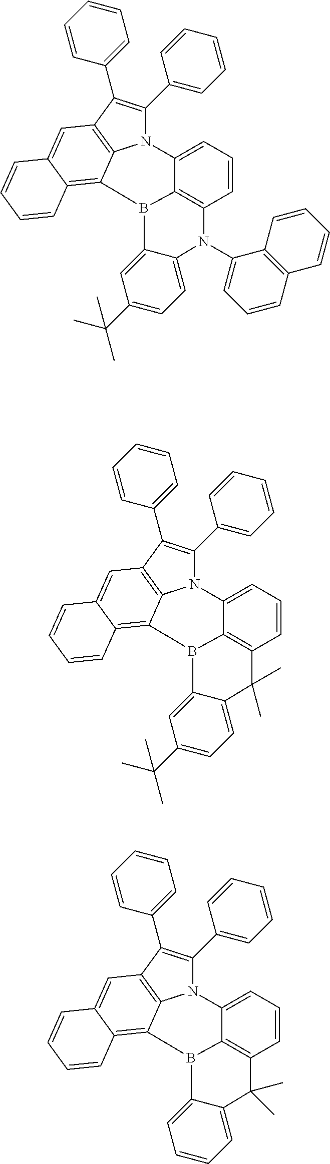 [SMILES: CC(C)(C)c1ccc2c(c1)B1c3c(cccc3-n3c(-c4ccccc4)c(-c4ccccc4)c4cc5ccccc5c1c43)N2c1cccc2ccccc12 ; CC(C)(C)c1ccc2c(c1)B1c3c(cccc3C2(C)C)-n2c(-c3ccccc3)c(-c3ccccc3)c3cc4ccccc4c1c32 ; CC1(C)c2ccccc2B2c3c(cccc31)-n1c(-c3ccccc3)c(-c3ccccc3)c3cc4ccccc4c2c31]

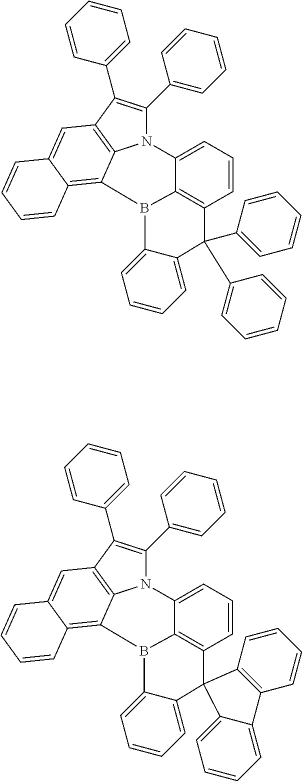 [SMILES: c1ccc(-c2c(-c3ccccc3)n3c4c(c5ccccc5cc24)B2c4ccccc4C(c4ccccc4)(c4ccccc4)c4cccc-3c42)cc1 ; c1ccc(-c2c(-c3ccccc3)n3c4c(c5ccccc5cc24)B2c4ccccc4C4(c5ccccc5-c5ccccc54)c4cccc-3c42)cc1]

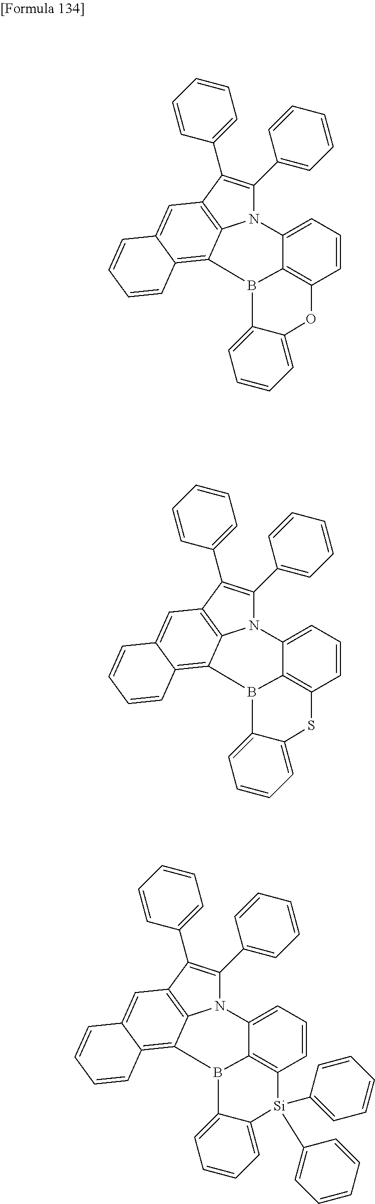 [SMILES: c1ccc(-c2c(-c3ccccc3)n3c4c(c5ccccc5cc24)B2c4ccccc4Oc4cccc-3c42)cc1 ; c1ccc(-c2c(-c3ccccc3)n3c4c(c5ccccc5cc24)B2c4ccccc4Sc4cccc-3c42)cc1 ; c1ccc(-c2c(-c3ccccc3)n3c4c(c5ccccc5cc24)B2c4ccccc4[Si](c4ccccc4)(c4ccccc4)c4cccc-3c42)cc1]

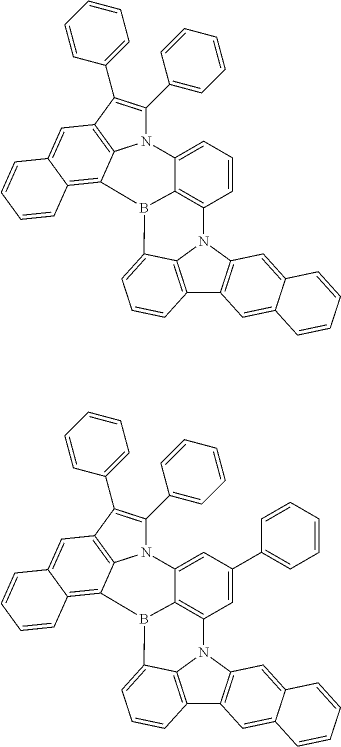 [SMILES: c1ccc(-c2c(-c3ccccc3)n3c4c(c5ccccc5cc24)B2c4c-3cccc4-n3c4cc5ccccc5cc4c4cccc2c43)cc1 ; c1ccc(-c2cc3c4c(c2)-n2c5cc6ccccc6cc5c5cccc(c52)B4c2c4ccccc4cc4c(-c5ccccc5)c(-c5ccccc5)n-3c24)cc1]

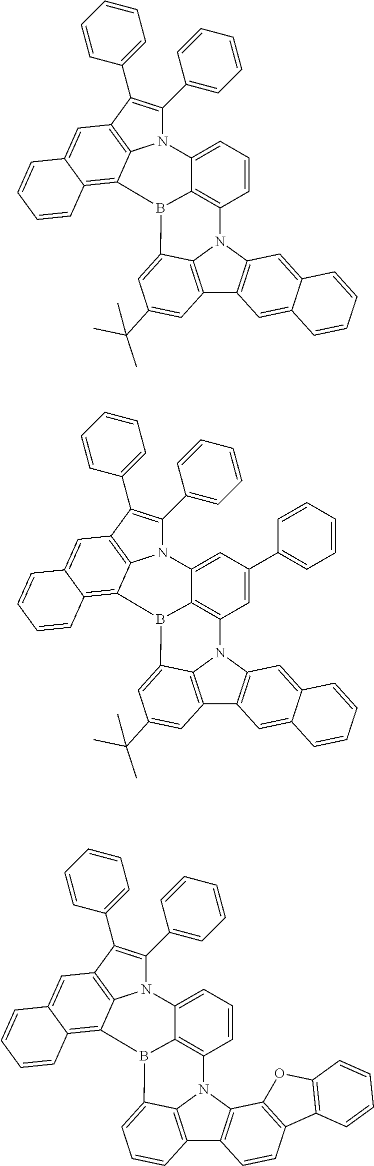 [SMILES: CC(C)(C)c1cc2c3c(c1)c1cc4ccccc4cc1n3-c1cccc3c1B2c1c2ccccc2cc2c(-c4ccccc4)c(-c4ccccc4)n-3c12 ; CC(C)(C)c1cc2c3c(c1)c1cc4ccccc4cc1n3-c1cc(-c3ccccc3)cc3c1B2c1c2ccccc2cc2c(-c4ccccc4)c(-c4ccccc4)n-3c12 ; c1ccc(-c2c(-c3ccccc3)n3c4c(c5ccccc5cc24)B2c4c-3cccc4-n3c4c2cccc4c2ccc4c5ccccc5oc4c23)cc1]

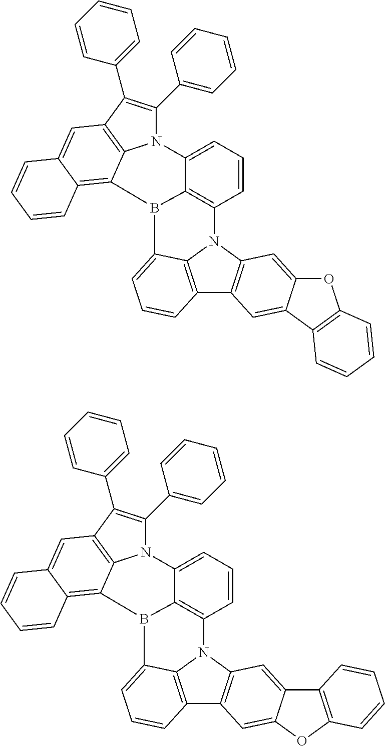 [SMILES: c1ccc(-c2c(-c3ccccc3)n3c4c(c5ccccc5cc24)B2c4c-3cccc4-n3c4cc5oc6ccccc6c5cc4c4cccc2c43)cc1 ; c1ccc(-c2c(-c3ccccc3)n3c4c(c5ccccc5cc24)B2c4c-3cccc4-n3c4cc5c(cc4c4cccc2c43)oc2ccccc25)cc1]

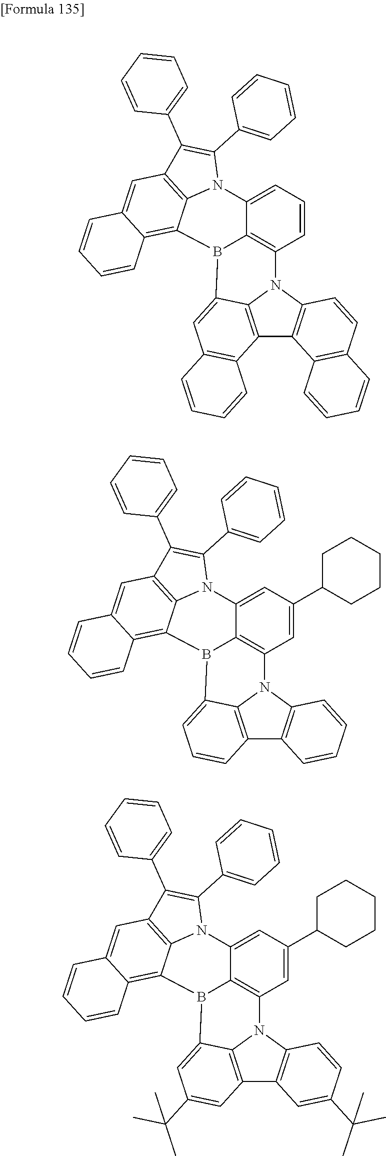 [SMILES: c1ccc(-c2c(-c3ccccc3)n3c4c(c5ccccc5cc24)B2c4c-3cccc4-n3c4ccc5ccccc5c4c4c5ccccc5cc2c43)cc1 ; c1ccc(-c2c(-c3ccccc3)n3c4c(c5ccccc5cc24)B2c4c-3cc(C3CCCCC3)cc4-n3c4ccccc4c4cccc2c43)cc1 ; CC(C)(C)c1ccc2c(c1)c1cc(C(C)(C)C)cc3c1n2-c1cc(C2CCCCC2)cc2c1B3c1c3ccccc3cc3c(-c4ccccc4)c(-c4ccccc4)n-2c13]

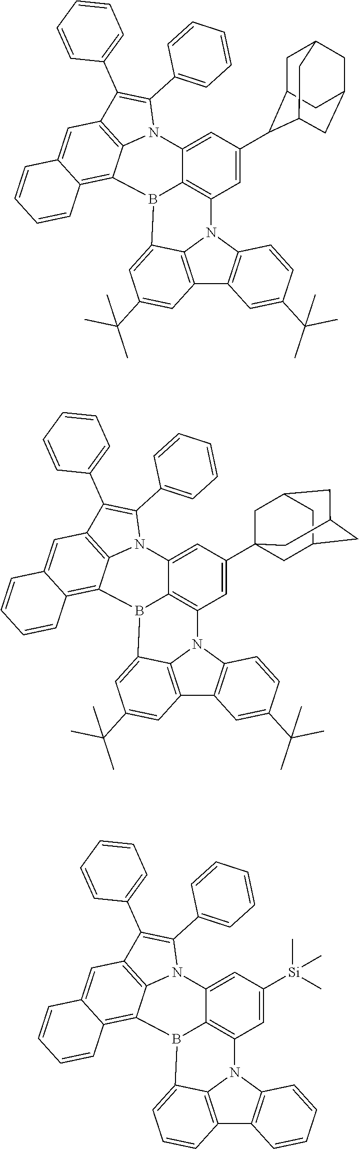 [SMILES: CC(C)(C)c1ccc2c(c1)c1cc(C(C)(C)C)cc3c1n2-c1cc(C2C4CC5CC(C4)CC2C5)cc2c1B3c1c3ccccc3cc3c(-c4ccccc4)c(-c4ccccc4)n-2c13 ; CC(C)(C)c1ccc2c(c1)c1cc(C(C)(C)C)cc3c1n2-c1cc(C24CC5CC(CC(C5)C2)C4)cc2c1B3c1c3ccccc3cc3c(-c4ccccc4)c(-c4ccccc4)n-2c13 ; C[Si](C)(C)c1cc2c3c(c1)-n1c4ccccc4c4cccc(c41)B3c1c3ccccc3cc3c(-c4ccccc4)c(-c4ccccc4)n-2c13]

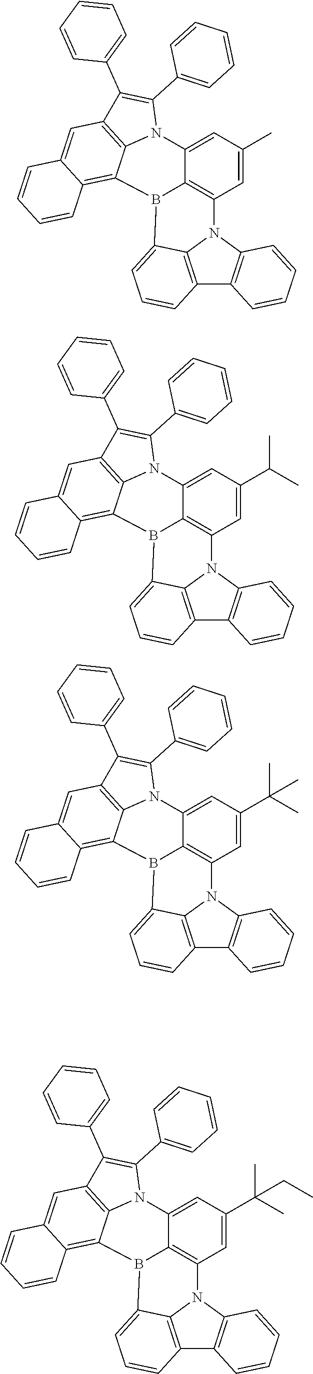

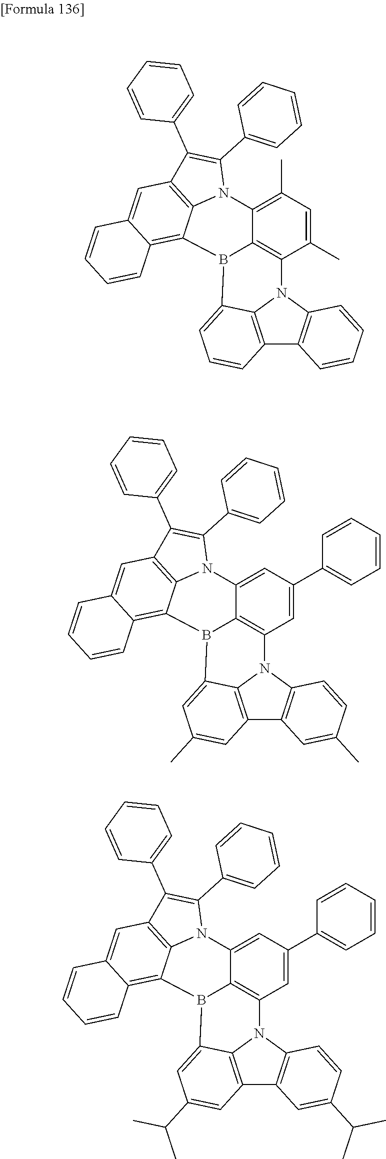

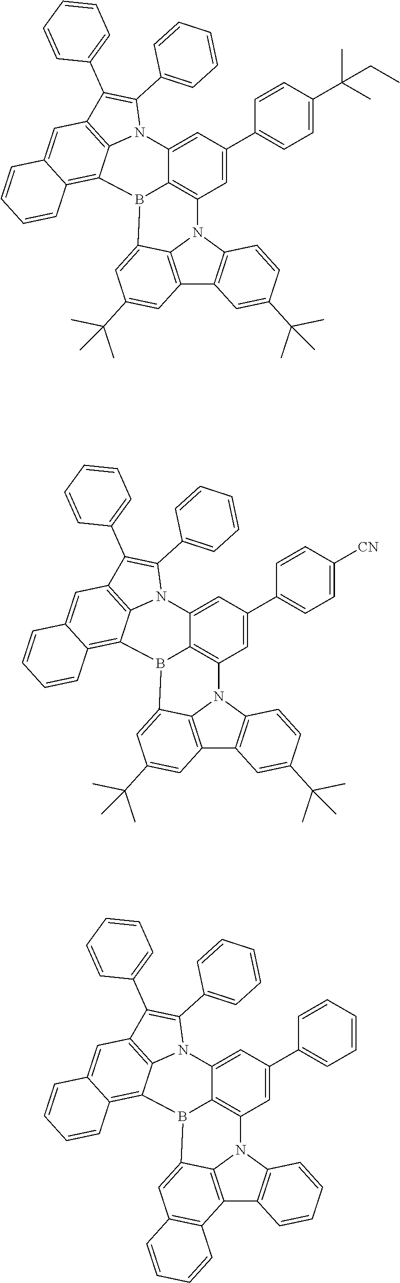 [SMILES: CCC(C)(C)c1ccc(-c2cc3c4c(c2)-n2c5ccc(C(C)(C)C)cc5c5cc(C(C)(C)C)cc(c52)B4c2c4ccccc4cc4c(-c5ccccc5)c(-c5ccccc5)n-3c24)cc1 ; CC(C)(C)c1ccc2c(c1)c1cc(C(C)(C)C)cc3c1n2-c1cc(-c2ccc(C#N)cc2)cc2c1B3c1c3ccccc3cc3c(-c4ccccc4)c(-c4ccccc4)n-2c13 ; c1ccc(-c2cc3c4c(c2)-n2c5ccccc5c5c6ccccc6cc(c52)B4c2c4ccccc4cc4c(-c5ccccc5)c(-c5ccccc5)n-3c24)cc1]

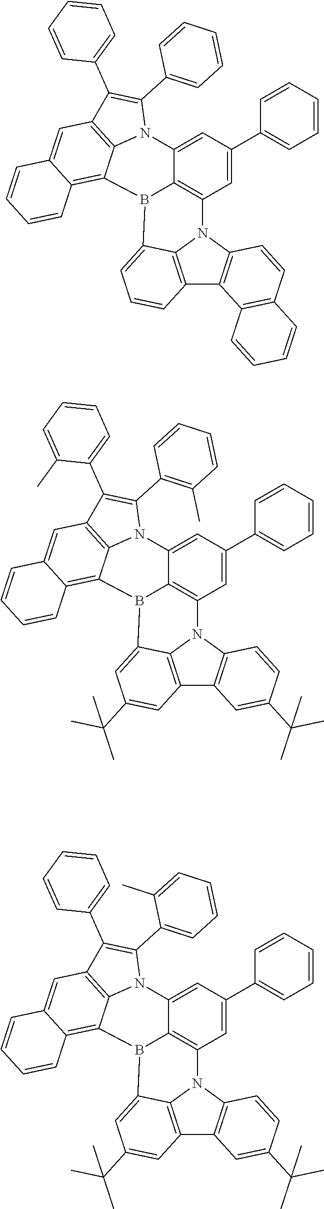 [SMILES: c1ccc(-c2cc3c4c(c2)-n2c5ccc6ccccc6c5c5cccc(c52)B4c2c4ccccc4cc4c(-c5ccccc5)c(-c5ccccc5)n-3c24)cc1 ; Cc1ccccc1-c1c(-c2ccccc2C)n2c3c(c4ccccc4cc13)B1c3c-2cc(-c2ccccc2)cc3-n2c3ccc(C(C)(C)C)cc3c3cc(C(C)(C)C)cc1c32 ; Cc1ccccc1-c1c(-c2ccccc2)c2cc3ccccc3c3c2n1-c1cc(-c2ccccc2)cc2c1B3c1cc(C(C)(C)C)cc3c4cc(C(C)(C)C)ccc4n-2c13]

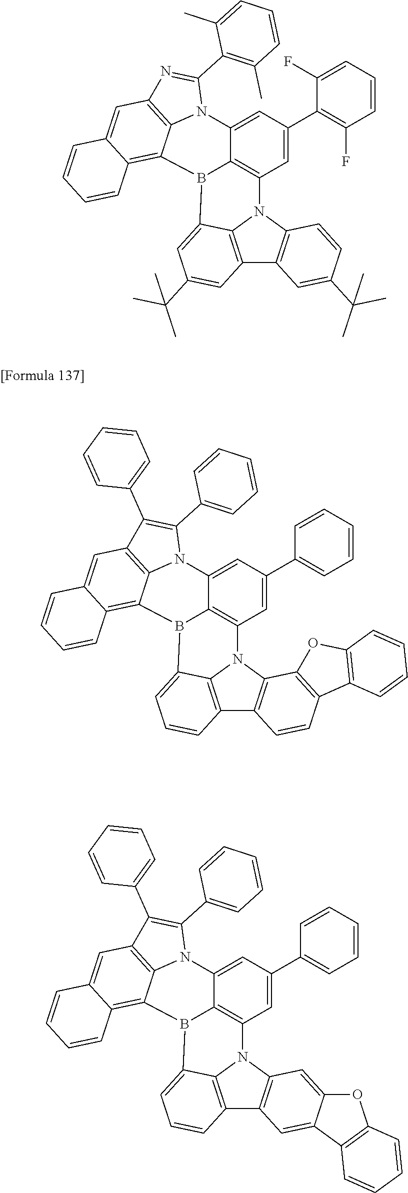 [SMILES: Cc1cccc(C)c1-c1nc2cc3ccccc3c3c2n1-c1cc(-c2c(F)cccc2F)cc2c1B3c1cc(C(C)(C)C)cc3c4cc(C(C)(C)C)ccc4n-2c13 ; c1ccc(-c2cc3c4c(c2)-n2c5c(cccc5c5ccc6c7ccccc7oc6c52)B4c2c4ccccc4cc4c(-c5ccccc5)c(-c5ccccc5)n-3c24)cc1 ; c1ccc(-c2cc3c4c(c2)-n2c5cc6oc7ccccc7c6cc5c5cccc(c52)B4c2c4ccccc4cc4c(-c5ccccc5)c(-c5ccccc5)n-3c24)cc1]

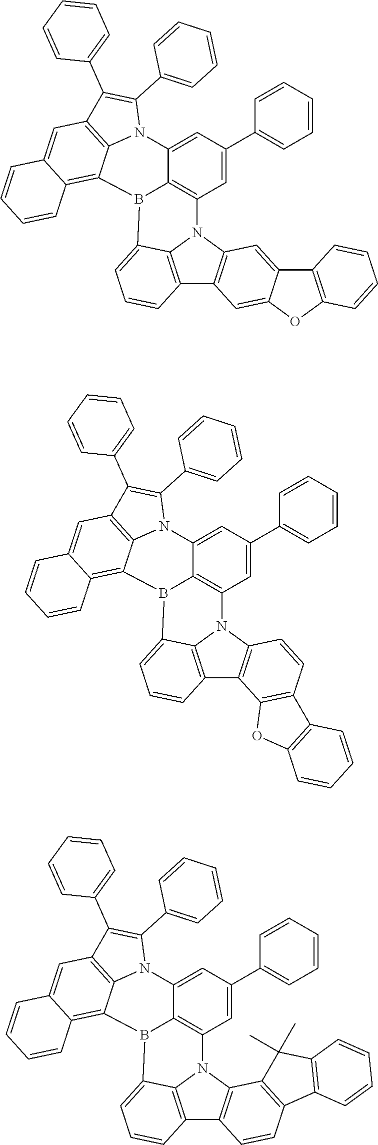 [SMILES: c1ccc(-c2cc3c4c(c2)-n2c5cc6c(cc5c5cccc(c52)B4c2c4ccccc4cc4c(-c5ccccc5)c(-c5ccccc5)n-3c24)oc2ccccc26)cc1 ; c1ccc(-c2cc3c4c(c2)-n2c5ccc6c7ccccc7oc6c5c5cccc(c52)B4c2c4ccccc4cc4c(-c5ccccc5)c(-c5ccccc5)n-3c24)cc1 ; CC1(C)c2ccccc2-c2ccc3c4cccc5c4n(c3c21)-c1cc(-c2ccccc2)cc2c1B5c1c3ccccc3cc3c(-c4ccccc4)c(-c4ccccc4)n-2c13]

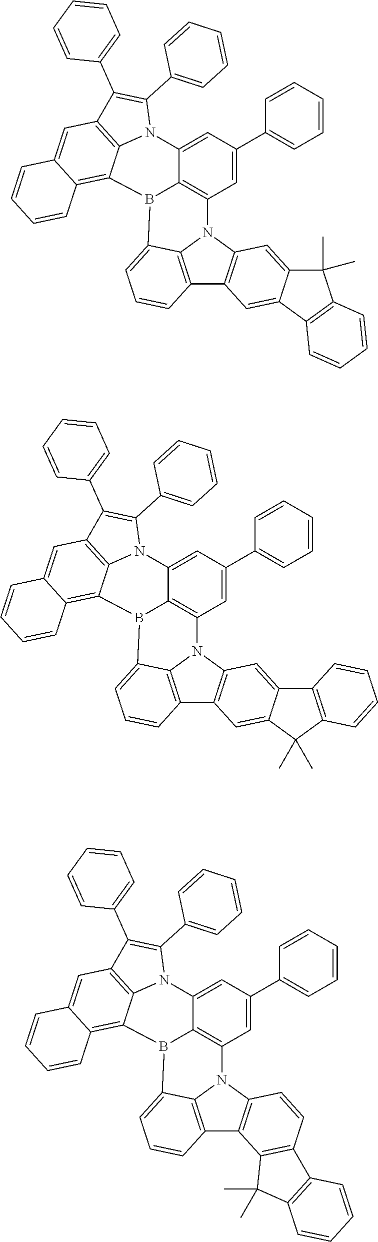 [SMILES: CC1(C)c2ccccc2-c2cc3c4cccc5c4n(c3cc21)-c1cc(-c2ccccc2)cc2c1B5c1c3ccccc3cc3c(-c4ccccc4)c(-c4ccccc4)n-2c13 ; CC1(C)c2ccccc2-c2cc3c(cc21)c1cccc2c1n3-c1cc(-c3ccccc3)cc3c1B2c1c2ccccc2cc2c(-c4ccccc4)c(-c4ccccc4)n-3c12 ; CC1(C)c2ccccc2-c2ccc3c(c21)c1cccc2c1n3-c1cc(-c3ccccc3)cc3c1B2c1c2ccccc2cc2c(-c4ccccc4)c(-c4ccccc4)n-3c12]

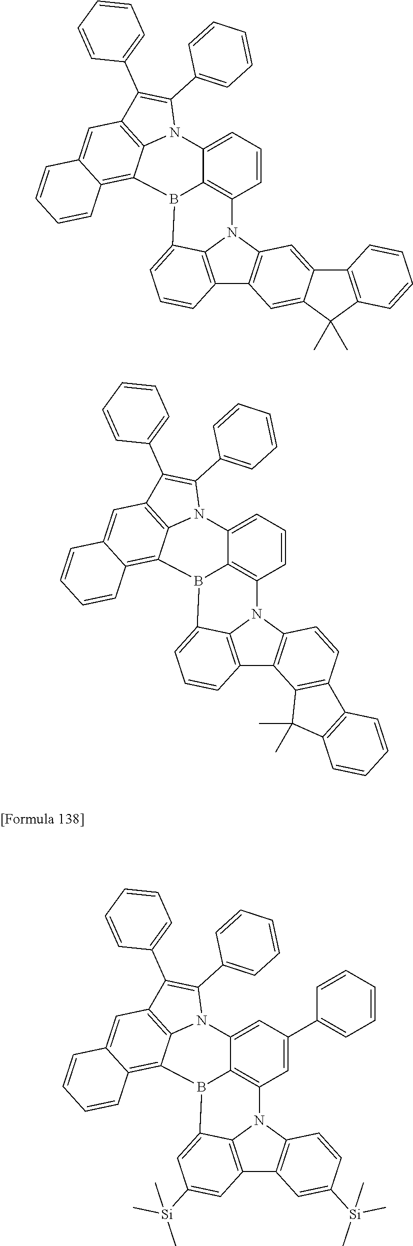 [SMILES: CC1(C)c2ccccc2-c2cc3c(cc21)c1cccc2c1n3-c1cccc3c1B2c1c2ccccc2cc2c(-c4ccccc4)c(-c4ccccc4)n-3c12 ; CC1(C)c2ccccc2-c2ccc3c(c21)c1cccc2c1n3-c1cccc3c1B2c1c2ccccc2cc2c(-c4ccccc4)c(-c4ccccc4)n-3c12 ; C[Si](C)(C)c1ccc2c(c1)c1cc([Si](C)(C)C)cc3c1n2-c1cc(-c2ccccc2)cc2c1B3c1c3ccccc3cc3c(-c4ccccc4)c(-c4ccccc4)n-2c13]

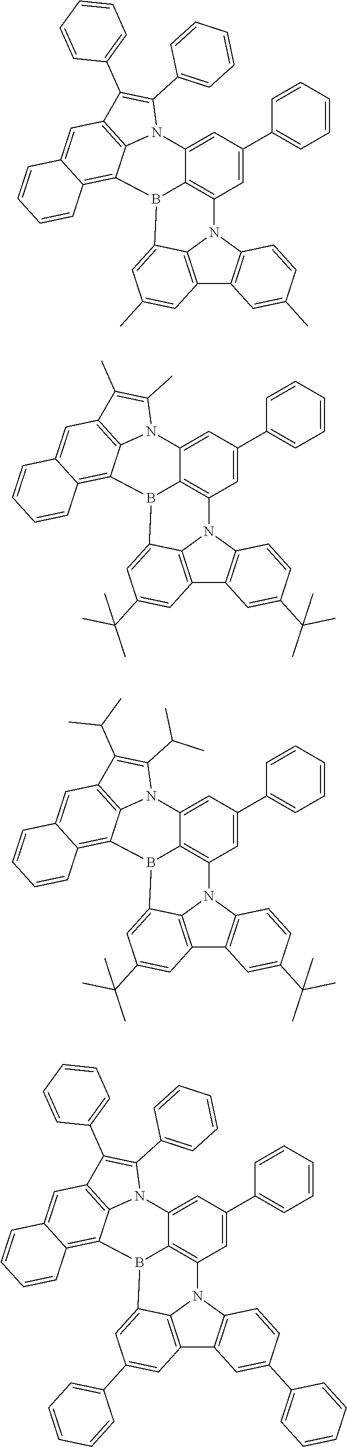

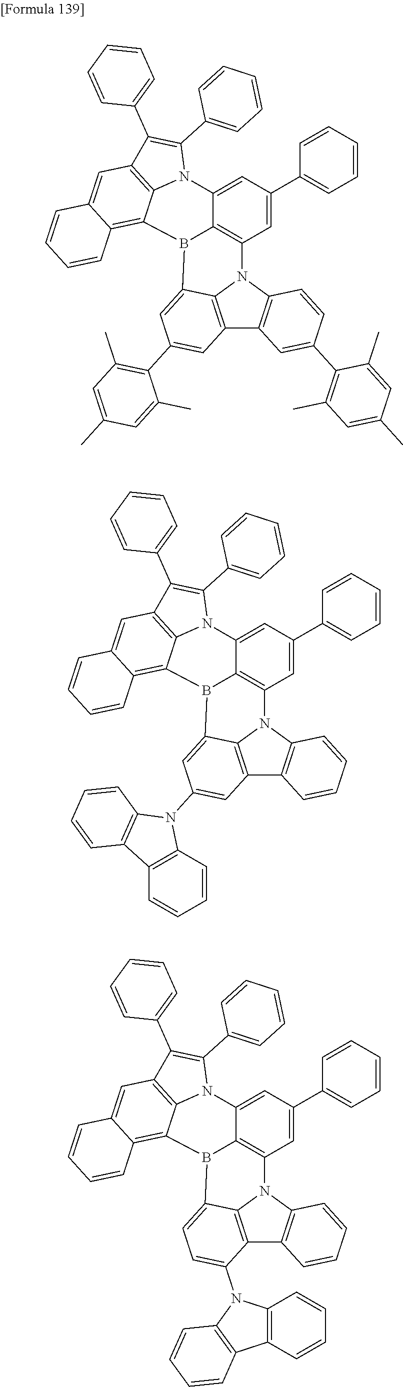 [SMILES: Cc1cc(C)c(-c2ccc3c(c2)c2cc(-c4c(C)cc(C)cc4C)cc4c2n3-c2cc(-c3ccccc3)cc3c2B4c2c4ccccc4cc4c(-c5ccccc5)c(-c5ccccc5)n-3c24)c(C)c1 ; c1ccc(-c2cc3c4c(c2)-n2c5ccccc5c5cc(-n6c7ccccc7c7ccccc76)cc(c52)B4c2c4ccccc4cc4c(-c5ccccc5)c(-c5ccccc5)n-3c24)cc1 ; c1ccc(-c2cc3c4c(c2)-n2c5ccccc5c5c(-n6c7ccccc7c7ccccc76)ccc(c52)B4c2c4ccccc4cc4c(-c5ccccc5)c(-c5ccccc5)n-3c24)cc1]

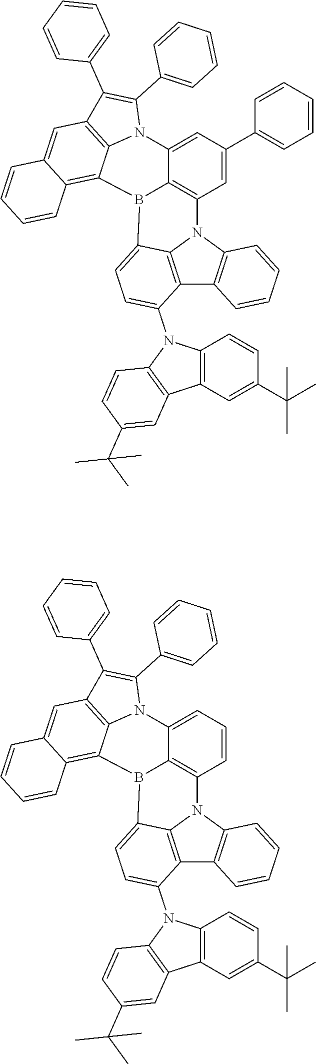 [SMILES: CC(C)(C)c1ccc2c(c1)c1cc(C(C)(C)C)ccc1n2-c1ccc2c3c1c1ccccc1n3-c1cc(-c3ccccc3)cc3c1B2c1c2ccccc2cc2c(-c4ccccc4)c(-c4ccccc4)n-3c12 ; CC(C)(C)c1ccc2c(c1)c1cc(C(C)(C)C)ccc1n2-c1ccc2c3c1c1ccccc1n3-c1cccc3c1B2c1c2ccccc2cc2c(-c4ccccc4)c(-c4ccccc4)n-3c12]

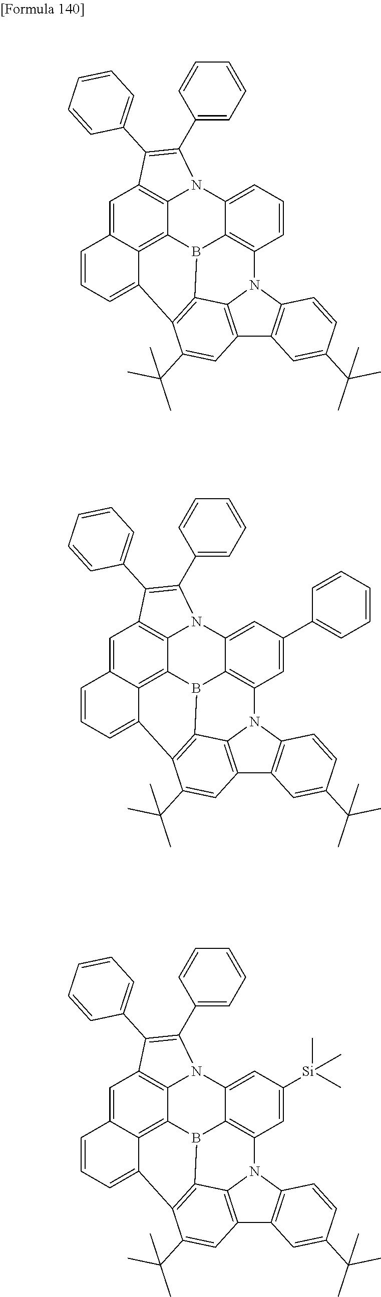 [SMILES: CC(C)(C)c1ccc2c(c1)c1cc(C(C)(C)C)c3c4c1n2-c1cccc2c1B4c1c4c-3cccc4cc3c(-c4ccccc4)c(-c4ccccc4)n-2c13 ; CC(C)(C)c1ccc2c(c1)c1cc(C(C)(C)C)c3c4c1n2-c1cc(-c2ccccc2)cc2c1B4c1c4c-3cccc4cc3c(-c4ccccc4)c(-c4ccccc4)n-2c13 ; CC(C)(C)c1ccc2c(c1)c1cc(C(C)(C)C)c3c4c1n2-c1cc([Si](C)(C)C)cc2c1B4c1c4c-3cccc4cc3c(-c4ccccc4)c(-c4ccccc4)n-2c13]

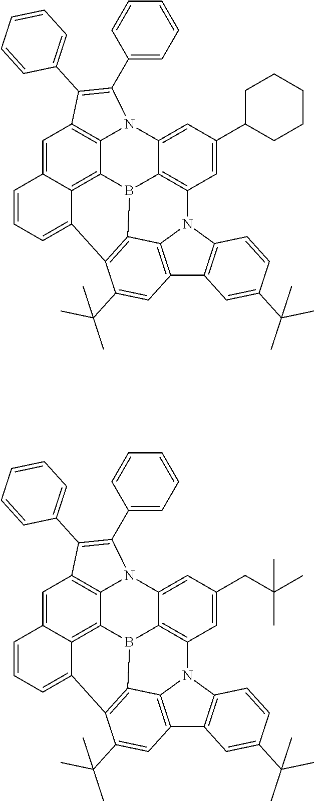 [SMILES: CC(C)(C)c1ccc2c(c1)c1cc(C(C)(C)C)c3c4c1n2-c1cc(C2CCCCC2)cc2c1B4c1c4c-3cccc4cc3c(-c4ccccc4)c(-c4ccccc4)n-2c13 ; CC(C)(C)Cc1cc2c3c(c1)-n1c4ccc(C(C)(C)C)cc4c4cc(C(C)(C)C)c5c(c41)B3c1c3c-5cccc3cc3c(-c4ccccc4)c(-c4ccccc4)n-2c13]

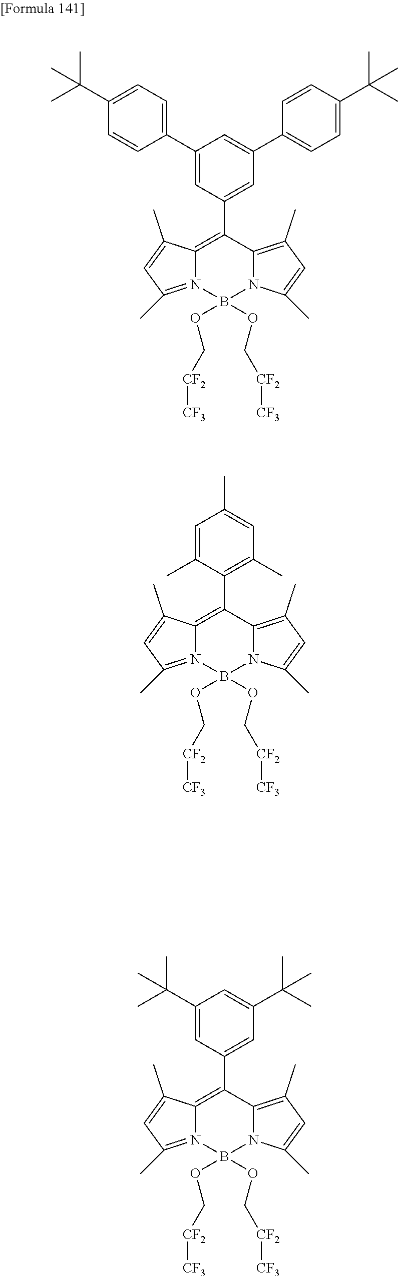

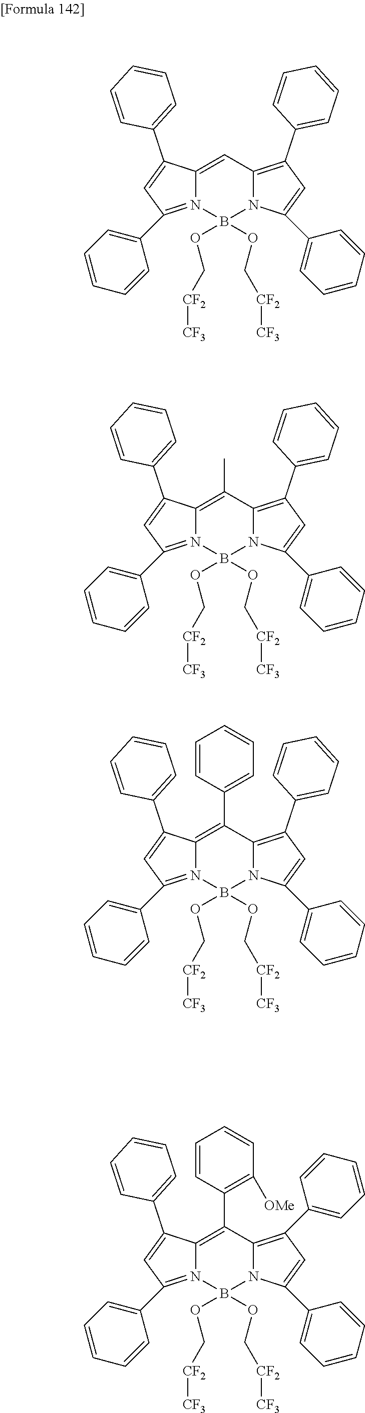

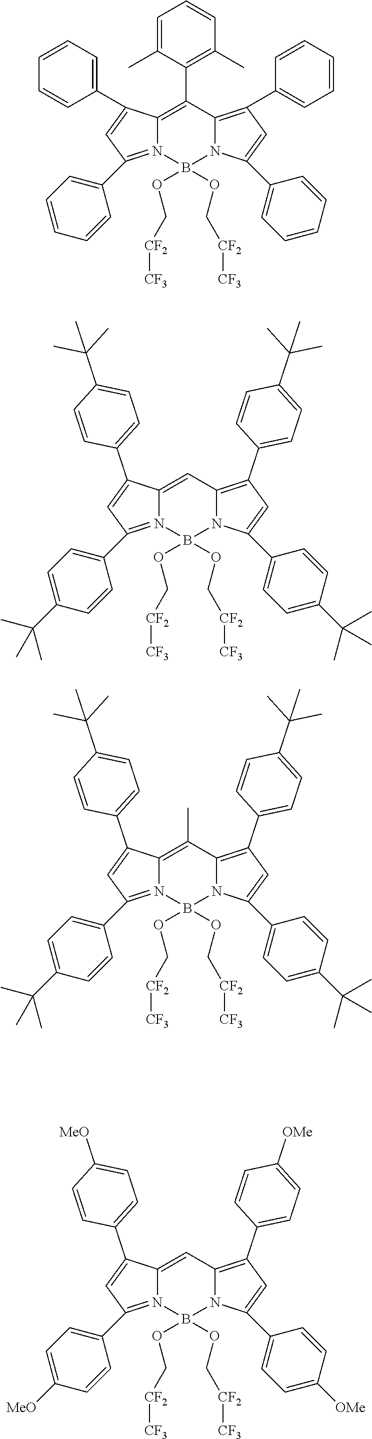

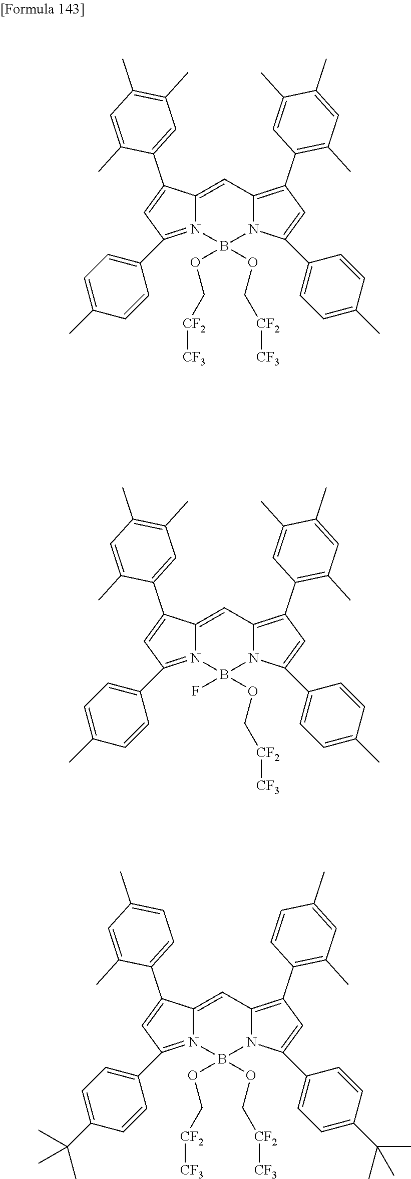

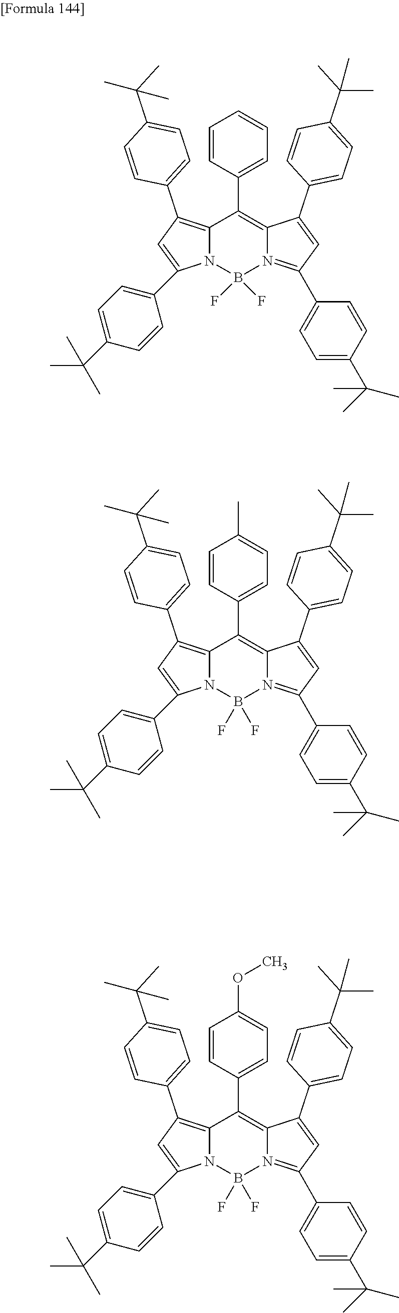

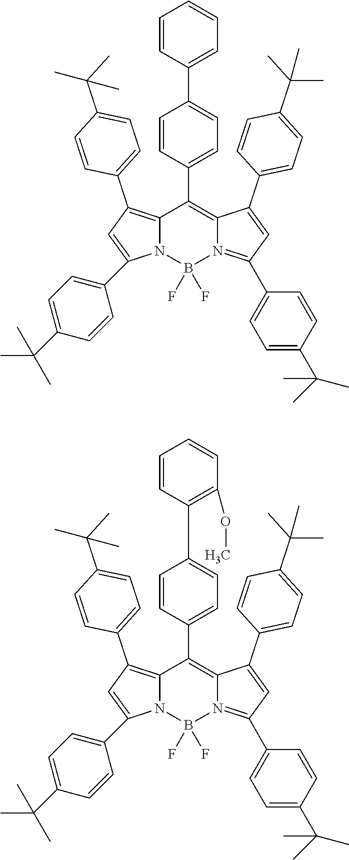

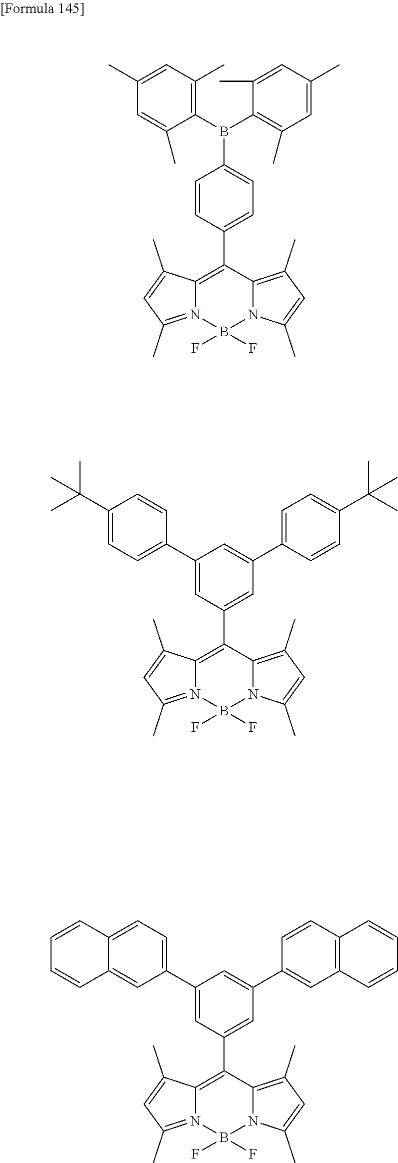

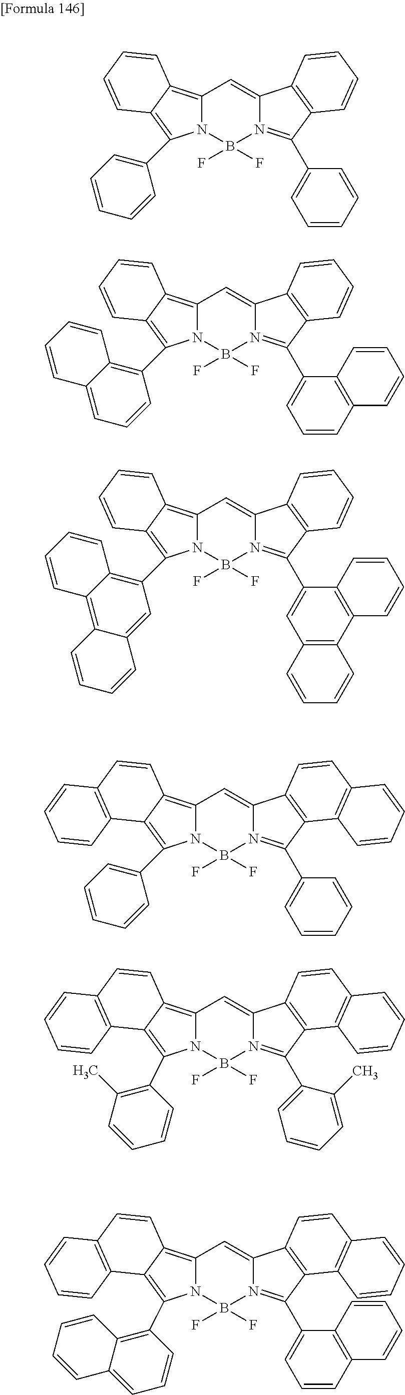

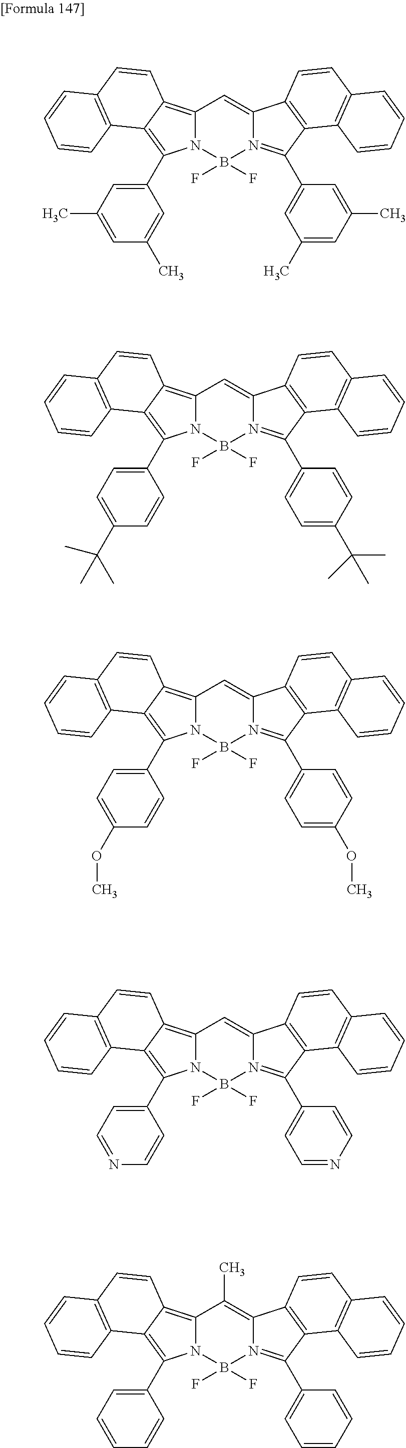

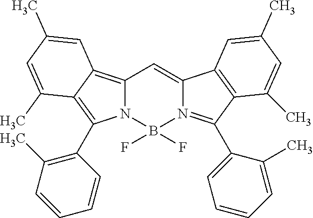

When the compound M1 is a fluorescent compound, the compound M1 preferably emits light having a maximum peak wavelength in a range from 400 nm to 700 nm.

Herein, the maximum peak wavelength means a peak wavelength of a fluorescence spectrum exhibiting a maximum luminous intensity among fluorescence spectra measured in a toluene solution in which a measurement target compound is dissolved at a concentration ranging from 10⁻⁶ mol/l to 10⁻⁵ mol/l. A spectrophotofluorometer (F-7000 produced by Hitachi High-Tech Science Corporation) is used as a measurement apparatus.

The compound M1 preferably exhibits red or green light emission.

Herein, the red light emission refers to light emission in which the maximum peak wavelength of fluorescence spectrum is in a range from 600 nm to 660 nm.

When the compound M1 is a red fluorescent compound, the maximum peak wavelength of the compound M1 is preferably in a range from 600 nm to 660 nm, more preferably in a range from 600 nm to 640 nm, and still more preferably in a range from 610 nm to 630 nm.

Herein, the green light emission refers to light emission in which the maximum peak wavelength of fluorescence spectrum is in a range from 500 nm to 560 nm.

When the compound M1 is a green fluorescent compound, the maximum peak wavelength of the compound M1 is preferably in a range from 500 nm to 560 nm, more preferably in a range from 500 nm to 540 nm, and still more preferably in a range from 510 nm to 540 nm.

Herein, the blue light emission refers to light emission in which the maximum peak wavelength of fluorescence spectrum is in a range from 430 nm to 480 nm.

When the compound M1 is a blue fluorescent compound, the maximum peak wavelength of the compound M1 is preferably in a range from 430 nm to 480 nm, more preferably in a range from 440 nm to 480 nm.

The maximum peak wavelength of light emitted from the organic EL device is measured as follows.

Voltage is applied to the organic EL device such that a current density becomes 10 mA/cm², where spectral radiance spectrum is measured by a spectroradiometer CS-2000 (manufactured by Konica Minolta, Inc.).

A peak wavelength of an emission spectrum, at which the luminous intensity of the resultant spectral radiance spectrum is at the maximum, is measured and defined as the maximum peak wavelength (unit: nm).

### Relationship Between Compound M1 and Compound M2 in Emitting Layer

In the organic EL device according to the exemplary embodiment, a singlet energy S₁(Mat2) of the compound M2 as a delayed fluorescent compound and a singlet energy S₁(Mat1) of the fluorescent compound M1 preferably satisfy a relationship of a numerical formula (Numerical Formula 3) below.

S₁(Mat2)>S₁(Mat1) (Numerical Formula 3)

An energy gap T_{77K}(Mat2) at 77K of the compound M2 and an energy gap T_{77K}(Mat1) at 77K of the compound M1 preferably satisfy a relationship of a numerical formula (Numerical Formula 3A) below.

T_{77K}(Mat2)>T_{77K}(Mat1) (Numerical Formula 3A)

It is preferable that mainly the fluorescent compound M1 emits light in the emitting layer when the organic EL device of the exemplary embodiment emits light.

### Relationship Between Triplet Energy and Energy Gap at 77K

Here, a relationship between a triplet energy and an energy gap at 77K will be described. In the exemplary embodiment, the energy gap at 77K is different from a typical triplet energy in some aspects.

The triplet energy is measured as follows. First, a solution in which a compound (measurement target) is dissolved in an appropriate solvent is encapsulated in a quartz glass tube to prepare a sample. A phosphorescence spectrum (ordinate axis: phosphorescent luminous intensity, abscissa axis: wavelength) of the measurement sample is measured at a low temperature (77K). A tangent is drawn to the rise of the phosphorescence spectrum close to the short-wavelength region. The triplet energy is calculated by a predetermined conversion equation based on a wavelength value at an intersection of the tangent and the abscissa axis.

Herein, among the compounds of the exemplary embodiment, the thermally activated delayed fluorescent compound is preferably a compound having a small ΔST. When ΔST is small, intersystem crossing and inverse intersystem crossing are likely to occur even at a low temperature (77K), so that the singlet state and the triplet state coexist. As a result, the spectrum to be measured in the same manner as the above includes emission from both the singlet state and the triplet state. Although it is difficult to distinguish from which state, the singlet state or the triplet state, light is emitted, the value of the triplet energy is basically considered dominant.

Accordingly, in the exemplary embodiment, the triplet energy is measured by the same method as a typical triplet energy T, but a value measured in the following manner is referred to as an energy gap T_{77K} in order to differentiate the measured energy from the typical triplet energy in a strict meaning. The measurement target compound is dissolved in EPA (diethylether:isopentane:ethanol=5.5:2 in volume ratio) at a concentration of 10 μmol/L, and the obtained solution is put in a quartz cell to provide a measurement sample. A phosphorescence spectrum (ordinate axis: phosphorescent luminous intensity, abscissa axis: wavelength) of the sample is measured at a low temperature (77K). A tangent is drawn to the rise of the phosphorescence spectrum close to the short-wavelength region. An energy amount is calculated by a conversion equation (F1) below based on a wavelength value λ_{edge} [nm] at an intersection of the tangent and the abscissa axis and is defined as an energy gap T_{77K} at 77K.

T_{77K} [eV]=1239.85/λ_{edge} Conversion Equation (F1):

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 (produced by Hitachi High-Technologies Corporation) is usable. Any apparatus for phosphorescence measurement is usable. A combination of a cooling unit, a low temperature container, an excitation light source and a tight-receiving unit may be used for phosphorescence measurement.

### Singlet Energy S₁

A method of measuring the singlet energy Si with use of a solution (occasionally referred to as a solution method) is exemplified by a method below.

A toluene solution of a measurement target compound at a concentration of 10 μmol/L is prepared and put in a quartz cell. An absorption spectrum (ordinate axis: absorption intensity, abscissa axis: wavelength) of the thus-obtained sample is measured at a normal temperature (300K). A tangent is drawn to the fall of the absorption spectrum close to the long-wavelength region, and a wavelength value λ_{edge} [nm] at an intersection of the tangent and the abscissa axis is assigned to a conversion equation (F2) below to calculate the singlet energy.

S₁ [eV]=1239.85/λ_{edge} Conversion Equation (F2):

Any apparatus for measuring absorption spectrum is usable. For instance, a spectrophotometer (U3310 produced by Hitachi. Ltd.) is usable.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased) A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

In the exemplary embodiment, a difference (S₁−T_{77K}) between the singlet energy S₁ and the energy gap T_{77K} at 77K is defined as ΔST.

In the exemplary embodiment, a difference ΔST(Mat2) between the singlet energy S₁(Mat2) of the compound M2 and the energy gap T_{77K}(Mat2) at 77K of the compound M2 is preferably less than 0.3 eV, more preferably less than 0.2 eV, still more preferably less than 0.1 eV, and still further more preferably less than 0.01 eV. That is, ΔST(Mat2) preferably satisfies a relationship of one of numerical formulae (Numerical Formula 1A) to (Numerical Formula 1D) below.

$$Δ ST ( Mat 2 ) = {S}_{1} ( Mat 2 ) - {T}_{77 K} ( Mat 2 ) < 0.3 eV \qquad ( Numerical Formula 1 A )$$

$$Δ ST ( Mat 2 ) = {S}_{1} ( Mat 2 ) - {T}_{77 K} ( Mat 2 ) < 0.2 eV \qquad ( Numerical Formula 1 B )$$

$$Δ ST ( Mat 2 ) = {S}_{1} ( Mat 2 ) - {T}_{77 K} ( Mat 2 ) < 0.1 eV \qquad ( Numerical Formula 1 C )$$

$$Δ ST ( Mat 2 ) = {S}_{1} ( Mat 2 ) - {T}_{77 K} ( Mat 2 ) < 0.01 eV \qquad ( Numerical Formula 1 D )$$

The organic EL device according to the exemplary embodiment preferably emits red light or green light.

When the organic EL device according to the exemplary embodiment emits green light, the maximum peak wavelength of light emitted from the organic EL device is preferably in a range from 500 nm to 560 nm.

When the organic EL device according to the exemplary embodiment emits red light, the maximum peak wavelength of light emitted from the organic EL device is preferably in a range from 600 nm to 660 nm.

When the organic EL device according to the exemplary embodiment emits blue light, the maximum peak wavelength of light emitted from the organic EL device is preferably in a range from 430 nm to 480 nm.

The maximum peak wavelength of light emitted from the organic EL device is measured as follows.

Voltage is applied to the organic EL device such that a current density becomes 10 mA/cm², where spectral radiance spectrum is measured by a spectroradiometer CS-2000 (manufactured by Konica Minolta, Inc.).

A peak wavelength of an emission spectrum, at which the luminous intensity of the resultant spectral radiance spectrum is at the maximum, is measured and defined as the maximum peak wavelength (unit: nm).

### Film Thickness of Emitting Layer

A film thickness of the emitting layer of the organic EL device according to the exemplary embodiment is preferably in a range from 5 nm to 50 nm: more preferably in a range from 7 nm to 50 nm, most preferably in a range from 10 nm to 50 nm. A film thickness of the emitting layer of 5 nm or more facilitates the formation of the emitting layer and the adjustment of the chromaticity. A film thickness of the emitting layer of 50 nm or less easily inhibits an increase in the drive voltage.

### Content Ratios of Compounds in Emitting Layer

For instance, the content ratios of the compound M2 and the compound M1 in the emitting layer preferably fall within ranges shown below.

The content ratio of the compound M2 is preferably in a range from 10 mass % to 80 mass %, more preferably in a range from 10 mass % to 60 mass %, and still more preferably in a range from 20 mass % to 60 mass %.

The content ratio of the compound M1 is preferably in a range from 0.01 mass % to 10 mass %, more preferably in a range from 0.01 mass % to 5 mass %, and still more preferably in a range from 0.01 mass % to 1 mass %.

It should be noted that the emitting layer of the exemplary embodiment may contain any other material than the compound M2 and the compound M1.

The emitting layer may contain a single type of the compound M2 or may contain two or more types of the compound M2. The emitting layer may contain a single type of the compound M1 or may contain two or more types of the compound M1.

### TADF Mechanism

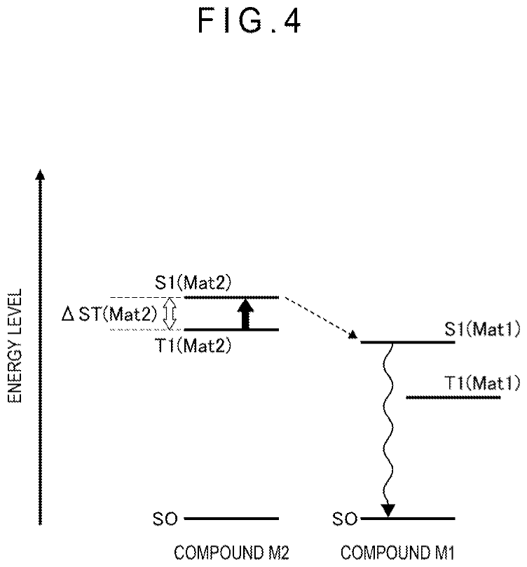

FIG. 4 illustrates an example of a relationship between energy levels of the compound M2 and the compound M1 in the emitting layer. In FIG. 4, S0 represents a ground state. S1(Mat2) represents a lowest singlet state of the compound M2. T1(Mat2) represents a lowest triplet state of the compound M2. S1(Mat1) represents a lowest singlet state of the compound M1. T1(Mat1) represents a lowest triplet state of the compound M1.

A dashed arrow directed from S1(Mat2) to S1(Mat1) in FIG. 4 represents Forster energy transfer from the lowest singlet state of the compound M2 to the lowest singlet state of the compound M1

As illustrated in FIG. 4, when a compound having a small ΔST(Mat2) is used as the compound M2, inverse intersystem crossing from the lowest triplet state T1(Mat1) to the lowest singlet state S1(Mat2) can be caused by heat energy. Subsequently, Forster energy transfer from the lowest singlet state S1(Mat2) of the compound M2 to the compound M1 occurs to generate the lowest singlet state S1(Mat1). Consequently, fluorescence from the lowest singlet state S1(Mat1) of the compound M1 can be observed. It is inferred that the internal quantum efficiency can be theoretically raised up to 100% also by using delayed fluorescence by the TADF mechanism.

According to the first exemplary embodiment, there can be provided an organic EL device excellent in performance, specifically, capable of achieving at least one of low voltage, high efficiency, or long lifetime.

The organic EL device according to the first exemplary embodiment is applicable to an organic electroluminescence display device (hereinafter, occasionally referred to as organic EL display device).

The organic EL device according to the first, exemplary embodiment is applicable to an electronic device such as a display device and a light-emitting unit.

### Arrangement of Organic EL Device

An arrangement of the organic EL device 1 will be further detailed. It should be noted that the reference numerals are occasionally omitted below.

### Substrate

The substrate is used as a support for the organic EL device. For instance, glass, quartz, plastics and the like are usable for the substrate. A flexible substrate is also usable. The flexible substrate is a bendable substrate, which is exemplified by a plastic substrate Examples of the material for the plastic substrate include polycarbonate, polyarylate, polyethersulfone, polypropylene, polyester, polyvinyl fluoride, polyvinyl chloride, polyimide, and polyethylene naphthalate. Further, an inorganic vapor deposition film is also usable

### Anode

Metal, an alloy, an electrically conductive compound, a mixture thereof, or the like having a large work function (specifically, 4.0 eV or more) is preferably used as the anode formed on the substrate. Specific examples of the material include ITO (Indium Tin Oxide), indium oxide tin oxide containing silicon or silicon oxide, indium oxide-zinc oxide, indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), and nitrides of a metal material (e.g., titanium nitride) are usable.

The material is typically formed into a film by a sputtering method. For instance, the indium oxide-zinc oxide can be formed into a film by the sputtering method using a target in which zinc oxide in a range from 1 mass % to 10 mass % is added to indium oxide. Moreover, for instance, the indium oxide containing tungsten oxide and zinc oxide can be formed by the sputtering method using a target in which tungsten oxide in a range from 0.5 mass % to 5 mass % and zinc oxide in a range from 0.1 mass % to 1 mass % are added to indium oxide. In addition, the anode may be formed by a vacuum deposition method, a coating method, an inkjet method, a spin coating method or the like

Among the EL layers formed on the anode, since the hole injecting layer adjacent to the anode is formed of a composite material into which holes are easily injectable irrespective of the work function of the anode, a material usable as an electrode material (e.g., metal, an alloy, an electroconductive compound, a mixture thereof, and the elements belonging to the group 1 or 2 of the periodic table) is also usable for the anode.

The elements belonging to the group 1 or 2 of the periodic table, which are a material having a small work function, specifically, an alkali metal such as lithium (Li) and cesium (Cs), an alkaline earth metal such as magnesium (Mg), calcium (Ca) and strontium (Sr), an alloy containing the alkali metal and the alkaline earth metal (e.g., MgAg, AlLi), a rare earth metal such as europium (Eu) and ytterbium (Yb), and an alloy containing the rare earth metal are usable for the anode. It should be noted that the vacuum deposition method and the sputtering method are usable for forming the anode using the alkali metal, alkaline earth metal and the alloy thereof. Further, when a silver paste is used for the anode, the coating method and the inkjet method are usable.

### Cathode

It is preferable to use metal, an alloy, an electroconductive compound, a mixture thereof, or the like having a small work function (specifically, 3.8 eV or less) for the cathode. Examples of materials for the cathode include elements belonging to the group 1 or 2 of the periodic table, specifically, an alkali metal such as lithium (Li) and cesium (Cs), an alkaline earth metal such as magnesium (Mg), calcium (Ca) and strontium (Sr), an alloy containing the alkali metal and the alkaline earth metal (e.g., MgAg, AlLi), a rare earth metal such as europium (Eu) and ytterbium (Yb), and an alloy containing the rare earth metal.

It should be noted that the vacuum deposition method and the sputtering method are usable for forming the cathode using the alkali metal, alkaline earth metal and the alloy thereof. Further, when a silver paste is used for the cathode, the coating method and the inkjet method are usable.

By providing the electron injecting layer, various conductive materials such as Al, Ag, ITO, graphene, and indium oxide-tin oxide containing silicon or silicon oxide may be used for forming the cathode regardless of the work function. The conductive materials can be formed into a film using the sputtering method, inkjet method, spin coating method and the like.

### Hole Injecting Layer

The hole injecting layer is a layer containing a substance exhibiting a high hole injectability. Examples of the substance exhibiting a high hole injectability include molybdenum oxide, titanium oxide, vanadium oxide, rhenium oxide, ruthenium oxide, chrome oxide, zirconium oxide, hafnium oxide, tantalum oxide, silver oxide, tungsten oxide, and manganese oxide.

In addition, the examples of the highly hole-injectable substance include: an aromatic amine compound, which is a low-molecule organic compound, such that 4,4′,4″-Iris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl(abbreviation: DPAB), 4,4′-bis(N-4-[N′-(3-methylphenyl)-N′-phenylamino]phenyl-N-phenylamino)biphenyl (abbreviation: DNTPD), 1,3,5-iris[N-(4-diphenylaminophenyl-N-phenylamino]benzene (abbreviation: DPA3B), 3-[N-(9-phenylcarbazate-3-yl)-N-phenylamino]-9-phenylcarbazole (abbreviation: PCzPCA1), 3,6-bis[N-(9-phenylcarbazole-3-yl)-N-phenylamino]-9-phenylcarbazole (abbreviation: PCzPCA2), and 3-[N-(1-naphthyl)-N-(9-phenylcarbazole-3-yl)amino]-9-phenylcarbazole (abbreviation: PCzPCN1); and dipyrazino[2,3-f:20,30-h]quinoxaline-2,3,6,7,10,11-hexacarbonitrile (HAT-CN).

In addition, a high polymer compound (e.g., oligomer, dendrimer and polymer) is usable as the substance exhibiting a high hole injectability. Examples of the high-molecule compound include poly(N-vinylcarbazole) (abbreviation: PVK), poly(4-vinyltriphenylamine) (abbreviation: PVTPA), poly[N-(4-N′-[4-(4-diphenylamino)phenyl]phenyl-N′-phenylaminophenyl)methacrylamide](abbreviation: PTPDMA), and poly[N,N′-bis(4-butylphenyl)-N,N′-bis(phenyl)benzidine] (abbreviation: Poly-TPD). Moreover, an acid-added high polymer compound such as poly(3,4-ethylenedioxythiophene)/poly(styrene sulfonic acid) (PEDOT/PSS) and polyaniline/poly(styrene sulfonic acid) (PAni/PSS) is also usable.

### Hole Transporting Layer

The hole transporting layer is a layer containing a highly hole-transporting substance. An aromatic amine compound, carbazole derivative, anthracene derivative and the like are usable for the hole transporting layer. Specific examples of a material for the hole transporting layer include 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4-phenyl-4′-(9-phenylfluorene-9-yl)triphenylamine (abbreviation: BAFLP), 4,4-bis[N-(9,9-dimethylfluorene-2-yl)-N-phenylamino]biphenyl (abbreviation: DFLDPBi), 4,4′,4′-tris(N,N-diphenylamino)triphenylamine (abbreviation: TDATA): 4,4′,4″-tris[N-(3-methylphenyl)-N-phenylamino]triphenylamine (abbreviation: MTDATA), and 4,4′-bis[N-(spiro-9,9′-bifluorene-2-yl)-N-phenylamino]biphenyl (abbreviation: BSPB). The above-described substances mostly have a hole mobility of 10⁻⁶ cm²/Vs or more.

For the hole transporting layer, a carbazole derivative such as CBP, 9-[4-(N-carbazolyl)]phenyl]-9H-phenylanthracene (CzPA), and 9-phenyl-3-[4-(10-phenyl-9-anthryl)phenyl]-9H-carbazole (PCzPA) and an anthracene derivative such as t-BuDNA, DNA, and DPAnth may be used A high polymer compound such as poly(N-vinylcarbazole) (abbreviation: PVK) and poly(4-vinyltriphenylamine) (abbreviation: PVTPA) is also usable.

However, in addition to the above substances, any substance exhibiting a higher hole transportability than an electron transportability may be used. It should be noted that the layer containing the substance exhibiting a high hole transportability may be not only a single layer but also a laminate of two or more layers formed of the above substance(s).

When the hole transporting layer includes two or more layers, one of the layers with a larger energy gap is preferably provided closer to the emitting layer.

### Electron Transporting Layer

The electron transporting layer is a layer containing a highly electron-transporting substance. For the electron transporting layer, 1) a metal complex such as an aluminum complex, beryllium complex, and zinc complex, 2) a hetero aromatic compound such as an imidazole derivative, benzimidazole derivative, azine derivative, carbazole derivative, and phenanthroline derivative, and 3) a high polymer compound are usable. Specifically, as a low-molecule organic compound, a metal complex such as Alq, tris(4-methyl-8-quinolinolato)aluminum (abbreviation: Almq₃), bis(10-hydroxybenzo[h]quinolinato)beryllium (abbreviation: BeBq₂), BAlq, Znq, ZnPBO and ZnBTZ is usable. In addition to the metal complex, a hetermaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7) 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl)stilbene (abbreviation. BzOs) is usable. In the present exemplary embodiment, a benzimidazole compound is preferably usable. The above-described substances mostly have an electron mobility of 10⁻⁶ cm²/(V·s) or more. It should be noted that any other substance than the above substance may be used for the electron transporting layer as long as the substance exhibits a higher electron transportability than the hole transportability. The electron transporting layer may be provided in the form of a single layer or a laminate of two or more layers of the above substance(s).

Further, a high polymer compound is usable for the electron transporting layer. For instance, poly[(9,9-dihexylfluorene-2,7-diyl)-co-(pyndine-3,5-diyl)](abbreviation: PF-Py), poly[(9,9-dioctylfluorene-2,7-diyl)-co-(2,2′-bipyridine-6,6′-diyl)](abbreviation: PF-BPy) and the like are usable.

### Electron Injecting Layer

The electron injecting layer is a layer containing a highly electron-injectable substance. Examples of a material for the electron injecting layer include an alkali metal, alkaline earth metal and a compound thereof, examples of which include lithium (Li), cesium (Cs), calcium (Ca), lithium fluoride (LiF), cesium fluoride (CsF), calcium fluoride (CaF₂), and lithium oxide (LiOx). In addition, the alkali metal, alkaline earth metal or the compound thereof may be added to the substance exhibiting the electron transportability in use. Specifically, for instance, magnesium (Mg) added to Alq may be used. In this case, the electrons can be more efficiently injected from the cathode.

Alternatively, the electron injecting layer may be provided by a composite material in a form of a mixture of the organic compound and the electron donor. Such a composite material exhibits excellent electron injectability and electron transportability since electrons are generated in the organic compound by the electron donor. In this case, the organic compound is preferably a material excellent in transporting the generated electrons. Specifically, the above examples (e.g., the metal complex and the hetero aromatic compound) of the substance forming the electron transporting layer are usable. As the electron donor, any substance exhibiting electron donating property to the organic compound is usable. Specifically, the electron donor is preferably alkali metal, alkaline earth metal and rare earth metal such as lithium, cesium, magnesium, calcium, erbium and ytterbium. The electron donor is also preferably alkali metal oxide and alkaline earth metal oxide such as lithium oxide, calcium oxide, and barium oxide. Moreover, a Lewis base such as magnesium oxide is usable. Further, the organic compound such as tetrathiafulvalene (abbreviation: TTF) is usable.

The organic EL device 1 of the exemplary embodiment includes, between the anode 3 and the emitting layer 5, a hole transporting zone including at least one organic layer. The hole transporting zone illustrated in FIG. 1 is provided by the first layer 61 and the anode-side organic layer 63. The hole transporting zone preferably includes a plurality of organic layers.

### Layer Formation Method

A method for forming each layer of the organic EL device in the exemplary embodiment is subject to no limitation except for the above particular description. However, known methods of dry film-forming such as vacuum deposition, sputtering, plasma or ion plating and wet film-forming such as spin coating, dipping, flow coating or ink-jet are applicable.

### Film Thickness

A thickness of each of the organic layers in the organic EL device according to the exemplary embodiment is not limited except for the above particular description. In general, the thickness preferably ranges from several nanometers to 1 μm because excessively small film thickness is likely to cause defects (e.g. pin holes) and excessively large thickness leads to the necessity of applying high voltage and consequent reduction in efficiency.

### Second Exemplary Embodiment

An arrangement of an organic EL device according to a second exemplary embodiment will be described below. In the description of the second exemplary embodiment, the same components as those in the first exemplary embodiment are denoted by the same reference signs and names to simplify or omit an explanation of the components. In the second exemplary embodiment, the same materials and compounds as described in the first exemplary embodiment are usable, unless otherwise specified.

The organic EL device according to the second exemplary embodiment is different from the organic EL device according to the first exemplary arrangement in that the emitting layer contains the compound M3 in addition to the delayed fluorescent compound M2 and the fluorescent compound M1. The second exemplary embodiment is the same as the first exemplary embodiment in other respects.

Specifically, in the organic EL device of the second exemplary embodiment, the emitting layer contains the delayed fluorescent compound M2, the fluorescent compound M1, and the compound M3; the first layer contains the first compound; the ionization potential of the first compound Ip(HT1) satisfies the numerical formula (Numerical Formula 1); and the hole mobility of the first compound μh(HT1) satisfies the numerical formula (Numerical Formula 2). The first layer has a film thickness of 15 nm or more.

In the second exemplary embodiment, the compound M2 in the emitting layer is preferably a host material, the compound M1 is preferably a dopant material, and the compound M3 is preferably a host material One of the compound M2 and the compound M3 is occasionally referred to as a first host material, and the other is occasionally referred to as a second host material.

As the compound M2, the compound M2 described in the first exemplary embodiment is usable.

As the compound M1, the compound M1 described in the first exemplary embodiment is usable.

As the first compound, the first compound described in the first exemplary embodiment is usable.

### Compound M3

The compound M3 may be a thermally activated delayed fluorescent compound or a compound exhibiting no thermally activated delayed fluorescence. However, the compound M3 is preferably a compound exhibiting no thermally activated delayed fluorescence.

In the exemplary embodiment, the compound M3 is preferably a compound represented by a formula (3X) or (3Y) below.

### Compound Represented by Formula (3X)

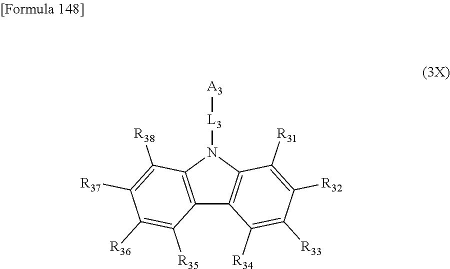

in the formula (3X):
A3 is a substituted or unsubstituted aryl group having 6 to 50 ring carbon atoms, or a substituted or unsubstituted heterocyclic group having 5 to 50 ring atoms.
L₃ is a single bond, a substituted or unsubstituted arylene group having 6 to 50 ring carbon atoms, a substituted or unsubstituted divalent heterocyclic group having 5 to 50 ring atoms, a divalent group formed by bonding two groups selected from the group consisting of a substituted or unsubstituted arylene group having 6 to 50 ring carbon atoms and a substituted or unsubstituted divalent heterocyclic group having 5 to 50 ring atoms, or a divalent group formed by bonding three groups selected from the group consisting of a substituted or unsubstituted arylene group having 6 to 30 ring carbon atoms and a substituted or unsubstituted divalent heterocyclic group having 5 to 30 ring atoms;
at least one combination of adjacent two or more of R₃₁ to R₃₈ are mutually bonded to form a substituted or unsubstituted monocyclic ring, mutually bonded to form a substituted or unsubstituted fused ring, or not mutually bonded; and
R₃₁ to R₃₈ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₃₆)(R₉₃₇), a substituted or unsubstituted aralkyl group having 7 to 50 carbon atoms, a group represented by —C(═O)R₉₀₈, a group represented by —COOR₉₀₉, a halogen atom, a cyano group, a nitro group, a group represented by —P(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, a substituted or unsubstituted heterocyclic group having 5 to 50 ring atoms, or a group represented by a formula (3A) below.

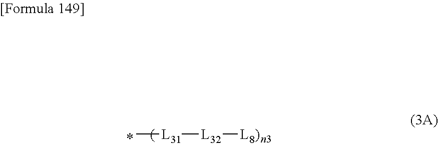

In the formula (3A):
R_{B} is a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a halogen atom, a cyano group, a nitro group, a group represented by —P(═O)(R₉₃₁)(R₉₃), a group represented by —Ge(R₉₃₃)(R₉₃₄)(R₉₃₅) a group represented by —B(R₃₃₆)(R₉₃₇), a substituted or unsubstituted aryl group having 6 to 50 ring carbon atoms, or a substituted or unsubstituted heterocyclic group having 5 to 50 ring atoms;
when a plurality of R_{B} are present, the plurality of R_{B} are mutually the same or different;
L₃₁ is a single bond; a substituted or unsubstituted arylene group having 6 to 50 ring carbon atoms, a trivalent group, tetravalent group, pentavalent group, or hexavalent group derived from the arylene group, a substituted or unsubstituted divalent heterocyclic group having 5 to 50 ring atoms, a trivalent group, tetravalent group, pentavalent group, or hexavalent group derived from the heterocyclic group, or a divalent group formed by bonding two groups selected from the group consisting of a substituted or unsubstituted arylene group having 6 to 50 ring carbon atoms and a substituted or unsubstituted divalent heterocyclic group having 5 to 50 ring atoms, or a trivalent group, tetravalent group, pentavalent group, or hexavalent group derived from the divalent group;
L₃₂ is a single bond; a substituted or unsubstituted arylene group having 6 to 50 ring carbon atoms, a substituted or unsubstituted divalent heterocyclic group having 5 to 50 ring atoms;
n₃ is 1, 2, 3, 4 or 5;
when L₃₁ is a single bond, n₃ is 1 and L₃₂ is bonded to a carbon atom in a six-membered ring in the formula (3X);
when a plurality of L₃₂ are present, the plurality of L₃₂ are mutually the same or different; and
* represents a bonding position to a carbon atom in a six-membered ring in the formula (3X).

In the compound M3, R₉₀₁, R₉₀₂, R₉₀₃, R₉₀₄, R₉₀₅, R₉₀₆, R₉₀₇, R₉₀₈, R₉₀₉, R₉₃₁, R₉₃₂, R₉₃₃, R₉₃₄, R₉₃₅, R₉₃₆ and R₉₃₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆, are mutually the same or different;
when a plurality of R₉₀₇ are present, the plurality of R₉₀₇ are mutually the same or different;
when a plurality of R₉₀₈ are present, the plurality of R₉₀₈ are mutually the same or different.
when a plurality of R₉₀₉ are present, the plurality of R₉₀₉ are mutually the same or different;
when a plurality of R₉₃₁ are present, the plurality of R₉₃₁ are mutually the same or different;
when a plurality of R₉₃₂ are present, the plurality of Rau are mutually the same or different;
when a plurality of R₉₃₃ are present, the plurality of R₉₁₃ are mutually the same or different;
when a plurality of R₉₃₄ are present, the plurality of R₉₃₄ are mutually the same or different;
when a plurality of R₉₃₅ are present, the plurality of R₉₃₅ are mutually the same or different;
when a plurality of R₉₃₆ are present, the plurality of R₉₃₆ are mutually the same or different; and
when a plurality of R₉₃₇ are present, the plurality of R₉₃₇ are mutually the same or different.

The compound M3 is also preferably a compound represented by one of formulae (31) to (36) below.

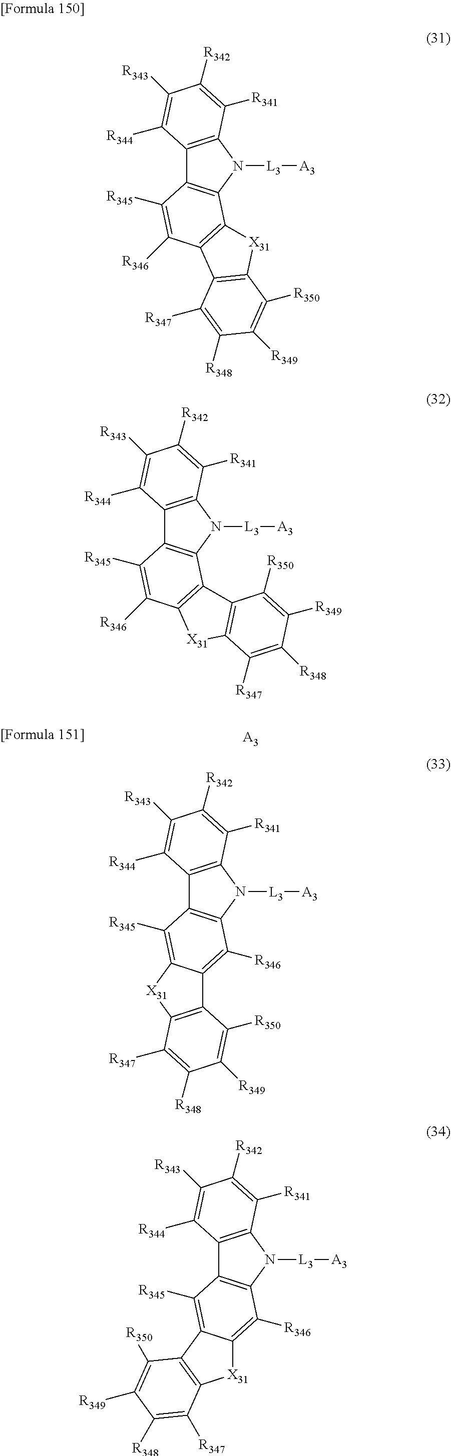

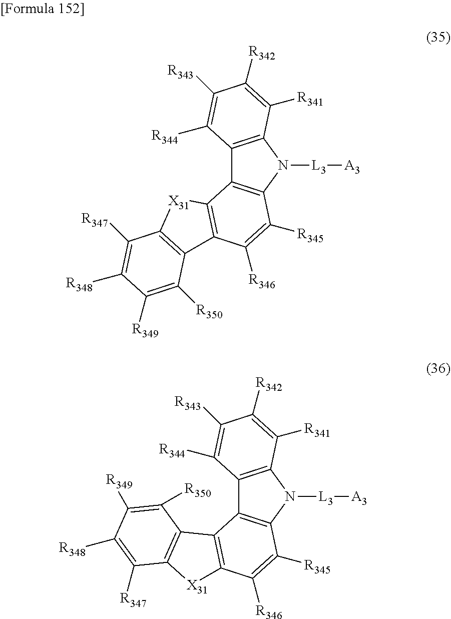

In the formulae (31) to (36):
A₃ and L₃ respectively represent the same as A₃ and L₃ in the formula (3X);
at least one combination of adjacent two or more of R₃₄₁ to R₃₅₀ are mutually bonded to form a substituted or unsubstituted monocyclic ring, mutually bonded to form a substituted or unsubstituted fused ring, or not mutually bonded;
X₃₁ is a sulfur atom, an oxygen atom, NR₃₅₂, or CR₃₅₃R₃₅₄;
a combination of R₃₅₃ and R₃₅₄ are mutually bonded to form a substituted or unsubstituted monocyclic ring, mutually bonded to form a substituted or unsubstituted fused ring, or not mutually bonded; and
R₃₄₁ to R₃₅₀ forming neither the substituted or unsubstituted monocyclic ring nor the substituted or unsubstituted fused ring, R₃₅₂, and R₃₅₃ and R₃₅₄ forming neither the substituted or unsubstituted monocyclic ring nor the substituted or unsubstituted fused ring each independently represent the same as R₃₁ to R₃₈ forming neither the substituted or unsubstituted monocyclic ring nor the substituted or unsubstituted fused ring.

In compound M3, R₃₅₂ is preferably a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In the compound M3, it is preferable that:
a combination of R₃₅₃ and R₃₅₄ are mutually bonded to form a substituted or unsubstituted monocyclic ring, mutually bonded to form a substituted or unsubstituted fused ring, or not mutually bonded; and
R₃₅₃ and R₃₅₄ forming neither the substituted or unsubstituted monocyclic ring nor the substituted or unsubstituted fused ring are each independently a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In the compound M3. X₃₁ is preferably a sulfur atom or an oxygen atom.

In the compound M3, A₃ is preferably a group represented by one of formulae (A31) to (A37) below.

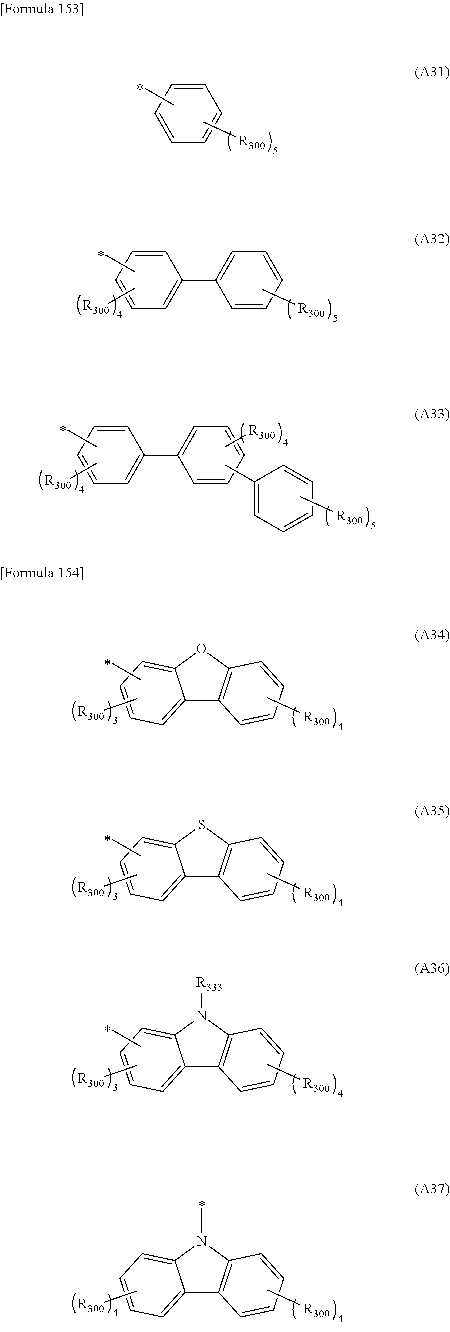

In the formulae (A31) to (A37):
at least one combination of adjacent two or more of a plurality of R₃₀₀ are mutually bonded to form a substituted or unsubstituted monocyclic ring, mutually bonded to form a substituted or unsubstituted fused ring, or not mutually bonded;
R₃₀₀ forming neither the substituted or unsubstituted monocyclic ring nor the substituted or unsubstituted fused ring, and R₃₃₃ each independently represent the same as R₃₁ to R₃₈ forming neither the substituted or unsubstituted monocyclic ring nor the substituted or unsubstituted fused ring; and
* in the formulae (A31) to (A37) each represent a bonding position to L₃ in the compound M3.

In the compound M3, A₃ is also preferably a group represented by the formula (A34), (A35), or (A37).

The compound M3 is also preferably a compound represented by one of formulae (311) to (316) below.

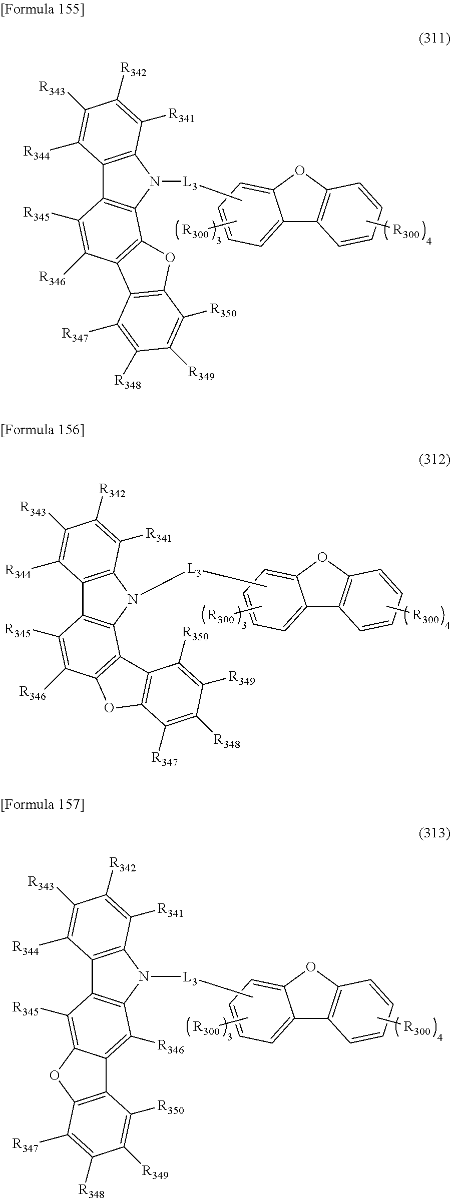

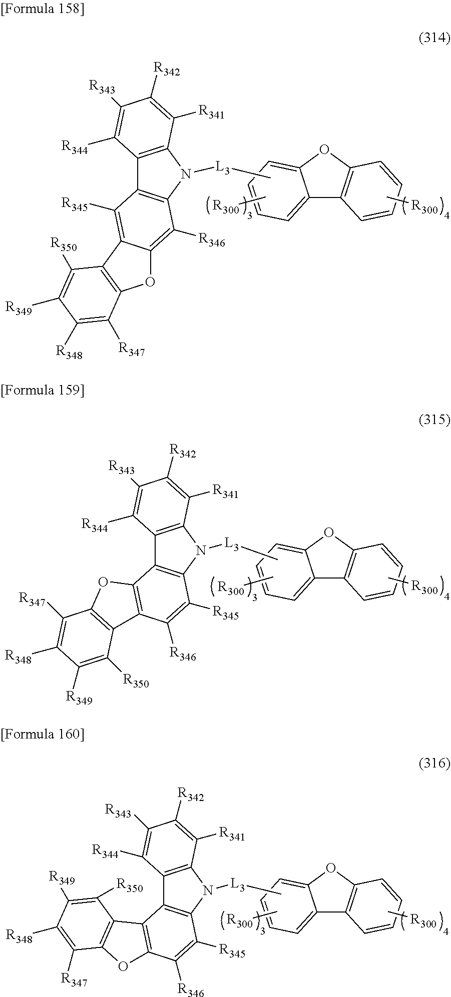

In the formulae (311) to (316):
L₃ represents the same as L₃ in the formula (3X);
at least one combination of adjacent two or more of a plurality of R₃₀₀ are mutually bonded to form a substituted or unsubstituted monocyclic ring, mutually bonded to form a substituted or unsubstituted fused ring, or not mutually bonded;
at least one combination of adjacent two or more of R₃₄₁ to R₃₅₀ are mutually bonded to form a substituted or unsubstituted monocyclic ring, mutually bonded to form a substituted or unsubstituted fused ring, or not mutually bonded; and
R₃₀₀ forming neither the substituted or unsubstituted monocyclic ring nor the substituted or unsubstituted fused ring, and R₃₄₁ to R₃₅₀ forming neither the substituted or unsubstituted monocyclic ring nor the substituted or unsubstituted fused ring each independently represent the same as R₃₁ to R₃₈ forming neither the substituted or unsubstituted monocyclic ring nor the substituted or unsubstituted fused ring.

The compound M3 is also preferably a compound represented by a formula (321) below.

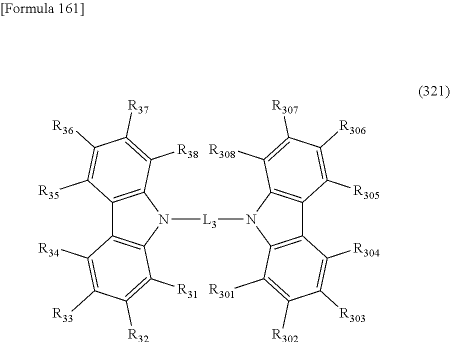

In the formula (321).
L₃ represents the same as L₃ in the formula (3X); and
R₃₁ to R₃₈ and R₃₀₁ to R₃₀₈ each independently represent the same as R₃₁ to R₃₈ forming neither the substituted or unsubstituted monocyclic ring nor the substituted or unsubstituted fused ring.

In the compound M3, L₃ is preferably a single bond or a substituted or unsubstituted arylene group having 6 to 50 ring carbon atoms.

In the compound M3, L₃ is preferably a single bond; a substituted or unsubstituted phenylene group; a substituted or unsubstituted biphenylene group; or a substituted or unsubstituted terphenylene group.

In the compound M3, L₃ is preferably a group represented by a formula (317) below.

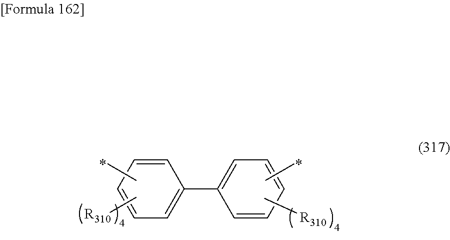

In the formula (317):

R₃₁₀ each independently represent the same as R₃₁ to R₃₈ forming neither the substituted or unsubstituted monocyclic ring nor the substituted or unsubstituted fused ring, and * each independently represent a bonding position.

In the compound M3, L₃ also preferably contains a divalent group represented by a formula (318) or (319) below.

In the compound M3, L₃ is also preferably a divalent group represented by the formula (318) or (319) below.

The compound M3 is also preferably a compound represented by a formula (322) or a formula (323) below.

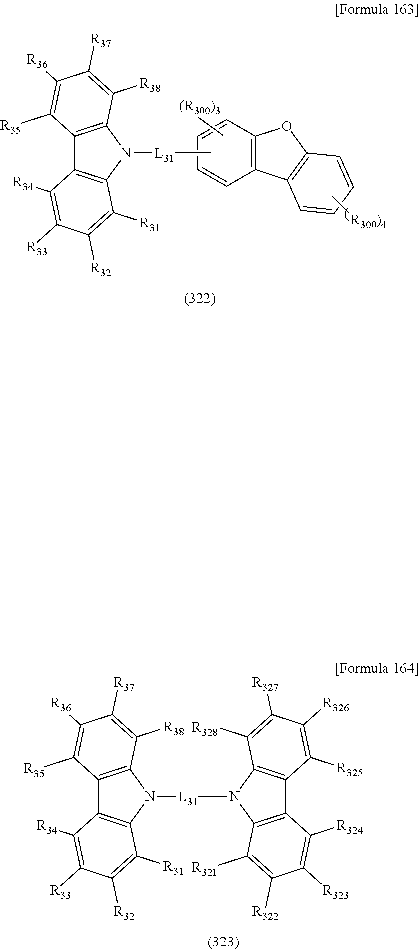

In the formulae (322) and (323):
L₃₁ is a substituted or unsubstituted arylene group having 6 to 50 ring carbon atoms, a substituted or unsubstituted divalent heterocyclic group having 5 to 50 ring atoms, or a divalent group formed by bonding two groups selected from the group consisting of a substituted or unsubstituted arylene group having 6 to 50 ring carbon atoms and a substituted or unsubstituted divalent heterocyclic group having 5 to 50 ring atoms;
L₃₁ includes a divalent group represented by a formula (318) or (319) below; and
R₃₁ to R₃₈, R₃₀₀, and R₃₂₁ to R₃₂₃ each independently represent the same as R₃₁ to R₃₈ forming neither the substituted or unsubstituted monocyclic ring nor the substituted or unsubstituted fused ring.

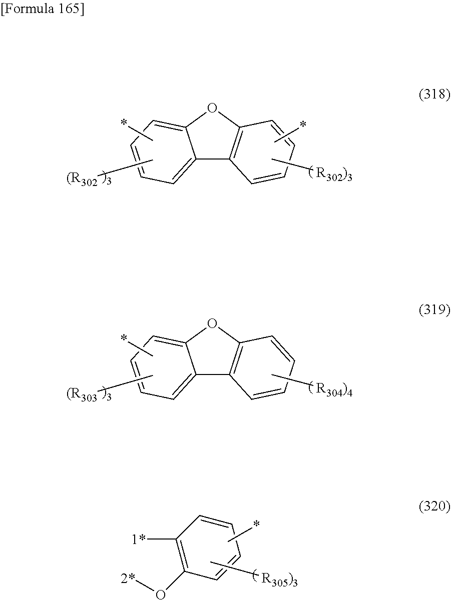

In the formula (319):
a combination of adjacent two of a plurality of R₃₀₄ are mutually bonded to form a ring represented by the formula (320);
in the formulae (320), 1* and 2* each independently represent a bonding position to a ring bonded to R₃₀₄; and
R₃₀₂ in the formula (318), R₃₀₃ in the formula (318), R₃₀₃ in the formula (319), R₃₀₄ forming no ring represented by the formula (320), and R₃₀₅ in the formula (320) each independently represent the same as R₃₁ to R₃₆ forming neither the substituted or unsubstituted monocyclic ring nor the substituted or unsubstituted fused ring; and
* in the formulae (318) to (320) each represent a bonding position.

In the compound M3, the group represented by the formula (319) for L₃ or L₃₁ is, for instance, a group represented by a formula (319A) below

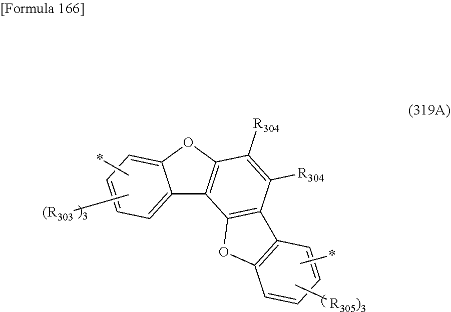

In the formula (319A), R₃₀₃, R₃₀₄, and R₃₀₅ each independently represent the same as R₃₁ to R₃₈ forming neither the substituted or unsubstituted monocyclic ring nor the substituted or unsubstituted fused ring, and * in the formula (319A) each represent a bonding position.

Also preferably, the compound M3 is a compound represented by the formula (322) and L₃₁ is a group represented by the formula (318).

The compound M3 is also preferably a compound represented by a formula (324) below.

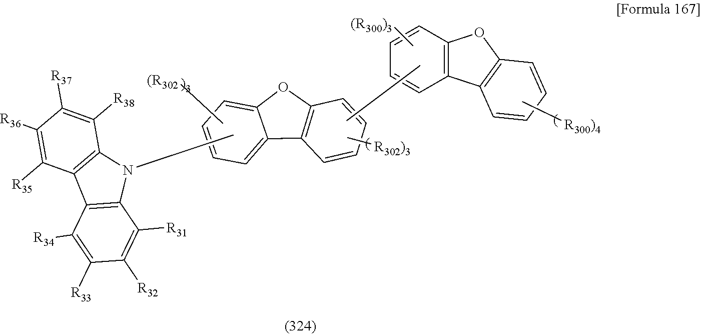

In the formula (324), R₃₁ to R₃₈, R₃₀₀ and R₃₀₂ each independently represent the same as R₃₁ to R₃₈ forming neither the substituted or unsubstituted monocyclic ring nor the substituted or unsubstituted fused ring.

It is preferable that:
R₃₁ to R₃₈ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted aryl group having 6 to 50 ring carbon atoms, a substituted or unsubstituted heterocyclic group having 5 to 50 ring atoms, or a group represented by the formula (3A); and
R_{B} in the formula (3A) is a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

It is preferable that.
R₃₁ to R₃₈ forming neither the substituted or unsubstituted monocyclic ring nor the substituted or unsubstituted fused ring are each independently a hydrogen atom, a substituted or unsubstituted aryl group having 6 to 50 ring carbon atoms, or a group represented by the formula (3A); and
R_{B} in the formula (3A) is a substituted or unsubstituted aryl group having 6 to 50 ring carbon atoms.

It is preferable that:
R₃₁ to R₃₈ forming neither the substituted or unsubstituted monocyclic ring nor the substituted or unsubstituted fused ring are each independently a hydrogen atom, a substituted or unsubstituted phenyl group, or a group represented by the formula (3A); and
R_{B} in the formula (3A) is a substituted or unsubstituted phenyl group.

The compound M3 is also preferably a compound having no pyridine ring, no pyrimidine ring; and no triazine ring.

### Compound Represented by Formula (3Y)

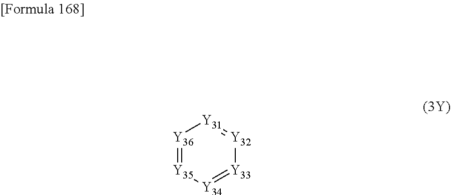

In the formula (3Y):
Y₃₁ to Y₃₆ are each independently CR₃ or a nitrogen atom;
two or more of Y₃₁ to Y₃₆ are each a nitrogen atom;
when a plurality of R₃ are present, at least one combination of adjacent two or more of the plurality of R₃ are mutually bonded to form a substituted or unsubstituted monocyclic ring, mutually bonded to form a substituted or unsubstituted fused ring, or not mutually bonded; and
R₃ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by S—(R₉₀₅), a group represented by —N(R₉₀₆)(R₉₀₇), a substituted or unsubstituted aralkyl group having 7 to 50 carbon atoms, a group represented by —C(O)R₉₀₈, a group represented by —COOR₉₀₉, a halogen atom, a cyano group, a nitro group, a group represented by —P(═O)(R₉₃₁)(R₉₃₂), a group represented by —Ge(R₉₃₃)(R₉₃₄)(R₉₃₅), a group represented by —B(R₉₃₆)(R₉₃), a substituted or unsubstituted aryl group having 6 to 50 ring carbon atoms, a substituted or unsubstituted heterocyclic group having to 50 ring atoms, or a group represented by a formula (3B) below.

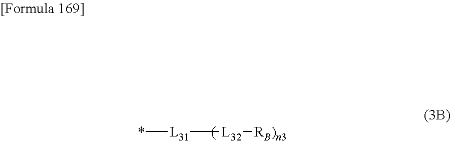

In the formula (3B): R_{B}, L₃₁, L₃₂ and n₃ each independently represent the same as R_{B}, L₃₁, L₃₂ and n₃ in the formula (3A);
when a plurality of R_{B} are present, the plurality of R_{B} are mutually the same or different;
when L₃₁ is a single bond, n₃ is 1 and L₃₂ is bonded to a carbon atom in a six-membered ring in the formula (3Y);
when a plurality of L₃₂ are present, the plurality of L₃₂ are mutually the same or different; and
* represents a bonding position to a carbon atom in a six-membered ring in the formula (3Y).

The compound M3 preferably does not include a pyridine ring in a molecule.

The compound M3 is also preferably a compound represented by a formula (31a) or a formula (32a) below.

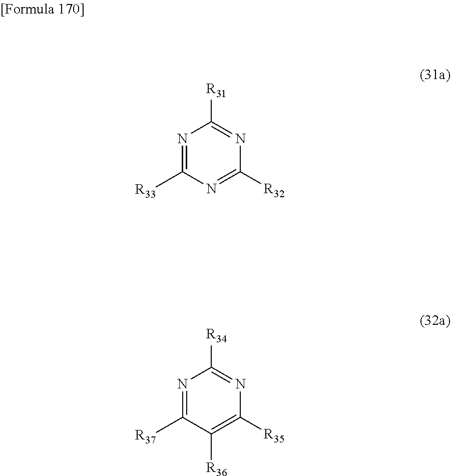

In the formula (32a).
at least one combination of adjacent two or more of R₃₅ to R₃₇ are mutually bonded to form a substituted or unsubstituted monocyclic ring, mutually bonded to form a substituted or unsubstituted fused ring, or not mutually bonded; and
R₃₁ to R₃₃ in the formula (31a), R₃₄ in the formula (32a), and R₃₅ to R₃₇ forming neither the substituted or unsubstituted monocyclic ring nor the substituted or unsubstituted fused ring each independently represent the same as R₃ in the formula (3Y).

The compound M3 is also preferably a compound represented by the formula (31a).
R₃ in the formula (3Y) are preferably each independently a hydrogen atom, a substituted or unsubstituted alkyl group having 1 to 50 carbon atoms, a substituted or unsubstituted aryl group having 6 to 50 ring carbon atoms, a substituted or unsubstituted heterocyclic group having 5 to 50 ring atoms, or a group represented by the formula (3B).

R₃ in the formula (3Y) are preferably each independently a hydrogen atom, a substituted or unsubstituted alkyl group having 1 to 50 carbon atoms, a substituted or unsubstituted aryl group having 6 to 50 ring carbon atoms, or a group represented by the formula (3B).

The compound M3 represented by the formula (3Y) preferably includes, in a molecule, at least one group selected from the group consisting of groups represented by formulae (B31) to (B44) below.

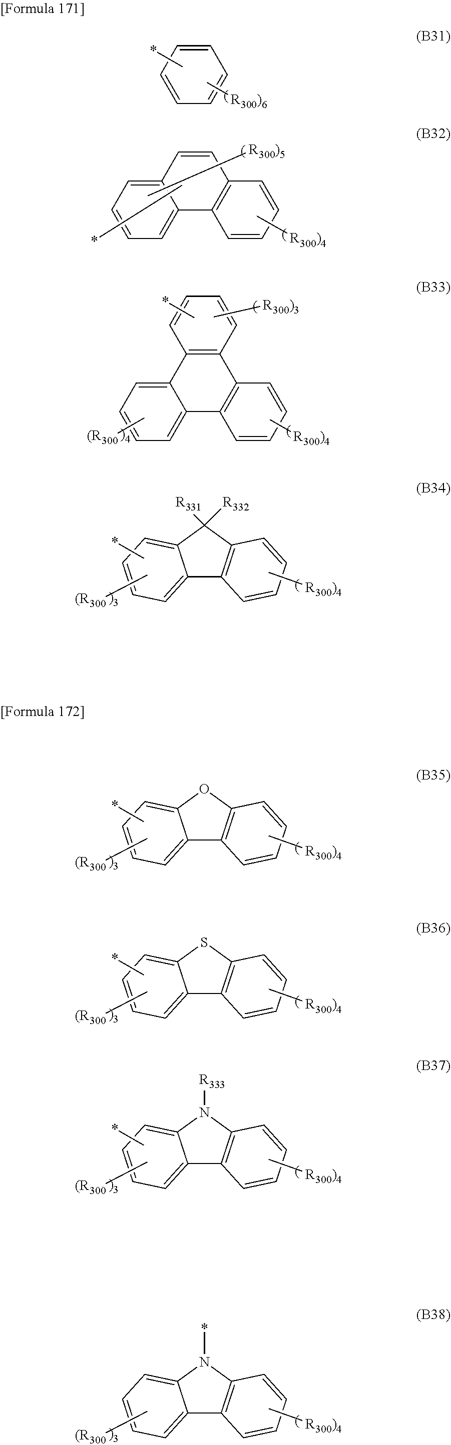

In the formulae (B31) to (B38):
at least one combination of adjacent two or more of a plurality of R₃₀₀ are mutually bonded to form a substituted or unsubstituted monocyclic ring, mutually bonded to form a substituted or unsubstituted fused ring, or not mutually bonded; and
a combination of R₃₃₁ and R₃₃₂ are mutually bonded to form a substituted or unsubstituted monocyclic ring, mutually bonded to form a substituted or unsubstituted fused ring, or not mutually bonded;
R₃₀₀, R₃₃₁ and R₃₃₂ forming neither the substituted or unsubstituted monocyclic ring nor the substituted or unsubstituted fused ring, and R₃₃₃ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(O)R₉₀₆, a group represented by —COOR₉₀₉, a halogen atom, a cyano group, a nitro group, a substituted or unsubstituted aryl group having 6 to 50 ring carbon atoms, or a substituted or unsubstituted heterocyclic group having 5 to 50 ring atoms, and
* in the formulae (B31) to (B38) each represent a bonding position to another atom in a molecule of the compound M3.

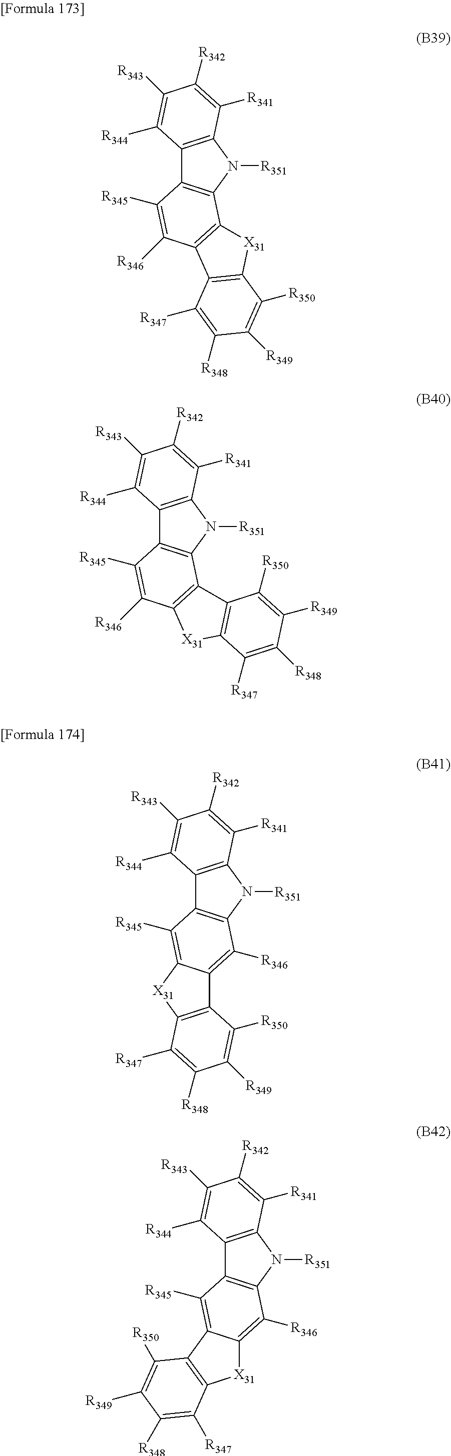

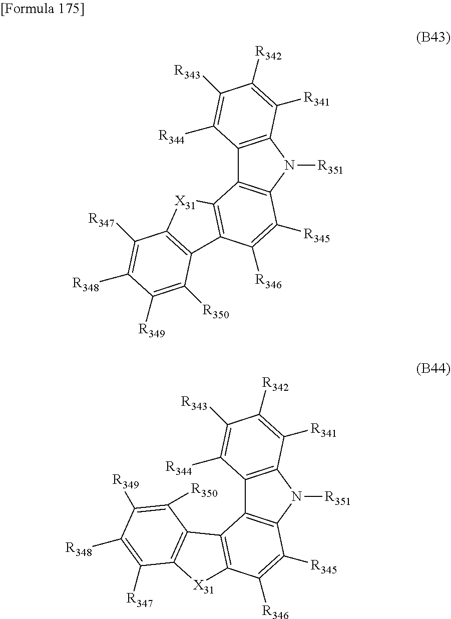

In the formulae (B39) to (B44):
at least one combination of adjacent two or more of R₉₄₁ to R₃₅₀ are mutually bonded to form a substituted or unsubstituted monocyclic ring, mutually bonded to form a substituted or unsubstituted fused ring, or not mutually bonded;
at least one of R₃₄₁ to R₉₅₁ represents a bonding position to another atom in a molecule of the compound M3;
X₃₁ is a sulfur atom, an oxygen atom, NR₃₅₂, or CR₃₅₃R₃₅₄;
a combination of R₃₅₃ and R₃₅₄ are mutually bonded to form a substituted or unsubstituted monocyclic ring, mutually bonded to form a substituted or unsubstituted fused ring, or not mutually bonded; and
R₃₄₁ to R₃₅₁ not being the bonding position to another atom in the molecule of the compound M3, not forming the substituted or unsubstituted monocyclic ring, and not forming the substituted or unsubstituted fused ring, R₃₅₂; and R₃₅₃ and R₃₅₄ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)Rce, a group represented by —COOR₉₀₉, a halogen atom, a cyano group, a nitro group, a substituted or unsubstituted aryl group having 6 to 50 ring carbon atoms, or a substituted or unsubstituted heterocyclic group having 5 to 50 ring atoms.

The compound M3 represented by the formula (3Y) preferably includes, in a molecule, at least one group selected from the group consisting of groups represented by the formulae (B38) to (B44).

In the formula (3Y), it is preferable that at least one of Y₃₁ to Y₃₆ is CR₃, at least one R₃ is a group represented by the formula (3B), and R_{B} is a group represented by one of the formulae (B31) to (B44).

In the formula (3Y), it is preferable that at least one of Y₃₁ to Y₃₆ is CR₃, at least one R₃ is a group represented by the formula (3B), and R_{B} is a group represented by one of the formulae (B38) to (B44).

In the formulae (3A) and (3B), it is preferable that:
L₃₁ is a single bond; a substituted or unsubstituted arylene group having 6 to 50 ring carbon atoms, a trivalent group, tetravalent group, pentavalent group, or hexavalent group derived from the arylene group, or a divalent group formed by bonding two groups selected from the group consisting of a substituted or unsubstituted arylene group having 6 to 50 ring carbon atoms, or a trivalent group, tetravalent group, pentavalent group, or hexavalent group derived from the divalent group, and
L₃₂ are each independently a single bond, or a substituted or unsubstituted arylene group having 6 to 50 ring carbon atoms.

In the formulae (3A) and (3B), it is preferable that:
L₃₁ is a single bond, or a substituted or unsubstituted arylene group having 6 to 50 ring carbon atoms;
n₃ is 1; and
L₃₂ is a single bond, or a substituted or unsubstituted arylene group having 6 to 50 ring carbon atoms.

In the formulae (3A) and (36), it is preferable that.

L₃₁ is a single bond; a substituted or unsubstituted phenylene group; a substituted or unsubstituted biphenylene group; or a divalent group formed by bonding two groups selected from the group consisting of a substituted or unsubstituted phenylene group and a substituted or unsubstituted biphenylene group, or a trivalent group, tetravalent group, pentavalent group, or hexavalent group derived from the divalent group;
n₃ is 1; and
L₃₂ is a single bond; a substituted or unsubstituted phenylene group, or a substituted or unsubstituted biphenylene group.

In the compounds represented by the formulae (3X) and (3Y), R₃₅₂ is preferably a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In the compounds represented by the formulae (3X) and (3Y), it is preferable that:
a combination of R₃₅₃ and R₃₅₄ are mutually bonded to form a substituted or unsubstituted monocyclic ring, mutually bonded to form a substituted or unsubstituted fused ring, or not mutually bonded; and
R₃₅₃ and R₃₅₄ forming neither the substituted or unsubstituted monocyclic ring nor the substituted or unsubstituted fused ring are each independently a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In the compounds represented by the formulae (3X) and (3Y), it is preferable that
the substituent for the “substituted or unsubstituted” group is an unsubstituted alkyl group having 1 to 25 carbon atoms, an unsubstituted alkenyl group having 2 to 25 carbon atoms, an unsubstituted alkynyl group having 2 to 25 carbon atoms, an unsubstituted cycloalkyl group having 3 to 25 ring carbon atoms, a group represented by —Si(R₉₀₁)(R₉₀₂)(R₉₀₃), a group represented by —O—(R₉₀₄), a group represented by —S—(R₉₀₆), a group represented by —N(R₉₀₆)(R₉₀₇), an unsubstituted aralkyl group having 7 to 50 carbon atoms, a group represented by —C(═O)R₉₀₈, a group represented by —COOR₉₀₉, a group represented by -(═O)(R₉₃₁)(R₉₃₂), a group represented by —Ge(R₉₃₃)(R₉₃₄)(R₉₃₅), a group represented by —B(R₉₃₆)(R₉₃₇), a group represented by —S(═O)₂R₉₃₈, a halogen atom, a cyano group, a nitro group, an unsubstituted aryl group having 6 to 25 ring carbon atoms, or an unsubstituted heterocyclic group having 5 to 25 ring atoms; and
R₉₀₁ to R₉₀₉ and R₉₃₁ to R₉₃₈ are each independently a hydrogen atom, an unsubstituted alkyl group having 1 to 25 carbon atoms, an unsubstituted aryl group having 6 to 25 ring carbon atoms, or an unsubstituted heterocyclic group having 5 to 25 ring atoms.

In the compounds represented by the formulae (3X) and (3Y), it is preferable
that the substituent for the “substituted or unsubstituted” group is a halogen atom, an unsubstituted alkyl group having 1 to 25 carbon atoms, an unsubstituted aryl group having 6 to 25 ring carbon atoms, or an unsubstituted heterocyclic group having 5 to 25 ring atoms.

In the compounds represented by the formulae (3X) and (3Y), it is preferable that the substituent for the “substituted or unsubstituted” group is an unsubstituted alkyl group having 1 to 10 carbon atoms, an unsubstituted aryl group having 6 to 12 ring carbon atoms, or an unsubstituted heterocyclic group having 5 to 12 ring atoms.

In the compounds represented by the formulae (3X) and (3Y), it is also preferable that the groups specified to be “substituted or unsubstituted” are each an unsubstituted group.

### Method of Producing Compound M3

The compound M3 of the exemplary embodiment can be produced by a known method.

### Specific Examples of Compound M3

Specific examples of the compound M3 in the exemplary embodiment include compounds below. However, the invention is not limited to the specifically listed compounds.

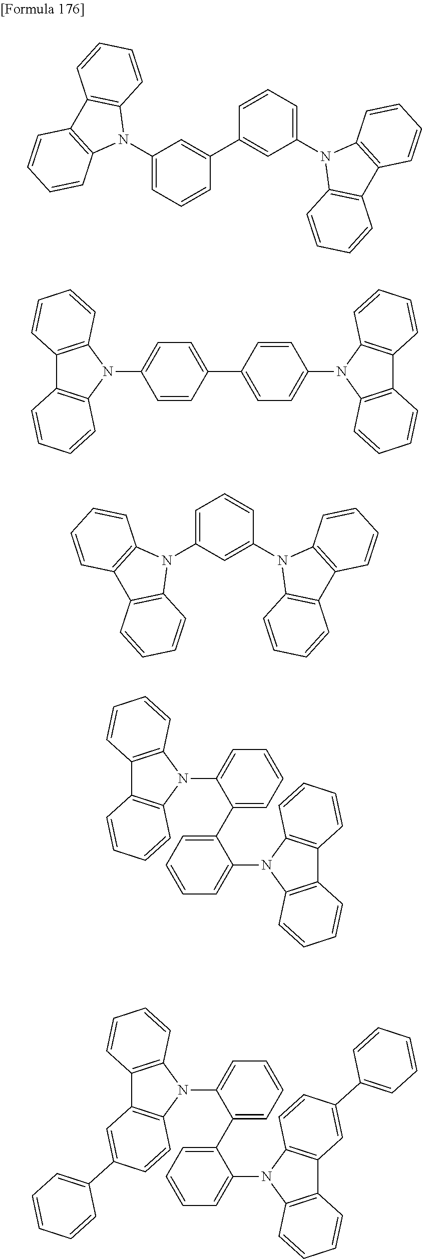

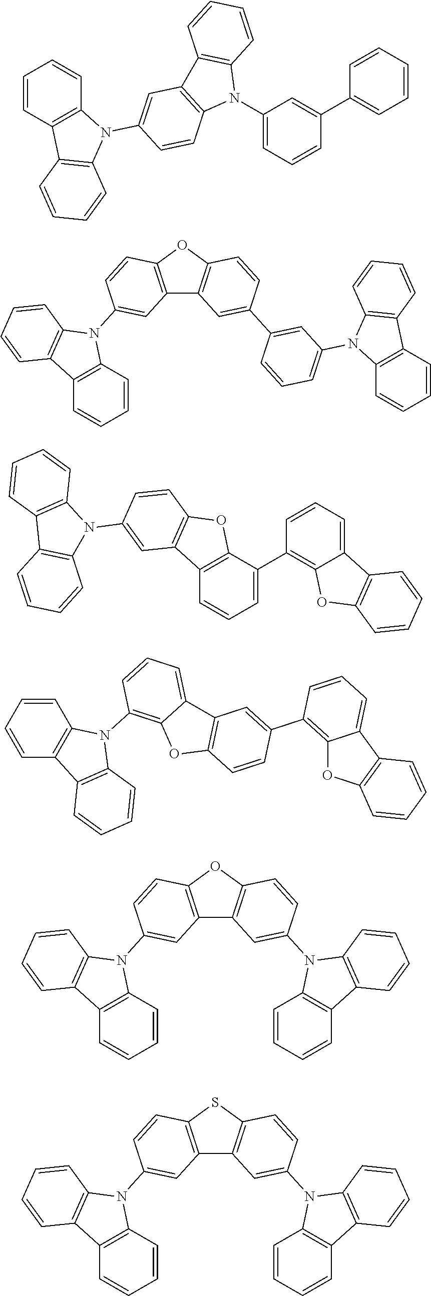 [SMILES: c1ccc(-c2cccc(-n3c4ccccc4c4cc(-n5c6ccccc6c6ccccc65)ccc43)c2)cc1 ; c1cc(-c2ccc3oc4ccc(-n5c6ccccc6c6ccccc65)cc4c3c2)cc(-n2c3ccccc3c3ccccc32)c1 ; c1ccc2c(c1)oc1c(-c3cccc4c3oc3ccc(-n5c6ccccc6c6ccccc65)cc34)cccc12 ; c1ccc2c(c1)oc1c(-c3ccc4oc5c(-n6c7ccccc7c7ccccc76)cccc5c4c3)cccc12 ; c1ccc2c(c1)c1ccccc1n2-c1ccc2oc3ccc(-n4c5ccccc5c5ccccc54)cc3c2c1 ; c1ccc2c(c1)c1ccccc1n2-c1ccc2sc3ccc(-n4c5ccccc5c5ccccc54)cc3c2c1]

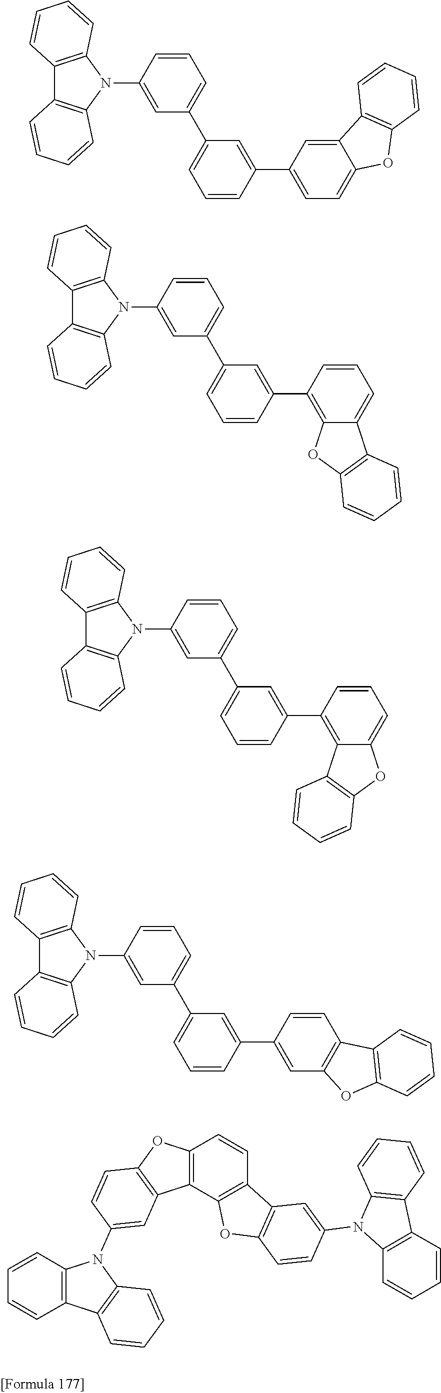

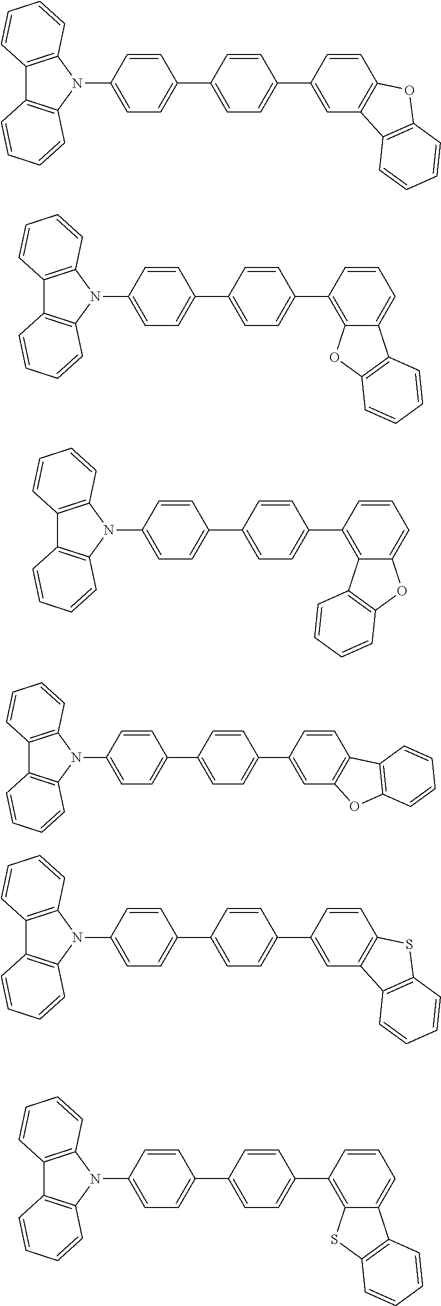

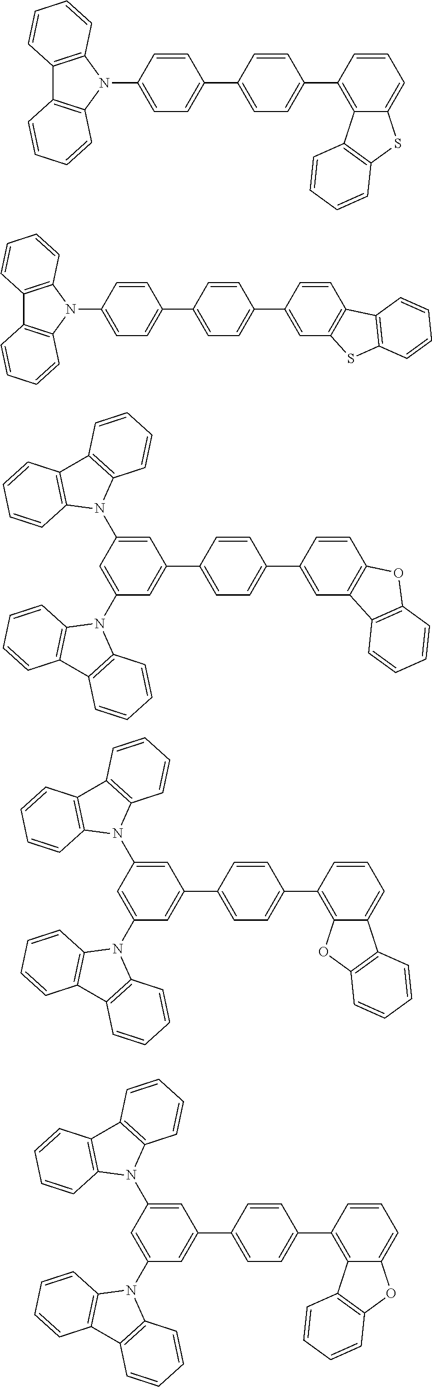

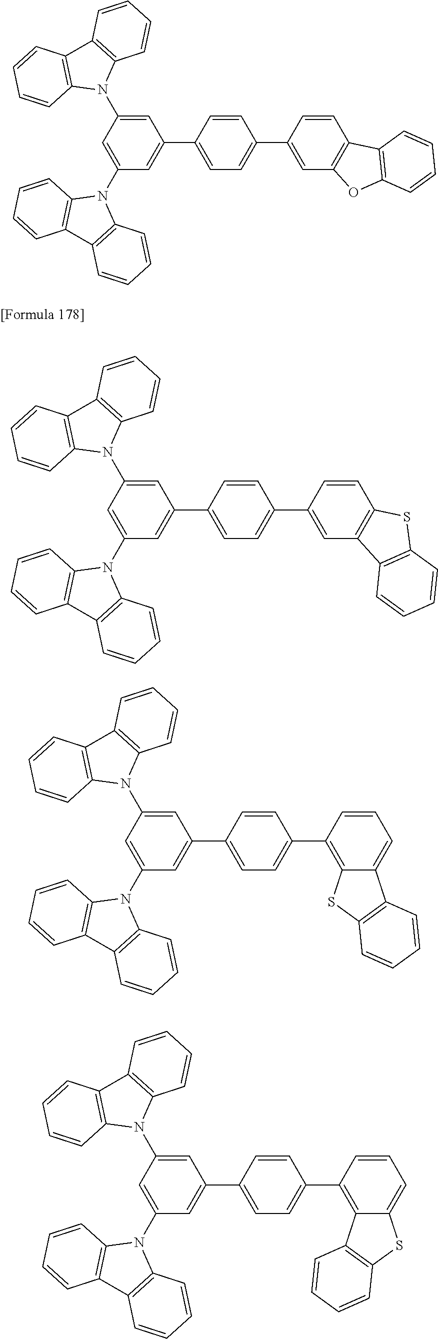

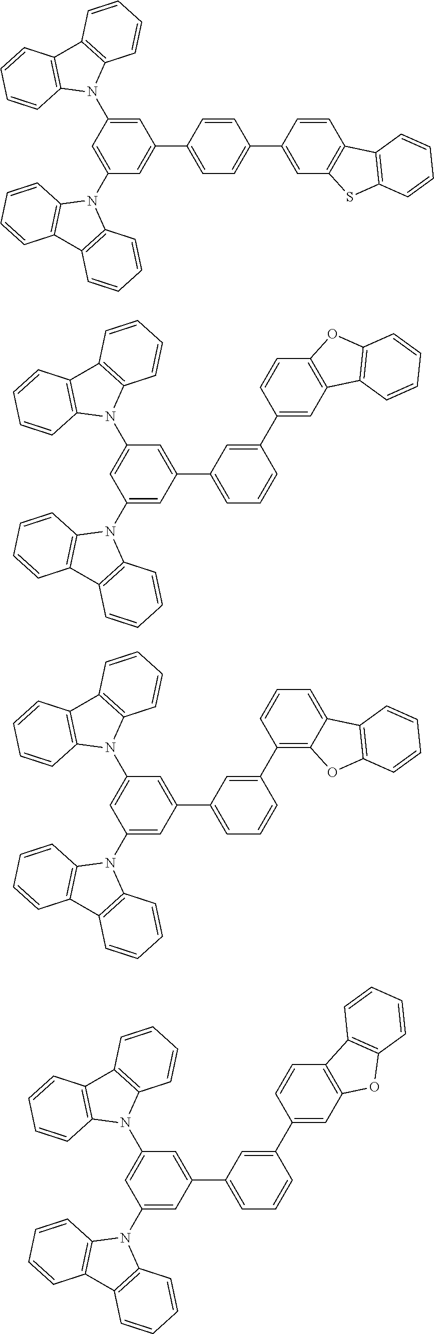

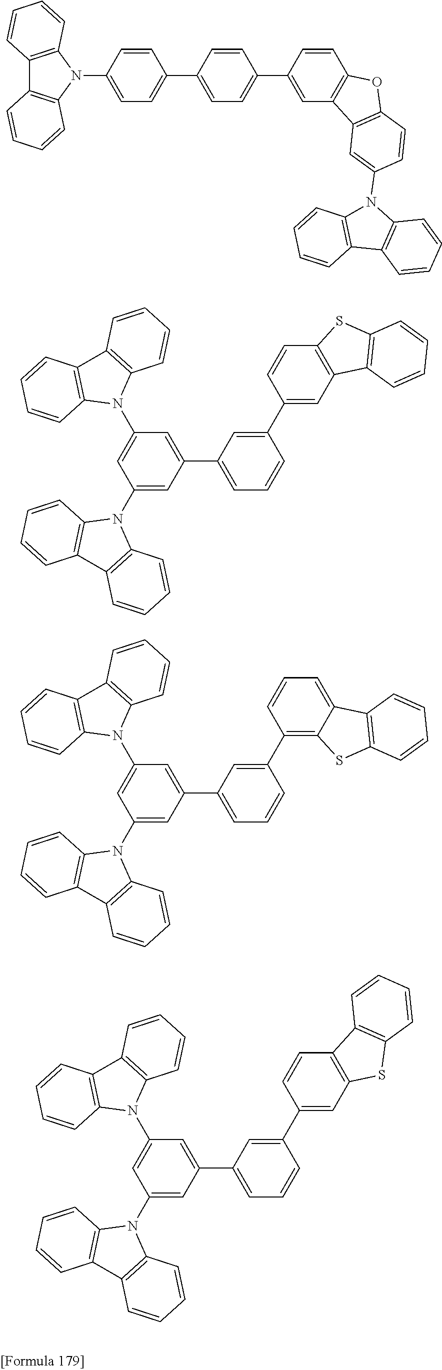

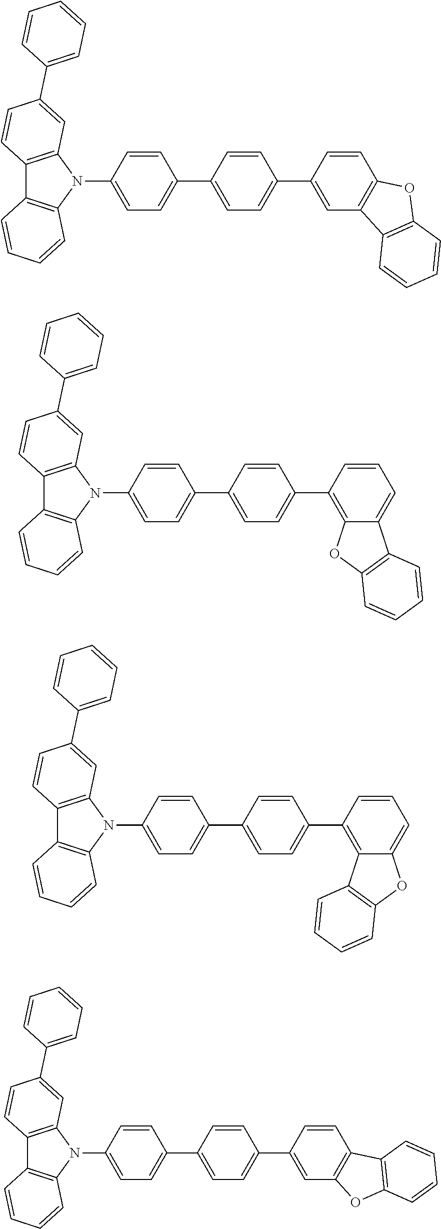 [SMILES: c1ccc(-c2ccc3c4ccccc4n(-c4ccc(-c5ccc(-c6ccc7oc8ccccc8c7c6)cc5)cc4)c3c2)cc1 ; c1ccc(-c2ccc3c4ccccc4n(-c4ccc(-c5ccc(-c6cccc7c6oc6ccccc67)cc5)cc4)c3c2)cc1 ; c1ccc(-c2ccc3c4ccccc4n(-c4ccc(-c5ccc(-c6cccc7oc8ccccc8c67)cc5)cc4)c3c2)cc1 ; c1ccc(-c2ccc3c4ccccc4n(-c4ccc(-c5ccc(-c6ccc7c(c6)oc6ccccc67)cc5)cc4)c3c2)cc1]

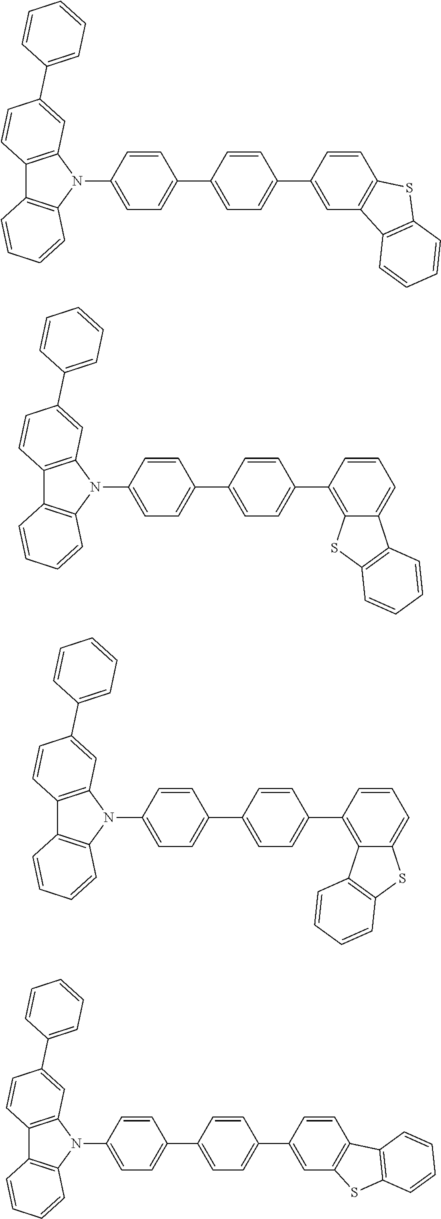 [SMILES: c1ccc(-c2ccc3c4ccccc4n(-c4ccc(-c5ccc(-c6ccc7sc8ccccc8c7c6)cc5)cc4)c3c2)cc1 ; c1ccc(-c2ccc3c4ccccc4n(-c4ccc(-c5ccc(-c6cccc7c6sc6ccccc67)cc5)cc4)c3c2)cc1 ; c1ccc(-c2ccc3c4ccccc4n(-c4ccc(-c5ccc(-c6cccc7sc8ccccc8c67)cc5)cc4)c3c2)cc1 ; c1ccc(-c2ccc3c4ccccc4n(-c4ccc(-c5ccc(-c6ccc7c(c6)sc6ccccc67)cc5)cc4)c3c2)cc1]

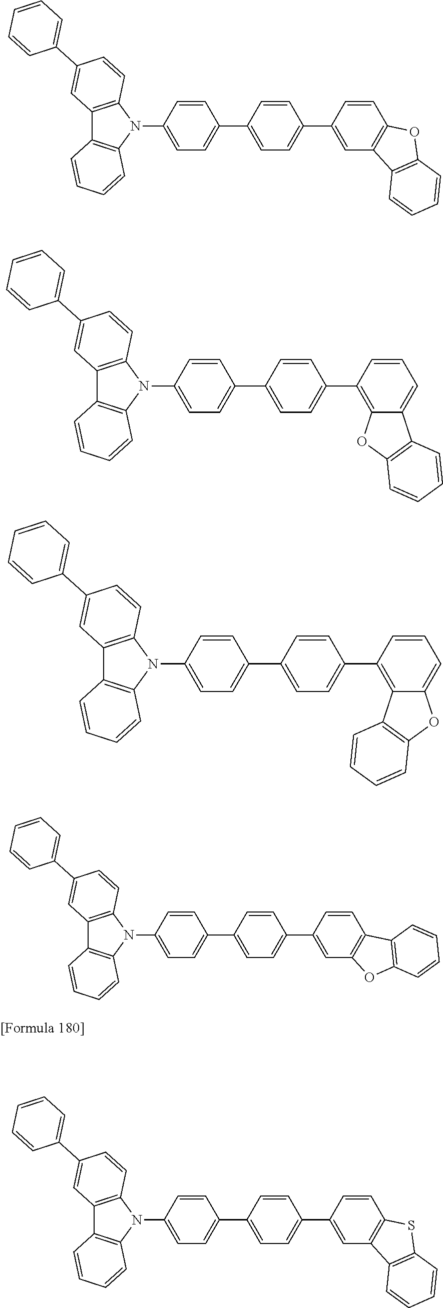 [SMILES: c1ccc(-c2ccc3c(c2)c2ccccc2n3-c2ccc(-c3ccc(-c4ccc5oc6ccccc6c5c4)cc3)cc2)cc1 ; c1ccc(-c2ccc3c(c2)c2ccccc2n3-c2ccc(-c3ccc(-c4cccc5c4oc4ccccc45)cc3)cc2)cc1 ; c1ccc(-c2ccc3c(c2)c2ccccc2n3-c2ccc(-c3ccc(-c4cccc5oc6ccccc6c45)cc3)cc2)cc1 ; c1ccc(-c2ccc3c(c2)c2ccccc2n3-c2ccc(-c3ccc(-c4ccc5c(c4)oc4ccccc45)cc3)cc2)cc1 ; c1ccc(-c2ccc3c(c2)c2ccccc2n3-c2ccc(-c3ccc(-c4ccc5sc6ccccc6c5c4)cc3)cc2)cc1]

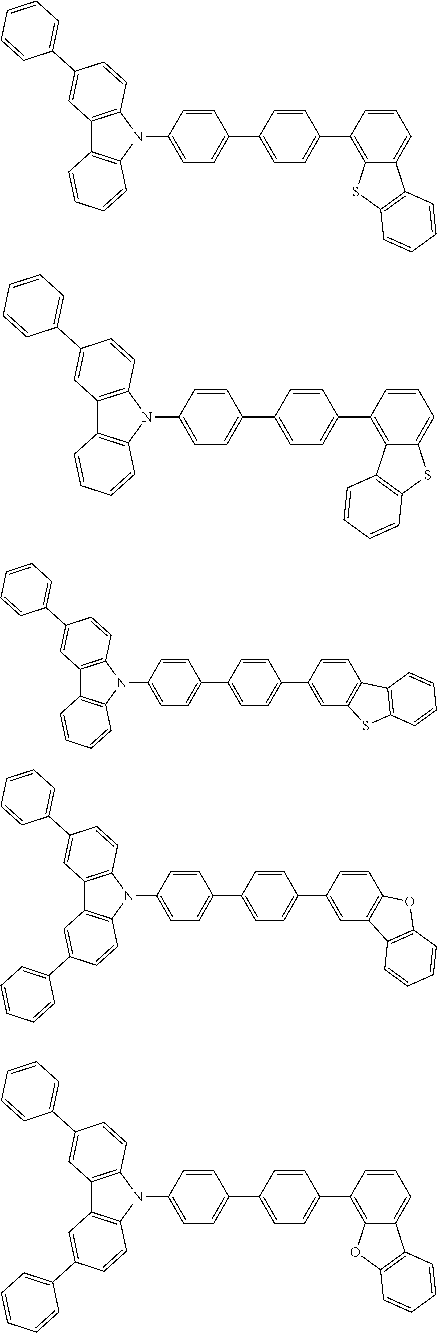

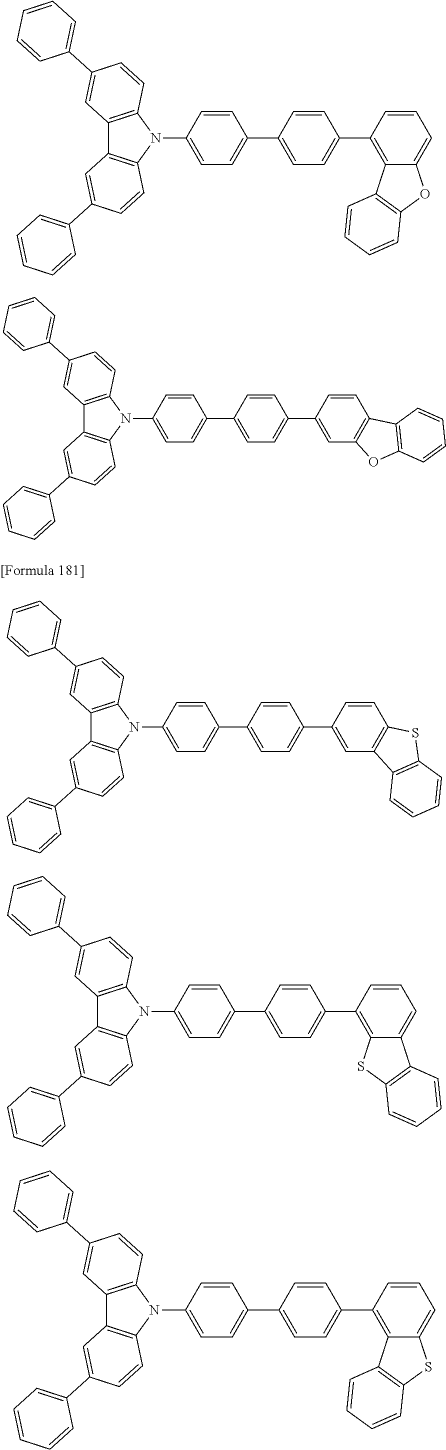

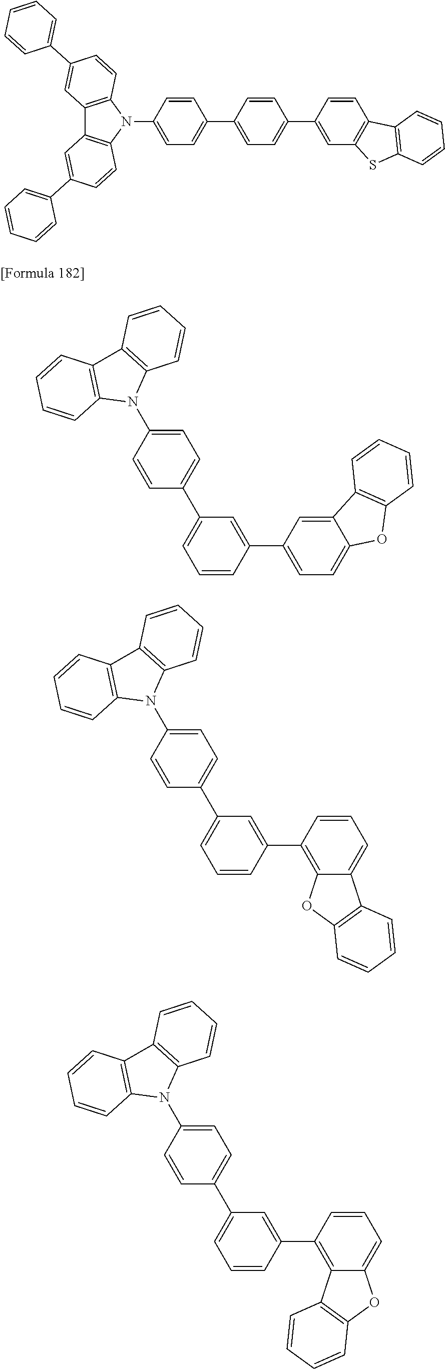

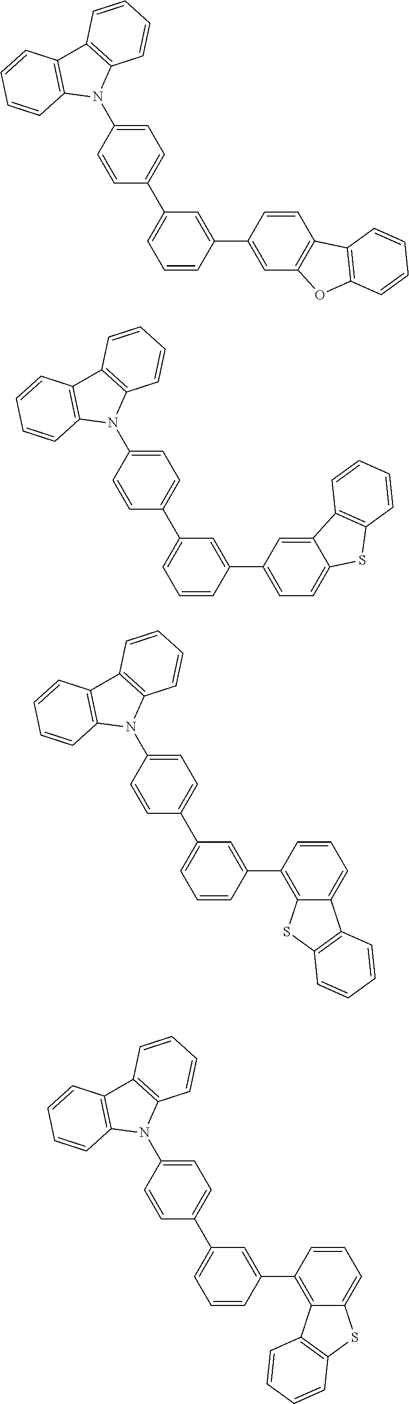

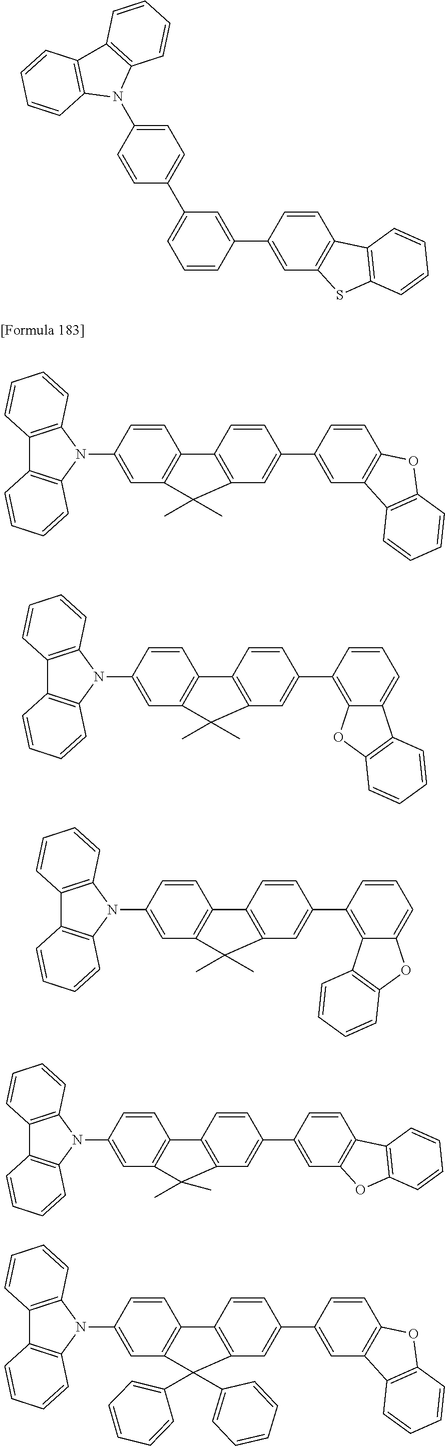

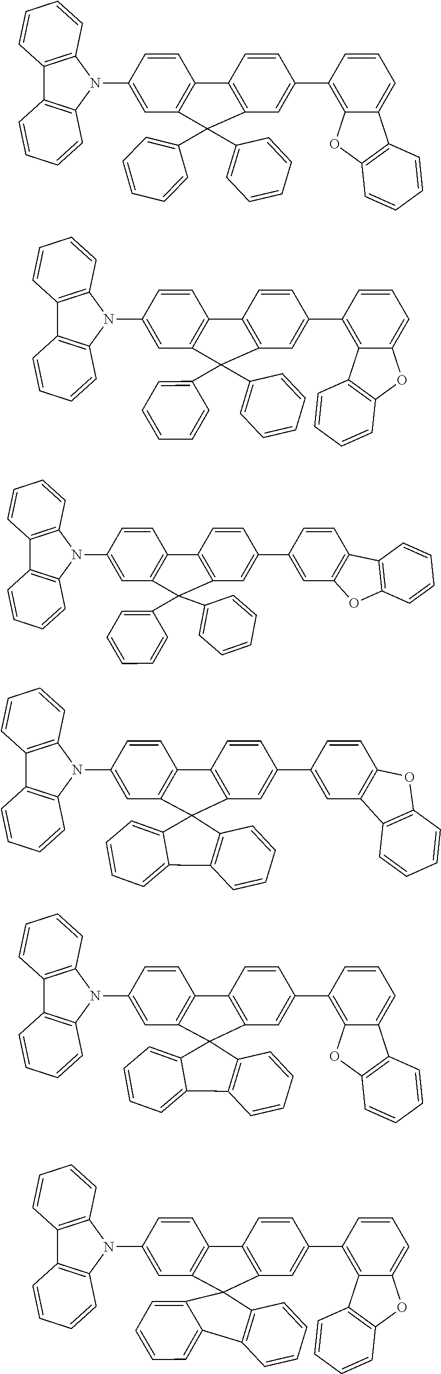

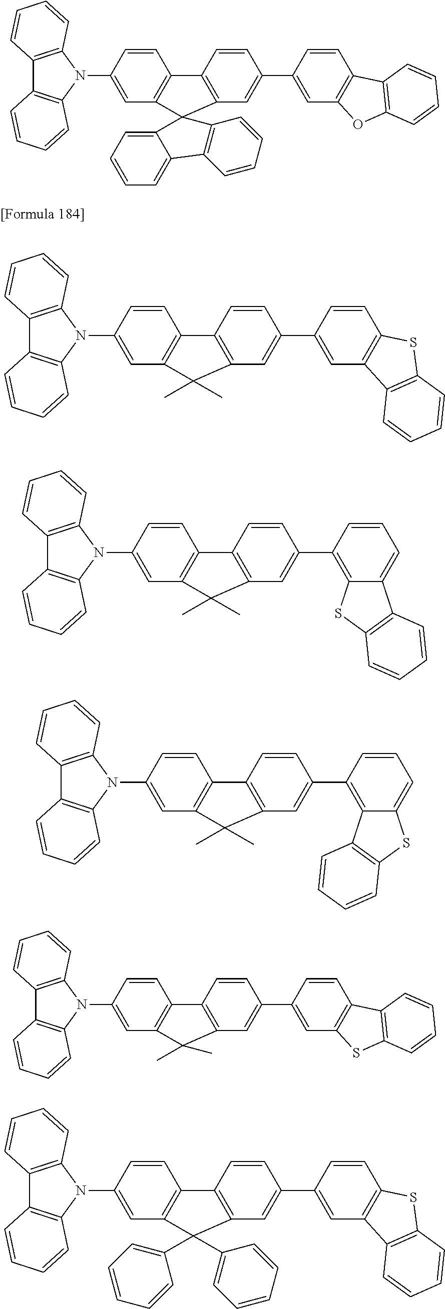

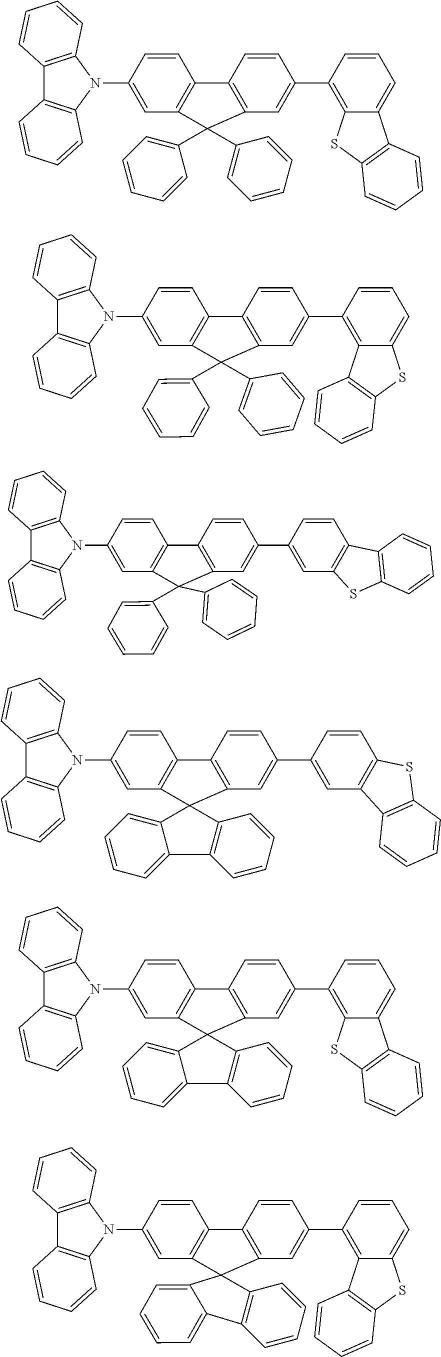

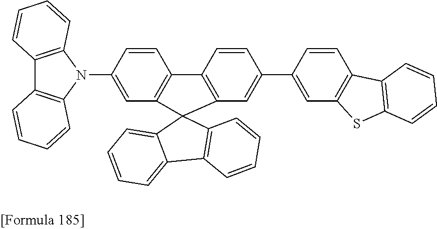 [SMILES: c1ccc2c(c1)-c1ccccc1C21c2cc(-c3ccc4c(c3)sc3ccccc34)ccc2-c2ccc(-n3c4ccccc4c4ccccc43)cc21]

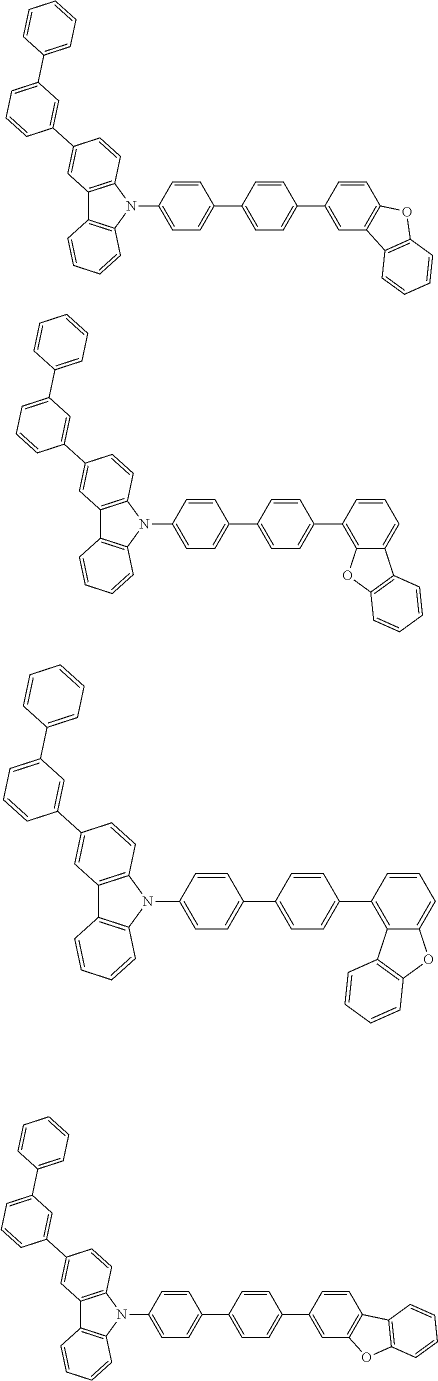 [SMILES: c1ccc(-c2cccc(-c3ccc4c(c3)c3ccccc3n4-c3ccc(-c4ccc(-c5ccc6oc7ccccc7c6c5)cc4)cc3)c2)cc1 ; c1ccc(-c2cccc(-c3ccc4c(c3)c3ccccc3n4-c3ccc(-c4ccc(-c5cccc6c5oc5ccccc56)cc4)cc3)c2)cc1 ; c1ccc(-c2cccc(-c3ccc4c(c3)c3ccccc3n4-c3ccc(-c4ccc(-c5cccc6oc7ccccc7c56)cc4)cc3)c2)cc1 ; c1ccc(-c2cccc(-c3ccc4c(c3)c3ccccc3n4-c3ccc(-c4ccc(-c5ccc6c(c5)oc5ccccc56)cc4)cc3)c2)cc1]

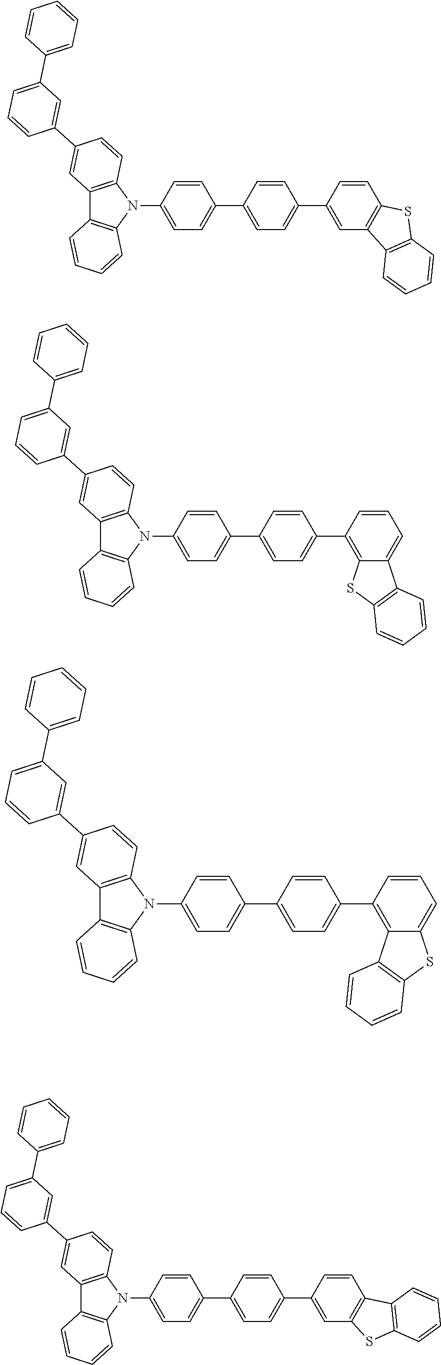 [SMILES: c1ccc(-c2cccc(-c3ccc4c(c3)c3ccccc3n4-c3ccc(-c4ccc(-c5ccc6sc7ccccc7c6c5)cc4)cc3)c2)cc1 ; c1ccc(-c2cccc(-c3ccc4c(c3)c3ccccc3n4-c3ccc(-c4ccc(-c5cccc6c5sc5ccccc56)cc4)cc3)c2)cc1 ; c1ccc(-c2cccc(-c3ccc4c(c3)c3ccccc3n4-c3ccc(-c4ccc(-c5cccc6sc7ccccc7c56)cc4)cc3)c2)cc1 ; c1ccc(-c2cccc(-c3ccc4c(c3)c3ccccc3n4-c3ccc(-c4ccc(-c5ccc6c(c5)sc5ccccc56)cc4)cc3)c2)cc1]

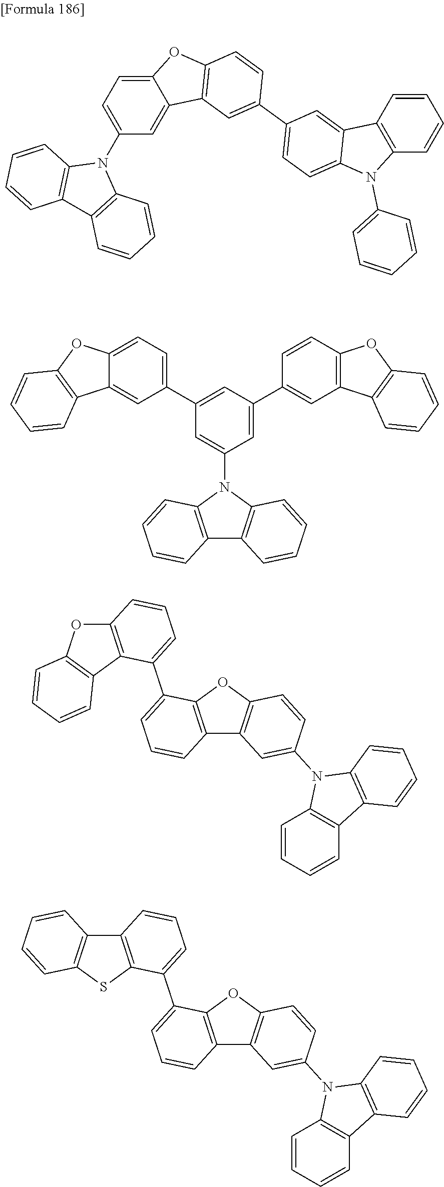 [SMILES: c1ccc(-n2c3ccccc3c3cc(-c4ccc5oc6ccc(-n7c8ccccc8c8ccccc87)cc6c5c4)ccc32)cc1 ; c1ccc2c(c1)oc1ccc(-c3cc(-c4ccc5oc6ccccc6c5c4)cc(-n4c5ccccc5c5ccccc54)c3)cc12 ; c1ccc2c(c1)oc1cccc(-c3cccc4c3oc3ccc(-n5c6ccccc6c6ccccc65)cc34)c12 ; c1ccc2c(c1)sc1c(-c3cccc4c3oc3ccc(-n5c6ccccc6c6ccccc65)cc34)cccc12]

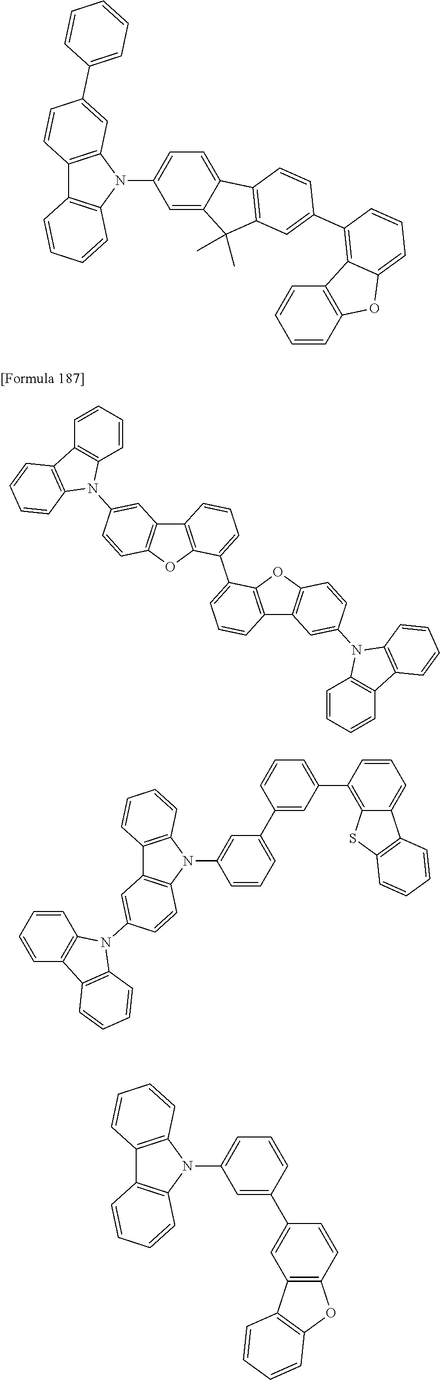

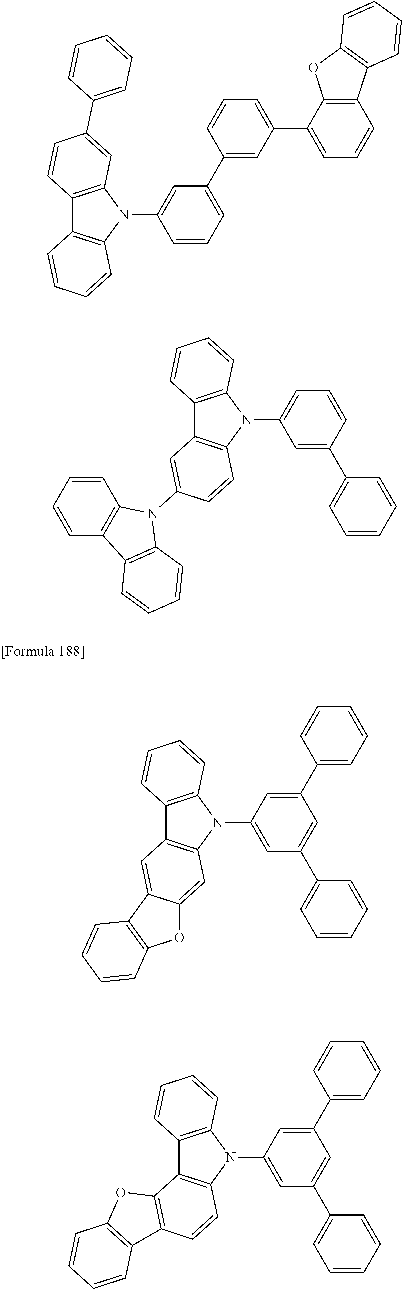 [SMILES: c1ccc(-c2ccc3c4ccccc4n(-c4cccc(-c5cccc(-c6cccc7c6oc6ccccc67)c5)c4)c3c2)cc1 ; c1ccc(-c2cccc(-n3c4ccccc4c4cc(-n5c6ccccc6c6ccccc65)ccc43)c2)cc1 ; c1ccc(-c2cc(-c3ccccc3)cc(-n3c4ccccc4c4cc5c(cc43)oc3ccccc35)c2)cc1 ; c1ccc(-c2cc(-c3ccccc3)cc(-n3c4ccccc4c4c5oc6ccccc6c5ccc43)c2)cc1]

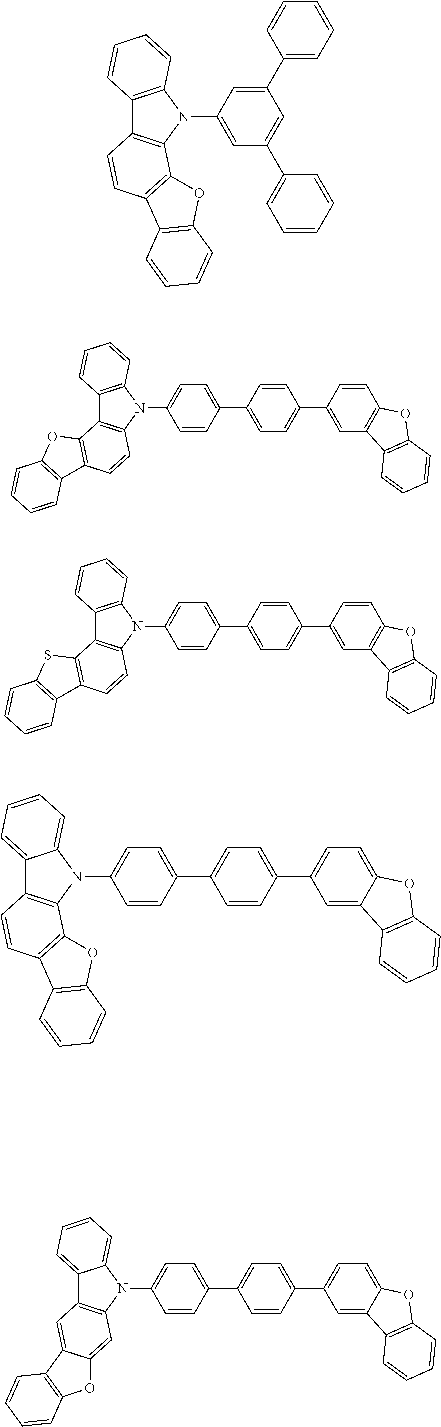 [SMILES: c1ccc(-c2cc(-c3ccccc3)cc(-n3c4ccccc4c4ccc5c6ccccc6oc5c43)c2)cc1 ; c1ccc2c(c1)oc1ccc(-c3ccc(-c4ccc(-n5c6ccccc6c6c7oc8ccccc8c7ccc65)cc4)cc3)cc12 ; c1ccc2c(c1)oc1ccc(-c3ccc(-c4ccc(-n5c6ccccc6c6c7sc8ccccc8c7ccc65)cc4)cc3)cc12 ; c1ccc2c(c1)oc1ccc(-c3ccc(-c4ccc(-n5c6ccccc6c6ccc7c8ccccc8oc7c65)cc4)cc3)cc12 ; c1ccc2c(c1)oc1ccc(-c3ccc(-c4ccc(-n5c6ccccc6c6cc7c(cc65)oc5ccccc57)cc4)cc3)cc12]

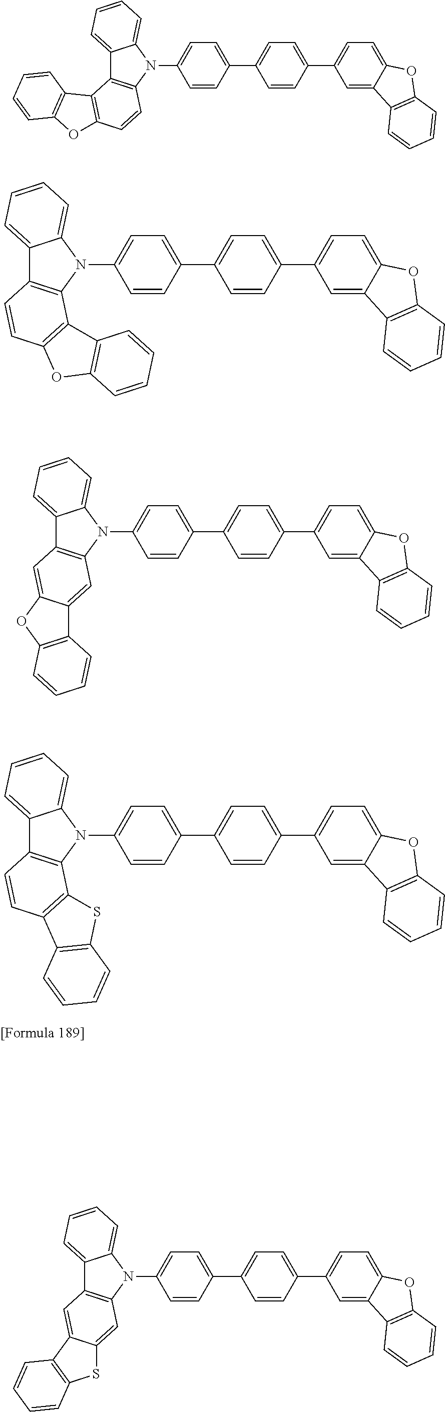 [SMILES: c1ccc2c(c1)oc1ccc(-c3ccc(-c4ccc(-n5c6ccccc6c6c7c(ccc65)oc5ccccc57)cc4)cc3)cc12 ; c1ccc2c(c1)oc1ccc(-c3ccc(-c4ccc(-n5c6ccccc6c6ccc7oc8ccccc8c7c65)cc4)cc3)cc12 ; c1ccc2c(c1)oc1ccc(-c3ccc(-c4ccc(-n5c6ccccc6c6cc7oc8ccccc8c7cc65)cc4)cc3)cc12 ; c1ccc2c(c1)oc1ccc(-c3ccc(-c4ccc(-n5c6ccccc6c6ccc7c8ccccc8sc7c65)cc4)cc3)cc12 ; c1ccc2c(c1)oc1ccc(-c3ccc(-c4ccc(-n5c6ccccc6c6cc7c(cc65)sc5ccccc57)cc4)cc3)cc12]

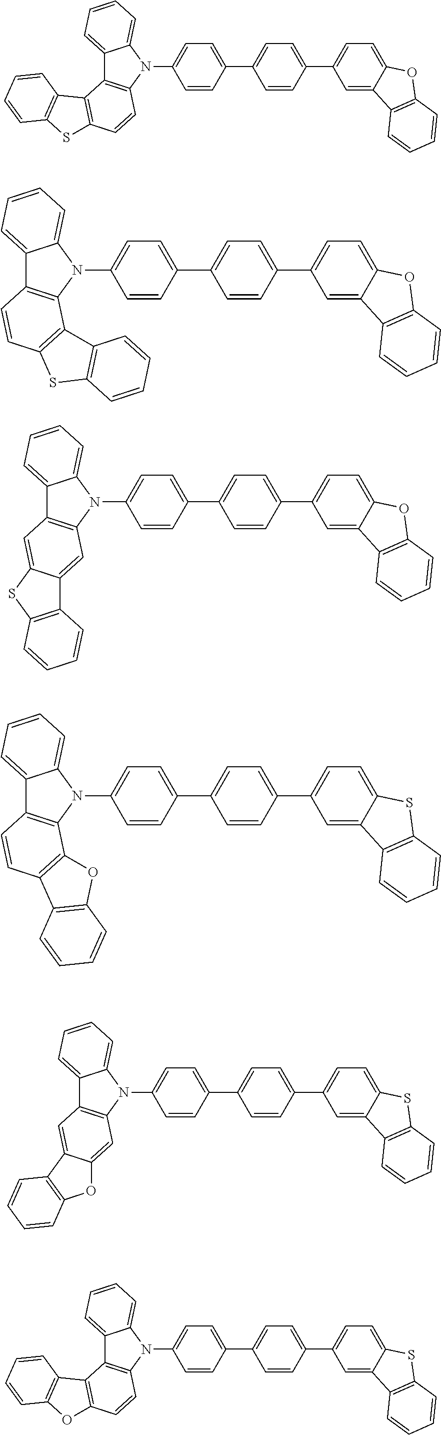 [SMILES: c1ccc2c(c1)oc1ccc(-c3ccc(-c4ccc(-n5c6ccccc6c6c7c(ccc65)sc5ccccc57)cc4)cc3)cc12 ; c1ccc2c(c1)oc1ccc(-c3ccc(-c4ccc(-n5c6ccccc6c6ccc7sc8ccccc8c7c65)cc4)cc3)cc12 ; c1ccc2c(c1)oc1ccc(-c3ccc(-c4ccc(-n5c6ccccc6c6cc7sc8ccccc8c7cc65)cc4)cc3)cc12 ; c1ccc2c(c1)oc1c2ccc2c3ccccc3n(-c3ccc(-c4ccc(-c5ccc6sc7ccccc7c6c5)cc4)cc3)c21 ; c1ccc2c(c1)oc1cc3c(cc12)c1ccccc1n3-c1ccc(-c2ccc(-c3ccc4sc5ccccc5c4c3)cc2)cc1 ; c1ccc2c(c1)oc1ccc3c(c4ccccc4n3-c3ccc(-c4ccc(-c5ccc6sc7ccccc7c6c5)cc4)cc3)c12]

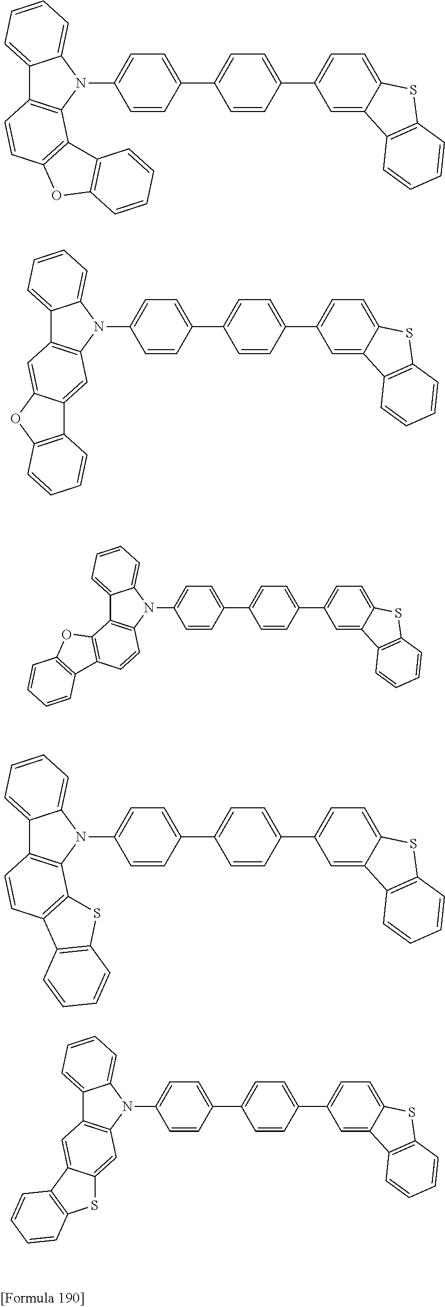

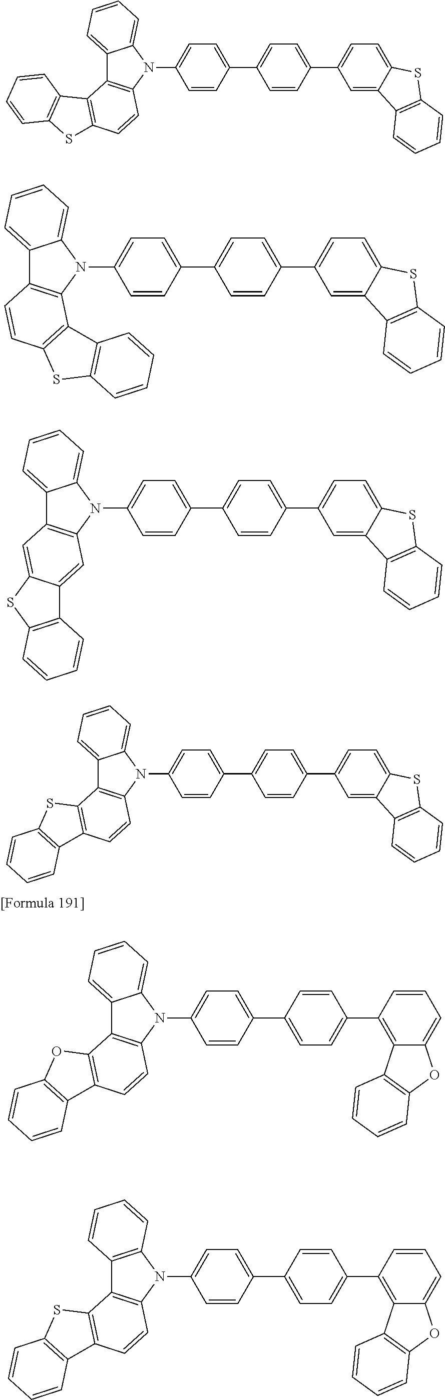 [SMILES: c1ccc2c(c1)sc1ccc(-c3ccc(-c4ccc(-n5c6ccccc6c6c7c(ccc65)sc5ccccc57)cc4)cc3)cc12 ; c1ccc2c(c1)sc1ccc(-c3ccc(-c4ccc(-n5c6ccccc6c6ccc7sc8ccccc8c7c65)cc4)cc3)cc12 ; c1ccc2c(c1)sc1ccc(-c3ccc(-c4ccc(-n5c6ccccc6c6cc7sc8ccccc8c7cc65)cc4)cc3)cc12 ; c1ccc2c(c1)sc1ccc(-c3ccc(-c4ccc(-n5c6ccccc6c6c7sc8ccccc8c7ccc65)cc4)cc3)cc12 ; c1ccc2c(c1)oc1c2ccc2c1c1ccccc1n2-c1ccc(-c2ccc(-c3cccc4oc5ccccc5c34)cc2)cc1 ; c1ccc2c(c1)oc1cccc(-c3ccc(-c4ccc(-n5c6ccccc6c6c7sc8ccccc8c7ccc65)cc4)cc3)c12]

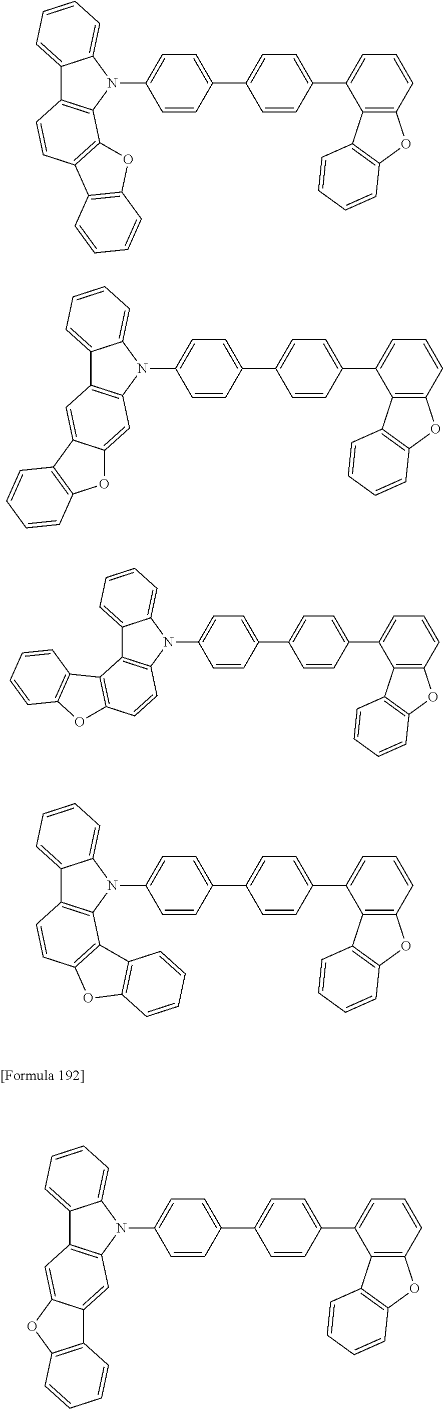

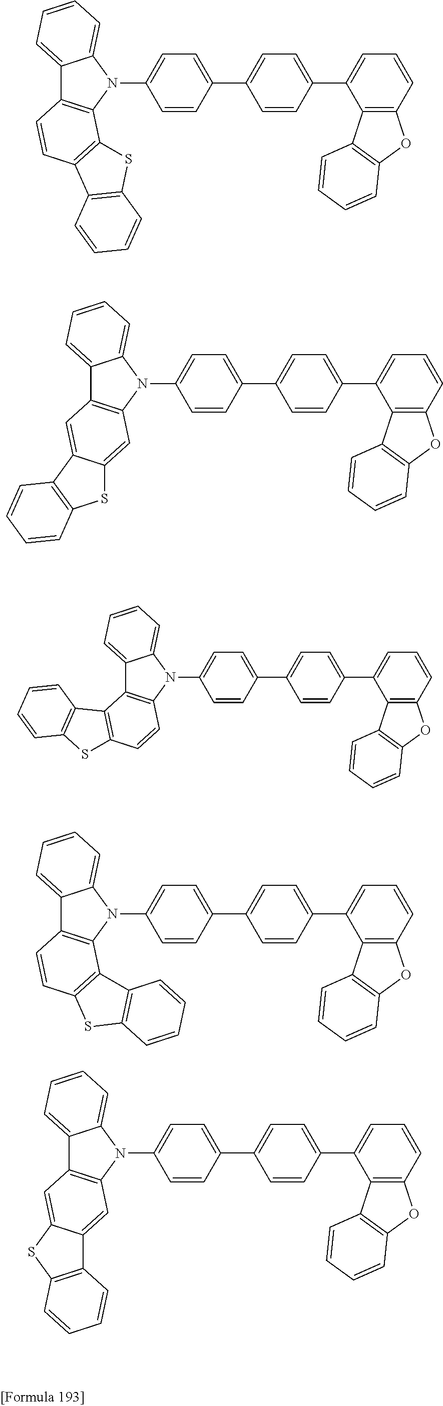

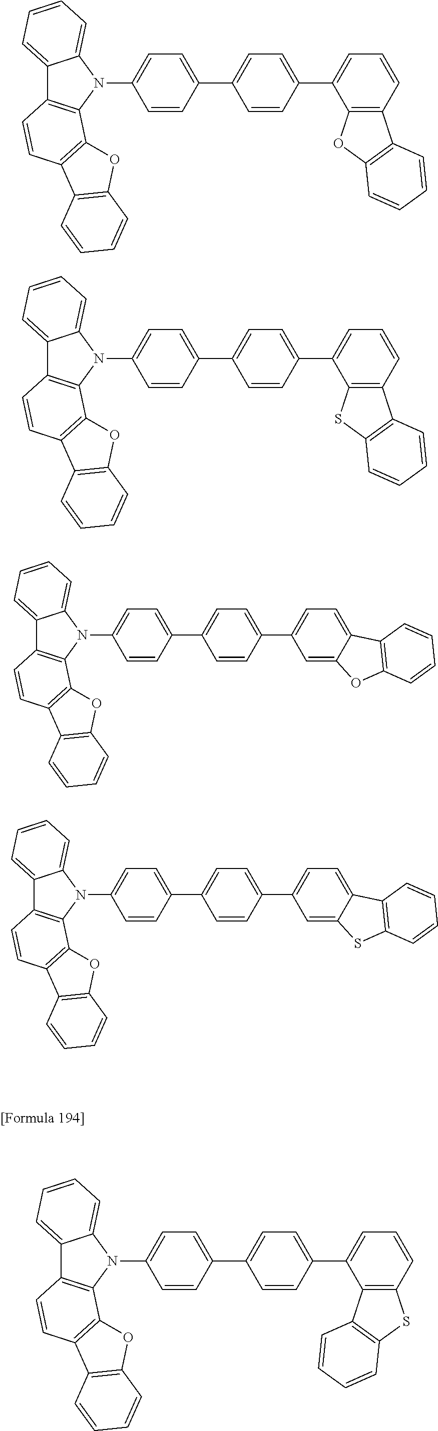

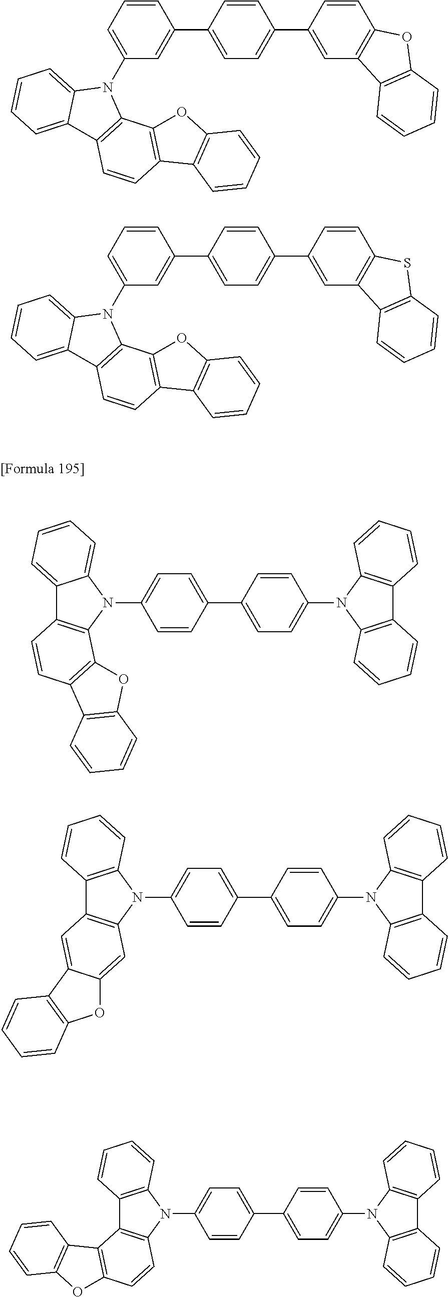

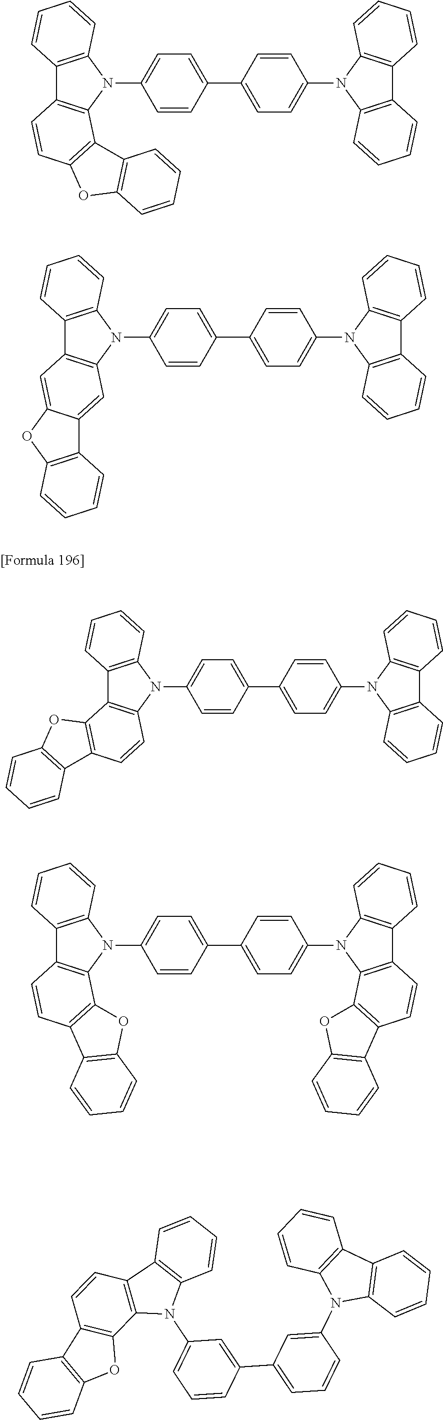 [SMILES: c1ccc2c(c1)oc1ccc3c4ccccc4n(-c4ccc(-c5ccc(-n6c7ccccc7c7ccccc76)cc5)cc4)c3c12 ; c1ccc2c(c1)oc1cc3c4ccccc4n(-c4ccc(-c5ccc(-n6c7ccccc7c7ccccc76)cc5)cc4)c3cc12 ; c1ccc2c(c1)oc1c2ccc2c1c1ccccc1n2-c1ccc(-c2ccc(-n3c4ccccc4c4ccccc43)cc2)cc1 ; c1ccc2c(c1)oc1c2ccc2c3ccccc3n(-c3ccc(-c4ccc(-n5c6ccccc6c6ccc7c8ccccc8oc7c65)cc4)cc3)c21 ; c1cc(-c2cccc(-n3c4ccccc4c4ccc5c6ccccc6oc5c43)c2)cc(-n2c3ccccc3c3ccccc32)c1]

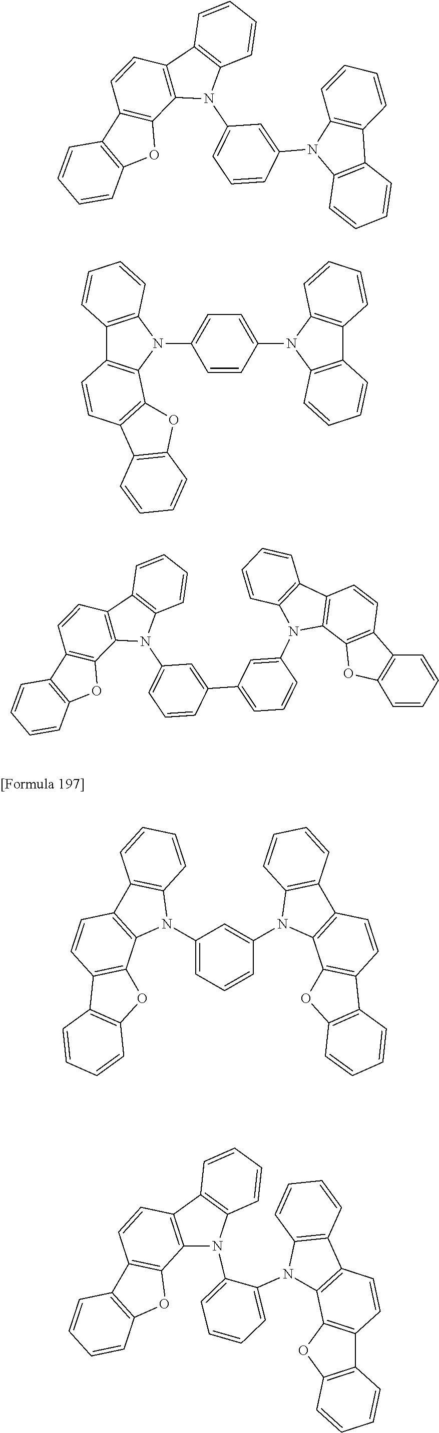

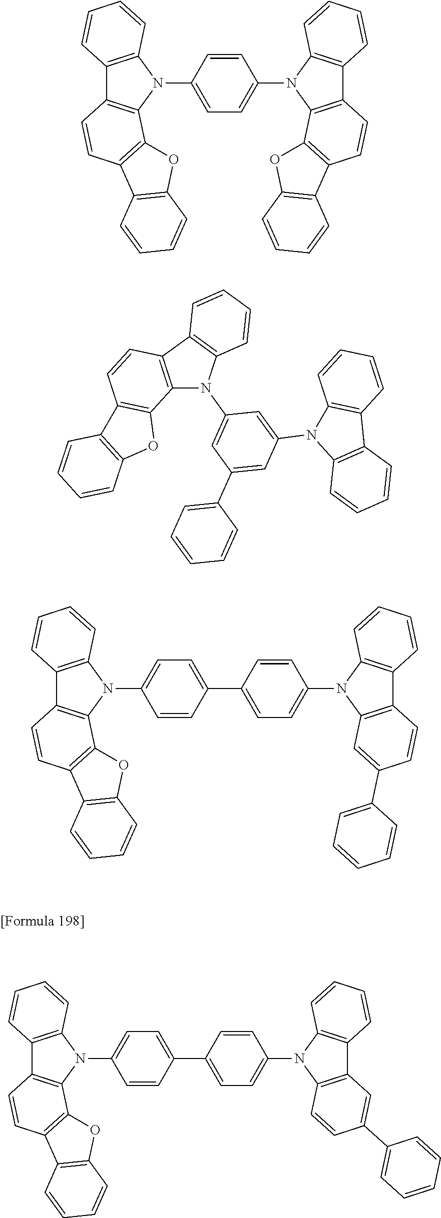 [SMILES: c1ccc2c(c1)oc1c2ccc2c3ccccc3n(-c3ccc(-n4c5ccccc5c5ccc6c7ccccc7oc6c54)cc3)c21 ; c1ccc(-c2cc(-n3c4ccccc4c4ccccc43)cc(-n3c4ccccc4c4ccc5c6ccccc6oc5c43)c2)cc1 ; c1ccc(-c2ccc3c4ccccc4n(-c4ccc(-c5ccc(-n6c7ccccc7c7ccc8c9ccccc9oc8c76)cc5)cc4)c3c2)cc1 ; c1ccc(-c2ccc3c(c2)c2ccccc2n3-c2ccc(-c3ccc(-n4c5ccccc5c5ccc6c7ccccc7oc6c54)cc3)cc2)cc1]

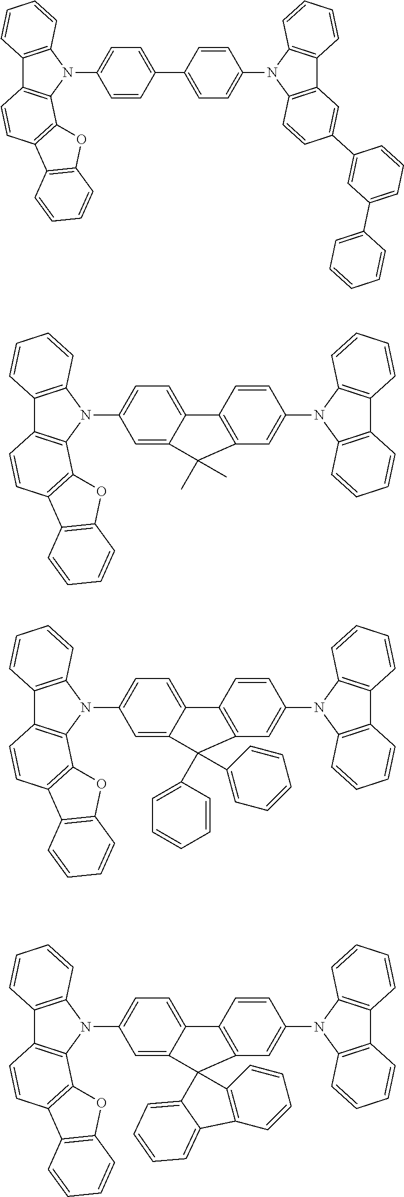

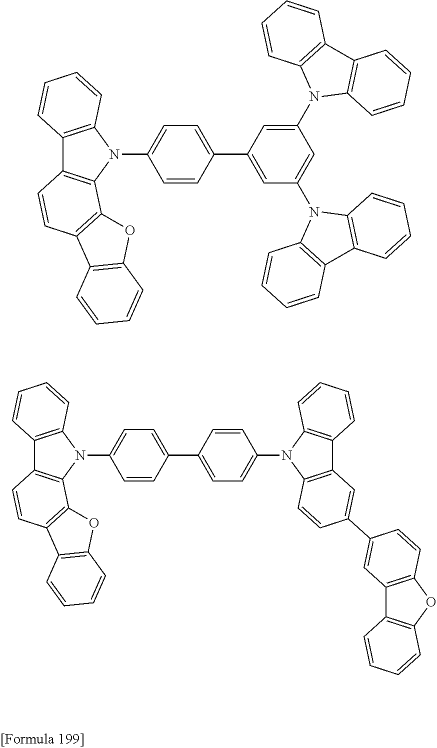 [SMILES: c1ccc2c(c1)oc1c2ccc2c3ccccc3n(-c3ccc(-c4cc(-n5c6ccccc6c6ccccc65)cc(-n5c6ccccc6c6ccccc65)c4)cc3)c21 ; c1ccc2c(c1)oc1ccc(-c3ccc4c(c3)c3ccccc3n4-c3ccc(-c4ccc(-n5c6ccccc6c6ccc7c8ccccc8oc7c65)cc4)cc3)cc12]

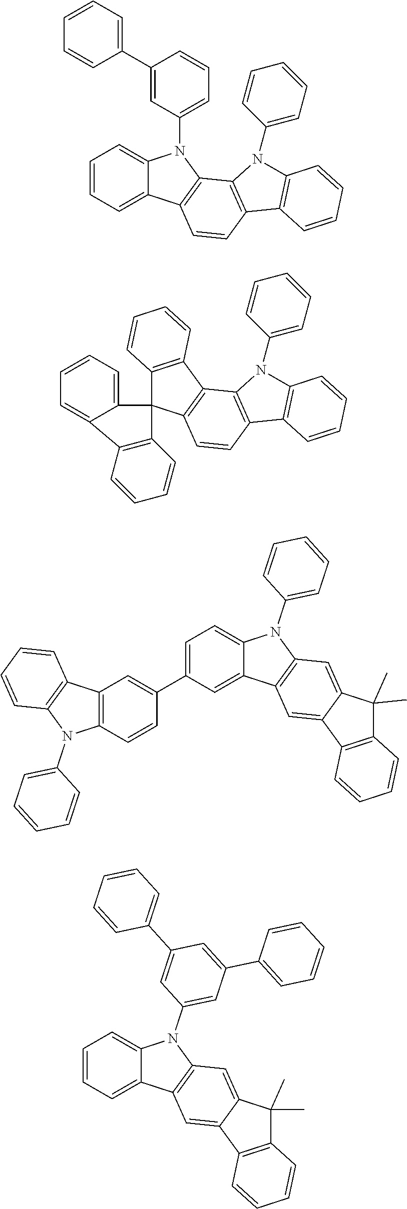

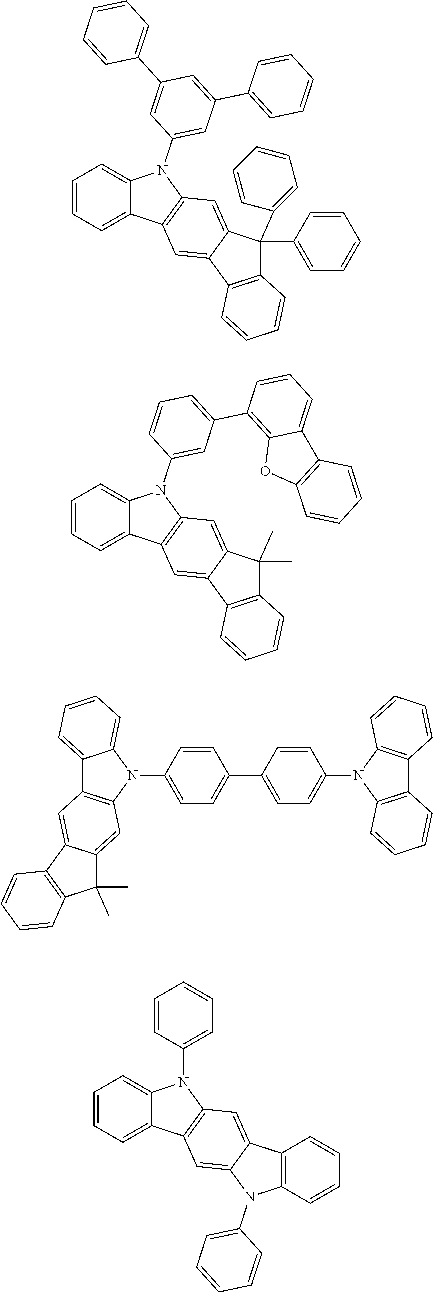

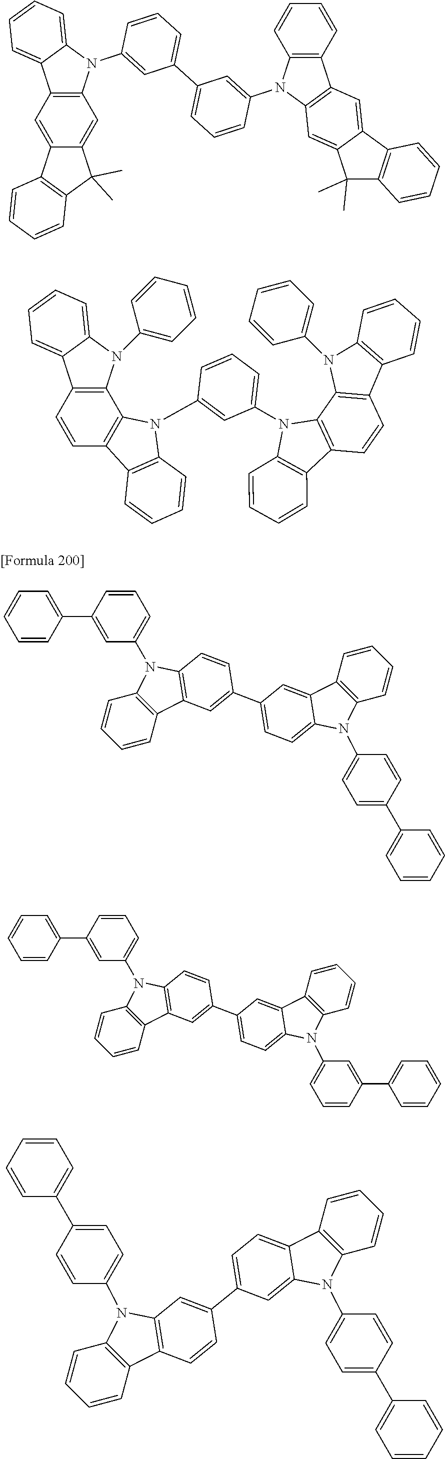 [SMILES: CC1(C)c2ccccc2-c2cc3c4ccccc4n(-c4cccc(-c5cccc(-n6c7ccccc7c7cc8c(cc76)C(C)(C)c6ccccc6-8)c5)c4)c3cc21 ; c1ccc(-n2c3ccccc3c3ccc4c5ccccc5n(-c5cccc(-n6c7ccccc7c7ccc8c9ccccc9n(-c9ccccc9)c8c76)c5)c4c32)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2ccc(-n3c4ccccc4c4ccc(-c5ccc6c7ccccc7n(-c7ccc(-c8ccccc8)cc7)c6c5)cc43)cc2)cc1]

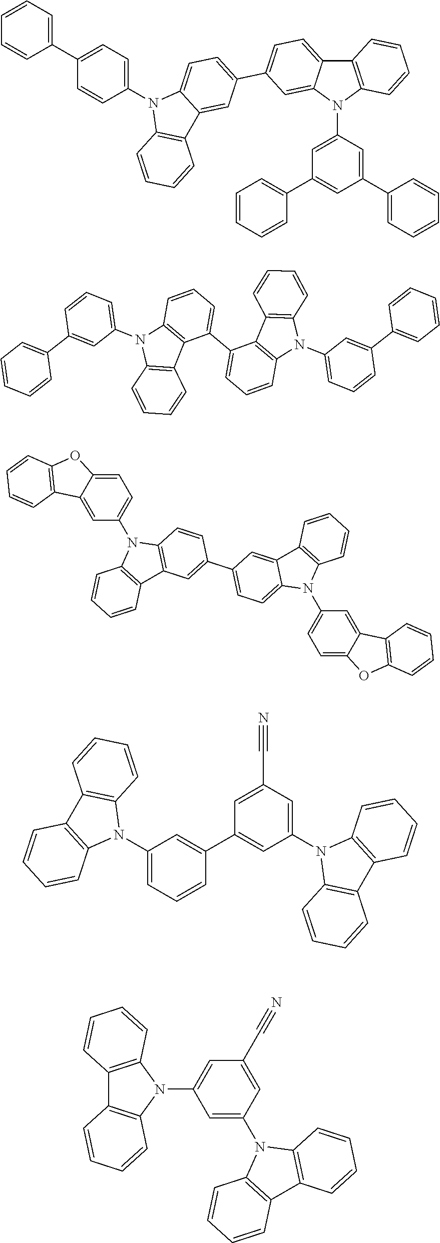

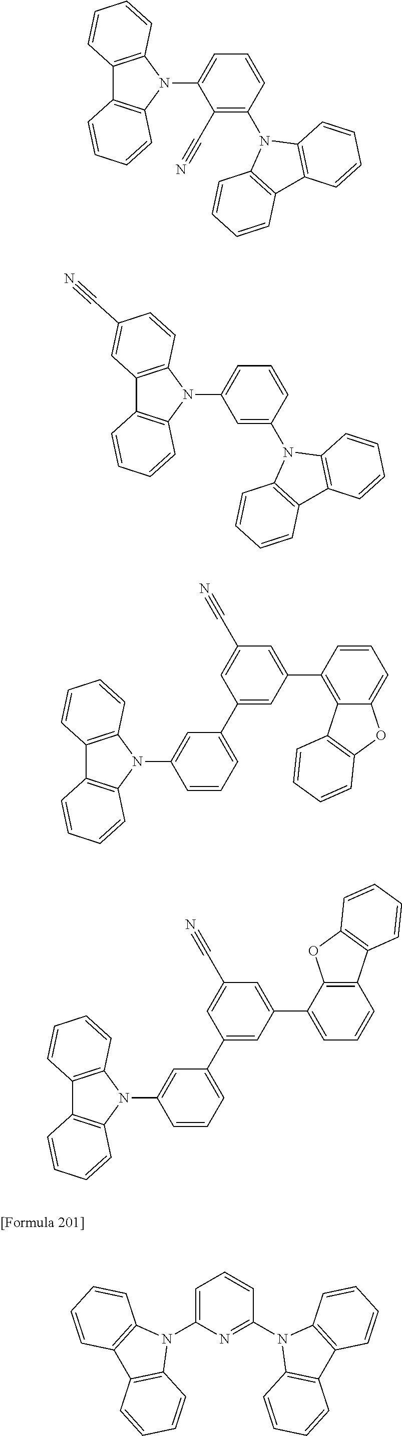 [SMILES: N#Cc1c(-n2c3ccccc3c3ccccc32)cccc1-n1c2ccccc2c2ccccc21 ; N#Cc1ccc2c(c1)c1ccccc1n2-c1cccc(-n2c3ccccc3c3ccccc32)c1 ; N#Cc1cc(-c2cccc(-n3c4ccccc4c4ccccc43)c2)cc(-c2cccc3oc4ccccc4c23)c1 ; N#Cc1cc(-c2cccc(-n3c4ccccc4c4ccccc43)c2)cc(-c2cccc3c2oc2ccccc23)c1 ; c1cc(-n2c3ccccc3c3ccccc32)nc(-n2c3ccccc3c3ccccc32)c1]

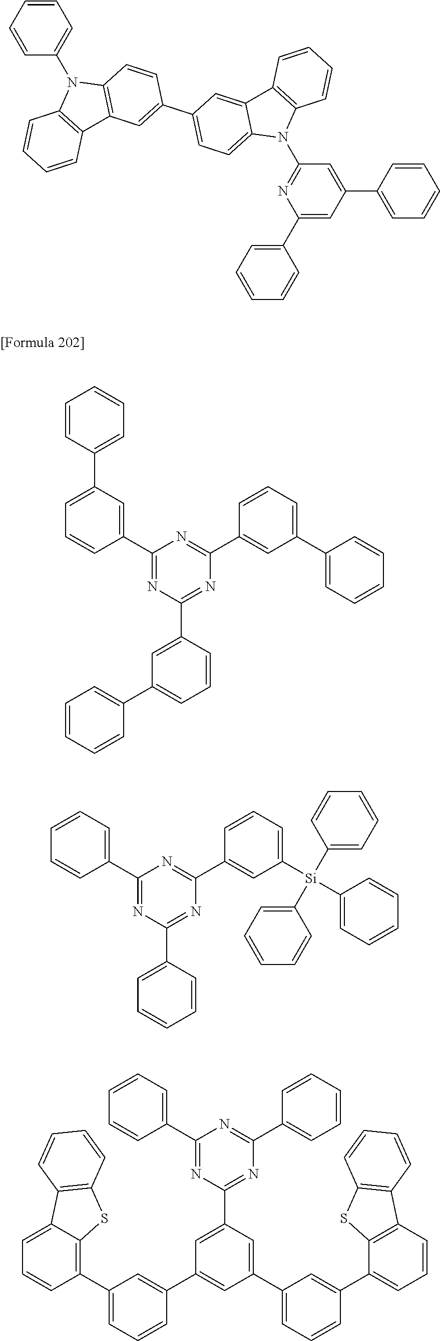 [SMILES: c1ccc(-c2cc(-c3ccccc3)nc(-n3c4ccccc4c4cc(-c5ccc6c(c5)c5ccccc5n6-c5ccccc5)ccc43)c2)cc1 ; c1ccc(-c2cccc(-c3nc(-c4cccc(-c5ccccc5)c4)nc(-c4cccc(-c5ccccc5)c4)n3)c2)cc1 ; c1ccc(-c2nc(-c3ccccc3)nc(-c3cccc([Si](c4ccccc4)(c4ccccc4)c4ccccc4)c3)n2)cc1 ; c1ccc(-c2nc(-c3ccccc3)nc(-c3cc(-c4cccc(-c5cccc6c5sc5ccccc56)c4)cc(-c4cccc(-c5cccc6c5sc5ccccc56)c4)c3)n2)cc1]

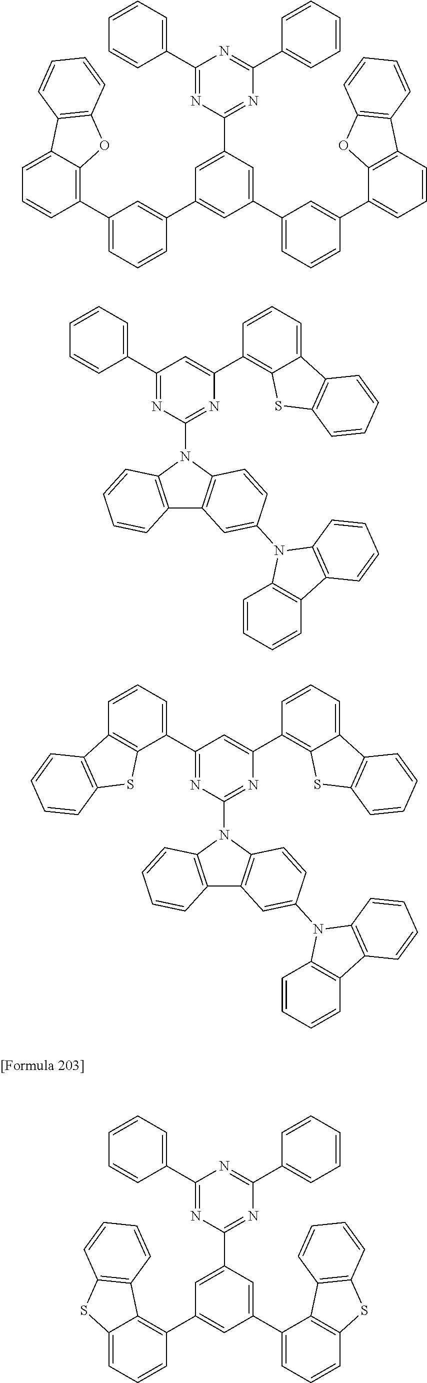 [SMILES: c1ccc(-c2nc(-c3ccccc3)nc(-c3cc(-c4cccc(-c5cccc6c5oc5ccccc56)c4)cc(-c4cccc(-c5cccc6c5oc5ccccc56)c4)c3)n2)cc1 ; c1ccc(-c2cc(-c3cccc4c3sc3ccccc34)nc(-n3c4ccccc4c4cc(-n5c6ccccc6c6ccccc65)ccc43)n2)cc1 ; c1ccc2c(c1)sc1c(-c3cc(-c4cccc5c4sc4ccccc45)nc(-n4c5ccccc5c5cc(-n6c7ccccc7c7ccccc76)ccc54)n3)cccc12 ; c1ccc(-c2nc(-c3ccccc3)nc(-c3cc(-c4cccc5sc6ccccc6c45)cc(-c4cccc5sc6ccccc6c45)c3)n2)cc1]

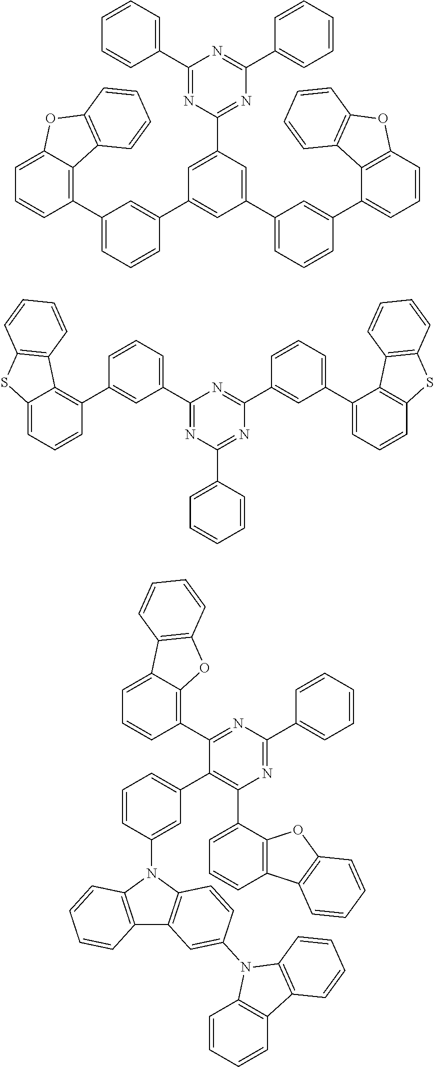 [SMILES: c1ccc(-c2nc(-c3ccccc3)nc(-c3cc(-c4cccc(-c5cccc6oc7ccccc7c56)c4)cc(-c4cccc(-c5cccc6oc7ccccc7c56)c4)c3)n2)cc1 ; c1ccc(-c2nc(-c3cccc(-c4cccc5sc6ccccc6c45)c3)nc(-c3cccc(-c4cccc5sc6ccccc6c45)c3)n2)cc1 ; c1ccc(-c2nc(-c3cccc4c3oc3ccccc34)c(-c3cccc(-n4c5ccccc5c5cc(-n6c7ccccc7c7ccccc76)ccc54)c3)c(-c3cccc4c3oc3ccccc34)n2)cc1]

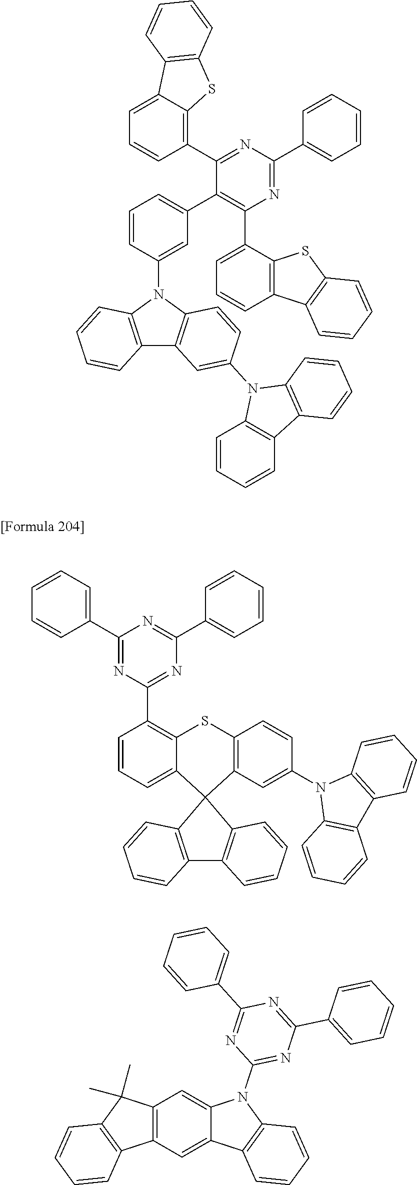 [SMILES: c1ccc(-c2nc(-c3cccc4c3sc3ccccc34)c(-c3cccc(-n4c5ccccc5c5cc(-n6c7ccccc7c7ccccc76)ccc54)c3)c(-c3cccc4c3sc3ccccc34)n2)cc1 ; c1ccc(-c2nc(-c3ccccc3)nc(-c3cccc4c3Sc3ccc(-n5c6ccccc6c6ccccc65)cc3C43c4ccccc4-c4ccccc43)n2)cc1 ; CC1(C)c2ccccc2-c2cc3c4ccccc4n(-c4nc(-c5ccccc5)nc(-c5ccccc5)n4)c3cc21]

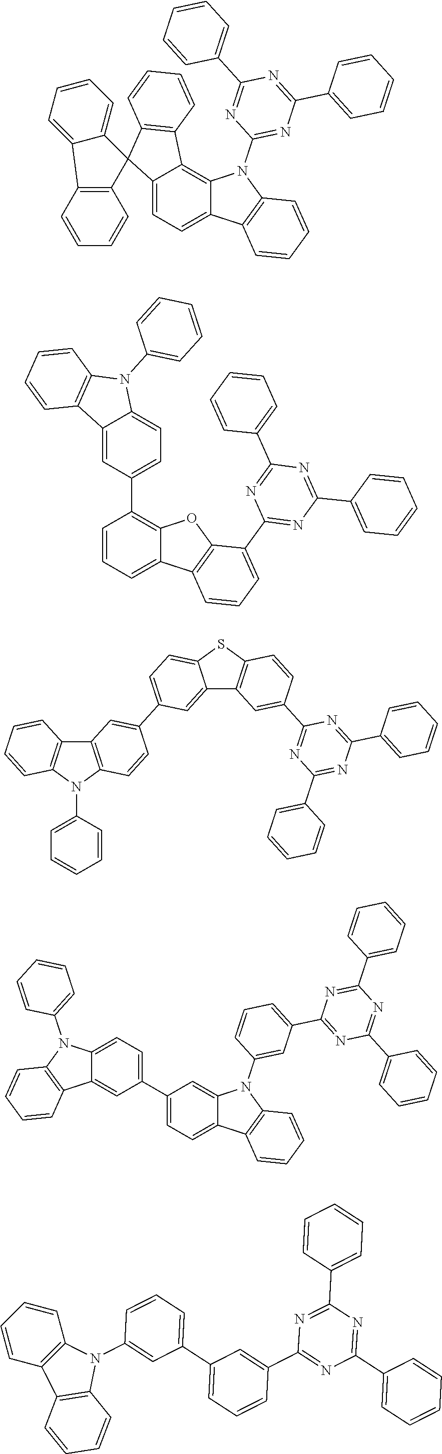

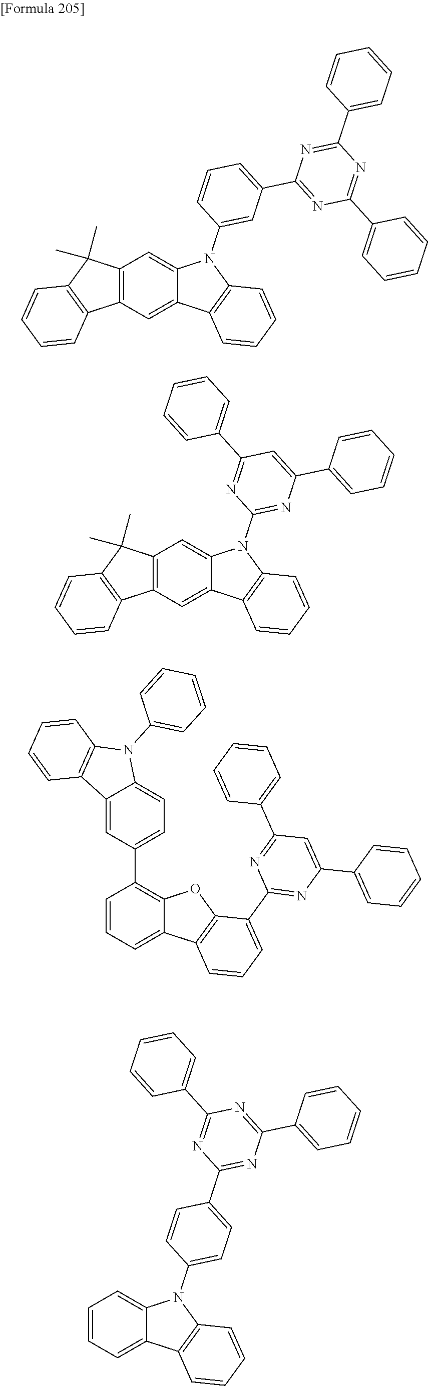

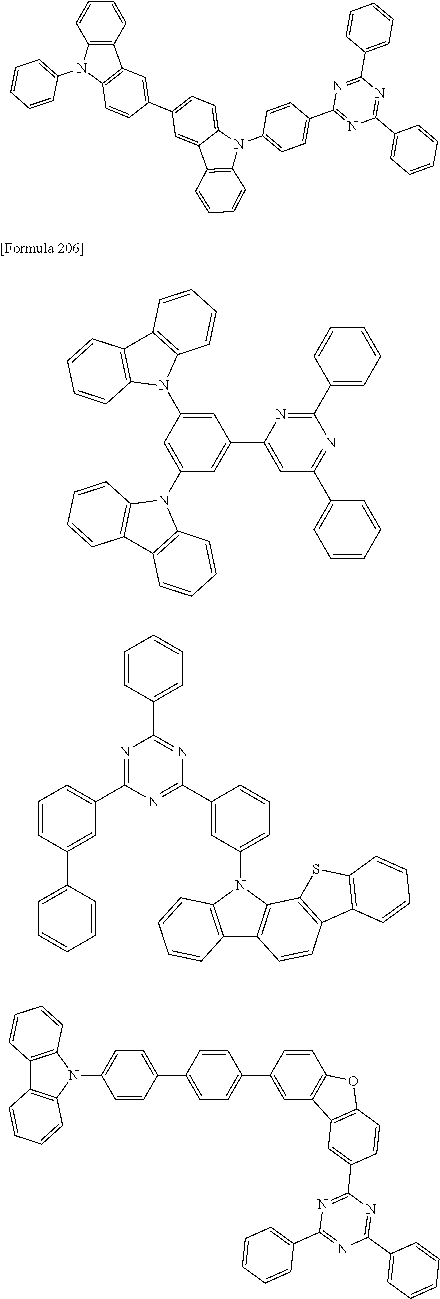 [SMILES: c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2cccc(-c3nc(-c4ccccc4)nc(-c4cccc(-n5c6ccccc6c6ccc7c8ccccc8sc7c65)c4)n3)c2)cc1 ; c1ccc(-c2nc(-c3ccccc3)nc(-c3ccc4oc5ccc(-c6ccc(-c7ccc(-n8c9ccccc9c9ccccc98)cc7)cc6)cc5c4c3)n2)cc1]

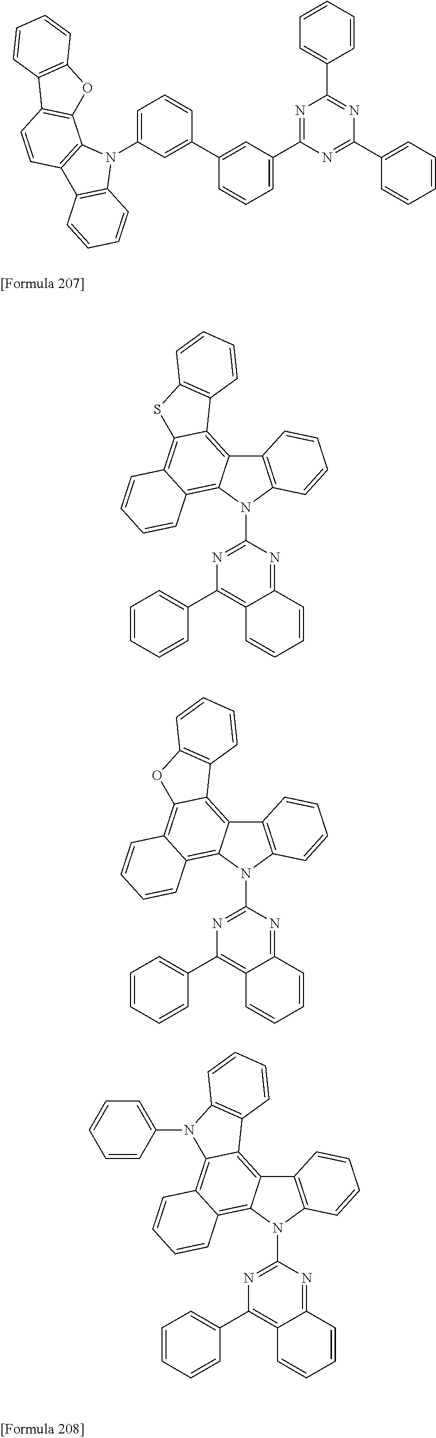

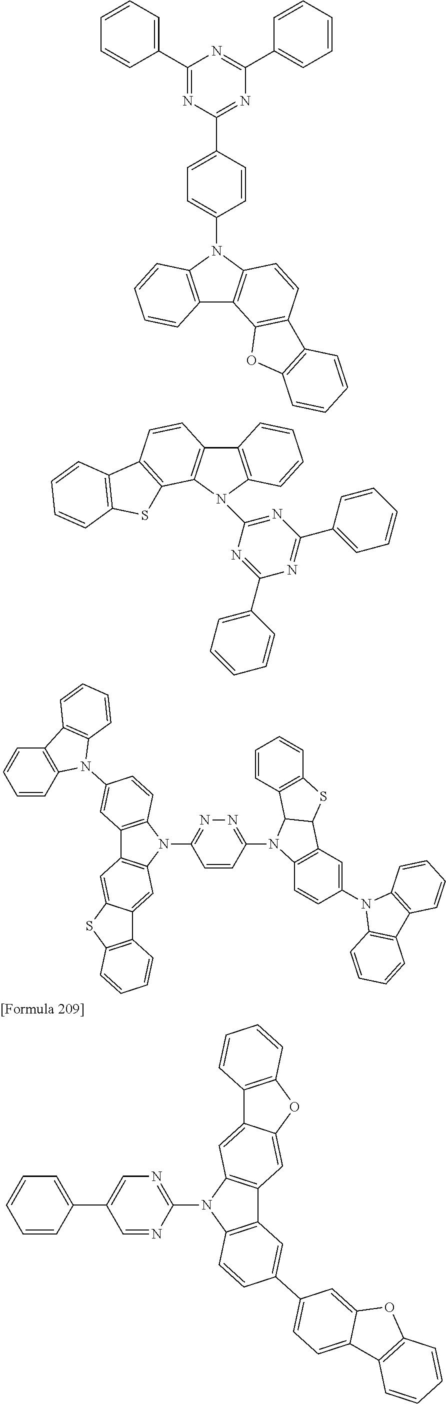

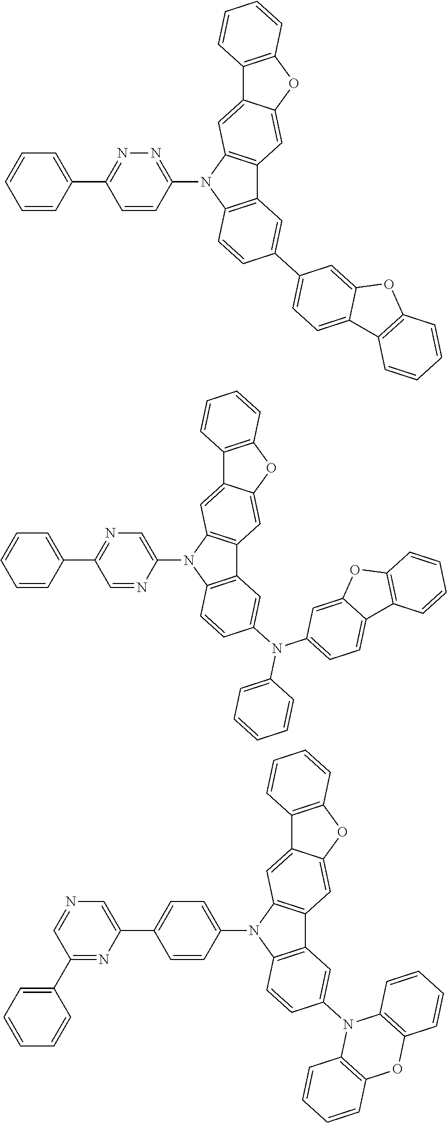

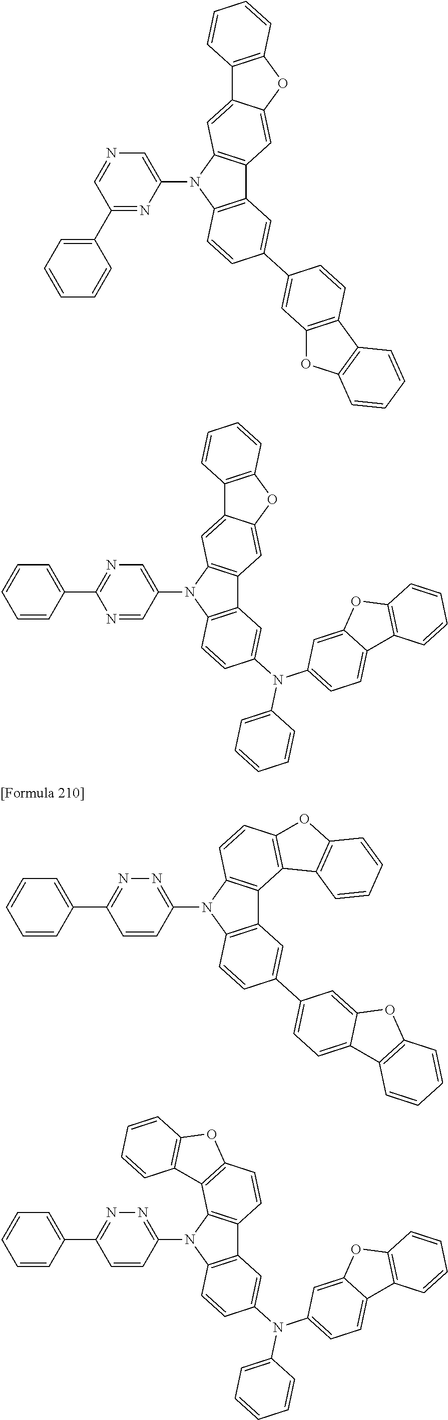 [SMILES: c1ccc(-c2cncc(-n3c4ccc(-c5ccc6c(c5)oc5ccccc56)cc4c4cc5oc6ccccc6c5cc43)n2)cc1 ; c1ccc(-c2ncc(-n3c4ccc(N(c5ccccc5)c5ccc6c(c5)oc5ccccc56)cc4c4cc5oc6ccccc6c5cc43)cn2)cc1 ; c1ccc(-c2ccc(-n3c4ccc(-c5ccc6c(c5)oc5ccccc56)cc4c4c5c(ccc43)oc3ccccc35)nn2)cc1 ; c1ccc(-c2ccc(-n3c4ccc(N(c5ccccc5)c5ccc6c(c5)oc5ccccc56)cc4c4ccc5oc6ccccc6c5c43)nn2)cc1]

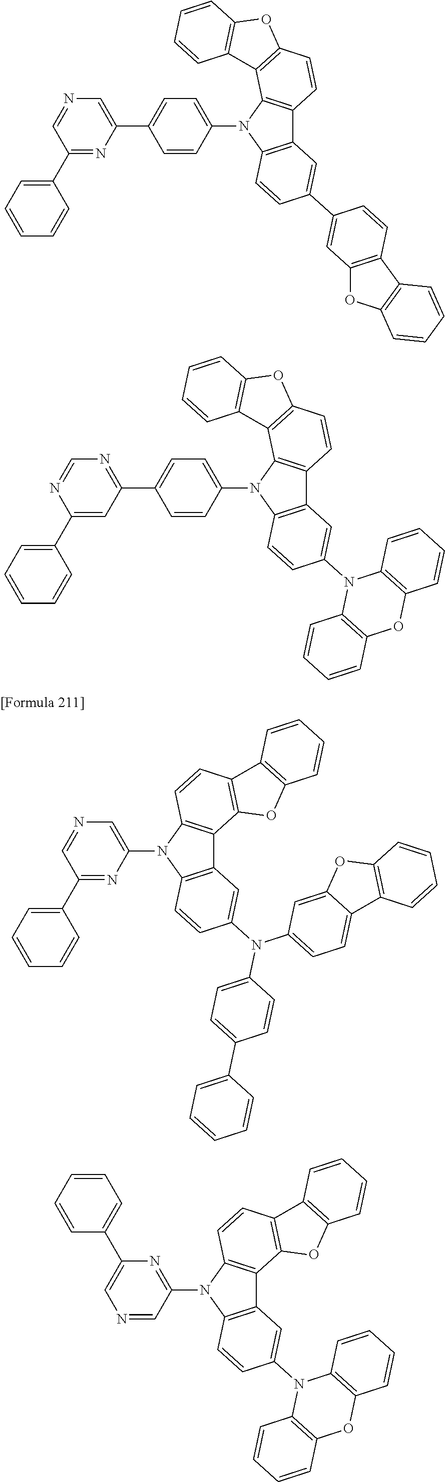 [SMILES: c1ccc(-c2cncc(-c3ccc(-n4c5ccc(-c6ccc7c(c6)oc6ccccc67)cc5c5ccc6oc7ccccc7c6c54)cc3)n2)cc1 ; c1ccc(-c2cc(-c3ccc(-n4c5ccc(N6c7ccccc7Oc7ccccc76)cc5c5ccc6oc7ccccc7c6c54)cc3)ncn2)cc1 ; c1ccc(-c2ccc(N(c3ccc4c(c3)oc3ccccc34)c3ccc4c(c3)c3c5oc6ccccc6c5ccc3n4-c3cncc(-c4ccccc4)n3)cc2)cc1 ; c1ccc(-c2cncc(-n3c4ccc(N5c6ccccc6Oc6ccccc65)cc4c4c5oc6ccccc6c5ccc43)n2)cc1]

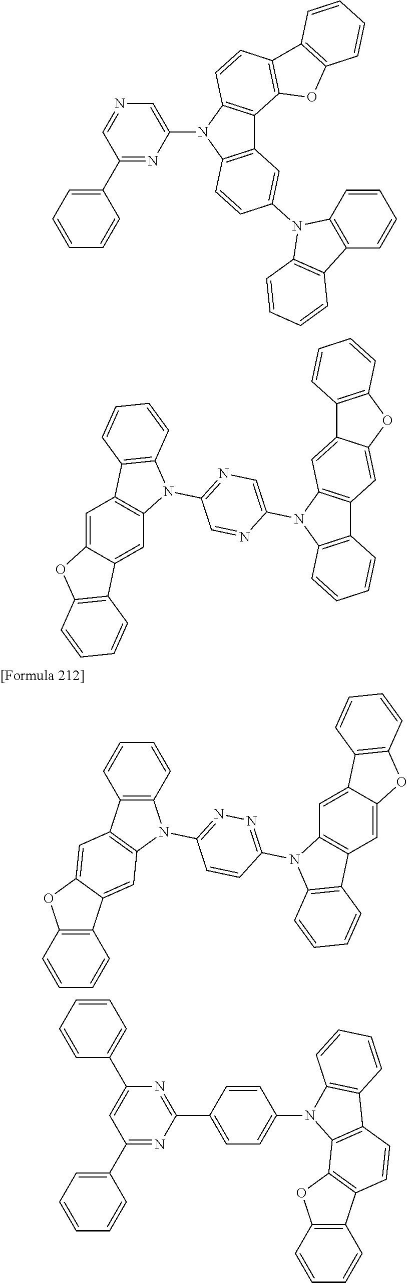

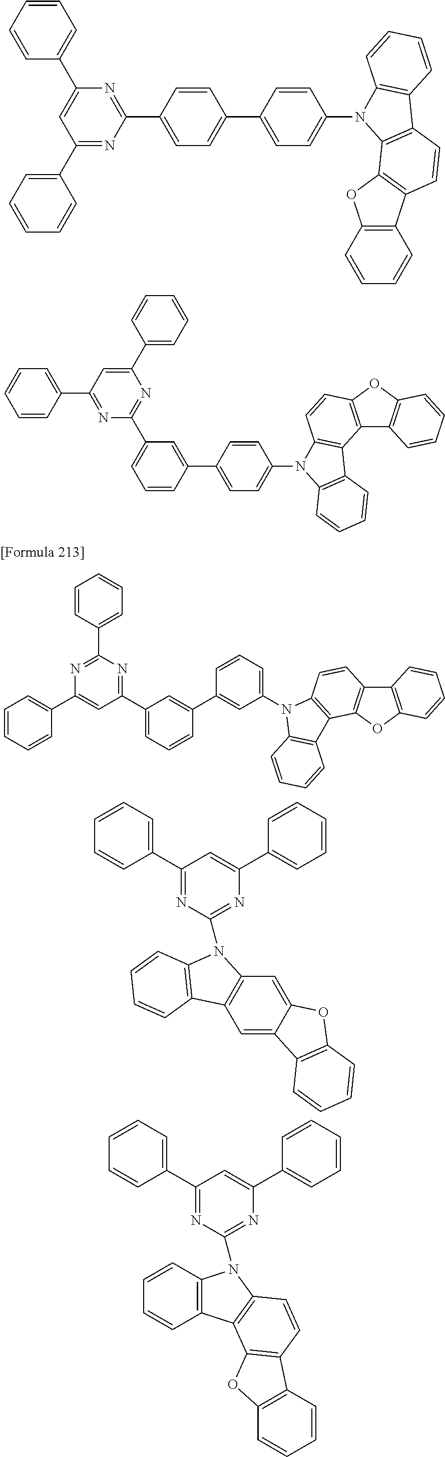

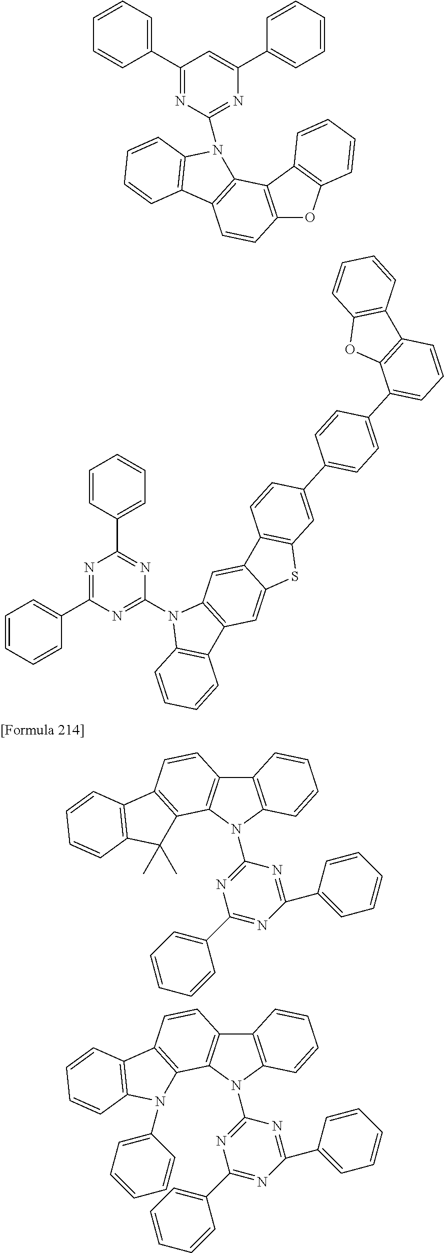

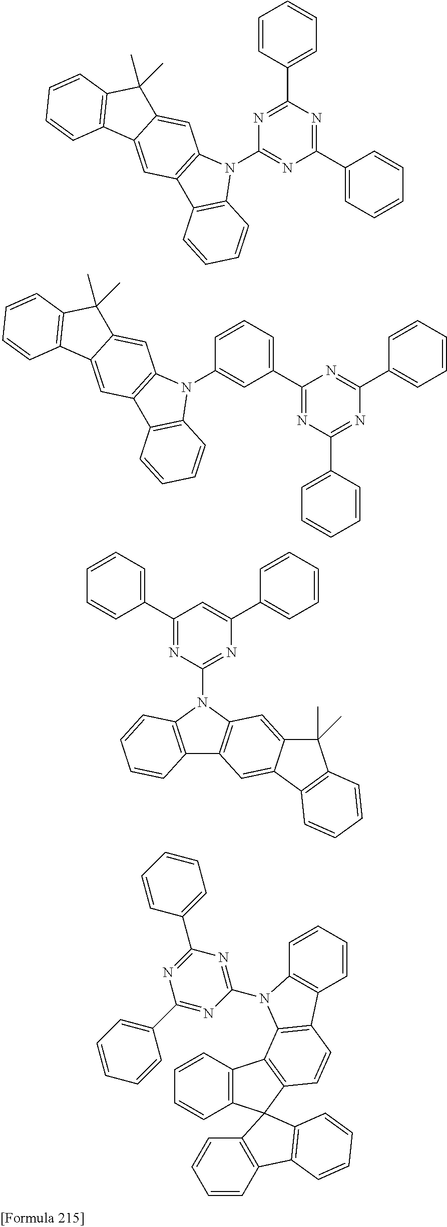

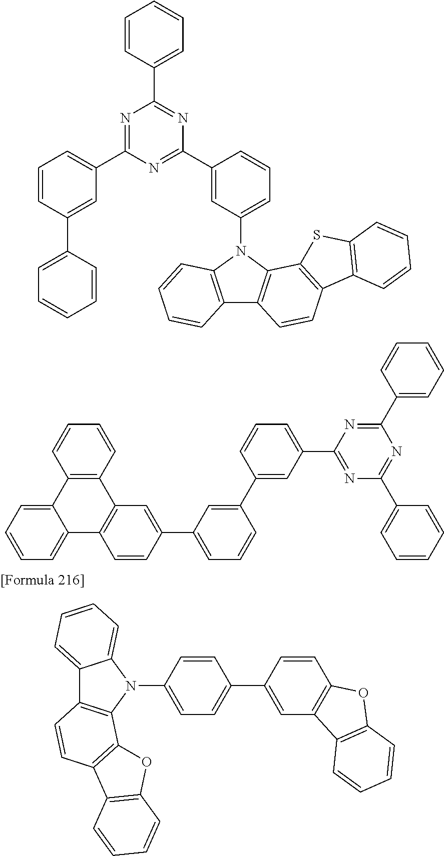 [SMILES: c1ccc(-c2cccc(-c3nc(-c4ccccc4)nc(-c4cccc(-n5c6ccccc6c6ccc7c8ccccc8sc7c65)c4)n3)c2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc2c(c1)oc1ccc(-c3ccc(-n4c5ccccc5c5ccc6c7ccccc7oc6c54)cc3)cc12]

Relationship between Compound M9. Compound M2 and Compound M3 in Emitting Layer

In the organic EL device according to the exemplary embodiment, the singlet energy S₁(Mat2) of the compound M2 and the singlet energy S₁(Mat3) of the compound M3 preferably satisfy a relationship of a numerical formula (Numerical Formula 4) below.

S₁(Mat3)>S₁(Mat2) (Numerical Formula 4)

An energy gap T₇₇ₖ(Mat3) at 77K of the compound M3 is preferably larger than an energy gap T_{77K}(Mat2) at 77K of the compound M2.

The energy gap T_{77K}(Mat3) at 77K of the compound M3 is preferably larger than an energy gap T_{77K}(Mat1) at 77K of the compound M1.

In the organic EL device according to the exemplary embodiment, the singlet energy S₁(Mat2) of the compound M2, the singlet energy S₁(Mat1) of the compound M1, and the singlet energy S₁(Mat3) of the compound M3 preferably satisfy a relationship of a numerical formula (Numerical Formula 5) below.

$${S}_{1} ( Mat 3 ) > {S}_{1} ( Mat 2 ) > {S}_{1} ( Mat 1 ) \qquad ( Numerical Formula 5 )$$

In the organic EL device according to the exemplary embodiment, the energy gap T_{77K}(Mat2) at 77K of the compound M2, the energy gap T_{77K}(Mat1) at 77K of the compound M1, and the energy gap T_{77K}(Mat3) at 77K of the compound M3 preferably satisfy a relationship of a numerical formula (Numerical Formula 5A) below.

$${T}_{77 K} ( Mat 3 ) > {T}_{77 K} ( Mat 2 ) > {T}_{77 K} ( Mat 1 ) \qquad ( Numerical Formula 5 A )$$

It is preferable that mainly the fluorescent compound M1 emits light in the emitting layer when the organic EL device of the exemplary embodiment emits light.

The organic EL device according to the exemplary embodiment preferably emits red light or green light.

The maximum peak wavelength of light emitted from the organic EL device can be measured by the same method as that for the organic EL device of the first exemplary embodiment.

### Content Ratios of Compounds in Emitting Layer

Content ratios of the compound M1, the compound M2, and the compound M3 in the emitting layer preferably fall, for instance, within ranges below.

The content ratio of the compound M1 is preferably in a range from 0.01 mass % to 10 mass %, more preferably in a range from 0.01 mass % to 5 mass %, and still more preferably in a range from 0.01 mass % to 1 mass %.

The content ratio of the compound M2 is preferably in a range from 10 mass % to 80 mass %, more preferably in a range from 10 mass % to 60 mass %, and still more preferably in a range from 20 mass % to 60 mass %.

The content ratio of the compound M3 is preferably in a range from 10 mass % to 80 mass %.

The upper limit of a total of the content ratios of the compound M1, the compound M2, and the compound M3 in the emitting layer is 100 mass %. It should be noted that the emitting layer of the exemplary embodiment may further contain any other material than the compounds M1, M2 and M3.

The emitting layer may contain a single type of the compound M1 or may contain two or more types of the compound M1. The emitting layer may contain a single type of the compound M2 or may contain two or more types of the compound M2 The emitting layer may contain a single type of the compound M3 or may contain two or more types of the compound M3.

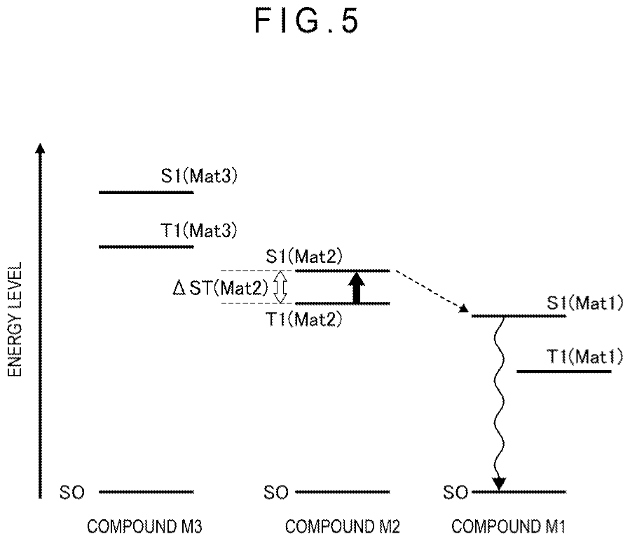

FIG. 5 illustrates an example of a relationship between energy levels of the compound M1, the compound M2, and the compound M3 in the emitting layer. In FIG. 5, S0 represents a ground state. S1(Mat1) represents a lowest singlet state of the compound M1, and T1(Mat1) represents a lowest triplet state of the compound M1. S1(Mat2) represents a lowest singlet state of the compound M2, and T1(Mat2) represents a lowest triplet state of the compound M2. S1(Mat3) represents a lowest singlet state of the compound M3, and T1(Mat3) represents a lowest triplet state of the compound M3. A dashed arrow directed from S1(Mat2) to S1(Mat1) in FIG. 5 represents Forster energy transfer from the lowest singlet state of the compound M2 to the lowest singlet state of the compound M1.

As illustrated in FIG. 5, when a compound having a small ΔST(Mat1) is used as the compound M2, inverse intersystem crossing from the lowest triplet state T1(Mat2) to the lowest singlet state S1(Mat2) can be caused by heat energy. Subsequently. Forster energy transfer from the lowest singlet state S1 (Mat2) of the compound M2 to the compound M1 occurs to generate the lowest singlet state S1(Mat1). Consequently, fluorescence from the lowest singlet state S1(Mat2) of the compound M1 can be observed. It is inferred that the internal quantum efficiency can be theoretically raised up to 100% also by using delayed fluorescence by the TADF mechanism.

According to the second exemplary embodiment, there can be provided an organic EL device excellent in performance, specifically, capable of achieving at least one of low voltage, high efficiency, or long lifetime.

The organic EL device according to the second exemplary embodiment is applicable to an organic EL display device.

The organic EL device according to the second exemplary embodiment is applicable to an electronic device such as a display device and a light-emitting unit.

### Third Exemplary Embodiment

An arrangement of an organic EL device according to a third exemplary embodiment will be described below. In the description of the third exemplary embodiment, the same components as those in the first and second exemplary embodiments are denoted by the same reference signs and names to simplify or omit an explanation of the components. In the third exemplary embodiment, any materials and compounds that are not specified may be the same as those in the first and second exemplary embodiments.

The organic EL device according to the third exemplary embodiment is different from the organic EL device according to the first exemplary embodiment in that the emitting layer contains the delayed fluorescent compound M2 and a compound M4. The third exemplary embodiment is the same as the first exemplary embodiment in other respects.

Specifically, in the organic EL device of the third exemplary embodiment, the emitting layer contains the delayed fluorescent compound M2 and the compound M4; the first layer contains the first compound; the ionization potential of the first compound p(HT1) satisfies the numerical formula (Numerical Formula 1); and the hole mobility of the first compound μh(HT1) satisfies the numerical formula (Numerical Formula 2). The first layer has a film thickness of 15 nm or more.

In the third exemplary embodiment, the compound M2 in the emitting layer is preferably a dopant material, and the compound M4 is preferably a host material. The compound M4 may be a delayed fluorescent compound or a compound exhibiting no delayed fluorescence.

The compound M4 is not particularly limited, and the compound M3 described in the second exemplary embodiment is usable as the compound M4.

As the first compound, the first compound described in the first exemplary embodiment is usable.

As the compound M2, the compound M2 described in the first exemplary embodiment is usable.

### Relationship Between Compound M2 and Compound M4 in Emitting Layer

In the organic EL device according to the exemplary embodiment, the singlet energy S₁(Mat2) of the compound M2 and the singlet energy S₁(Mat4) of the compound M4 preferably satisfy a relationship of a numerical formula (Numerical Formula 6) below.

S₁(Mat4)>S₁(Mat2) (Numerical Formula 6)

An energy gap T_{77K}(Mat4) at 77K of the compound M4 is preferably larger than an energy gap T_{77K}(Mat2) at 77K of the compound M2.

When the organic EL device according to the exemplary embodiment emits light, it is preferable that the compound M2 mainly emits light in the emitting layer.

### Content Ratios of Compounds in Emitting Layer

For instance, the content ratios of the compound M2 and the compound M4 in the emitting layer preferably fall within ranges shown below.

The content ratio of the compound M2 is preferably in a range from 10 mass % to 80 mass %, more preferably in a range from 10 mass % to 60 mass %, and still more preferably in a range from 20 mass % to 60 mass %.

The content ratio of the compound M4 is preferably in a range from 20 mass % to 90 mass %, more preferably in a range from 40 mass #(to 90 mass %, and still more preferably in a range from 40 mass % to 80 mass %.

It should be noted that the emitting layer of the exemplary embodiment may contain any other material than the compound M2 and the compound M4.

The emitting layer may contain a single type of the compound M2 or may contain two or more types of the compound M2. The emitting layer may contain a single type of the fourth compound or may contain two or more types of the fourth compound.

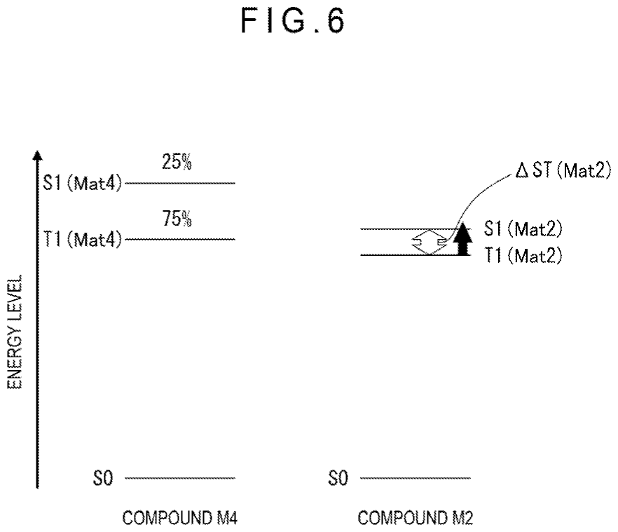

FIG. 6 illustrates an example of a relationship between energy levels of the compound M2 and the compound M4 in the emitting layer. In FIG. 6, S0 represents a ground state S1(Mat2) represents a lowest singlet state of the compound M2, and T1(Mat2) represents a lowest triplet state of the compound M2. S1(Mat4) represents a lowest singlet state of the compound M4, and T1 (Mat4) represents a lowest triplet state of the compound M4 As illustrated in FIG. 6, when a material having a small ΔST(Mat2) is used as the compound M2, inverse intersystem crossing from the lowest triplet state T1 of the compound M2 to the lowest singlet state Si can be caused by heat energy.

The inverse intersystem crossing caused in the compound M2 enables light emission from the lowest singlet state S1(Mat2) of the compound M2 to be observed when the emitting layer does not contain a fluorescent dopant with the lowest singlet state S1 smaller than the lowest singlet state S1(Mat2) of the compound M2. It is inferred that the internal quantum efficiency can be theoretically raised up to 100% also by using delayed fluorescence by the TADF mechanism.

According to the third exemplary embodiment, there can be provided an organic EL device excellent in performance, specifically, capable of achieving at least one of low voltage, high efficiency, or long lifetime.

The organic EL device according to the third exemplary embodiment is applicable to an organic EL display device.

The organic EL device according to the third exemplary embodiment is applicable to an electronic device such as a display device and a light-emitting unit.

### Fourth Exemplary Embodiment

An arrangement of an organic EL device according to a fourth exemplary embodiment will be described below. In the description of the fourth exemplary embodiment, the same components as those in the first to third exemplary embodiments are denoted by the same reference signs and names to simplify or omit an explanation of the components. In the fourth exemplary embodiment, any materials and compounds that are not specified may be the same as those in the first to third exemplary embodiments.

The organic EL device according to the fourth exemplary embodiment is different from the organic EL devices according to the above exemplary embodiments in that a second layer is further provided between the anode and the first layer. The second layer contains a second compound. The first compound and the second compound are different compounds. The rest of the arrangement of the organic EL device according to the fourth exemplary embodiment is the same as the above exemplary embodiments.

Specifically, the organic EL device according to the fourth exemplary embodiment may be any of the organic EL devices below.
An organic EL device further including the second layer between the anode and the first layer in the first exemplary embodiment. The emitting layer represents the same as the emitting layer of the first exemplary embodiment.
An organic EL device further including the second layer between the anode and the first layer in the second exemplary embodiment. The emitting layer represents the same as the emitting layer of the second exemplary embodiment.
An organic EL device further including the second layer between the anode and the first layer in the third exemplary embodiment. The emitting layer represents the same as the emitting layer of the third exemplary embodiment.

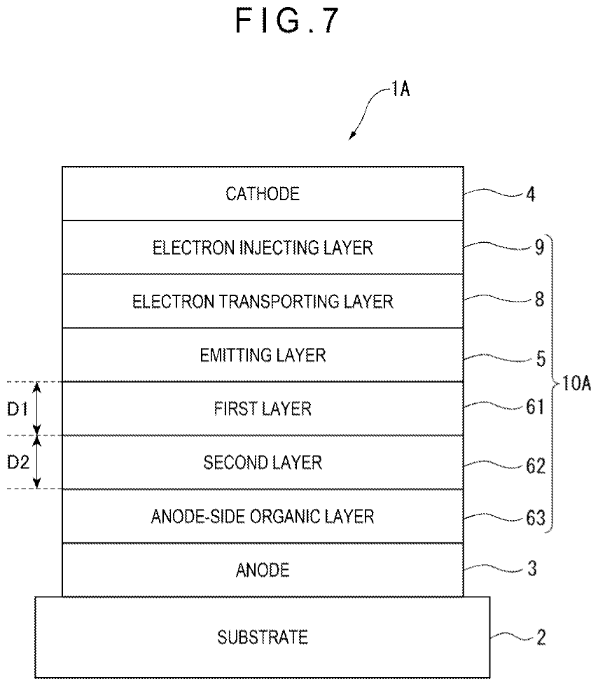

FIG. 7 schematically depicts an exemplary arrangement of an organic EL device according to the fourth exemplary embodiment.

FIG. 7 depicts a case where the emitting layer 5 of the first exemplary embodiment is applied as the emitting layer.

An organic EL device 1A includes the light-transmissive substrate 2, the anode 3, the cathode 4, and organic layers 10A provided between the anode 3 and the cathode 4. The organic layers 10A include the anode-side organic layer 63, a second layer 62, the first layer 61, the emitting layer 5, the electron transporting layer 8, and the electron injecting layer 9, which are sequentially layered on the anode 3. In FIG. 1, D1 represents a film thickness of the first layer 61 and D2 represents a film thickness of the second layer 62. D1 is 15 nm or more.

According to the fourth exemplary embodiment, there can be provided an organic EL device excellent in performance, specifically, capable of achieving at least one of low voltage, high efficiency, or long lifetime.

The organic EL device according to the fourth exemplary embodiment is applicable to an organic EL display device.

The organic EL device according to the fourth exemplary embodiment is applicable to an electronic device such as a display device and a light-emitting unit.

### Second Layer

In the fourth exemplary embodiment, the second layer is preferably the hole transporting layer.

In the fourth exemplary embodiment, the second layer is preferably adjacent to the first layer.

In a case of FIG. 7, the second layer is preferably adjacent to the anode-side organic layer.

In an exemplary arrangement of the fourth exemplary embodiment, the film thickness of the second layer is in a range from 20 to 200 nm

### Second Compound

The second layer contains the second compound. The second compound is not particularly limited, and it is possible to use, as the second compound, a material usable for the hole transporting layer (e.g., an aromatic amine compound, a carbazole derivative, and an anthracene derivative) described in the above Arrangement of Organic EL Device.

### Ionization Potential of Second Compound Ip(HT2)

The ionization potential of the second compound Ip(HT2) preferably satisfies a numerical formula (Numerical Formula 11) below.

Ip(HT2)≥5.0 eV (Numerical Formula 11)

Hole Mobility of Second Compound μh(HT2)

The hole mobility of the second compound μh(HT2) preferably satisfies a numerical formula (Numerical Formula 12) below.

$$μ h ( HT 2 ) \geq 1. \times {10}^{- 5} {cm}^{2} / Vs \qquad ( Numerical Formula 12 )$$

In the fourth exemplary embodiment, it is preferable that the ionization potential of the second compound Ip(HT2) satisfies the numerical formula (Numerical Formula 11) and the hole mobility of the second compound μh(HT2) satisfies the numerical formula (Numerical Formula 12).

### Fifth Exemplary Embodiment

### Organic Electroluminescence Display Device

An organic EL display device of a fifth exemplary embodiment is an organic electroluminescence display device including: an anode and a cathode arranged opposite each other; a blue-emitting organic EL device as a blue pixel; a green-emitting organic EL device as a green pixel; and a red-emitting organic EL device as a red pixel, in which the green pixel includes the organic EL device according to any of the first to fourth exemplary embodiments as the green-emitting organic EL device,
the green-emitting organic EL device includes a green emitting layer as the emitting layer, and the first layer provided between the green emitting layer and the anode,
the blue-emitting organic EL device includes a blue emitting layer disposed between the anode and the cathode and a blue organic layer disposed between the blue emitting layer and the anode, and
the red-emitting organic EL device includes a red emitting layer disposed between the anode and the cathode and a red organic layer disposed between the red emitting layer and the anode.

In the organic EL display device of the fifth exemplary embodiment, the green-emitting organic EL device included in the green pixel is an organic EL device that emits light using the TADF mechanism, and the green-emitting organic EL device is the organic EL device according to any of the first to fourth exemplary embodiments.

Specifically, in the organic EL display device of the fifth exemplary embodiment, the first layer provided between the green emitting layer and the anode contains the first compound satisfying specific parameters (Numerical Formula 1 and Numerical Formula 2); and the first layer has a film thickness of 15 nm or more.

Thus, in the organic EL display device of the fifth exemplary embodiment, cavity adjustment can be easily performed, for instance, by simply increasing the film thickness of the first layer of the green-emitting organic EL device.

The organic EL display device of the fifth exemplary embodiment is excellent in performance, because it includes the green-emitting organic EL device that achieves at least one of tow voltage, high efficiency, or long lifetime.

Herein, “blue”, “green”, or “red” used for each element, such as “pixel”, “emitting layer”, “organic layer, or “material”, is used to distinguish one from another. Although “blue”, “green”, or red” may represent a color of tight emitted from “pixel”, “emitting layer”, “organic layer”, or “material”, “blue”, “green”, or “red” does not mean the color of appearance of each element.

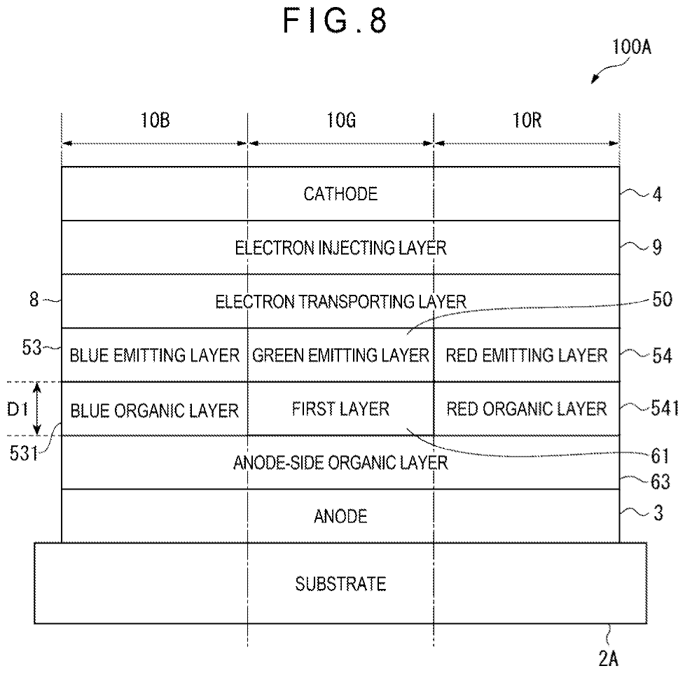

Referring to FIG. 8, an exemplary arrangement of an organic EL display device according to the fifth exemplary embodiment will be described below.

FIG. 8 depicts an organic EL display device 100A according to an exemplary embodiment.

The organic EL display device 100A includes electrodes and organic layers supported by a substrate 2A.

The organic EL display device 100A includes the anode 3 and the cathode 4 arranged opposite each other.

The organic EL display device 100A includes a blue-emitting organic EL device 10B as a blue pixel, a green-emitting organic EL device 10G as a green pixel, and a red-emitting organic EL device 10R as a red pixel.

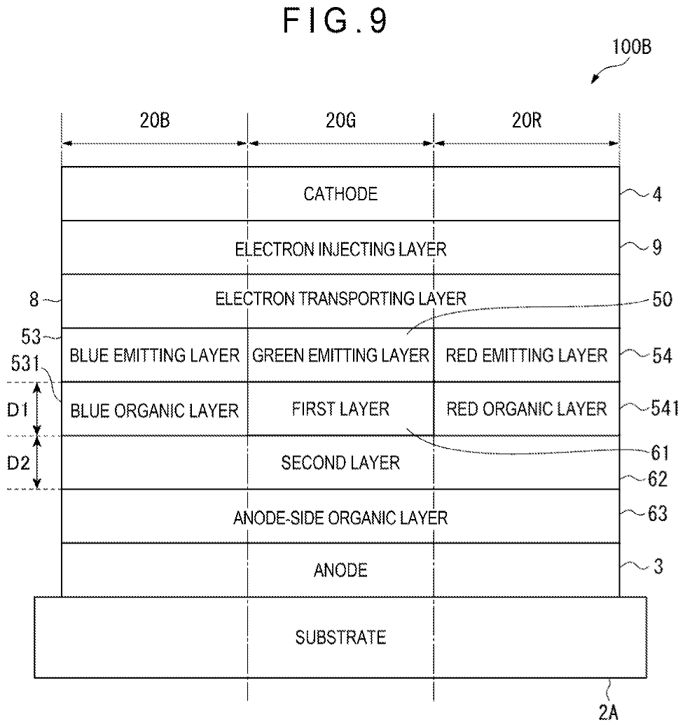

FIG. 8, which schematically depicts the organic EL display device 100A, does not limit a size of the device 100A, a thickness of each layer of the device 110A, and the like. For instance, although a blue emitting layer 53, a green emitting layer 50, and a red emitting layer 54 in FIG. 8 have the same thickness, these layers may have different thicknesses in an actual organic EL display device. The same applies to an organic EL display device depicted in FIG. 9.

In the blue-emitting organic EL device 10B, a blue organic layer 531 as a non-common layer is provided between the blue emitting layer 53 and the anode-side organic layer 63. The blue organic layer 531 is in direct contact with the blue emitting layer 53. The blue organic layer 531 is preferably an electron blocking layer.

In the green-emitting organic EL device 10G, the first layer 61 as a non-common layer is provided between the green emitting layer 50 and the anode-side organic layer 63. The green emitting layer 50 corresponds to the emitting layer according to any of the first exemplary embodiment, the second exemplary embodiment, and the third exemplary embodiment. The first layer 61 corresponds to the first layer according to any of the first exemplary embodiment, the second exemplary embodiment, and the third exemplary embodiment.

The first layer 61 is in direct contact with the green emitting layer 50. The first layer 61 is preferably an electron blocking layer.

In the red-emitting organic EL device 10R, a red organic layer 541 as a non-common layer is provided between the red emitting layer 54 and the anode-side organic layer 63. The red organic layer 541 is in direct contact with the red emitting layer 54. The red organic layer 541 is preferably an electron blocking layer.

In the blue-emitting organic EL device 10B, the green-emitting organic EL device 10G, and the red-emitting organic EL device 10R of the organic EL display device 100A, the anode-side organic layer 63 as a common layer is provided between the anode 3 and the blue emitting layer 53, the green emitting layer 50, and the red emitting layer 54.

Further, between the cathode 4 and the blue emitting layer 53, the green emitting layer 50, and the red emitting layer 54, the electron transporting layer 8 and the electron injecting layer 9 as common layers are layered in this order from the side close to the anode 3.

The anode 3 is independently provided for each of the blue-emitting organic EL device 10B, the green-emitting organic EL device 10G, and the red-emitting organic EL device 10R. Thus, the blue-emitting organic EL device 10B, the green-emitting organic EL device 10G, and the red-emitting organic EL device 10R can be individually driven in the organic EL display device 100A. The respective anodes of the organic EL devices 10B, 10G, and 10R are insulated from each other by an insulation material (not illustrated in the drawings). The cathode 4 is provided in a shared manner across the blue-emitting organic EL device 108, the green-emitting organic EL device 100, and the red-emitting organic EL device 10R.

In an exemplary embodiment, the blue-emitting organic EL device 10B, the green-emitting organic EL device 100, and the red-emitting organic EL device 14R as pixels are arranged in parallel with each other on the substrate 2A.

In the organic EL display device according to the fifth exemplary embodiment, the common layer(s) is/are preferably provided between the anode(s) and the blue organic layer, the first layer, and the red organic layer in a shared manner across the blue-emitting organic EL device, the green-emitting organic EL device, and the red-emitting organic EL device.

FIG. 9 schematically depicts another exemplary arrangement of an organic EL display device according to the fifth exemplary embodiment.

In an organic EL display device 100B depicted in FIG. 9, the second layer 62 (common layer) is provided between the anode(s) 3 (the anode-side organic layer 63 in a case of FIG. 9) and the blue organic layer 531, the first layer 61, and the red organic layer 541 in a shared manner across the blue-emitting organic EL device 10B, the green-emitting organic EL device 10G, and the red-emitting organic EL device 10R. The rest of the arrangement of the organic EL display device 100B is the same as the organic EL display device 100A depicted in FIG. 8.

The second layer 62 as a common layer corresponds to the second layer 62 of the fourth exemplary embodiment.

The common layer (second layer 62) is preferably adjacent to the blue organic layer 531, the first layer 61, and the red organic layer 541.

Further, the second layer 62 is preferably in direct contact with the anode-side organic layer 63.

The invention is not limited to the arrangement of the organic EL display device depicted in each of FIG. 8 and FIG. 9.

For instance, in an exemplary arrangement of the organic EL display device of the exemplary embodiment, the blue-emitting organic EL, device, the green-emitting organic EL device, and the red-emitting organic EL device may each independently further include any other layer than the layers depicted in FIGS. 8 to 9. For instance, a hole blocking layer may be provided as a common layer between the electron transporting layer and the emitting layer.

For instance, in an exemplary arrangement of the organic EL display device of the exemplary embodiment, the blue-emitting organic EL device and the red-emitting organic EL device may be each independently a device that fluoresces or a device that phosphoresces. The green-emitting organic EL device is preferably a device that fluoresces.

In an exemplary arrangement of the organic EL display device of the exemplary embodiment, the blue emitting layer contains a host material. For instance, the blue emitting layer contains 50 mass % or more of the host material with respect to a total mass of the blue emitting layer.

In an exemplary arrangement of the organic EL display device of the exemplary embodiment, the blue emitting layer of the blue-emitting organic EL device contains a blue emitting compound that emits light having a maximum peak wavelength in a range from 430 nm to 500 nm. The blue emitting compound is, for instance, a fluorescent compound that emits fluorescence having a maximum peak wavelength in a range from 430 nm to 500 nm. Further, the blue emitting compound is, for instance, a phosphorescent compound that exhibits phosphorescence having a maximum peak wavelength in a range from 430 nm to 500 nm. Herein, the blue light emission refers to a light emission in which the maximum peak wavelength of emission spectrum is in a range from 430 nm to 500 nm.

The fluorescent compound is a compound capable of emitting in a singlet excited state. The phosphorescent compound is a compound capable of emitting in a triplet excited state.

Examples of a blue fluorescent compound usable for the blue emitting layer include a pyrene derivative, a styrylamine derivative, a chrysene derivative, a fluoranthene derivative, a fluorene derivative, a diamine derivative, and a triarylamine derivative. Specific examples thereof include N,N′-bis[4-(9H-carbazole-9-yl)phenyl]-N, N′-diphenylstilbene-4,4′-diamine (abbreviation. YGA2S), 4-(9H-carbazole-9-yl)-4′-(10-phenyl-9-anthryl)triphenylamine (abbreviation: YGAPA), and 4-(10-phenyl-9-anthryl)-4′-(9-phenyl-9H-carbazole-3-yl)triphenylamine (abbreviation: PCBAPA).

Examples of a blue phosphorescent compound usable for the blue emitting layer include metal complexes such as an iridium complex, an osmium complex, and a platinum complex. Specific examples thereof include bis[2-(4′,6′-difluorophenyl)pyridinato-N,C2′]iridium(III)tetrakis(1-pyrazoyl)borate (abbreviation: FIr6), bis[2-(4′,6difluorophenyl)pyridinato-N,C2′]indium(III)picolinate (abbreviation: Flrpic), bis[2-(3′,5′bistrifluoromethylphenyl)pyridinato-N,C2′]iridium(III)picolinate (abbreviation: Ir(CF3ppy)2(pic)), and bis[2-(4′,6′-difluorophenyl)pyridinato-N,C2′]iridium(III)acetylacetonato (abbreviation: Flracac).

Maximum Phosphorescence Peak Wavelength (PH-peak) A maximum peak wavelength (maximum phosphorescence peak wavelength) of a phosphorescent compound is measurable by the following method. A measurement target compound is dissolved in EPA (diethylether: isopentane ethanol=5:5:2 in volume ratio) so as to fall within a range from 10⁻⁶ mol/L to 10⁻⁴ mol/L, and the obtained EPA solution is encapsulated in a quartz cell to provide a measurement sample. A phosphorescence spectrum (ordinate axis: phosphorescent luminous intensity, abscissa axis: wavelength) of the measurement sample is measured at a low temperature (77K). The local maximum value closest to the short-wavelength region among the local maximum values of the phosphorescence spectrum is defined as the maximum phosphorescence peak wavelength. A spectrophotofluorometer F-7004 produced by Hitachi High-Tech Science Corporation can be used to measure phosphorescence. Any apparatus for phosphorescence measurement is usable. A combination of a cooling unit, a low temperature container, an excitation light source and a light-receiving unit may be used for phosphorescence measurement. Herein: the maximum peak wavelength of phosphorescence is occasionally referred to as the maximum phosphorescence peak wavelength (PH-peak).

In an exemplary arrangement of the organic EL display device of the exemplary embodiment, the blue-emitting organic EL device preferably includes the blue organic layer between the blue emitting layer and the anode-side organic layer. The blue organic layer may be in direct contact with the anode-side organic layer. The blue organic layer may be in direct contact with the blue emitting layer.

In another exemplary arrangement of the organic EL display device of the exemplary embodiment, the blue-emitting organic EL device includes the blue organic layer between the blue emitting layer and the second layer. The blue organic layer may be in direct contact with the second layer. The blue organic layer may be in direct contact with the blue emitting layer.

An emission position in the blue-emitting organic EL device is easily adjustable by providing the blue organic layer in the blue-emitting organic EL device.

The blue organic layer contains a blue organic material. As the blue organic material, for instance, it is possible to use a material usable for the hole transporting layer (e.g., an aromatic amine compound, a carbazole derivative, and an anthracene derivative) described in the above Arrangement of Organic EL Device.

When the organic EL display device of the exemplary embodiment includes the second layer, the blue organic material and the second compound contained in the second layer may be the same compound or different compounds. However, the blue organic material is preferably different from the second compound.

The blue organic material is a compound different from the host material and the blue emitting compound contained in the blue emitting layer.

In an exemplary arrangement of the organic EL display device of the exemplary embodiment, the red emitting layer contains a host material. For instance, the red emitting layer contains 50 mass % or more of the host material with respect to a total mass of the red emitting layer.

In an exemplary arrangement of the organic EL display device of the exemplary embodiment, the red emitting layer of the red-emitting organic EL device contains a red emitting compound that emits light having a maximum peak wavelength in a range from 600 nm to 640 nm. The red emitting compound is, for instance, a fluorescent compound that emits fluorescence having a maximum peak wavelength in a range from 600 nm to 640 nm. Further, the red emitting compound is, for instance, a phosphorescent compound that exhibits phosphorescence having a maximum peak wavelength in a range from 600 nm to 640 nm. Herein, the red light emission refers to a light emission in which the maximum peak wavelength of emission spectrum is in a range from 800 nm to 640 nm.

Examples of a red fluorescent compound usable for the red emitting layer include a tetracene derivative and a diamine derivative. Examples of a red phosphorescent compound usable for the red emitting layer include metal complexes such as an iridium complex, platinum complex, terbium complex, and europium complex.

In an exemplary arrangement of the organic EL display device of the exemplary embodiment, the red-emitting organic EL device preferably includes the red organic layer between the red emitting layer and the anode-side organic layer. The red organic layer may be in direct contact with the anode-side organic layer. The red organic layer may be in direct contact with the red emitting layer.

In another exemplary arrangement of the organic EL display device of the exemplary embodiment, the red-emitting organic EL device includes the red organic layer between the red emitting layer and the second layer. The red organic layer may be in direct contact with the second layer. The red organic layer may be in direct contact with the red emitting layer.

An emission position in the red-emitting organic EL device is easily adjustable by providing the red organic layer in the red-emitting organic EL device.

The red organic layer contains a red organic material. As the red organic material, for instance, it is possible to use a material usable for the hole transporting layer (e.g., an aromatic amine compound, a carbazole derivative, and an anthracene derivative) described in the above Arrangement of Organic EL Device.

When the organic EL display device of the exemplary embodiment includes the second layer, the red organic material and the second compound contained in the second layer may be the same compound or different compounds. However, the red organic material is preferably different from the second compound.

The red organic material is a compound different from the host material and the red emitting compound contained in the red emitting layer.

Although the red organic material contained in the red organic layer of the red-emitting organic EL device and the blue organic material contained in the blue organic layer of the blue-emitting organic EL device may be the same compound or different compounds, the red organic material is preferably different from the blue organic material.

In an exemplary arrangement of the organic EL display device of the exemplary embodiment, the host material contained in the blue emitting layer and the host material contained in the red emitting layer are, for instance, a compound for dispersing a highly emittable substance (dopant material) in the emitting layers. As the host material contained in the blue emitting layer and the host material contained in the red emitting layer, it is possible to use, for instance, a substance having a higher Lowest Unoccupied Molecular Orbital (LUMO) level and a lower Highest Occupied Molecular Orbital (HOMO) level than the highly emittable substance.

For instance, the following compounds (1) to (4) can be each independently used as the host material contained in the blue emitting layer and the host material contained in the red emitting layer.
(1) a metal complex such as an aluminum complex, beryllium complex, and zinc complex
(2) a heterocyclic compound such as an oxadiazole derivative, benzimidazole derivative, or phenanthroline derivative
(3) a fused aromatic compound such as a carbazole derivative, anthracene derivative, phenanthrene derivative, pyrene derivative, or chrysene derivative
(4) an aromatic amine compound such as a triarylamine derivative or a fused polycyclic aromatic amine derivative

Referring to FIG. 8, the organic EL display device according to the exemplary embodiment will be further described. Descriptions on the same arrangements as those of the organic EL device according to the first exemplary embodiment are simplified or omitted.

### Anode

In an exemplary embodiment, the anode 3 is arranged opposite to the cathode 4.

In an exemplary embodiment, the anode 3 is typically a non-common layer In an exemplary embodiment, for instance, when the anode 3 is a non-common layer, the respective anodes in the blue-emitting organic EL device 109, the green-emitting organic EL device 10G and the red-emitting organic EL device 10R are physically separated from each other, and specifically, may be insulated from each other by an insulation material (not illustrated in the drawings) or the like.

### Cathode

In an exemplary embodiment, the cathode 4 is arranged opposite to the anode 3.

In an exemplary embodiment, the cathode 4 may be a common layer or a non-common layer.

In an exemplary embodiment, the cathode 4 is preferably a common layer provided in a shared manner across the blue-emitting organic EL device 10B, the green-emitting organic EL device 10G, and the red-emitting organic EL device 10R.

In an exemplary embodiment, the cathode 4 is in direct contact with the electron injecting layer 9.

In an exemplary embodiment, when the cathode 4 is a common layer, the film thickness of the cathode 4 is constant over the blue-emitting organic EL device 10B, the green-emitting organic EL device 10G, and the red-emitting organic EL device 10R. When the cathode 4 is a common layer, the cathode 4 provided for the blue-emitting organic EL device 10B, the green-emitting organic EL device 10G, and the red-emitting organic EL device 10R can be produced without changing a mask or the like. The organic EL display device 100A thus has enhanced productivity.

### Electron Transporting Layer

In an exemplary embodiment, the electron transporting layer 8 is a common layer provided in a shared manner across the blue-emitting organic EL device 10B, the green-emitting organic EL device 10G, and the red-emitting organic EL device 10R.

In an exemplary embodiment, the electron transporting layer 8 is provided between the electron injecting layer 9 and the emitting layers of the blue-emitting organic EL device 10B, the green-emitting organic EL device 10G, and the red-emitting organic EL device 10R.

In an exemplary embodiment, the side of the electron transporting layer 8 close to the anode 3 is in direct contact with the blue emitting layer 53, the green emitting layer 50, and the red emitting layer 54.

The side of the electron transporting layer 8 close to the cathode 4 is in direct contact with the electron injecting layer 9.

In an exemplary embodiment, the electron transporting layer 8 is a common layer, and the film thickness of the electron transporting layer 8 is constant over the blue-emitting organic EL device 10B, the green-emitting organic EL device 10G, and the red-emitting organic EL device 10R. When the electron transporting layer 8 is a common layer, the electron transporting layer 8 provided for the blue-emitting organic EL device 108, the green-emitting organic EL device 10G, and the red-emitting organic EL device 10R can be produced without changing a mask or the like. The organic EL display device 100A thus has enhanced productivity.

Electron Injecting Layer In an exemplary embodiment, the electron injecting layer 9 is a common layer provided in a shared manner across the blue-emitting organic EL device 10B, the green-emitting organic EL device 10G, and the red-emitting organic EL device 10R.

In an exemplary embodiment, the electron injecting layer 9 is disposed between the electron transporting layer 8 and the cathode 4.

In an exemplary embodiment, the electron injecting layer 9 is in direct contact with the electron transporting layer 8.

In an exemplary embodiment, the electron injecting layer 9 is a common layer, and the film thickness of the electron injecting layer 9 is constant over the blue-emitting organic EL device 108, the green-emitting organic EL device 10G, and the red-emitting organic EL device 10R. When the electron injecting layer 9 is a common layer, the electron injecting layer 9 provided for the blue-emitting organic EL device 108, the green-emitting organic EL device 10G, and the red-emitting organic EL device 10R can be produced without changing a mask or the like. The organic EL display device 100A thus has enhanced productivity.

In an exemplary embodiment, any other layer than the blue emitting layer 53, the green emitting layer 50, the red emitting layer 54, the blue organic layer 531, the first layer 61, and the red organic layer 541 is preferably provided in a shared manner across the blue-emitting organic EL device, the green-emitting organic EL device, and the red-emitting organic EL device. Reducing the number of the non-common layers in the organic EL display device improves productivity of the device.

### Method of Producing Organic EL Display Device

As an exemplary method of producing the organic EL display device of the exemplary embodiment, a method of producing the organic EL display device 100A depicted in FIG. 8 will be described.

First, the anode 3 is formed on the substrate 2A.

Subsequently, the anode-side organic layer 63 as a common layer is formed on the anode 3. The anode-side organic layer 63 in the blue-emitting organic EL device 10B, the green-emitting organic EL device 10G, and the red-emitting organic EL device 10R is formed to have the same film thickness.

Subsequently, the blue organic layer 531 is formed on the anode-side organic layer 63 in a region corresponding to the anode 3 of the blue-emitting organic EL device 10B using a predetermined film-forming mask (mask for the blue-emitting organic EL device). After forming the blue organic layer 531, the blue emitting layer 53 is formed on the blue organic layer 531.

Subsequently, the first layer 61 is formed on the anode-side organic layer 63 in a region corresponding to the anode 3 of the green-emitting organic EL device 10G using a predetermined film-forming mask (mask for the green-emitting organic EL device). After forming the first layer 61, the green emitting layer 50 is formed on the first layer 61.

Subsequently, the red organic layer 541 is formed on the anode-side organic layer 63 in a region corresponding to the anode 3 of the red-emitting organic EL device 10R using a predetermined film-forming mask (mask for the red-emitting organic EL device). After forming the red organic layer 541, the red emitting layer 54 is formed on the red organic layer 541.

The blue emitting layer 53, the green emitting layer 50, and the red emitting layer 54 are formed from mutually different materials.

After the formation of the anode-side organic layer 63, the order of forming the non-common layers of the blue-emitting organic EL device 108, the green-emitting organic EL device 10G, and the red-emitting organic EL device 10R is not particularly limited.

For instance, after forming the anode-side organic layer 63, the first layer 61 and the green emitting layer 50 of the green-emitting organic EL device 10G may be formed, then the red organic layer 541 and the red emitting layer 54 of the red-emitting organic EL device 10R may be formed, and then the blue organic layer 531 and the blue emitting layer 53 of the blue-emitting organic EL device 10B may be formed.

Alternatively, for instance, after forming the anode-side organic layer 63, the red organic layer 541 and the red emitting layer 54 of the red-emitting organic EL device 10R may be formed, then the first layer 61 and the green emitting layer 50 of the green-emitting organic EL device 10G may be formed, and then the blue organic layer 531 and the blue emitting layer 53 of the blue-emitting organic EL device 10B may be formed.

Subsequently, the electron transporting layer 8 as a common layer is formed on the blue emitting layer 53, the green emitting layer 50, and the red emitting layer 54 to extend thereover. The electron transporting layer 8 of the blue-emitting organic EL device 108, the green-emitting organic EL device 10G, and the red-emitting organic EL device 10R is formed to have a constant film thickness using the same material.

Subsequently, the electron injecting layer 9 as a common layer is formed on the electron transporting layer 8. The electron injecting layer 9 of the blue-emitting organic EL device 10B, the green-emitting organic EL device 10G, and the red-emitting organic EL device 10R is formed to have a constant film thickness using the same material.

Subsequently, the cathode 4 as a common layer is formed on the electron injecting layer 9. The cathode 4 of the blue-emitting organic EL device 108, the green-emitting organic EL device 10G, and the red-emitting organic EL device 10R is formed to have a constant film thickness using the same material.

The organic EL display device 100A depicted in FIG. 8 is produced as described above.

The organic EL display device 100B depicted in FIG. 9 is different from the organic EL display device 100A depicted in FIG. 8 in that the organic EL display device 100B includes the second layer 62. In producing the organic EL display device 100B depicted in FIG. 9, the second layer 62 is formed on the anode-side organic layer 63 in a region corresponding to the anode(s) 3 of the blue-emitting organic EL device, the green-emitting organic EL device, and the red-emitting organic EL device.

Subsequently, the blue organic layer 531 and the blue emitting layer 53 are formed in any order in a region corresponding to the anode 3 of the blue-emitting organic EL device 10B using a predetermined film-forming mask (mask for the blue-emitting organic EL device). The first layer 61 and the green emitting layer 50 are formed in a region corresponding to the anode 3 of the green-emitting organic EL device 10G using a predetermined film-forming mask (mask for the green-emitting organic EL device). The red organic layer 541 and the red emitting layer 54 are formed in a region corresponding to the anode 3 of the green-emitting organic EL device 10R using a predetermined film-forming mask (mask for the red-emitting organic EL device). Any other producing steps of the organic EL display device 100B are similar to those of the organic EL display device 100A.

### Sixth Exemplary Embodiment

### Electronic Device

An electronic device according to a sixth exemplary embodiment is installed with the organic EL device according to any of the above exemplary embodiments or the organic EL display device according to any of the above exemplary embodiments. Examples of the electronic device include a display device and a light-emitting unit. Examples of the display device include a display component (e.g., an organic EL panel module), TV, mobile phone, tablet and personal computer. Examples of the light-emitting unit include an illuminator and a vehicle light.

### Modification of Embodiment(s)

The scope of the invention is not limited to the above-described exemplary embodiments but includes any modification and improvement as long as such modification and improvement are compatible with the invention.

For instance, the number of emitting layers is not limited to one, and two emitting layers or more than two emitting layers may be layered. For instance, the rest of the emitting layers may be a fluorescent emitting layer or a phosphorescent emitting layer with use of emission caused by electron transfer from the triplet excited state directly to the ground state. When the organic EL device includes a plurality of emitting layers, these emitting layers may be in direct contact with each other, or may form a so-called tandem organic EL device, in which a plurality of emitting units are layered via an intermediate layer (occasionally also referred to as a charge generating layer).

Further, for instance, a blocking layer is optionally provided adjacent to a side of the emitting layer close to the cathode. The blocking layer provided in direct contact with the side of the emitting layer close to the cathode preferably blocks at least one of holes or excitons.

For instance, when the blocking layer is provided in contact with the side of the emitting layer close to the cathode, the blocking layer permits transport of electrons, and blocks holes from reaching a layer provided closer to the cathode (e.g., the electron transporting layer) beyond the blocking layer. When the organic EL device includes the electron transporting layer, the blocking layer may be disposed between the emitting layer and the electron transporting layer.

Alternatively, the blocking layer may be provided adjacent to the emitting layer so that the excitation energy does not leak out from the emitting layer toward neighboring layer(s). The blocking layer blocks excitons generated in the emitting layer from being transferred to a layer(s) closer to the electrode(s) (e.g., the electron transporting layer and the like) beyond the blocking layer. The emitting layer is preferably in direct contact with the blocking layer.

A specific structure, shape, and the like of the components in the invention may be designed in any manner as long as an object of the invention can be achieved.

### EXAMPLES

Examples of the invention will be described below. However, the invention is by no means limited to Examples.

### Compounds

Structures of the first compound used for producing organic EL devices in Examples are shown below

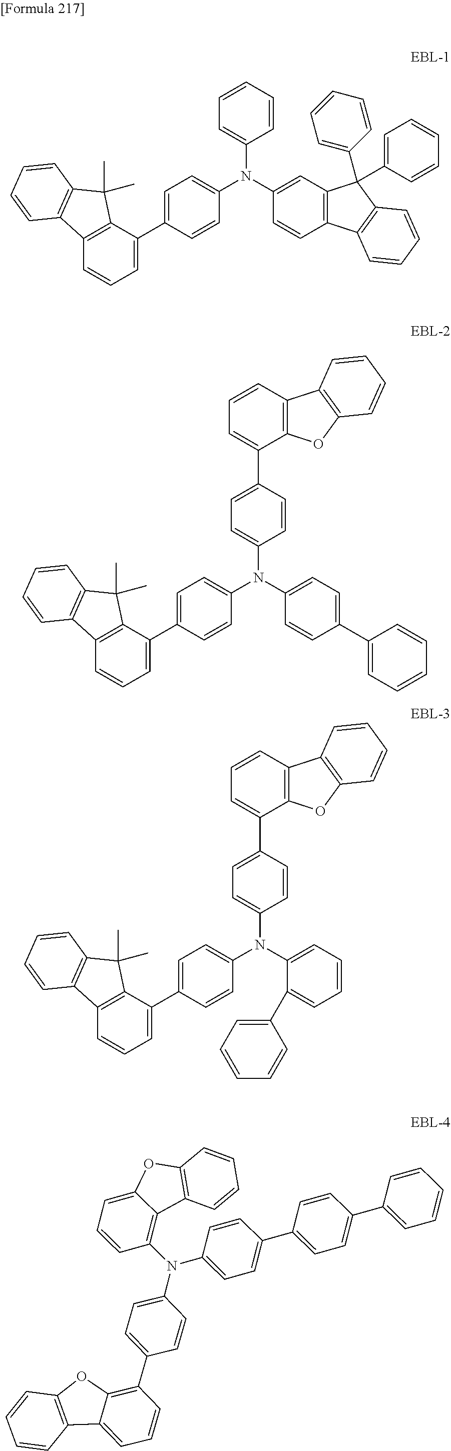 [SMILES: CC1(C)c2ccccc2-c2cccc(-c3ccc(N(c4ccccc4)c4ccc5c(c4)C(c4ccccc4)(c4ccccc4)c4ccccc4-5)cc3)c21 ; CC1(C)c2ccccc2-c2cccc(-c3ccc(N(c4ccc(-c5ccccc5)cc4)c4ccc(-c5cccc6c5oc5ccccc56)cc4)cc3)c21 ; CC1(C)c2ccccc2-c2cccc(-c3ccc(N(c4ccc(-c5cccc6c5oc5ccccc56)cc4)c4ccccc4-c4ccccc4)cc3)c21 ; c1ccc(-c2ccc(-c3ccc(N(c4ccc(-c5cccc6c5oc5ccccc56)cc4)c4cccc5oc6ccccc6c45)cc3)cc2)cc1]

Structures of comparative compounds used for producing organic EL devices in Comparatives are Shown below.

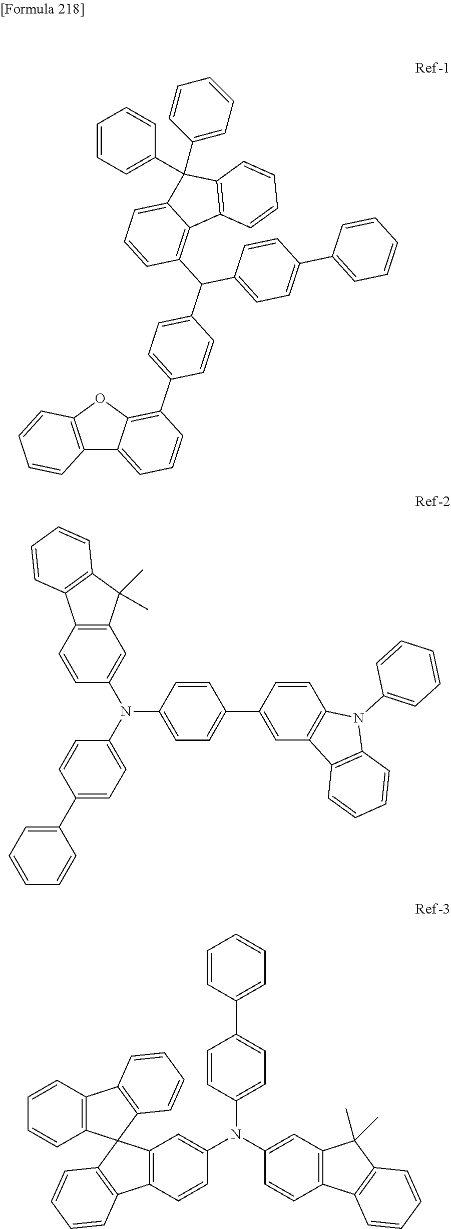 [SMILES: c1ccc(-c2ccc(C(c3ccc(-c4cccc5c4oc4ccccc45)cc3)c3cccc4c3-c3ccccc3C4(c3ccccc3)c3ccccc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21]

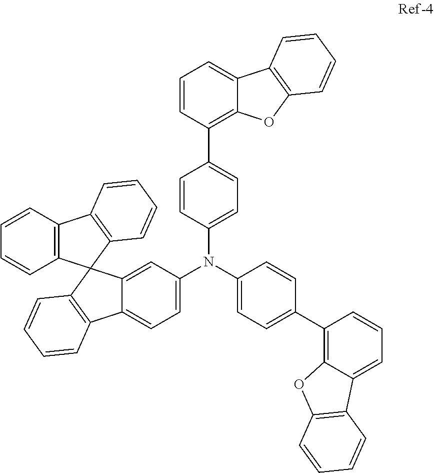 [SMILES: c1ccc2c(c1)-c1ccccc1C21c2ccccc2-c2ccc(N(c3ccc(-c4cccc5c4oc4ccccc45)cc3)c3ccc(-c4cccc5c4oc4ccccc45)cc3)cc21]

Structures of other compounds used for producing organic EL devices in Examples and Comparatives are shown below.

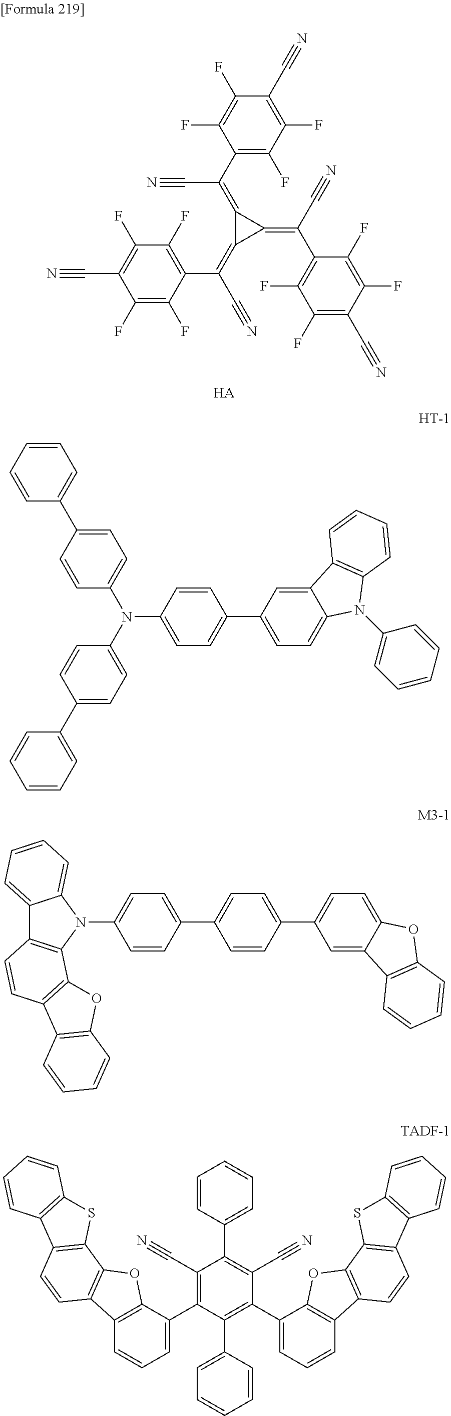 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; "HA" ; c1ccc(-c2ccc(N(c3ccc(-c4ccccc4)cc3)c3ccc(-c4ccc5c(c4)c4ccccc4n5-c4ccccc4)cc3)cc2)cc1 ; c1ccc2c(c1)oc1ccc(-c3ccc(-c4ccc(-n5c6ccccc6c6ccc7c8ccccc8oc7c65)cc4)cc3)cc12 ; N#Cc1c(-c2ccccc2)c(C#N)c(-c2cccc3c2oc2c3ccc3c4ccccc4sc32)c(-c2ccccc2)c1-c1cccc2c1oc1c2ccc2c3ccccc3sc21]

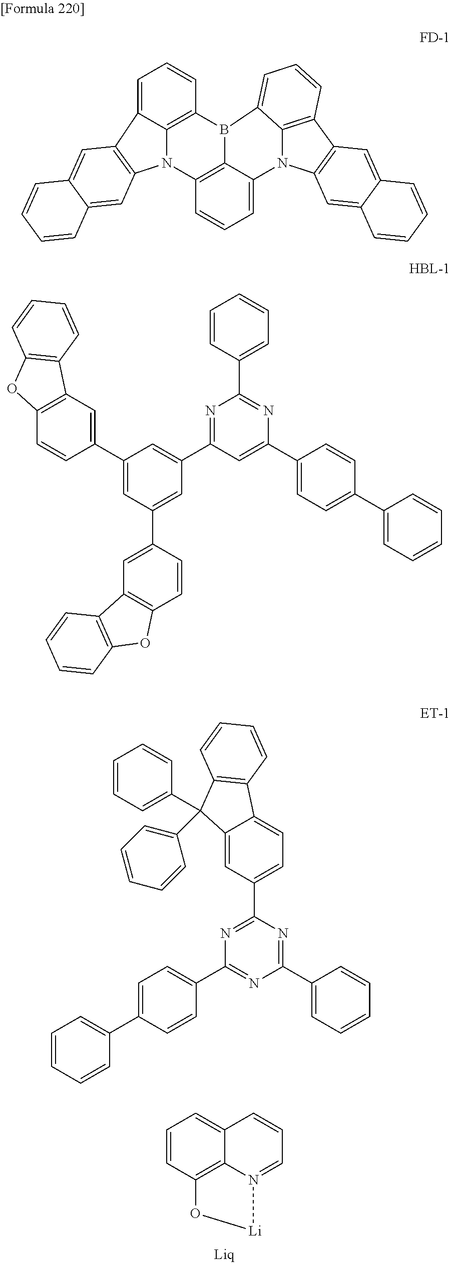

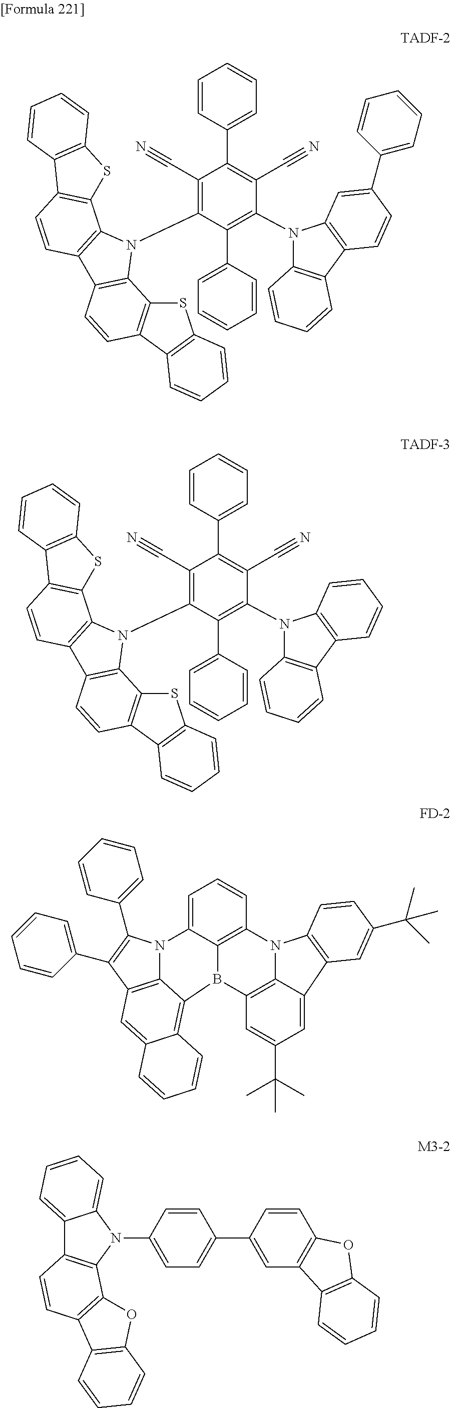 [SMILES: N#Cc1c(-c2ccccc2)c(C#N)c(-n2c3c(ccc4c5ccccc5sc43)c3ccc4c5ccccc5sc4c32)c(-c2ccccc2)c1-n1c2ccccc2c2ccc(-c3ccccc3)cc21 ; N#Cc1c(-c2ccccc2)c(C#N)c(-n2c3c(ccc4c5ccccc5sc43)c3ccc4c5ccccc5sc4c32)c(-c2ccccc2)c1-n1c2ccccc2c2ccccc21 ; CC(C)(C)c1ccc2c(c1)c1cc(C(C)(C)C)cc3c1n2-c1cccc2c1B3c1c3ccccc3cc3c(-c4ccccc4)c(-c4ccccc4)n-2c13 ; c1ccc2c(c1)oc1ccc(-c3ccc(-n4c5ccccc5c5ccc6c7ccccc7oc6c54)cc3)cc12]

### Production of Organic EL Device

The organic EL devices were produced and evaluated as follows.

### Example 1-1

A glass substrate (size: 25 mm×75 mm×1.1 mm thick, produced by Geomatec Co., Ltd.) having an ITO transparent electrode (anode) was ultrasonic, cleaned in isopropyl alcohol for five minutes, and then UV-ozone-cleaned for one minute. The film thickness of ITO was 130 nm.

After the glass substrate having the transparent electrode line was cleaned, the glass substrate was mounted on a substrate holder of a vacuum deposition apparatus. First, a compound HT-1 and a compound HA were co-deposited on a surface of the glass substrate where the transparent electrode line was provided in a manner to cover the transparent electrode, thereby forming a 10-nm-thick hole injecting layer. The concentrations of the compound HT-1 and the compound HA in the hole injecting layer were 97 mass % and 3 mass %, respectively.

Next, the compound HT-1 as the second compound was vapor-deposited on the hole injecting layer to form a 90-nm-thick second layer (occasionally also referred to as a first hole transporting layer (HT)).

Next, a compound EBL-1 as the first compound was vapor-deposited on the second layer to form a 30-nm-thick first layer (occasionally also referred to as a second hole transporting layer (HT) or an electron blocking layer (EBL)).

Next, a compound M3-1 as the compound M3, a compound TADF-1 as the compound M2, and a compound FD-1 as the compound M1 were co-deposited on the first layer to form a 25-nm-thick emitting layer. The concentrations of the compound M3-1, the compound TADF-1, and the compound FD-1 in the emitting layer were 74 mass %, 25 mass %, and 1 mass % respectively.

Next, a compound HBL-1 was vapor-deposited on the emitting layer to form a 5-nm-thick hole blocking layer.

Next, a compound ET-1 and a compound Liq were co-deposited on the hole blocking layer to form a 50-nm-thick electron transporting layer. The concentrations of the compound ET-1 and the compound Liq in the electron transporting layer were 50 mass % and 50 mass %, respectively.

Yb was vapor-deposited on the electron transporting layer to form a 1-nm-thick electron injecting layer.

Then, metal aluminum (Al) was vapor-deposited on the electron injecting layer to form an 80-nm-thick metal Al cathode.

A device arrangement of the organic EL device in Example 1-1 is roughly shown as follows.

ITO(130)IHT-1:HA(10:97%:3%)HT-1(90)/EBL-1(30)/M3-1:TADF-1: FD-1(25.74%:25%:1%)HBL-1(5)/ET-1:Liq(50.50%:50%)Yb(1)/Al(80)

Numerals in parentheses represent a film thickness (unit: nm).

The numerals (97%:3%) represented by percentage in the same parentheses indicate a ratio (mass %) between the compound HT-1 and the compound HA in the hole injecting layer. The numerals (74%:25%:1%) represented by percentage in the same parentheses indicate a ratio (mass %) between the compound M3-1, the compound TADF-1, and the compound FD-1 in the emitting layer. The numerals (50%:50%) represented by percentage in the same parentheses indicate a ratio (mass %) between the compound ET-1 and the compound Liq in the electron transporting layer.

### Examples 1-2 to 1-4 and Comparatives 1-1 to 1-4

The organic EL devices in Examples 1-2 to 1-4 and Comparatives 1-1 to 1-4 were produced as in Example 1-1 except that the first compound used in Example 1-1 was replaced with the compounds listed in Table 1.

### Example 2-1

The organic EL device in Example 2-1 was produced as in Example 1-1 except that the compound M1, the compound M2, and the compound M3 used in Example 1-1 were replaced with the compounds listed in Table 2.

### Examples 2-2 to 2-3 and Comparatives 2-1 to 2-3

The organic EL devices in Examples 2-2 to 2-3 and Comparatives 2-1 to 2-3 were produced as in Example 2-1 except that the first compound used in Example 2-1 was replaced with the compounds listed in Table 2.

### Example 3-1

The organic EL device in Example 3-1 was produced as in Example 1-1 except that the compound M1, the compound M2, and the compound M3 used in Example 1-1 were replaced with the compounds listed in Table 2.

### Examples 3-2 to 3-3 and Comparatives 3-1 to 3-3

The organic EL devices in Examples 3-2 to 3-3 and Comparatives 3-1 to 3-3 were produced as in Example 3-1 except that the first compound used in Example 3-1 was replaced with the compounds listed in Table 2.

### Evaluation of Organic EL Devices

The produced organic EL devices were evaluated as follows. Tables 1 and 2 show evaluation results.

### Maximum Peak Wavelength λp

Voltage was applied to the organic EL device such that a current density was 10 mA/cm², where spectral radiance spectrum was measured by a spectroradiometer GS-2000 (produced by Konica Minolta, Inc.), The maximum peak wavelength λₚ (unit: nm) was calculated based on the obtained spectral-radiance spectra

### Drive Voltage

Voltage (unit: V) was measured when current was applied to between the anode and the cathode such that a current density was 10 mA/cm².

### External Quantum Efficiency EQE

Voltage was applied to the organic EL device such that a current density was 10 mA/cm², where spectral radiance spectrum was measured by a spectroradiometer CS-2000 (produced by Konica Minolta, Inc.). The external quantum efficiency EQE (unit: %) was calculated based on the obtained spectral radiance spectra, assuming that the spectra were provided under a Lambertian radiation.

### Lifetime LT95

Voltage was applied to the produced organic EL device so that a current density was 50 mA/cm², where a time (LT95 (unit: h)) elapsed before a luminance intensity was reduced to 95% of the initial luminance intensity was measured as a lifetime. The luminance intensity was measured by a spectroradiometer CS-2000 (produced by Konica Minolta, Inc.).

TABLE 1

| | First layer | | | | | | | | | | |
|---|---|---|---|---|---|---|---|---|---|---|---|
| | | | | Film | Emitting layer | | | Device Evaluation | | | |
| | First compound | | | thick- | Com- | Com- | Com- | | Vol- | | |
| | | Ip | μh | ness | pound | pound | pound | λp | tage | EQE | LT95 |
| | Name | [eV] | [cm⁷/Vs] | (nm) | M3 | M2 | M1 | [nm] | [V] | [%] | [hr] |
| Ex 1-1 | EBL-1 | 5.73 | 7.0 × 10⁻⁵ | 30 | M3-1 | TADF-1 | FD-1 | 514 | 4.16 | 10.6 | 44 |
| Ex. 1-2 | EBL-2 | 5.76 | 2.0 × 10⁻⁵ | 30 | M3-1 | TADF-1 | FD-1 | 514 | 4.27 | 10.0 | 43 |
| Ex. 1-3 | EBL-3 | 5.76 | 1.0 × 10⁻⁵ | 30 | M3-1 | TADF-1 | FD-1 | 514 | 4.27 | 10.6 | 41 |
| Ex. 1.4 | EBL-4 | 5.72 | 2.0 × 10⁻⁴ | 30 | M3-1 | TADF-1 | FD-1 | 514 | 4.13 | 9.95 | 40 |
| Comp 1-3 | Ref-1 | 5.78 | 2.0 × 10⁻⁶ | 30 | M3-1 | TADF-1 | FD-1 | 514 | 4.44 | 10.4 | 30 |
| Comp 1-2 | Ref-2 | 5.48 | 5.0 × 10⁻⁴ | 30 | M3-1 | TADF-1 | FD-1 | 514 | 4.26 | 3.71 | 60 |
| Comp. 1-3 | Ref-3 | 5.61 | 2.0 × 10⁻² | 30 | M3-1 | TADF-1 | FD-1 | 514 | 4.20 | 5.13 | 71 |
| Comp. 1-4 | Ref-4 | 5.66 | 4.0 × 10⁻⁴ | 30 | M3-1 | TADF-1 | FD-1 | 514 | 4.43 | 5.16 | 63 |

In the organic EL devices in Examples 1-1 to 1-4, the first layer contained the first compound satisfying Numerical Formula 1 and Numerical Formula 2, and the film thickness of the first layer was increased (15 nm or more).

The organic EL devices in Examples 1-1 to 1-4 emitted light at lower voltage and had a longer lifetime than the organic EL device in Comparative 1-1 in which the first compound was replaced with the compound not satisfying Numerical Formula 2.

The organic EL devices in Examples 1-1 to 1-4 emitted light at higher EQE than the organic EL devices in Comparatives 1-2 to 1-4 in which the first compound was replaced with the compounds not satisfying Numerical Formula 1.

TABLE 2

| | First layer | | | | | | | | | | |
|---|---|---|---|---|---|---|---|---|---|---|---|
| | | | | Film | Emitting layer | | | Device Evaluation | | | |
| | First compound | | | thick- | Com- | Com- | Com- | | Vol- | | |
| | | Ip | μh | ness | pound | pound | pound | λp | tage | EQE | LT95 |
| | Name | [eV] | [cm⁷/Vs] | (nm) | M3 | M2 | M1 | [nm] | [V] | [%] | [hr] |
| Ex. 2.1 | EBL-1 | 5.73 | 7.0 × 10⁻⁵ | 30 | M3-2 | TADF-2 | FD-2 | 520 | 4.05 | 17.3 | 54 |
| Ex. 2-2 | EBL-3 | 5.75 | 1.0 × 10⁻⁵ | 30 | M3-2 | TADF-2 | FD-2 | 520 | 4.25 | 12.0 | 49 |
| Ex 2-3 | EBL-4 | 5.72 | 2.0 × 10⁻⁵ | 30 | M3-2 | TADF-2 | FD-2 | 520 | 4.01 | 16.5 | 50 |
| Comp. 2.1 | Ref-2 | 5.48 | 5.0 × 10⁻⁴ | 30 | M3-2 | TADF-2 | FD-2 | 520 | 4.29 | 5.30 | 111 |
| Comp. 2.2 | Ref-3 | 5.51 | 2.0 × 10⁻² | 30 | M3-2 | TADF-2 | FD-2 | 520 | 4.04 | 6.60 | 106 |
| Comp. 2.3 | Ref-4 | 5.68 | 4.0 × 10⁻⁴ | 30 | M3-2 | TADF-2 | FD-2 | 520 | 4.24 | 7.40 | 107 |
| Ex. 3-1 | EBL-1 | 5.73 | 7.0 × 10⁻⁵ | 30 | M3-2 | TADF-3 | FD-2 | 520 | 4.04 | 17.0 | 47 |
| Ex 3-2 | EBL-3 | 5.75 | 1.0 × 10⁻⁵ | 30 | M3-2 | TADF-3 | FD-2 | 520 | 4.18 | 17.5 | 46 |
| Ex. 3.3 | EBL-4 | 5.72 | 2.0 × 10⁻⁵ | 30 | M3-2 | TADF-3 | FD-2 | 520 | 4.02 | 16.2 | 46 |
| Comp. 3.1 | Ref-2 | 5.48 | 5.0 × 10⁻⁴ | 30 | M3-2 | TADF-3 | FD-2 | 520 | 4.19 | 6.00 | 95 |
| Comp. 3.2 | Ref-3 | 5.51 | 2.0 × 10⁻⁵ | 30 | M3-2 | TADF-3 | FD-2 | 520 | 3.82 | 5.80 | 101 |
| Comp. 3.3 | Ref-4 | 5.68 | 4.0 × 10⁻⁴ | 30 | M3-2 | TADF-3 | FD-2 | 520 | 4.04 | 6.00 | 130 |

In the organic EL devices in Examples 2-1 to 2-3 and Examples 3-1 to 3-3, the first layer contained the first compound satisfying Numerical Formula 1 and Numerical Formula 2, and the film thickness of the first layer was increased (15 nm or more).

The organic EL devices in Examples 2-1 to 2-3 emitted light at higher EQE than the organic EL devices in Comparatives 2-1 to 2-3 in which the first compound was replaced with the compounds not satisfying Numerical Formula 1.

The organic EL devices in Examples 3-1 to 3-3 emitted light at higher EQE than the organic EL devices in Comparatives 3-1 to 3-3 in which the first compound was replaced with the compounds not satisfying Numerical Formula 1.

### Evaluation of Compounds

### Thermally Activated Delayed Fluorescence

### Delayed Fluorescence of Compound TADF-1

Delayed fluorescence was confirmed by measuring transient PL using an apparatus illustrated in FIG. 2. The compound TADF-1 was dissolved in toluene to prepare a dilute solution with an absorbance of 0.05 or less at the excitation wavelength to eliminate contribution of self-absorption. In order to prevent quenching due to oxygen, the sample solution was frozen and degassed and then sealed in a cell with a lid under an argon atmosphere to obtain an oxygen-free sample solution saturated with argon.

The fluorescence spectrum of the sample solution was measured with a spectrofluorometer FP-8600 (produced by JASCO Corporation), and the fluorescence spectrum of a 9,10-diphenylanthracene ethanol solution was measured under the same conditions. Using the fluorescence area intensities of both spectra, the total fluorescence quantum yield was calculated by an equation (1) in Morris et al. J. Phys. Chem. 80 (1976) 969.

Prompt emission was observed immediately when the excited state was achieved by exciting the compound TADF-1 with a pulse beam (i.e., a beam emitted from a pulse laser) having a wavelength to be absorbed by the compound TADF-1, and Delay emission was observed not immediately when the excited state was achieved but after the excited state was achieved. The delayed fluorescence in Examples means that an amount of Delay emission is 5% or more with respect to an amount of Prompt emission. Specifically, provided that the amount of Prompt emission is denoted by X_{P} and the amount of Delay emission is denoted by X_{D}, the delayed fluorescence means that a value of X_{D}/X_{P} is 0.05 or more.

An amount of Prompt emission, an amount of Delay emission and a ratio between the amounts thereof can be obtained according to the method as described in “Nature 492, 234-238, 2012” (Reference Document 1). The amount of Prompt emission and the amount of Delay emission may be calculated using any other apparatus than one described in Reference Document 1 or one depicted in FIG. 2.

Measurement for compounds TADF-2 and TADF-3 was performed as in the compound TADF-1. It was confirmed that the amount of Delay emission was 5% or more with respect to the amount of Prompt emission in the compounds TADF-1, TADF-2, and TADF-3. Specifically, the value of X_{D}/X_{P} was 0.05 or more in the compounds TADF-1, TADF-2, and TADF-3.

### Singlet Energy S₁

The singlet energy S₁ of each measurement target compound was measured according to the above-described solution method.

The singlet energy S₁ of the compound M3-1 was 3.41 eV.

The singlet energy S₁ of the compound M3-2 was 3.43 eV.

The singlet energy S₁ of the compound TADF-1 was 2.66 eV.

The singlet energy S₁ of the compound TADF-2 was 2.66 eV.

The singlet energy S₁ of the compound TADF-3 was 2.65 eV.

The singlet energy S₁ of the compound FD-1 was 2.45 eV.

The singlet energy S₁ of the compound FD-2 was 2.41 eV.

### Energy Gap T_{77K}

T_{77K} of each measurement target compound was measured. T_{77K} was measured by the measurement method of the energy gap T_{77K} described in “Relationship between Triplet Energy and Energy Gap at 77K.”

### ΔST

ΔST was calculated based on the measured lowest singlet energy Si and energy gap T_{77K} at 77K.
ΔST of the compound M3-1 was 0.69 eV.
ΔST of the compound M3-2 was 0.59 eV
ΔST of the compound TADF-1 was less than 0.01 eV.
ΔST of the compound TADF-2 was less than 0.01 eV.
ΔST of the compound TADF-3 was less than 0.01 eV.
ΔST of the compound FD-1 was 0.27 eV.
ΔST of the compound FD-2 was 0.41 eV.

### Maximum Peak Wavelength A of Compounds

A 5-μmol/L toluene solution of each of the compounds (measurement target) was prepared and put in a quartz cell. A fluorescence spectrum (ordinate axis: fluorescence intensity, abscissa axis: wavelength) of each of the samples was measured at a normal temperature (300K). In Examples, a fluorescence spectrum was measured with a spectrophotofluorometer (produced by Hitachi High-Tech Science Corporation: F-7000). It should be noted that the fluorescence spectrum measuring device may be different from the above device. A peak wavelength of a fluorescence spectrum, a luminous intensity of which was the maximum in the fluorescence spectrum, was defined as the maximum peak wavelength λ.

The maximum peak wavelength of the compound FD-1 was 500 nm.

The maximum peak wavelength of the compound FD-2 was 511 nm.

### Ionization Potential Ip

The ionization potential Ip of each compound was measured under atmosphere using a photoelectron spectroscope (“AC-3” produced by RIKEN KEIKI Co., Ltd.). Specifically, the material was irradiated with light and the amount of electrons generated by charge separation was measured to measure the ionization potential of the compound. The ionization potential is occasionally referred to as Ip.

### Hole Mobility μh

A hole mobility μh was measured using a mobility evaluation device produced by the following steps.

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for 30 minutes. The film thickness of ITO was 130 nm.

After the glass substrate was cleaned, the glass substrate was mounted on a substrate holder of a vacuum evaporation apparatus. First, the compound HA-2 was vapor-deposited on a surface of the glass substrate, where the transparent electrode line was provided, to cover the transparent electrode, thereby forming a 5-nm-thick hole injecting layer

The compound HT-A was vapor-deposited on this hole injecting layer to form a 10-nm-thick hole transporting layer.

Subsequently, the compound Target to be measured for the hole mobility μh was vapor-deposited to form a 200-nm-thick measurement target layer.

Metal aluminum (Al) was vapor-deposited on this measurement target layer to form an 80-nm-thick metal cathode.

An arrangement of the mobility evaluation device above is roughly shown as follows.

ITO(130)/HA-2(5)/HT-A(10)/Target(200)/Al(80)

Numerals in parentheses represent a film thickness (nm).

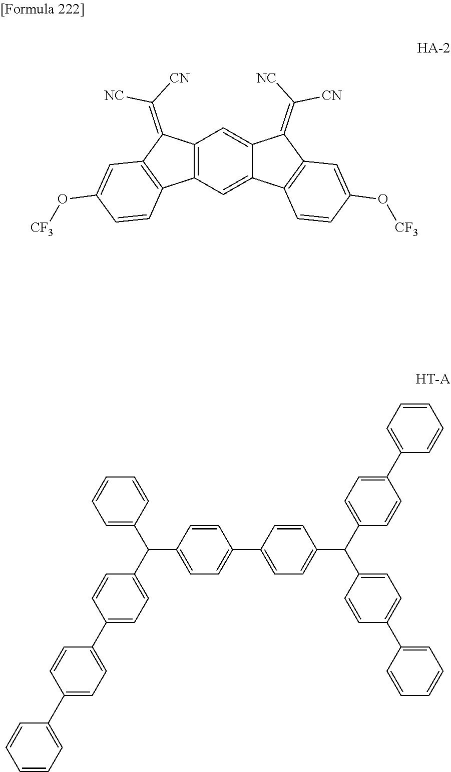

Subsequently, the hole mobility is measured by the following steps using the mobility evaluation device produced as described above.

The mobility evaluation device was set in an impedance measurement apparatus to perform an impedance measurement.

In the impedance measurement, a measurement frequency was swept from 1 Hz to 1 MHz. At this time, an alternating current amplitude of 0.1 V and a direct current voltage V were applied to the device.

A modulus M was calculated from a measured impedance Z using a relationship of a calculation formula (C1) below.

M=jωZ Calculation formula (C1):

In the calculation formula (C1), j is an imaginary unit whose square is −1 and ω is an angular frequency [rad/s).

In a bode plot in which an imaginary part of the modulus M is represented by an ordinate axis and the frequency [Hz] is represented by an abscissa axis, an electrical time constant T of the mobility evaluation device was obtained from a frequency fmax showing a peak using a calculation formula (C2) below.

Y=τ=1/(2πfmax) Calculation formula (C2):
π in the calculation formula (C2) is a symbol representing a circumference ratio.

The hole mobility μh was calculated from a relationship of a calculation formula (C3) below using τ.

μh=d²/(V_{τ}) Calculation Formula (C3):
d in the calculation formula (C3) is a total film thickness of organic thin film(s) forming the device. As in the arrangement of the mobility evaluation device, d=215 (nm] is satisfied.

The mobility herein is a value obtained in a case where a square root of an electric field intensity meets E^{1/2}=500 [V^{1/2}/cm^{1/2}]. The square root of the electric field intensity. E_{1/2}, can be calculated from a relationship of a calculation formula (C4) below.

E^{1/2}=V^{1/2}/d^{1/2} Calculation formula (C4):

For the impedance measurement in Examples, a 1260 type by Solartron Analytical was used as the impedance measurement apparatus, and a 1296 type dielectric constant measurement interface by Solartron Analytical was used together therewith to enhance measurement accuracy.

### Synthesis of Compound

### Synthesis Example 1: Synthesis of Compound TADF-1

A synthesis method of the compound TADF-1 will be described below.

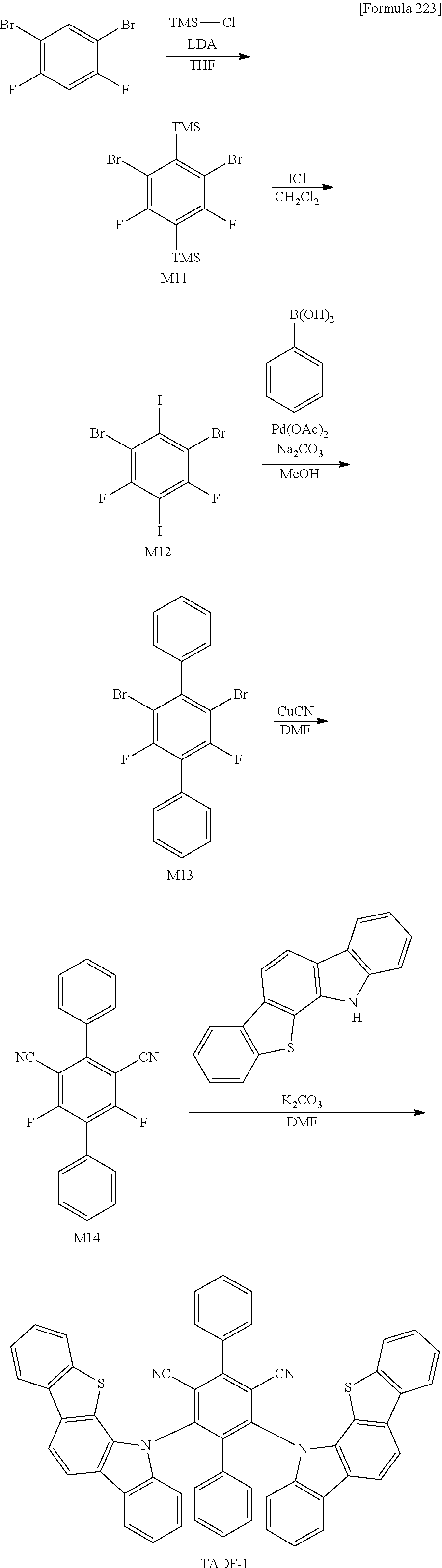

Under nitrogen atmosphere, 1,5-dibromo-2,4-difluorobenzene (50 g, 184 mmol), chlorotrimethylsilane (60 g, 552 mmol), and THE (200 mL) were put into a 1000-mL three-necked flask. The material in the three-necked flask was cooled to −78 degrees C., in a dry ice/acetone bath. Subsequently, 230 mL of lithium diisopropyl amide (2M, THE solution) was dropped thereinto. This was stirred at −78 degrees C. for 2 hours, then returned to room temperature (25 degrees C.), and further stirred for 2 hours. After stirring, water (200 mL) was added into the three-necked flask. Subsequently, an organic layer was extracted with acetic ether. The extracted organic layer was washed with water and a saline solution and dried with magnesium sulfate. Then, the solvent was removed by a rotary evaporator under reduced pressure. The obtained intermediate M11 (73 g, 175 mmol, a yield of 95%) was not purified and used for a next reaction. Chlorotrimethylsilane is occasionally abbreviated as TMS-C1. TMS in a formula representing the intermediate M11 is a trimethylsilyl group. LDA is an abbreviation for lithium diisopropyl amide.

Under nitrogen atmosphere, the intermediate M11 (73 g, 175 mmol) and dichloromethane (200 mL) were put into a 1000-mL eggplant flask. Iodine monochloride (85 g, 525 mmol) was dissolved in dichloromethane (200 mL) and dropped therein at 0 degrees C. Subsequently, the mixture was stirred at 40 degrees C, for 4 hours. After stirring, the mixture was returned to room temperature and added with a saturated aqueous solution of sodium hydrogen sulfite (100 mL). Then, an organic layer was extracted with dichloromethane. The extracted organic layer was washed with water and a saline solution. The washed organic layer was dried with magnesium sulfate. The dried organic layer was condensed by a rotary evaporator. A compound obtained through condensation was purified by silica-gel column chromatography to obtain an intermediate M12 (65 g, 124 mmol, a yield of 71%).

Under nitrogen atmosphere, the intermediate M12 (22 g, 42 mmol), phenylboronic acid (12.8 g, 105 mmol), palladium acetate (0.47 g, 2.1 mmol), sodium carbonate (22 g, 210 mmol), and methanol (15 mL) were put into a 500-mL three-necked flask and stirred for four hours at 80 degrees C. After stirring, the reaction solution was left to be cooled to room temperature. Subsequently, an organic layer was extracted with acetic ether. The extracted organic layer was washed with water and a saline solution. The washed organic layer was condensed by a rotary evaporator. A compound obtained through condensation was purified by silica-gel column chromatography to obtain an intermediate M13 (10 g, 24 mmol, a yield of 56%). The structure of the purified compound was identified by ASAP/MS. ASAP/MS is an abbreviation for Atmospheric Pressure Solid Analysis Probe Mass Spectrometry.

Under nitrogen atmosphere, the intermediate M13 (10 g, 24 mmol), copper cyanide (10.6 g, 118 mmol), and DMF (15 mL) were put into a 200-mL three-necked flask and heated at 150 degrees C., for eight hours with stirring. After stirring, the reaction solution was cooled to room temperature and then poured into ammonia water (10 mL). Next, an organic layer was extracted with methylene chloride. The extracted organic layer was washed with water and a saline solution. The washed organic layer was dried with magnesium sulfate. After drying, the solvent was removed by a rotary evaporator under reduced pressure. A compound obtained through removal under reduced pressure was purified by silica-gel column chromatography to obtain an intermediate M14 (5.8 g, 18.34 mmol, a yield of 78%). DMF is an abbreviation for N,N-dimethylformamide.

Under nitrogen atmosphere, the intermediate M14 (1.0 g, 3.2 mmol), 12H-[1]Benzothieno[2,3-a]carbazole (1.9 g, 7 mmol), potassium carbonate (1.3 g, 950 mmol), and DMF (30 mL) were put into a 100-mL three-necked flask and stirred at 120 degrees C., for six hours. After stirring, the deposited solid was collected by filtration and purified by silica-gel column chromatography to obtain a compound TADF-1 (1.8 g, 2.2 mmol, a yield of 69%). The obtained compound was identified as the compound TADF-1 by analysis according to ASAP-MS.

### Synthesis Example 2: Synthesis of Compound TADF-2

A synthesis method of the compound TADF-2 will be described below.

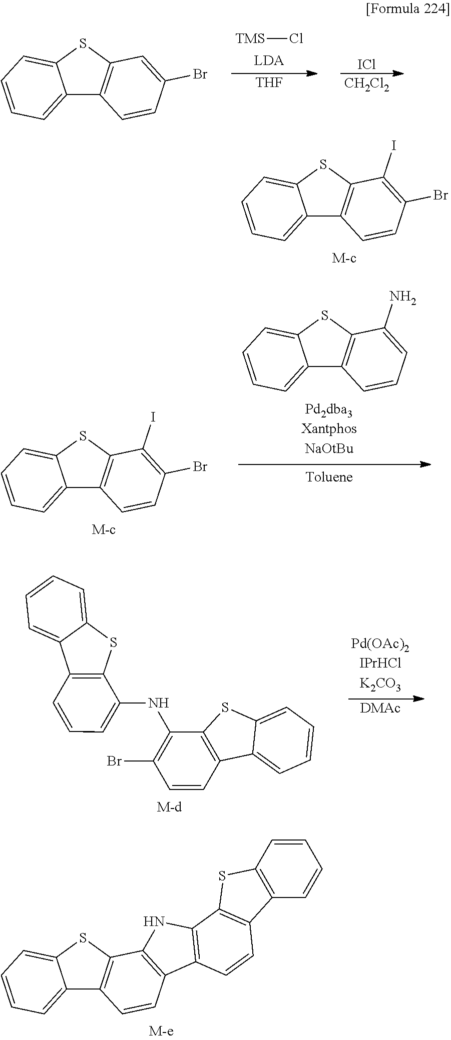

Under nitrogen atmosphere, 3-bromodibenzothiophene (26.3 g, 100 mmol), chlorotrimethylsilane (33 g, 300 mmol), and THF (150 mL) were put into a 500-mL three-necked flask. The material in the three-necked flask was cooled to −78 degrees C. in a dry ice/acetone bath. Subsequently, 125 mL of lithium diisopropyl amide (2M, THF solution) was dropped thereinto. This was stirred at −78 degrees C., for 2 hours, then returned to room temperature, and further stirred for 2 hours. After stirring, water (100 mL) was added into the three-necked flask. Subsequently, an organic layer was extracted with acetic ether. The extracted organic layer was washed with water and a saline solution and dried with magnesium sulfate. Then, the solvent was removed by a rotary evaporator under reduced pressure. The obtained liquid was added with dichloromethane (200 mL). Then, iodine monochloride (49 g, 300 mmol) was dropped therein at 0 degrees C. Subsequently, the mixture was stirred at 40 degrees C., for six hours. The mixture was returned to room temperature and added with a saturated aqueous solution of sodium hydrogen sulfite (100 mL). Then, an organic layer was extracted with dichloromethane. The extracted organic layer was washed with water and a saline solution. The washed organic layer was dried with magnesium sulfate. The dried organic layer was condensed by a rotary evaporator. A compound obtained through condensation was purified by silica-gel column chromatography to obtain an intermediate M-c (28 g, 72 mmol, a yield of 72%).

Under nitrogen atmosphere, the intermediate M-c (24.5 g, 63.0 mmol), Dibenzo[b,d]thiophen-4-amine (12.55 g, 63.0 mmol), tris(dibenzylideneacetone)dipalladium(0) (0.865 g, 0.945 mmol), Xantphos (1.385 g, 1.889 mmol), sodium tert-butoxide (9.08 g, 94 mmol), and toluene (210 mL) were added into a 500-mL three-necked flask, and heated at 60 degrees C., for eight hours with stirring. Then, the mixture was cooled to room temperature (25 degrees C.). The deposited solid was filtrated and washed with toluene (200 mL) to obtain a white solid (25 g). The obtained white solid was identified as the intermediate M-d by analysis according to GC-MS (a yield of 86%).

Under nitrogen atmosphere, the intermediate M-d (9.5 g, 20.7 mmol), 1,3-bis(2,6-diisopropylphenyl)imidazolium chloride (IPrHCl) (0.36 g, 0.82 mmol), palladium(II) acetate (0.093g, 0.41 mmol), potassium carbonate (5.8 g, 42 mmol) and N,N-dimethylacetamide (DMAc) (60 mL) were added into a 200-mL three-necked flask, and stirred at 160 degrees C., for 10 hours. After stirring, the mixture was cooled to room temperature (25 degrees C.). The deposited solid was filtrated and washed with acetone to obtain a white solid (6.9 g). The obtained white solid was identified as the intermediate M-e by analysis according to ASAP-MS (a yield of 86%).

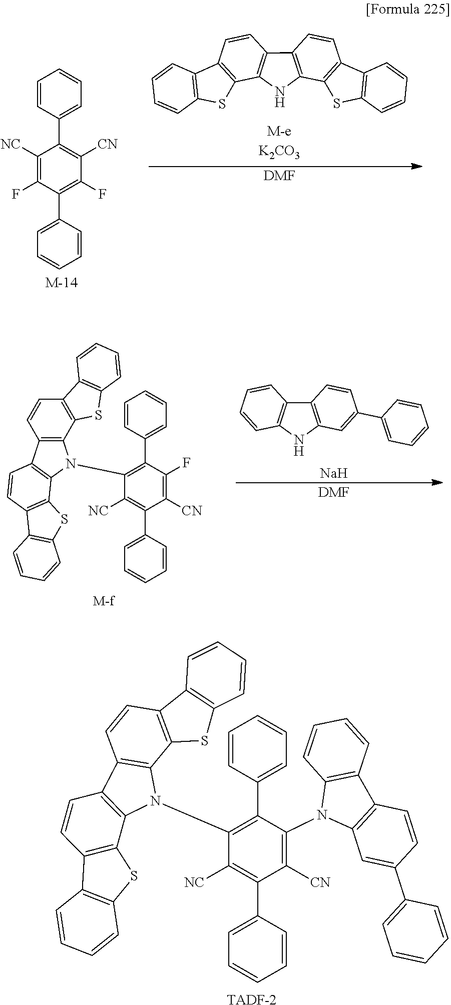

Under nitrogen atmosphere, an intermediate M-14 (3.0 g, 9.48 mmol), the intermediate M-e (369, 9.5 mmol), potassium carbonate (2.6 g, 19 mmol) and DMF (50 mL) were put into a 200-mL, three-necked flask, and stirred at 100 degrees C., for four hours. Ion exchange water (100 mL) was added to the reaction solution, and the deposited solid was filtrated. The filtered solid was purified by silica-gel column chromatography to obtain a yellow solid (4.1 g). The obtained yellow solid was identified as an intermediate M-f by analysis according to ASAP-MS (a yield of 64%).

Under nitrogen atmosphere, 2-phenyl-5h-carbazole (1.1 g, 4.44 mmol), sodium hydride (containing oil at 40 mass %) (0.18 g, 4.44 mmol), and DMF (37 mL) were put into a 100-mL three-necked flask, and stirred at 0 degrees C., for one hour. Subsequently, the intermediate M-f (2.5 g, 3.70 mmol) was put at 0 degrees C., the temperature was slowly raised to room temperature, and the mixture was further stirred at room temperature for one hour. Ion exchange water (30 mL) was added to the reaction mixture, and the deposited solid was filtrated. The obtained solid was purified by silica-gel column chromatography to obtain a yellow solid. The obtained yellow solid was identified as the intermediate TADF-2 by analysis according to ASAP-MS (a yield of 63%).

### Synthesis Example 3: Synthesis of Compound TADF-3

A synthesis method of the compound TADF-3 will be described below.

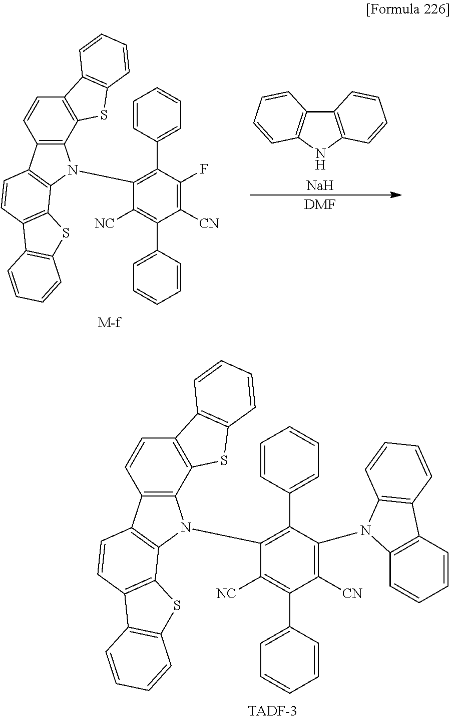

Under nitrogen atmosphere, 9H-carbazole (2.313 g, 13.84 mmol), sodium hydride (containing oil at 40 mass %) (0.488 g, 12.21 mmol), and DMF (40.7 mL) were put into a 100-mL three-necked flask, and stirred at 0 degrees C., for 30 minutes. Subsequently, the intermediate M-f (5.5 g, 8.14 mmol) was put into the reaction mixture, and this was stirred at room temperature for 2 hours. Methanol (20 mL) was added to the reaction mixture, and the deposited solid was purified by silica-gel column chromatography to obtain a yellow solid (6.3 g). The obtained yellow solid was identified as the intermediate TADF-3 by analysis according to ASAP-MS (a yield of 94%).

### EXPLANATION OF CODES

1, 1A . . . organic EL device, 100A, 1006 . . . organic EL display device, 10B, 20B . . . blue-emitting organic EL device, 10G, 20G . . . green-emitting organic EL device, 10R, 20R . . . red-emitting organic EL device, 2, 2A . . . substrate, 3 . . . anode, 4 . . . cathode, 50 . . . green organic layer, 53 . . . blue emitting layer, 54 . . . red emitting layer, 531 . . . blue organic layer, 541 . . . red organic layer. 61 . . . first layer. 62 . . . second layer, 63 . . . anode-side organic layer, 8 . . . electron transporting layer, 9 . . . electron injecting layer.

1. An organic electroluminescence device comprising:
an anode;
a cathode;
an emitting layer disposed between the anode and the cathode; and
a first layer disposed between the anode and the emitting layer,
wherein the emitting layer comprises a delayed fluorescent compound,
wherein the first layer comprises a first compound,
wherein an ionization potential of the first compound Ip(HT1) satisfies a numerical formula (Numerical Formula 1),
wherein a hole mobility of the first compound μh(HT1) satisfies a numerical formula (Numerical Formula 2), and
wherein the first layer has a film thickness of 15 nm or more,
$$Ip ( HT 1 ) \geq 5.7 eV … \qquad ( Numerical Formula 1 )$$
$$μ h ( H T 1 ) \geq 1 \times 1 {0}^{- 5} {cm}^{2} / Vs … . \qquad ( Numerical Formula 2 )$$

2. The organic electroluminescence device according to claim 1, wherein the first layer is adjacent to the emitting layer.

3. The organic electroluminescence device according to claim 1, wherein the emitting layer comprises a compound M2 as the delayed fluorescent compound and a fluorescent compound M1, and
wherein a singlet energy S₁(Mat2) of the compound M2 and a singlet energy S₁(Mat1) of the compound M1 satisfy a relationship of a numerical formula (Numerical Formula 3),
S₁(Mat2)>S₁(Mat1) (Numerical Formula 3).

4. The organic electroluminescence device according to claim 1, wherein the emitting layer comprises a compound M2 as the delayed fluorescent compound and a compound M3, and
wherein a singlet energy S₁(Mat2) of the compound M2 and a singlet energy S₁(Mat3) of the compound M3 satisfy a relationship of a numerical formula (Numerical Formula 4)
S₁(Mat3)>S₁(Mat2) (Numerical Formula 4).

5. The organic electroluminescence device according to claim 1, wherein the first layer has a film thickness of 20 nm or more.

6. The organic electroluminescence device according to claim 1, wherein the first layer has a film thickness of 25 nm or more.

7. The organic electroluminescence device according to claim 1, wherein the first layer has a film thickness of 30 nm or more.

8. The organic electroluminescence device according to claim 1, wherein the ionization potential of the first compound Ip(HT1) satisfies a numerical formula (Numerical Formula 1A),
Ip(HT1)≥5.73 eV (Numerical Formula 1A).

9. The organic electroluminescence device according to claim 1, wherein the hole mobility of the first compound μh(HT1) satisfies a numerical formula (Numerical Formula 2A),
$$μ h ( H T 1 ) \geq 5. \times {10}^{- 5} {cm}^{2} / Vs … . \qquad ( Numerical Formula 2 A )$$

10. The organic electroluminescence device according to claim 1, wherein the ionization potential of the first compound Ip(HT1) satisfies a numerical formula (Numerical Formula 1A), and
wherein the hole mobility of the first compound μh(HT1) satisfies a numerical formula (Numerical Formula 2A),
$$Ip ( HT 1 ) \geq 5.7 eV … \qquad ( Numerical Formula 1 )$$
$$μ h ( H T 1 ) \geq 1 \times 1 {0}^{- 5} {cm}^{2} / Vs … . \qquad ( Numerical Formula 2 )$$

11. The organic electroluminescence device according to claim 1, further comprising:
a second laver disposed between the anode and the first laver.

12. The organic electroluminescence device according to claim 11, wherein the second laver is adjacent to the first layer.

13. The organic electroluminescence device according to claim 11, wherein the second layer comprises a second compound,
wherein an ionization potential of the second compound Ip(HT2) satisfies a numerical formula (Numerical Formula 11), and
wherein a hole mobility of the second compound μh(HT2) satisfies a numerical formula (Numerical Formula 12),
$$Ip ( HT 1 ) \geq 5.7 eV … \qquad ( Numerical Formula 1 )$$
$$μ h ( H T 1 ) \geq 1 \times 1 {0}^{- 5} {cm}^{2} / Vs … . \qquad ( Numerical Formula 2 )$$

14. The organic electroluminescence device according to claim 11, wherein the second layer has a film thickness in a range from 20 nm to 200 nm.

15. The organic electroluminescence device according to claim 11, wherein the first compound is an amine compound.

16. The organic electroluminescence device according to claim 11, wherein the first compound is a compound represented by a formula (31), (32), or (33), 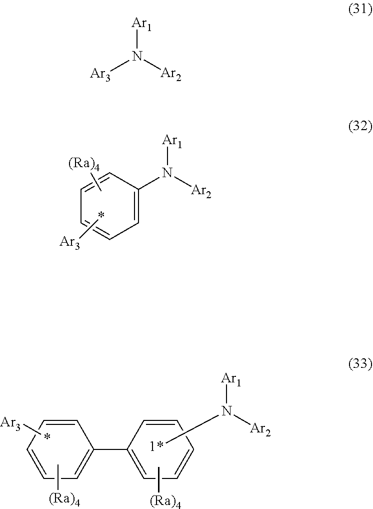
where, in the formulae (31) to (33):
Ar₁ and Ar₁ are each independently a substituted or unsubstituted aryl group having 6 to 50 ring carbon atoms, or a substituted or unsubstituted heterocyclic group having 5 to 50 ring atoms;
Ar₃ are each independently a group represented by a formula (3A) or (3B) below; * in the formula (32) represents a bonding position to a carbon atom in a six-membered ring having Ra; * in the formula (33) represents a bonding position to a carbon atom in a six-membered ring having Ra; and 1* in the formula (33) represents a bonding position to a carbon atom in a six-membered ring having Ra;
a combination of adjacent two or more of a plurality of Ra are mutually bonded to form a substituted or unsubstituted monocyclic ring, mutually bonded to form a substituted or unsubstituted fused ring, or not mutually bonded;
Ra forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a halogen atom, a cyano group, a nitro group, a group represented by —P(═O)(R₉₃₁)(R₉₃₂), a group represented by —Ge(R₉₃₃)(R₉₃₄)(R₉₃₃), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms; and
the plurality of Ra are mutually the same or different, 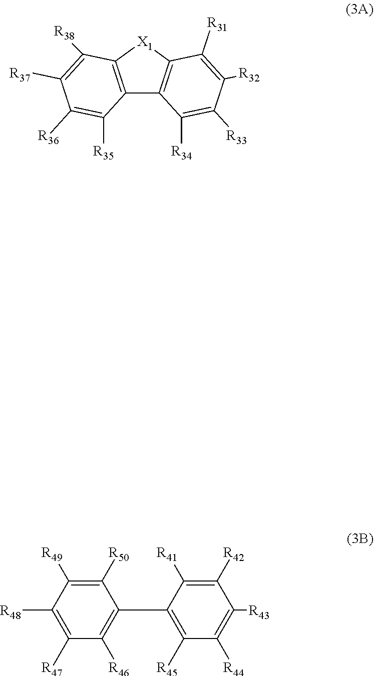
where, in the formulae (3A) and (3B):
X₁ is an oxygen atom, a sulfur atom, CR₃₀₁R₃₀₂, or NR₃₀₃;
a combination of R₃₀₁ and R₃₂ are mutually bonded to form a substituted or unsubstituted monocyclic ring, mutually bonded to form a substituted or unsubstituted fused ring, or not mutually bonded;
a combination of adjacent two or more of R₃₁ to R₃₄ are mutually bonded to form a substituted or unsubstituted monocyclic ring, mutually bonded to form a substituted or unsubstituted fused ring, or not mutually bonded;
a combination of adjacent two or more of R₃₅ to R₃₈ are mutually bonded to form a substituted or unsubstituted monocyclic ring, mutually bonded to form a substituted or unsubstituted fused ring, or not mutually bonded;
a combination of adjacent two or more of R₄₁ to R₅₀ are mutually bonded to form a substituted or unsubstituted monocyclic ring, mutually bonded to form a substituted or unsubstituted fused ring, or not mutually bonded;
R₃₀₃, and R₃₀₁, R₃₀₂, R₃₁ to R₃₈ and R₄₁, to R₅₀ forming neither the substituted or unsubstituted monocyclic ring nor the substituted or unsubstituted fused ring each independently represent the same as Ra in the formula (32); and
any one of R₃₀₁ to R₃₀₃ and R₃₁ to R₃₈ in the formula (3A) is a single bond bonded to a nitrogen atom in the formula (31), a single bond bonded to a carbon atom in a six-membered ring in the formula (32), or a single bond bonded to a carbon atom in a six-membered ring in the formula (33); and any one of R₄₁ to R₅₀ in the formula (313) is a single bond bonded to a nitrogen atom in the formula (31), a single bond bonded to a carbon atom in a six-membered ring in the formula (32), or a single bond bonded to a carbon atom in a six-membered ring in the formula (33),
in the first compound, R₉₀₁, R₉₀₂, R₉₀₃, R₉₀₄, R₉₀₅, R₉₀₆, R₉₀₇, R₉₀₈, R₉₀₉, R₉₃₁, R₉₃₂, R₉₃₃, R₉₃₄, R₉₃₅, R₉₃₆, and R₉₃₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₉₀₈ are present, the plurality of R₉₀₈ are mutually the same or different;
when a plurality of R₉₀₉ are present, the plurality of R₉₀₉ are mutually the same or different;
when a plurality of R₉₃₁ are present, the plurality of R₉₃₁ are mutually the same or different;
when a plurality of R₉₃₂ are present, the plurality of R₉₃₂ are mutually the same or different;
when a plurality of R₉₃₃ are present, the plurality of R₉₃₃ are mutually the same or different;
when a plurality of R₉₃₄ are present, the plurality of R₉₃₄ are mutually the same or different;
when a plurality of R₉₃₅ are present, the plurality of R₉₃₅ are mutually the same or different;
when a plurality of R₉₃₆ are present, the plurality of R₉₃₆ are mutually the same or different; and
when a plurality of R₉₃₇ are present, the plurality of R₉₃₇ are mutually the same or different.

17. The organic electroluminescence device according to claim 16, wherein when the first compound is represented by the formula (31), Ar₃ are each independently a group represented by one of formulae (30A) to (30G), and
wherein when the first compound is a compound represented by the formula (32) or (33), Ar₃ are each independently a group represented by one of formulae (30A) to (30H), 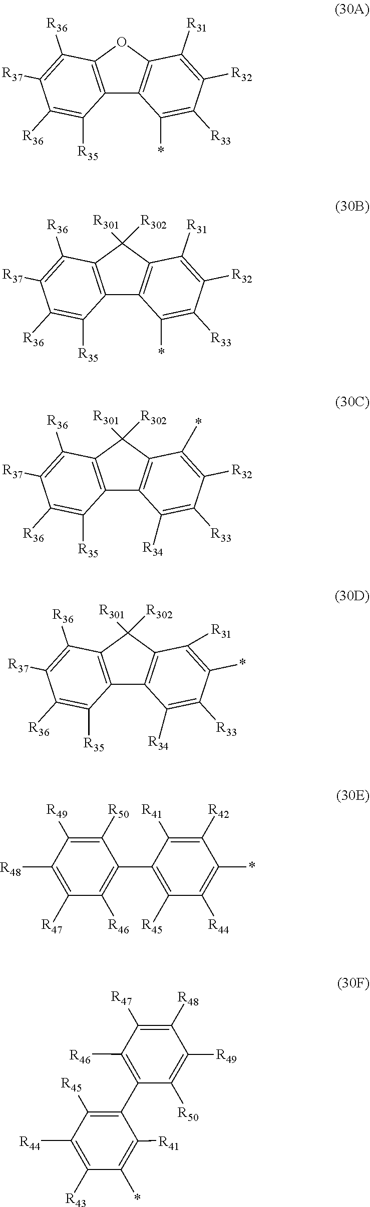 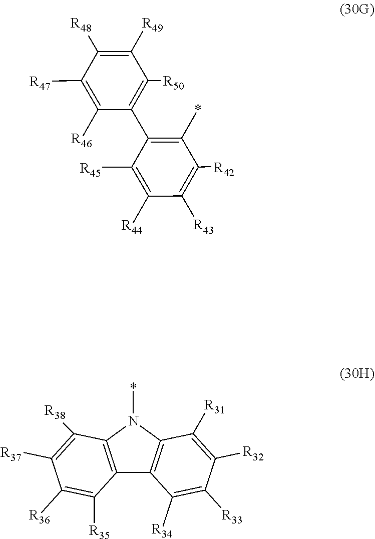
where, in the formulae (30A) to (30D),
R₃₀₁, R₃₀₂, and R₃₁ to R₃₈ each independently represent the same as R₃₀₁, R₃₀₂, and R₃₁ to R₃₈ in the formula (3A);
in the formulae (30E) to (30G), R₄₁ to R₅₀ each independently represent the same as R₄₁ to R₅₀ in the formula (3B);
in the formula (30H), R₃₁ to R₃₈ each independently represent the same as R₃₁ to R₃₈ in the formula (3A); and
* each represent a bonding position.

18. The organic electroluminescence device according to claim 16, wherein Ar₁ and Ar₂ are each independently a substituted or unsubstituted phenyl group, a substituted or unsubstituted biphenyl group, a substituted or unsubstituted terphenyl group, a substituted or unsubstituted dibenzofuranyl group, a substituted or unsubstituted dibenzothienyl group, a substituted or unsubstituted fluorenyl group, a substituted or unsubstituted carbazolyl group, a substituted or unsubstituted naphthyl group, or a substituted or unsubstituted phenanthrenyl group.

19. The organic electroluminescence device according to claim 16, wherein the first compound is a compound represented by one of formulae (301) to (310), 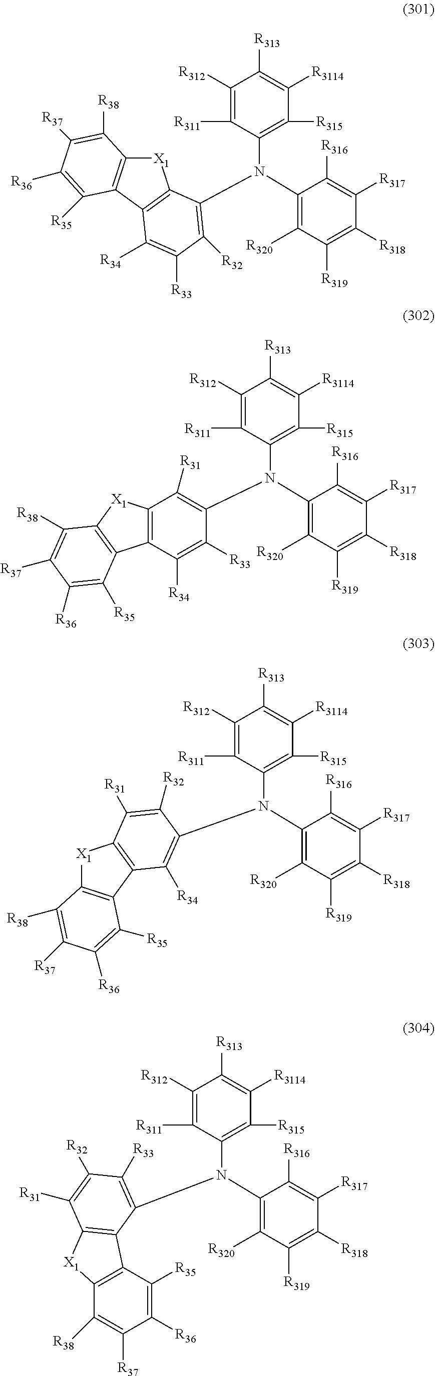 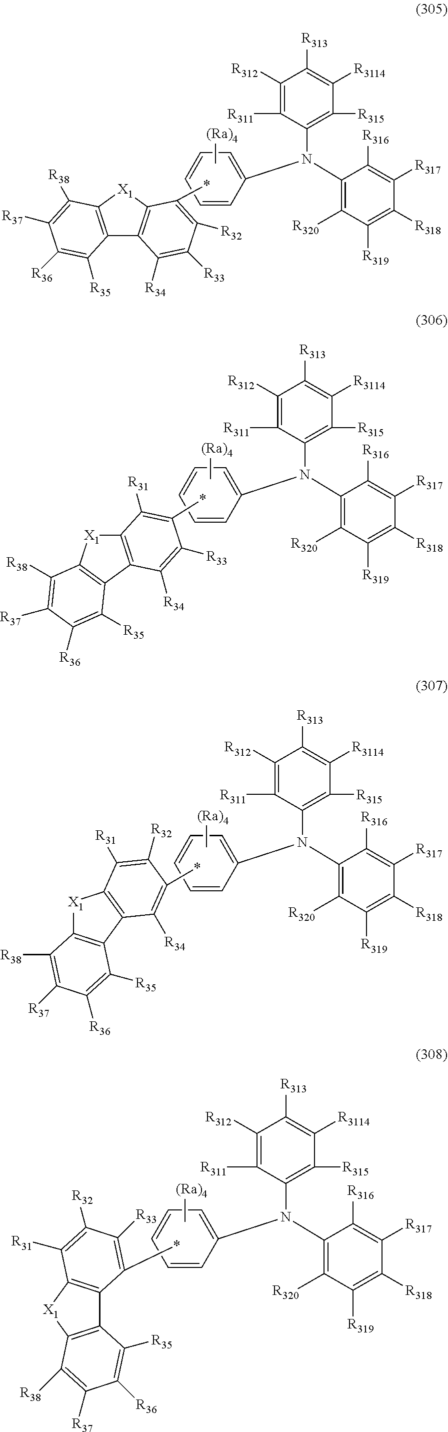 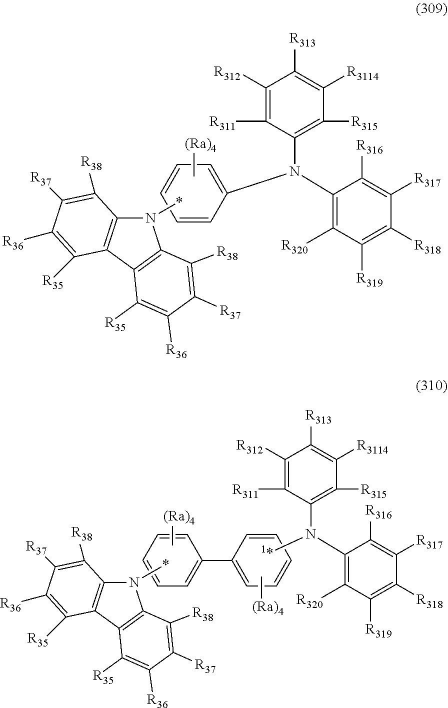
where, in the formulae (301) to (310):
X₁ and R₃₁ to R₃₈ each independently represent the same as X₁ and R₃₁ to R₃₈ in the formula (3A); Ra each independently represent the same as Ra in the formula (32);
a combination of adjacent two or more of R311 to R315 are mutually bonded to form a substituted or unsubstituted monocyclic ring, mutually bonded to form a substituted or unsubstituted fused ring, or not mutually bonded;
a combination of adjacent two or more of R316 to R320 are mutually bonded to form a substituted or unsubstituted monocyclic ring, mutually bonded to form a substituted or unsubstituted fused ring, or not mutually bonded; and
R₃₁₁ to R₃₂₀ forming neither the substituted or unsubstituted monocyclic ring nor the substituted or unsubstituted fused ring each independently represent the same as Ra in the formula (32); * each represent a bonding position to a carbon atom in a six-membered ring having Ra; and 1* represents a bonding position to a carbon atom in a six-membered ring having Ra.

20. The organic electroluminescence device according to claim 16, wherein R₃₁ to R₃₈, R₄₁ to R₅₀, R₃₀₁ to R₃₀₃ and Ra are each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

21. The organic electroluminescence device according to claim 16, wherein R₃₁ to R₃₈ and R₄₁ to R₅₀ are each independently a hydrogen atom, or a substituted or unsubstituted phenyl group.

22. The organic electroluminescence device according to claim 16, wherein R₃₁ to R₃₈ and R₄₁ to R₅₀ are each a hydrogen atom.

23. The organic electroluminescence device according to claim 1, wherein the emitting layer comprises no metal complex.

24. An electronic device, comprising:
the organic electroluminescence device according to claim 1.

25. An organic electroluminescence display device, comprising:
an anode and a cathode arranged opposite each other;
a blue-emitting organic EL device as a blue pixel;
a green-emitting organic EL device as a green pixel; and
a red-emitting organic EL device as a red pixel, wherein
the green pixel comprises, as the green-emitting organic EL device, the organic electroluminescence device according to claim 1,
the green-emitting organic EL device comprises a green emitting layer as the emitting layer and the first layer disposed between the green emitting layer and the anode,
the blue-emitting organic EL device comprises a blue emitting layer disposed between the anode and the cathode and a blue organic layer disposed between the blue emitting layer and the anode, and
the red-emitting organic EL device comprises a red emitting layer disposed between the anode and the cathode and a red organic layer disposed between the red emitting layer and the anode.

26. The organic electroluminescence display device according to claim 25, wherein a common laver is provided between the anode and the blue organic layer, the first laver, and
wherein the red organic layer in a shared manner across the blue-emitting organic EL device, the green-emitting organic EL device, and the red-emitting organic EL device.

27. The organic electroluminescence display device according to claim 26, wherein the common layer is adjacent to each of the blue organic layer, the first layer, and the red organic layer.

28. An electronic device comprising the organic electroluminescence display device according to claim 25.
